(19) United States
(12) Patent Application Publication
(10) Pub. No.: US 2015/0214259 A1
(43) Pub. Date: Jul. 30, 2015

(54) PHOTOELECTRIC CONVERTER AND METHOD FOR MANUFACTURING THE SAME

(71) Applicant: ROHM CO., LTD., Kyoto (JP)

(72) Inventors: Takamitsu YAMANAKA, Kyoto (JP); Goro NAKATANI, Kyoto (JP); Osamu MATSUSHIMA, Kyoto (JP); Kenichi MIYAZAKI, Kyoto (JP)

(73) Assignee: ROHM CO., LTD., Kyoto (JP)

(21) Appl. No.: 14/659,673

(22) Filed: Mar. 17, 2015

Related U.S. Application Data
(62) Division of application No. 13/393,631, filed on May 15, 2012.

(30) Foreign Application Priority Data
Sep. 1, 2009 (JP) 2009-201974
Sep. 1, 2009 (JP) 2009-201975
Sep. 1, 2009 (JP) 2009-201976
Sep. 1, 2009 (JP) 2009-201977
Sep. 1, 2009 (JP) 2009-201978
Sep. 1, 2009 (JP) 2009-201979
Sep. 1, 2009 (JP) 2009-201980
Nov. 11, 2009 (JP) 2009-258147
Nov. 11, 2009 (JP) 2009-258148
Nov. 18, 2009 (JP) 2009-262765

(51) Int. Cl. H01L 27/146; H01L 31/0224; H01L 31/032

(52) U.S. Cl. CPC H01L 27/1461; H01L 31/0322; H01L 31/022466; H01L 27/14643; H01L 27/14636

(57) ABSTRACT

A photoelectric converter according to the present invention includes an insulating layer, a plurality of lower electrodes that are mutually spaced and disposed on the insulating layer, a photoabsorption layer made of a chalcopyrite compound semiconductor and formed to cover the plurality of lower electrodes all together, and a transparent conductive film formed to cover the photoabsorption layer. Variation of sensitivity among pixels due to influence (damage) by etching of the photoabsorption layer is thereby eliminated and a pixel aperture ratio can be made 100%.

### CROSS REFERENCE TO RELATED APPLICATION

This application is a divisional of application Ser. No. 13/393,631, filed on May 15, 2012. Furthermore, this application claims the benefit of priority of PCT/JP2010/064797, filed on Aug. 31, 2010, and Japanese applications 2009-201974, 2009-201975, 2009-201976, 2009-201977, 2009-201978, 2009-201979, and 2009-201980, filed on Sep. 1, 2009, 2009-258147 and 2009-258148, filed on Nov. 11, 2009, and 2009-262765, filed on Nov. 18, 2009. The disclosures of these prior U.S. and Japanese applications are incorporated herein by reference.

### FIELD OF THE ART

The present invention relates to a photoelectric converter that uses a as a material of a photoabsorption layer and a method for manufacturing the same.

### BACKGROUND ART

CIGS (Cu(In,Ga)Se₂) and other chalcopyrite compound semiconductors have high optical absorption coefficients and are favorable as materials of photoabsorption layers of image sensors, solar cells, and other photoelectric converters.

For example, a photoelectric converter that includes a soda lime glass substrate, a lower electrode made of a Mo film, a photoabsorption layer made of a CIGS thin film formed on the lower electrode, a buffer layer (window layer) made of a CdS film formed on the photoabsorption layer, a light transmitting electrode layer made of a ZnO film formed on the buffer layer, and extraction electrodes respectively connected to the lower electrode and the light transmitting electrode layer has been proposed (see, for example, Patent Document 1).

### PRIOR ART DOCUMENT(S)

### Patent Document(s)

Patent Document 1: Japanese Published Unexamined Patent Application No. 2007-123721

### SUMMARY OF THE INVENTION

### Object(s) of the Invention

With the photoelectric converter, each single pixel is an independent element, a plurality of such elements are arranged together, and thus preferably, variation of sensitivity among the pixels is made as small as possible. Also, to increase the sensitivity of each pixel, it is desirable to increase a proportion (pixel aperture ratio) of an area (light receiving area) of a pn junction with respect to a pixel area.

An object of the present invention is to provide a photoelectric converter without variation of sensitivity among pixels due to influence (damage) by etching of the photoabsorption layer and having a pixel aperture ratio of 100%, and a method for manufacturing the same.

### Means for Solving the Problem

A photoelectric converter according to the present invention for achieving the above object includes an insulating layer, a plurality of lower electrodes that are mutually spaced and disposed on the insulating layer, a photoabsorption layer made of a chalcopyrite compound semiconductor and formed to cover the plurality of lower electrodes all together, and a transparent conductive film formed to cover the photoabsorption layer.

With the present photoelectric converter, the plurality of mutually-spaced lower electrodes disposed on the insulating layer are covered all together by the photoabsorption layer made of the chalcopyrite compound semiconductor. That is, the photoabsorption layer made of the chalcopyrite compound semiconductor is not cut and divided so as to cover each lower electrode individually. In other words, the photoabsorption layer made of the chalcopyrite compound semiconductor is not cut and divided according to each pixel that includes a single lower electrode but is provided in common to a plurality of pixels. The transparent conductive film is formed on the photoabsorption layer so as to cover the photoabsorption layer.

The photoabsorption layer is not cut and divided according to each pixel and variation of sensitivity among the pixels is thus not influenced by damage due to dry etching of the photoabsorption layer.

Also, grooves for cutting and dividing the photoabsorption layer are not formed and an isolation film for isolating the photoabsorption layer according to each pixel is not provided because the photoabsorption layer is not cut and divided according to each pixel. A pixel aperture ratio (pn junction area/pixel area) is thus 100%. A large number of carriers can thereby be generated even with weak light and dramatic improvement of sensitivity can be achieved.

Further, a shrinkage cavity does not form during forming of the transparent conductive film because grooves for cutting and dividing the photoabsorption layer are not formed. Degradation with time of the transparent conductive film can thus be prevented and reliability can be improved. When in the case of forming the photoabsorption layer in a cut and divided manner, the transparent conductive film cannot be formed so as to completely fill a groove in the isolation film that forms between mutually adjacent photoabsorption layers, a gap forms on the groove and such a gap is called a shrinkage cavity. When such a shrinkage cavity forms, the shrinkage cavity causes degradation with time of the transparent conductive film even if a topmost surface of the photoelectric converter is covered by a top surface protective film.

Also, a step of forming the isolation film is unnecessary and thus a manufacturing process is made simpler than that of a conventional photoelectric converter and time and cost required for manufacture can be reduced.

The chalcopyrite compound semiconductor that is the material of the photoabsorption layer may be CIGS (Cu(In,Ga)Se₂). In this case, the photoabsorption layer preferably has a thickness of no less than 1.0 μm and no more than 1.4 μm. CIGS has an optical absorption coefficient of 1 μm⁻¹ and thus if the thickness of the photoabsorption layer is no less than 1.0 μm, light can be absorbed adequately by the photoabsorption layer and satisfactory photoelectric conversion can be achieved. Meanwhile, by making the thickness of the photoabsorption layer no more than 1.4 μm, an electric field in a direction of a normal (vertical direction) to an interface of the photoabsorption layer and the transparent conductive film (pn junction surface) can be strengthened. By the electric field in the vertical direction being strengthened, carriers generated by the photoelectric conversion are satisfactorily taken into the lower electrode disposed at the portion at which the carriers are generated. Occurrence of so-called crosstalk, in which carriers become mixed in the lower electrode at the portion of carrier generation and an adjacent lower electrode, can thus be prevented.

The photoelectric converter with such a structure can be manufactured by a method for manufacture that includes the following steps A1 to A5.

A1. A step of forming an insulating layer.

A2. A step of laminating an electrode material layer, made of the material of lower electrodes, on the insulating layer.

A3. A step of forming a plurality of lower electrodes, which are mutually spaced and disposed on the insulating layer, by selectively removing the electrode material layer by photolithography and etching.

A4. A step of forming a photoabsorption layer, made of CIGS and having a thickness of no less than 1.0 μm and no more than 1.4 μm, on the insulating layer by molecular beam epitaxy method so as to cover the plurality of lower electrodes all together.

A5. A step of forming a transparent conductive film so as to cover the photoabsorption layer.

The lower electrodes may be disposed in a matrix with adjacent lower electrodes being spaced by equal intervals. In this case, the interval between mutually adjacent lower electrodes is preferably no less than three times a film thickness of the photoabsorption layer. The strength of the vertical direction electric field is thereby made no less than three times the strength of an electric field in a horizontal direction orthogonal to the vertical direction. In other words, the strength of the horizontal direction electric field is no more than ⅓ the strength of the vertical direction electric field. Occurrence of crosstalk can thus be prevented.

Also, in a case where the lower electrodes are disposed in a matrix, an interval between a lower electrode disposed at an outermost periphery and a side surface of the photoabsorption layer is preferably no less than 50 μm and no more than 100 μm. The side surface of the photoabsorption layer is damaged by dry etching during processing of the photoabsorption layer, and a dark current may be generated due to the damage. By setting the interval between the lower electrode disposed at the outermost periphery and the side surface of the photoabsorption layer to no less than 50 μm, the dark current can be prevented from being taken into the lower electrode disposed at the outermost periphery. Also, the lower electrode exhibits an anchor effect of preventing peeling of the photoabsorption layer from the insulating layer. By setting the interval between the lower electrode disposed at the outermost periphery and the side surface of the photoabsorption layer to no more than 100 μm, the anchor effect of the lower electrode can be secured and peeling of the photoabsorption layer from the insulating layer can be prevented.

A high-resistance buffer layer made of cadmium sulfide (CdS) may be formed between the photoabsorption layer and the transparent conductive film.

Also, wirings may be disposed at positions opposing the lower electrodes across the insulating layer and vias connecting the wirings and the lower electrodes may be formed penetratingly through the insulating layer. In this case, the lower electrode and the vias are preferably made of the same material. The material may be tungsten. If the material of the lower electrode and the material of the vias are the same, the lower electrode and the vias can be formed in the same step. Thus, a step of polishing a deposition layer of the via material by a CMP method and a step of forming a film made of the material of the lower electrode by a sputtering method, which are deemed to be required in the manufacture of the conventional photoelectric converter, can be omitted. Consequently, the time and cost required for manufacture can be reduced.

The photoelectric converter of the present structure may be manufactured by a manufacturing method including the following steps A6 and A7 in addition to the steps A1 to A5.

A6. A step of forming a plurality of wirings before forming the insulating layer.

A7. A step of forming via holes penetrating through the insulating layer in a thickness direction above the respective wirings before laminating the electrode material layer.

In the step of laminating the electrode material layer, the via holes are completely filled with the material of the lower electrodes. In the step of forming the lower electrodes, vias connected to the respective lower electrodes are formed along with the lower electrodes. Reliable connection of the lower electrodes and the vias can thereby be achieved and reliability of electrical connection of the lower electrodes and the vias can be improved.

### BRIEF DESCRIPTION OF THE DRAWINGS

FIG. 1 is a schematic plan view of an image sensor according to a preferred embodiment of a first aspect of the present invention.

FIG. 2 is a schematic sectional view of the image sensor taken along sectioning line II-II in FIG. 1.

FIG. 3A is a schematic sectional view of a manufacturing process of the image sensor shown in FIG. 2.

FIG. 3B is a schematic sectional view of a step subsequent to that of FIG. 3A.

FIG. 3C is a schematic sectional view of a step subsequent to that of FIG. 3B.

FIG. 3D is a schematic sectional view of a step subsequent to that of FIG. 3C.

FIG. 3E is a schematic sectional view of a step subsequent to that of FIG. 3D.

FIG. 3F is a schematic sectional view of a step subsequent to that of FIG. 3E.

FIG. 3G is a schematic sectional view of a step subsequent to that of FIG. 3F.

FIG. 3H is a schematic sectional view of a step subsequent to that of FIG. 3G.

FIG. 3I is a schematic sectional view of a step subsequent to that of FIG. 3H.

FIG. 4 is a diagram for describing resist patterns (masks) used in the manufacturing process of the image sensor shown in FIG. 2.

FIG. 5A is a schematic sectional view of a manufacturing process of an image sensor.

FIG. 5B is a schematic sectional view of a step subsequent to that of FIG. 5A.

FIG. 5C is a schematic sectional view of a step subsequent to that of FIG. 5B.

FIG. 5D is a schematic sectional view of a step subsequent to that of FIG. 5C.

FIG. 5E is a schematic sectional view of a step subsequent to that of FIG. 5D.

FIG. 5F is a schematic sectional view of a step subsequent to that of FIG. 5E.

FIG. 5G is a schematic sectional view of a step subsequent to that of FIG. 5F.

FIG. 5H is a schematic sectional view of a step subsequent to that of FIG. 5G.

FIG. 5I is a schematic sectional view of a step subsequent to that of FIG. 5H.

FIG. 5J is a schematic sectional view of a step subsequent to that of FIG. 5I.

FIG. 5K is a schematic sectional view of a step subsequent to that of FIG. 5J.

FIG. 6 is a diagram for describing resist patterns (masks) used in the manufacturing process of the image sensor shown in FIG. 5K.

FIG. 7 is a diagram (photograph) of a result of image pickup by an image sensor of Example 1.

FIG. 8 is a diagram (photograph) of a result of image pickup by an image sensor of Example 2.

FIG. 9 is a diagram (photograph) of a result of image pickup by an image sensor of Example 3.

FIG. 10 is a diagram (photograph) of a result of image pickup by an image sensor of Example 4.

FIG. 11 is a diagram (photograph) of a result of image pickup by an image sensor of Comparative Example 1.

FIG. 12 is a schematic plan view of an image sensor according to a preferred embodiment of a second aspect of the present invention.

FIG. 13 is a schematic sectional view of the image sensor taken along sectioning line II-II in FIG. 12.

FIG. 14A is a schematic sectional view of a manufacturing process of the image sensor shown in FIG. 13.

FIG. 14B is a schematic sectional view of a step subsequent to that of FIG. 14A.

FIG. 14C is a schematic sectional view of a step subsequent to that of FIG. 14B.

FIG. 14D is a schematic sectional view of a step subsequent to that of FIG. 14C.

FIG. 14E is a schematic sectional view of a step subsequent to that of FIG. 14D.

FIG. 14F is a schematic sectional view of a step subsequent to that of FIG. 14E.

FIG. 14G is a schematic sectional view of a step subsequent to that of FIG. 14F.

FIG. 14H is a schematic sectional view of a step subsequent to that of FIG. 14G.

FIG. 14I is a schematic sectional view of a step subsequent to that of FIG. 14H.

FIG. 14J is a schematic sectional view of a step subsequent to that of FIG. 14I.

FIG. 14K is a schematic sectional view of a step subsequent to that of FIG. 14J.

FIG. 14L is a schematic sectional view of a step subsequent to that of FIG. 14K.

FIG. 14M is a schematic sectional view of a step subsequent to that of FIG. 14L.

FIG. 14N is a schematic sectional view of a step subsequent to that of FIG. 14M.

FIG. 14O is a schematic sectional view of a step subsequent to that of FIG. 14N.

FIG. 14P is a schematic sectional view of a step subsequent to that of FIG. 14O.

FIG. 14Q is a schematic sectional view of a step subsequent to that of FIG. 14P.

FIG. 14R is a schematic sectional view of a step subsequent to that of FIG. 14Q.

FIG. 15 is a diagram for describing resist patterns (masks) used in the manufacturing process of the image sensor shown in FIG. 13.

FIG. 16 is a schematic sectional view of a modification example of the image sensor shown in FIG. 13.

FIG. 17 is a schematic plan view of an image sensor according to a preferred embodiment of a third aspect of the present invention.

FIG. 18 is a schematic sectional view of the image sensor taken along sectioning line II-II in FIG. 17.

FIG. 19A is a schematic sectional view of a manufacturing process of the image sensor shown in FIG. 18.

FIG. 19B is a schematic sectional view of a step subsequent to that of FIG. 19A.

FIG. 19C is a schematic sectional view of a step subsequent to that of FIG. 19B.

FIG. 19D is a schematic sectional view of a step subsequent to that of FIG. 19C.

FIG. 19E is a schematic sectional view of a step subsequent to that of FIG. 19D.

FIG. 19F is a schematic sectional view of a step subsequent to that of FIG. 19E.

FIG. 19G is a schematic sectional view of a step subsequent to that of FIG. 19F.

FIG. 19H is a schematic sectional view of a step subsequent to that of FIG. 19G.

FIG. 19I is a schematic sectional view of a step subsequent to that of FIG. 19H.

FIG. 19J is a schematic sectional view of a step subsequent to that of FIG. 19I.

FIG. 19K is a schematic sectional view of a step subsequent to that of FIG. 19J.

FIG. 19L is a schematic sectional view of a step subsequent to that of FIG. 19K.

FIG. 19M is a schematic sectional view of a step subsequent to that of FIG. 19L.

FIG. 19N is a schematic sectional view of a step subsequent to that of FIG. 19M.

FIG. 19O is a schematic sectional view of a step subsequent to that of FIG. 19N.

FIG. 19P is a schematic sectional view of a step subsequent to that of FIG. 19O.

FIG. 20 is a diagram for describing resist patterns (masks) used in the manufacturing process of the image sensor shown in FIG. 18.

FIG. 21 is a schematic plan view of an image sensor according to a preferred embodiment of a fourth aspect of the present invention.

FIG. 22 is a schematic sectional view of the image sensor taken along sectioning line II-II in FIG. 21.

FIG. 23A is a schematic sectional view of a manufacturing process of the image sensor shown in FIG. 22.

FIG. 23B is a schematic sectional view of a step subsequent to that of FIG. 23A.

FIG. 23C is a schematic sectional view of a step subsequent to that of FIG. 23B.

FIG. 23D is a schematic sectional view of a step subsequent to that of FIG. 23C.

FIG. 23E is a schematic sectional view of a step subsequent to that of FIG. 23D.

FIG. 23F is a schematic sectional view of a step subsequent to that of FIG. 23E.

FIG. 23G is a schematic sectional view of a step subsequent to that of FIG. 23F.

FIG. 23H is a schematic sectional view of a step subsequent to that of FIG. 23G.

FIG. 23I is a schematic sectional view of a step subsequent to that of FIG. 23h.

FIG. 23J is a schematic sectional view of a step subsequent to that of FIG. 23I.

FIG. 23K is a schematic sectional view of a step subsequent to that of FIG. 23J.

FIG. 23L is a schematic sectional view of a step subsequent to that of FIG. 23K.

FIG. 23M is a schematic sectional view of a step subsequent to that of FIG. 23L.

FIG. 23N is a schematic sectional view of a step subsequent to that of FIG. 23M.

FIG. 24 is a diagram for describing resist patterns (masks) used in the manufacturing process of the image sensor shown in FIG. 22.

FIG. 25 is a schematic plan view of an image sensor according to a preferred embodiment of a fifth aspect of the present invention.

FIG. 26 is a schematic sectional view of the image sensor taken along sectioning line II-II in FIG. 25.

FIG. 27A is a schematic sectional view of a manufacturing process of the image sensor shown in FIG. 26.

FIG. 27B is a schematic sectional view of a step subsequent to that of FIG. 27A.

FIG. 27C is a schematic sectional view of a step subsequent to that of FIG. 27B.

FIG. 27D is a schematic sectional view of a step subsequent to that of FIG. 27C.

FIG. 27E is a schematic sectional view of a step subsequent to that of FIG. 27D.

FIG. 27F is a schematic sectional view of a step subsequent to that of FIG. 27E.

FIG. 27G is a schematic sectional view of a step subsequent to that of FIG. 27F.

FIG. 27H is a schematic sectional view of a step subsequent to that of FIG. 27G.

FIG. 27I is a schematic sectional view of a step subsequent to that of FIG. 27H.

FIG. 27J is a schematic sectional view of a step subsequent to that of FIG. 27I.

FIG. 27K is a schematic sectional view of a step subsequent to that of FIG. 27J.

FIG. 27L is a schematic sectional view of a step subsequent to that of FIG. 27K.

FIG. 27M is a schematic sectional view of a step subsequent to that of FIG. 27L.

FIG. 27N is a schematic sectional view of a step subsequent to that of FIG. 27M.

FIG. 27O is a schematic sectional view of a step subsequent to that of FIG. 27N.

FIG. 28 is a diagram for describing resist patterns (masks) used in the manufacturing process of the image sensor shown in FIG. 26.

FIG. 29 is a schematic sectional view of a first modification example of the image sensor of FIG. 26.

FIG. 30 is a schematic sectional view of a second modification example of the image sensor of FIG. 26.

FIG. 31 is a schematic sectional view of a third modification example of the image sensor of FIG. 26.

FIG. 32 is a schematic plan view of an image sensor according to a first preferred embodiment of a sixth aspect of the present invention.

FIG. 33 is a schematic sectional view of the image sensor taken along sectioning line II-II in FIG. 32.

FIG. 34A is a schematic sectional view of a manufacturing process of the image sensor shown in FIG. 33.

FIG. 34B is a schematic sectional view of a step subsequent to that of FIG. 34A.

FIG. 34C is a schematic sectional view of a step subsequent to that of FIG. 34B.

FIG. 34D is a schematic sectional view of a step subsequent to that of FIG. 34C.

FIG. 34E is a schematic sectional view of a step subsequent to that of FIG. 34D.

FIG. 34F is a schematic sectional view of a step subsequent to that of FIG. 34E.

FIG. 34G is a schematic sectional view of a step subsequent to that of FIG. 34F.

FIG. 34H is a schematic sectional view of a step subsequent to that of FIG. 34G.

FIG. 34I is a schematic sectional view of a step subsequent to that of FIG. 34H.

FIG. 34J is a schematic sectional view of a step subsequent to that of FIG. 34I.

FIG. 34K is a schematic sectional view of a step subsequent to that of FIG. 34J.

FIG. 34L is a schematic sectional view of a step subsequent to that of FIG. 34K.

FIG. 34M is a schematic sectional view of a step subsequent to that of FIG. 34L.

FIG. 34N is a schematic sectional view of a step subsequent to that of FIG. 34M.

FIG. 35 is a diagram for describing resist patterns (masks) used in the manufacturing process of the image sensor shown in FIG. 33.

FIG. 36 is a schematic plan view of an image sensor according to a second preferred embodiment of the sixth aspect of the present invention.

FIG. 37 is a schematic sectional view of the image sensor taken along sectioning line II-II in FIG. 36.

FIG. 38A is a schematic sectional view of a manufacturing process of the image sensor shown in FIG. 37.

FIG. 38B is a schematic sectional view of a step subsequent to that of FIG. 38A.

FIG. 38C is a schematic sectional view of a step subsequent to that of FIG. 38B.

FIG. 38D is a schematic sectional view of a step subsequent to that of FIG. 38C.

FIG. 38E is a schematic sectional view of a step subsequent to that of FIG. 38D.

FIG. 38F is a schematic sectional view of a step subsequent to that of FIG. 38E.

FIG. 38G is a schematic sectional view of a step subsequent to that of FIG. 38F.

FIG. 38H is a schematic sectional view of a step subsequent to that of FIG. 38G.

FIG. 38I is a schematic sectional view of a step subsequent to that of FIG. 38H.

FIG. 38J is a schematic sectional view of a step subsequent to that of FIG. 38I.

FIG. 38K is a schematic sectional view of a step subsequent to that of FIG. 38J.

FIG. 38L is a schematic sectional view of a step subsequent to that of FIG. 38K.

FIG. 38M is a schematic sectional view of a step subsequent to that of FIG. 38L.

FIG. 38N is a schematic sectional view of a step subsequent to that of FIG. 38M.

FIG. 38O is a schematic sectional view of a step subsequent to that of FIG. 38N.

FIG. 39A is a schematic plan view of a pad forming region in a first modification example of the image sensor of FIG. 33.

FIG. 39B is a schematic sectional view of the pad forming region taken along sectioning line VIIIB-VIIIB in FIG. 39A.

FIG. 40A is a schematic plan view of a pad forming region in a second modification example of the image sensor of FIG. 33.

FIG. 40B is a schematic sectional view of the pad forming region taken along sectioning line IXB-IXB in FIG. 40A.

FIG. 41A is a schematic plan view of a pad forming region in a third modification example of the image sensor of FIG. 33.

FIG. 41B is a schematic sectional view of the pad forming region taken along sectioning line XB-XB in FIG. 41A.

FIG. 42A is a schematic plan view of a pad forming region in a fourth modification example of the image sensor of FIG. 33.

FIG. 42B is a schematic sectional view of the pad forming region taken along sectioning line XIB-XIB in FIG. 42A.

FIG. 43 is a schematic sectional view of a photoelectric converter according to a preferred embodiment of a seventh aspect of the present invention.

FIG. 44A is a schematic sectional view of state in a middle of manufacture of the image sensor shown in FIG. 43.

FIG. 44B is a schematic sectional view of a step subsequent to that of FIG. 44A.

FIG. 44C is a schematic sectional view of a step subsequent to that of FIG. 44B.

FIG. 44D is a schematic sectional view of a step subsequent to that of FIG. 44C.

FIG. 44E is a schematic sectional view of a step subsequent to that of FIG. 44D.

FIG. 44F is a schematic sectional view of a step subsequent to that of FIG. 44E.

FIG. 44G is a schematic sectional view of a step subsequent to that of FIG. 44F.

FIG. 44H is a schematic sectional view of a step subsequent to that of FIG. 44G.

FIG. 44I is a schematic sectional view of a step subsequent to that of FIG. 44H.

FIG. 44J is a schematic sectional view of a step subsequent to that of FIG. 44I.

FIG. 44K is a schematic sectional view of a step subsequent to that of FIG. 44J.

FIG. 44L is a schematic sectional view of a step subsequent to that of FIG. 44K.

FIG. 44M is a schematic sectional view of a step subsequent to that of FIG. 44L.

FIG. 44N is a schematic sectional view of a step subsequent to that of FIG. 44M.

FIG. 44O is a schematic sectional view of a step subsequent to that of FIG. 44N.

FIG. 44P is a schematic sectional view of a step subsequent to that of FIG. 44O.

FIG. 44Q is a schematic sectional view of a step subsequent to that of FIG. 44P.

FIG. 44R is a schematic sectional view of a step subsequent to that of FIG. 44Q.

FIG. 45 is a schematic plan view of an image sensor according to a preferred embodiment of an eighth aspect of the present invention.

FIG. 46 is a schematic sectional view of the image sensor taken along sectioning line II-II in FIG. 45.

FIG. 47A is a schematic sectional view of a manufacturing process of the image sensor shown in FIG. 46.

FIG. 47B is a schematic sectional view of a step subsequent to that of FIG. 47A.

FIG. 47C is a schematic sectional view of a step subsequent to that of FIG. 47B.

FIG. 47D is a schematic sectional view of a step subsequent to that of FIG. 47C.

FIG. 47E is a schematic sectional view of a step subsequent to that of FIG. 47D.

FIG. 47F is a schematic sectional view of a step subsequent to that of FIG. 47E.

FIG. 47G is a schematic sectional view of a step subsequent to that of FIG. 47F.

FIG. 47H is a schematic sectional view of a step subsequent to that of FIG. 47G.

FIG. 47I is a schematic sectional view of a step subsequent to that of FIG. 47H.

FIG. 47J is a schematic sectional view of a step subsequent to that of FIG. 47I.

FIG. 47K is a schematic sectional view of a step subsequent to that of FIG. 47J.

FIG. 47L is a schematic sectional view of a step subsequent to that of FIG. 47K.

FIG. 47M is a schematic sectional view of a step subsequent to that of FIG. 47L.

FIG. 47N is a schematic sectional view of a step subsequent to that of FIG. 47M.

FIG. 47O is a schematic sectional view of a step subsequent to that of FIG. 47N.

FIG. 47P is a schematic sectional view of a step subsequent to that of FIG. 47O.

FIG. 47Q is a schematic sectional view of a step subsequent to that of FIG. 47P.

FIG. 47R is a schematic sectional view of a step subsequent to that of FIG. 47Q.

FIG. 47S is a schematic sectional view of a step subsequent to that of FIG. 47R.

FIG. 48 is a diagram for describing resist patterns (masks) used in the manufacturing process of the image sensor shown in FIG. 46.

FIG. 49 is a schematic plan view of an image sensor according to a first preferred embodiment of a ninth aspect of the present invention.

FIG. 50 is a schematic sectional view of the image sensor taken along sectioning line II-II in FIG. 49.

FIG. 51A is a schematic sectional view of a manufacturing process of the image sensor shown in FIG. 50.

FIG. 51B is a schematic sectional view of a step subsequent to that of FIG. 51A.

FIG. 51C is a schematic sectional view of a step subsequent to that of FIG. 51B.

FIG. 51D is a schematic sectional view of a step subsequent to that of FIG. 51C.

FIG. 51E is a schematic sectional view of a step subsequent to that of FIG. 51D.

FIG. 51F is a schematic sectional view of a step subsequent to that of FIG. 51E.

FIG. 51G is a schematic sectional view of a step subsequent to that of FIG. 51F.

FIG. 51H is a schematic sectional view of a step subsequent to that of FIG. 51G.

FIG. 51I is a schematic sectional view of a step subsequent to that of FIG. 51H.

FIG. 51J is a schematic sectional view of a step subsequent to that of FIG. 51I.

FIG. 51K is a schematic sectional view of a step subsequent to that of FIG. 51J.

FIG. 51L is a schematic sectional view of a step subsequent to that of FIG. 51K.

FIG. 51M is a schematic sectional view of a step subsequent to that of FIG. 51L.

FIG. 51N is a schematic sectional view of a step subsequent to that of FIG. 51M.

FIG. 51O is a schematic sectional view of a step subsequent to that of FIG. 51N.

FIG. 51P is a schematic sectional view of a step subsequent to that of FIG. 51O.

FIG. 51Q is a schematic sectional view of a step subsequent to that of FIG. 51P.

FIG. 51R is a schematic sectional view of a step subsequent to that of FIG. 51Q.

FIG. 51S is a schematic sectional view of a step subsequent to that of FIG. 51R.

FIG. 52 is a diagram for describing resist patterns (masks) used in the manufacturing process of the image sensor shown in FIG. 50.

FIG. 53 is a schematic sectional view of an image sensor according to a second preferred embodiment of the ninth aspect of the present invention.

FIG. 54A is a schematic sectional view of a manufacturing process of the image sensor shown in FIG. 53.

FIG. 54B is a schematic sectional view of a step subsequent to that of FIG. 54A.

FIG. 54C is a schematic sectional view of a step subsequent to that of FIG. 54B.

FIG. 54D is a schematic sectional view of a step subsequent to that of FIG. 54C.

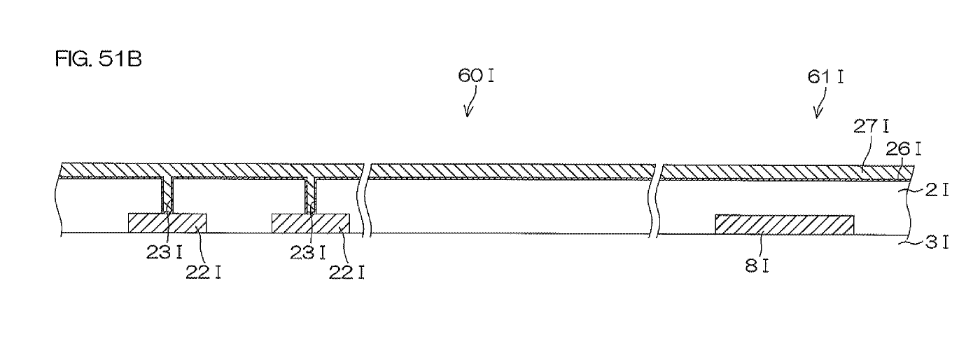

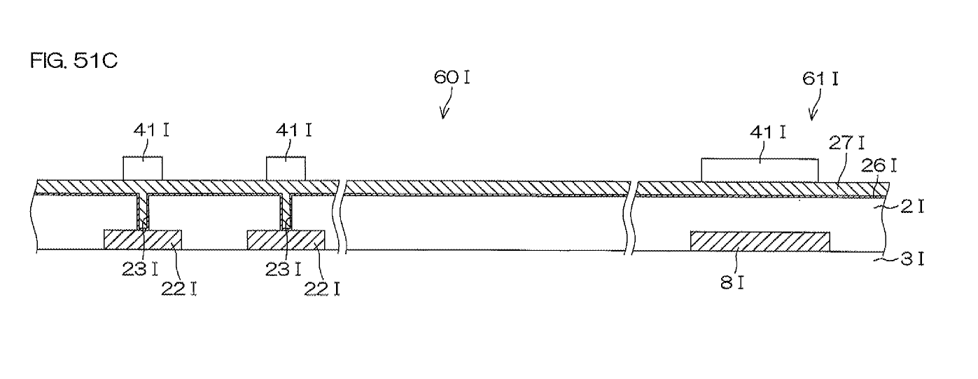

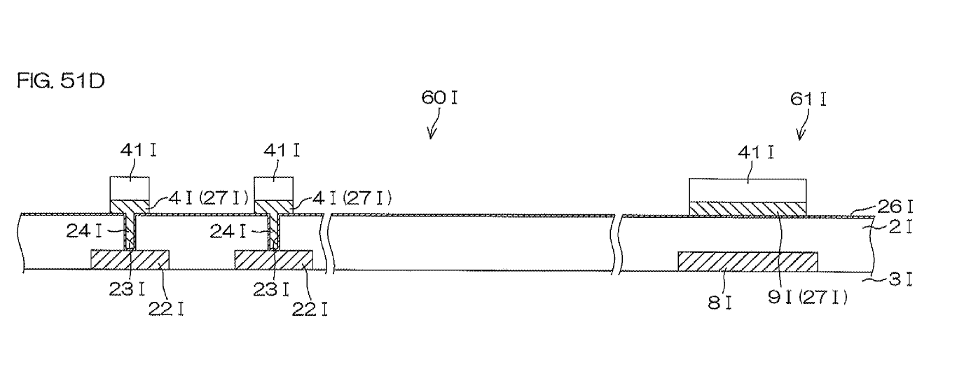

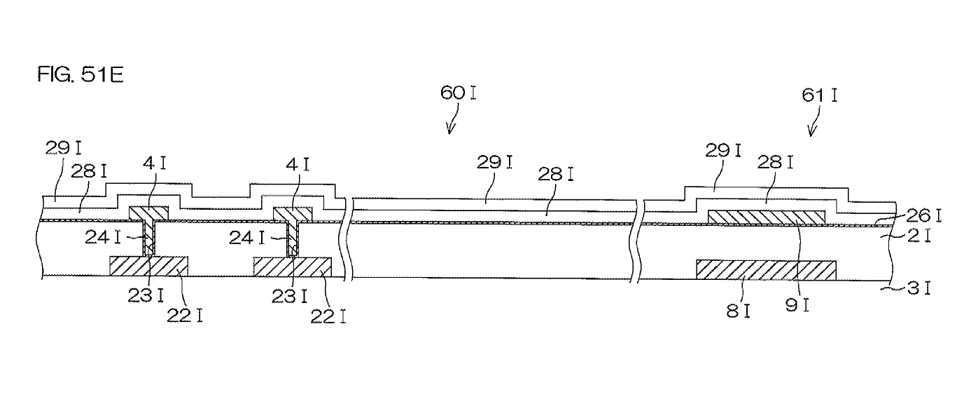

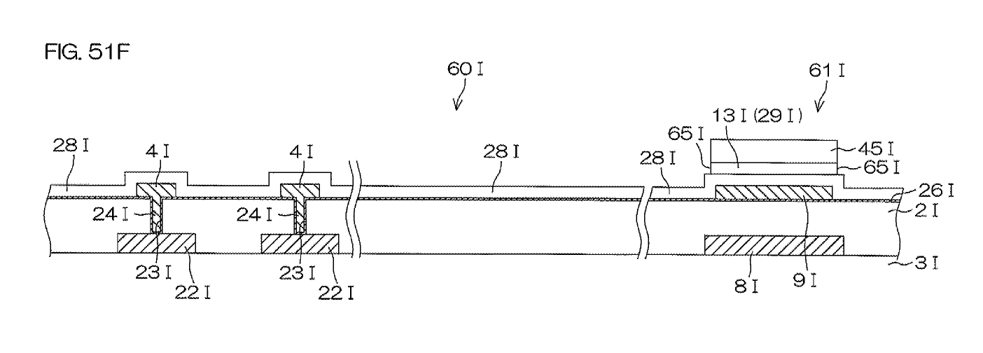

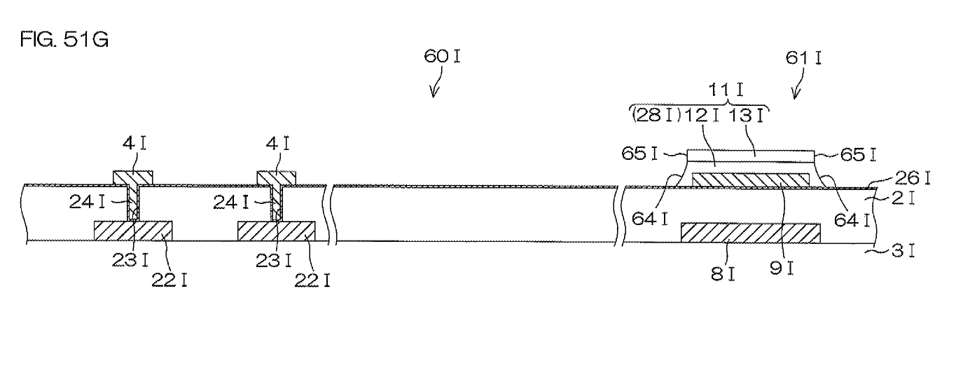

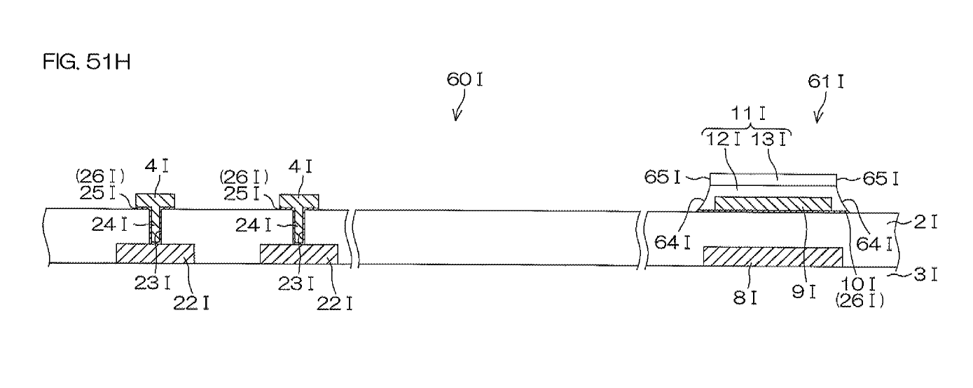

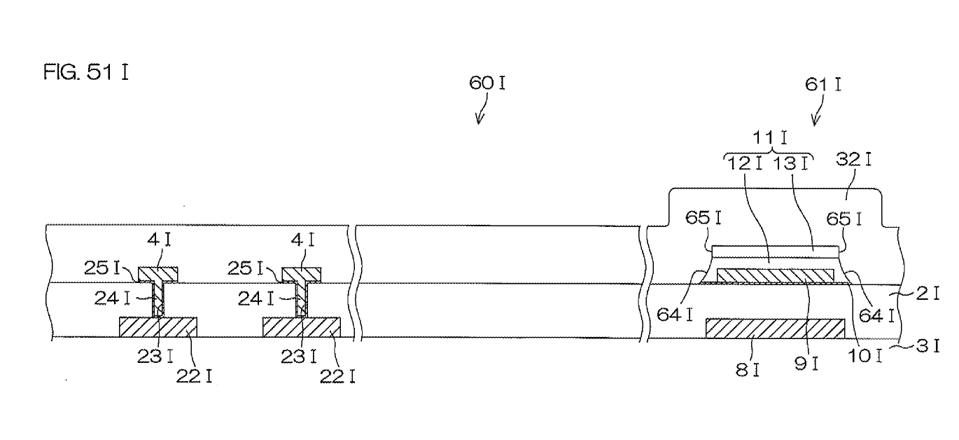

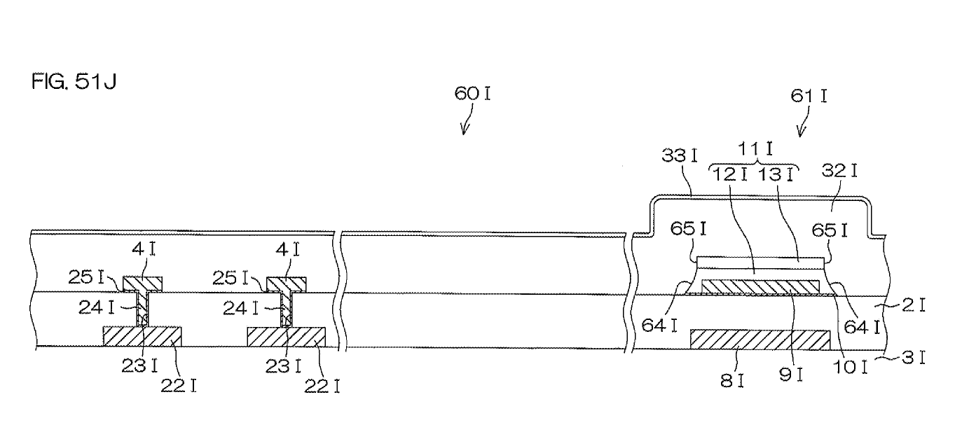

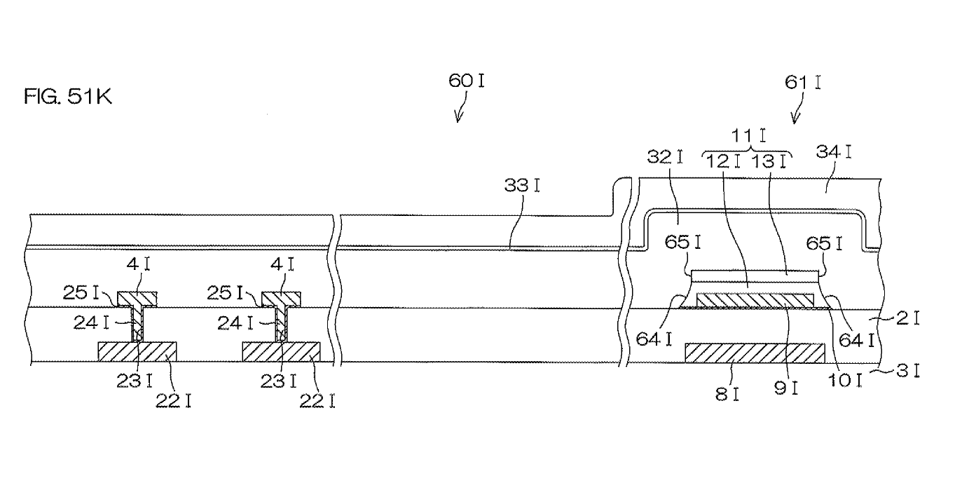

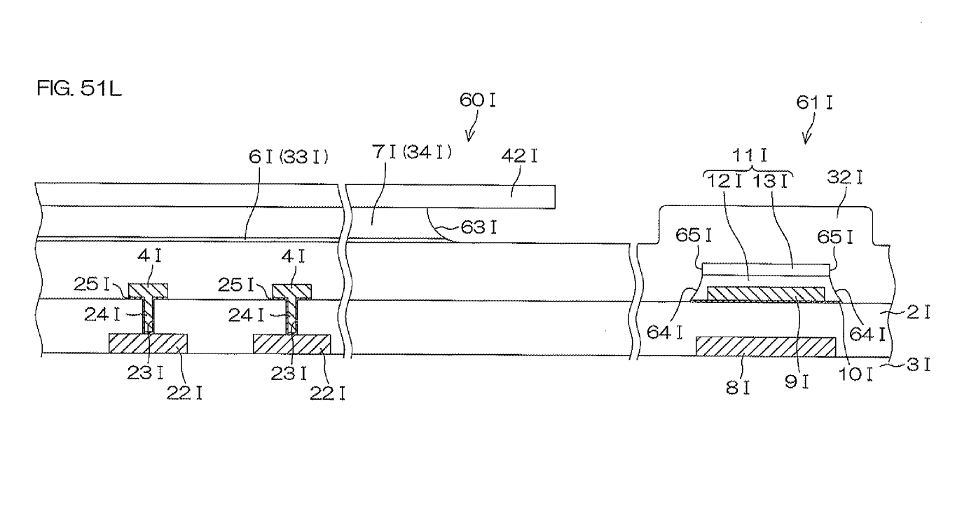

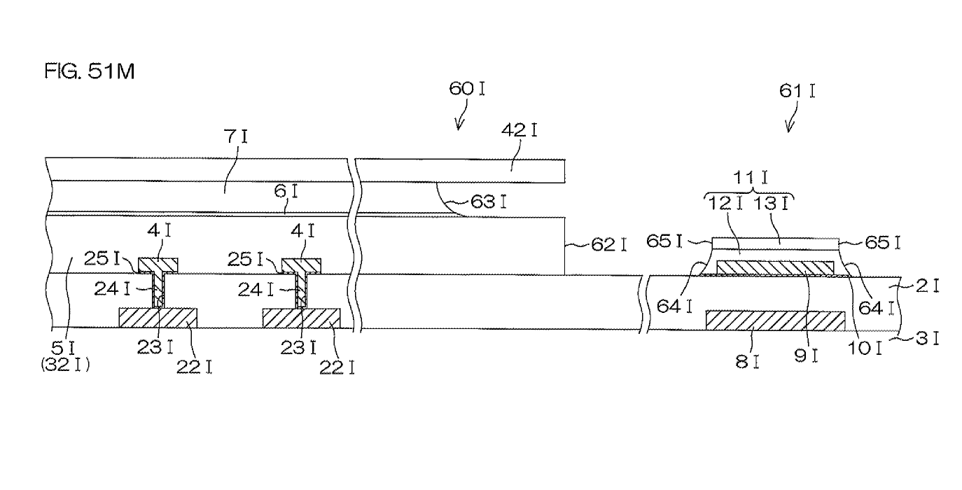

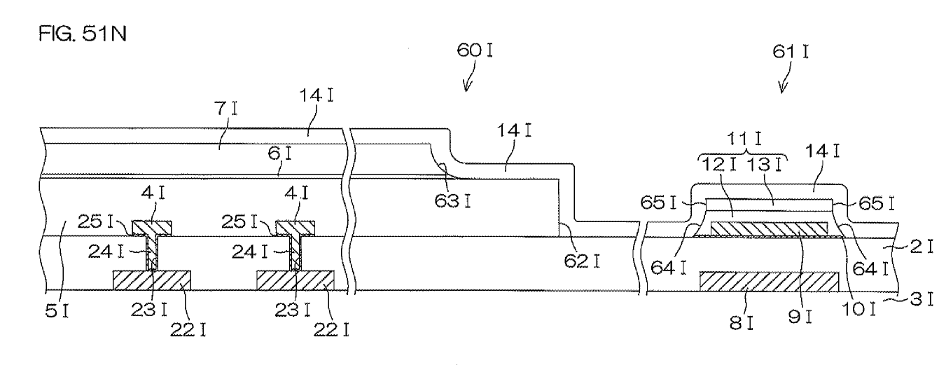

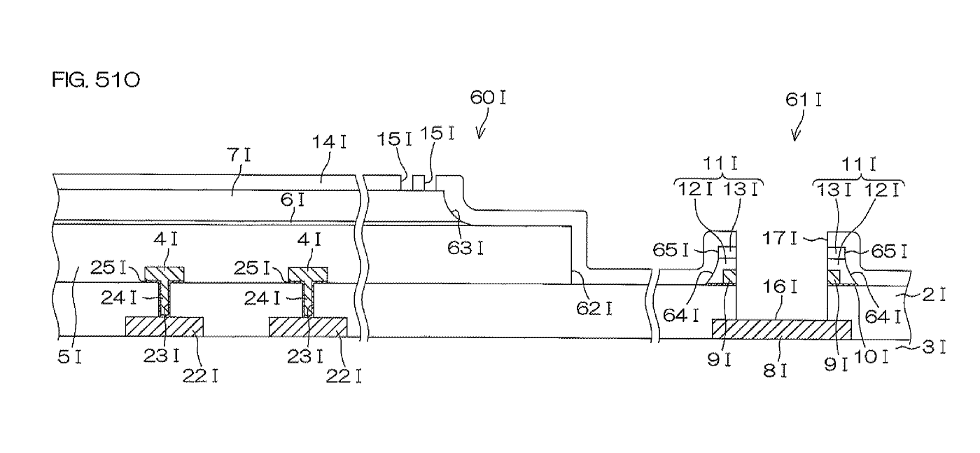

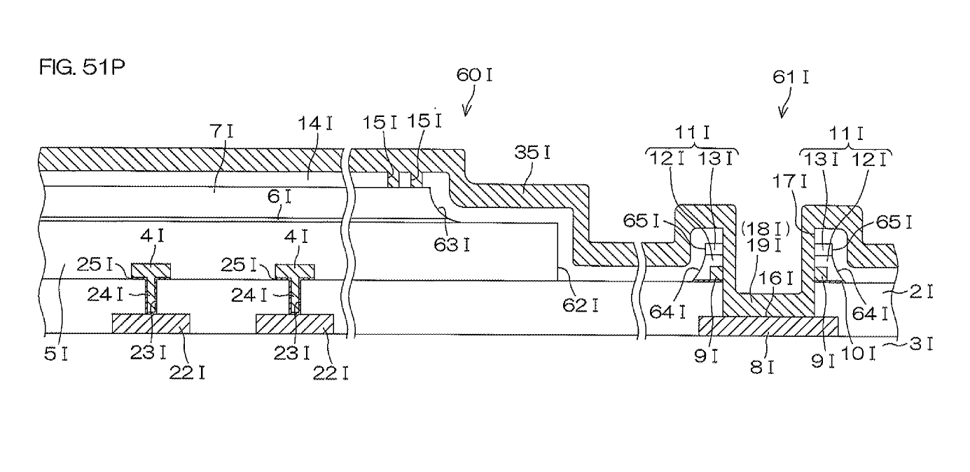

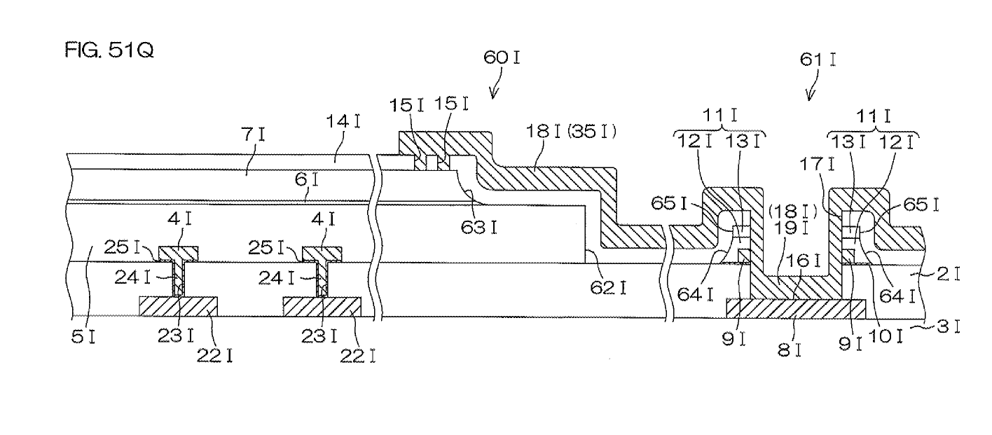

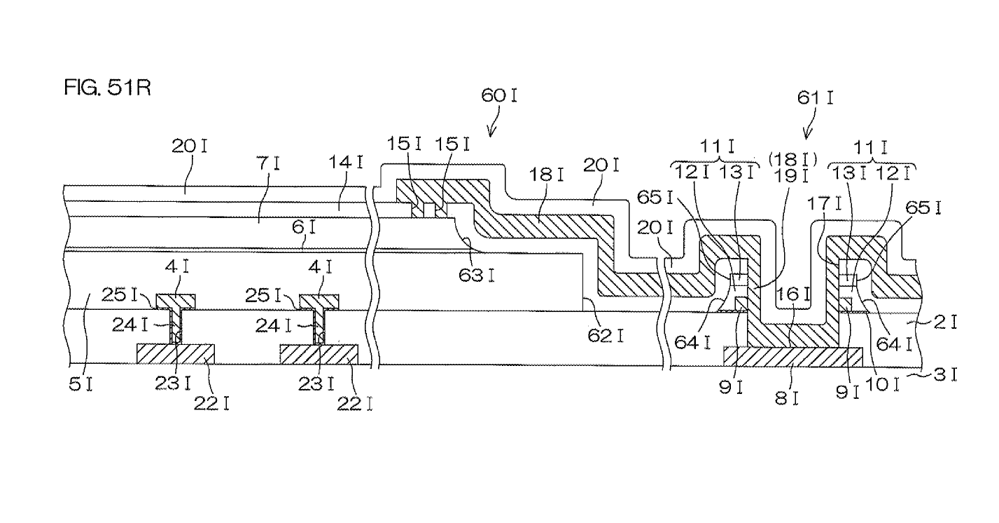

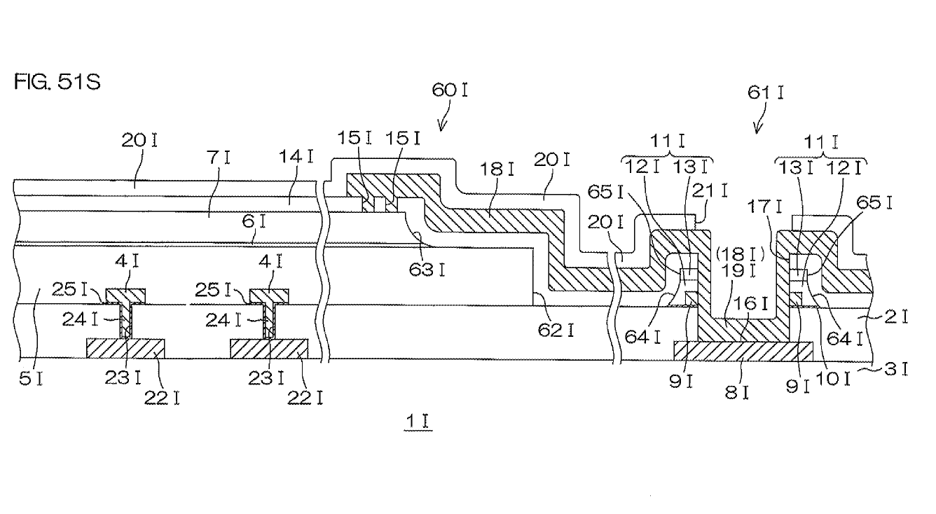

FIG. 51E is a schematic sectional view of a step subsequent to that of FIG. 51D.

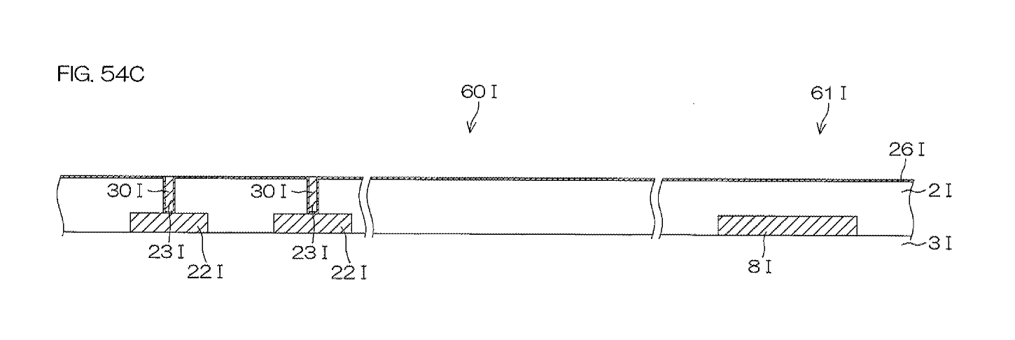

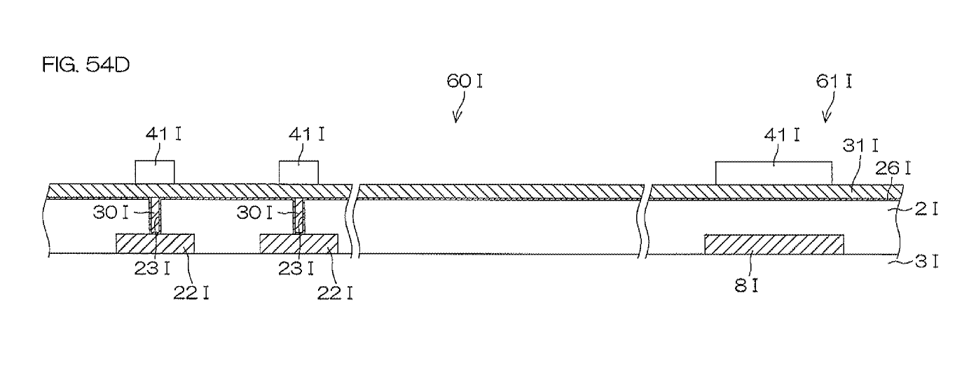

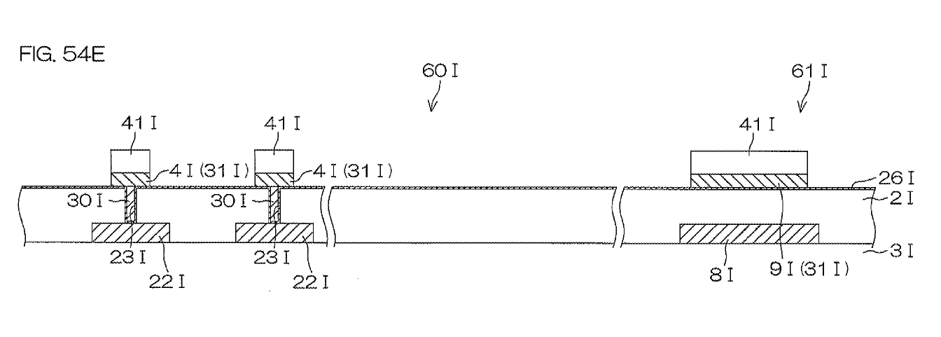

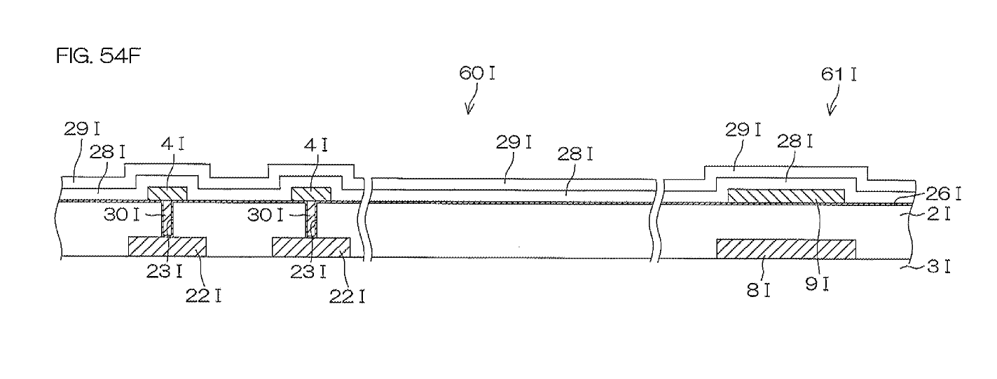

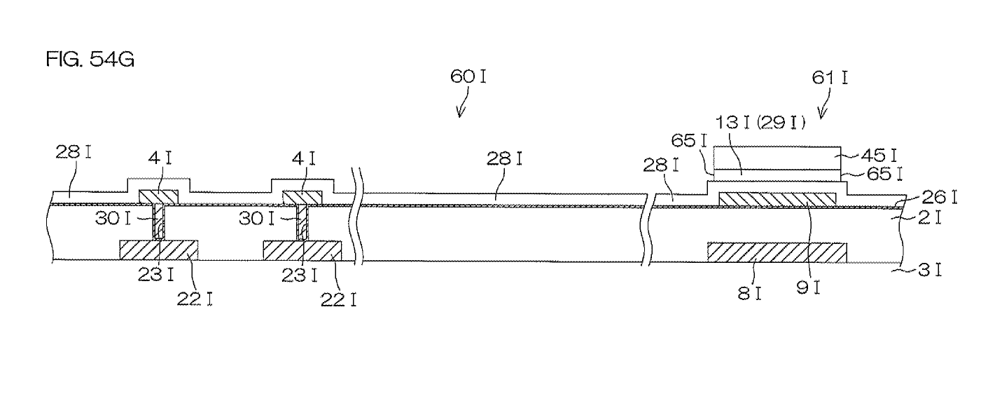

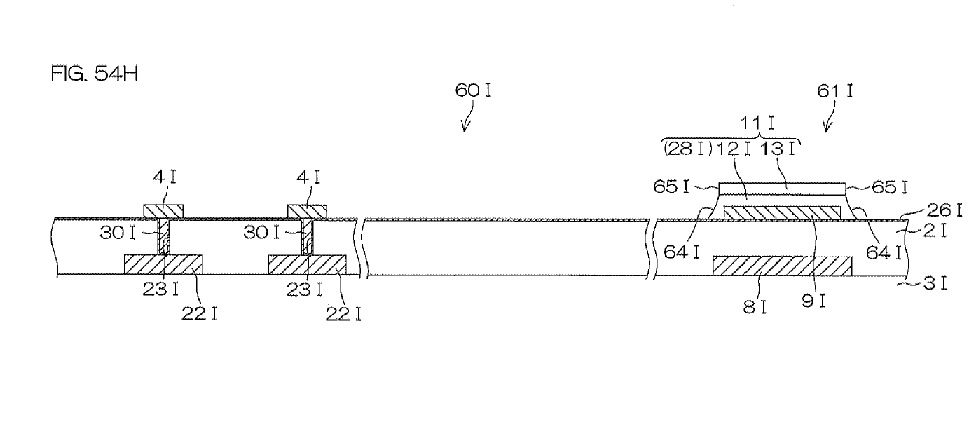

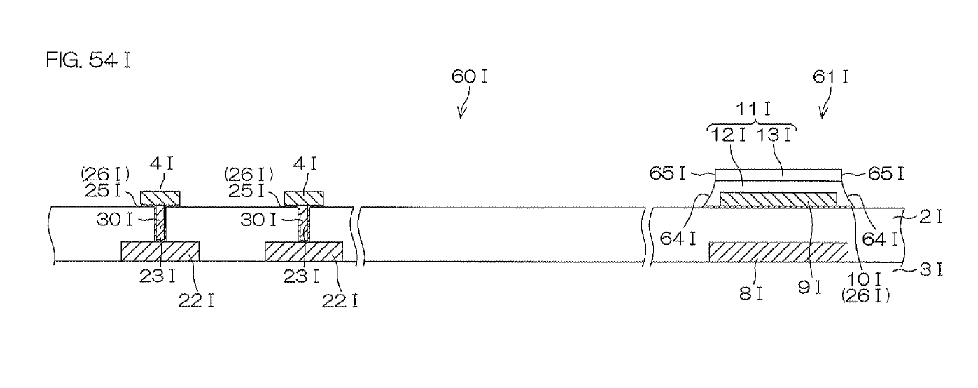

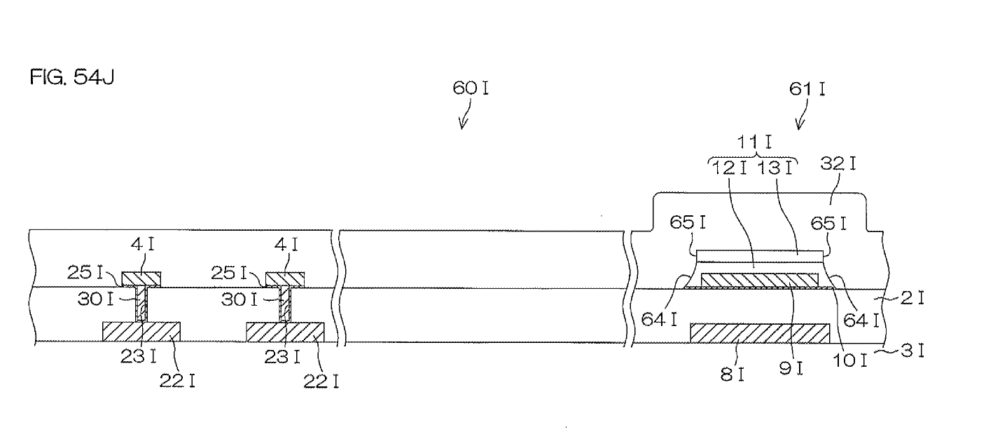

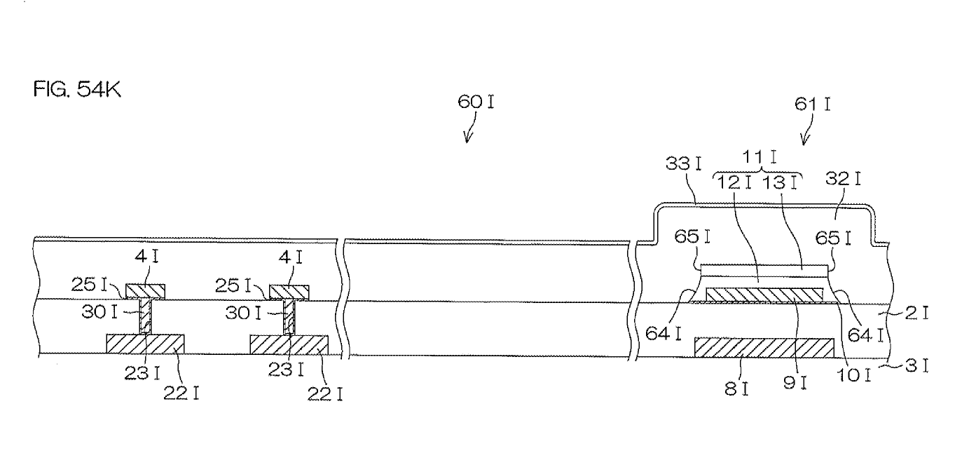

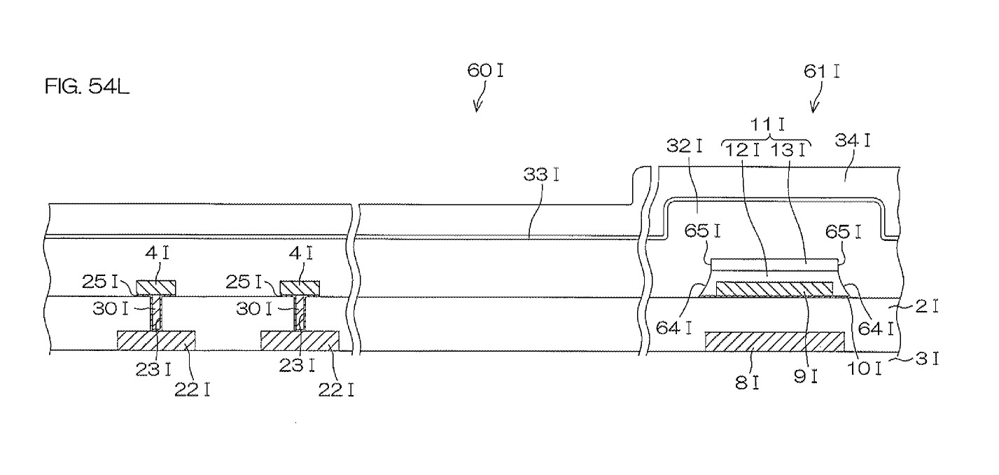

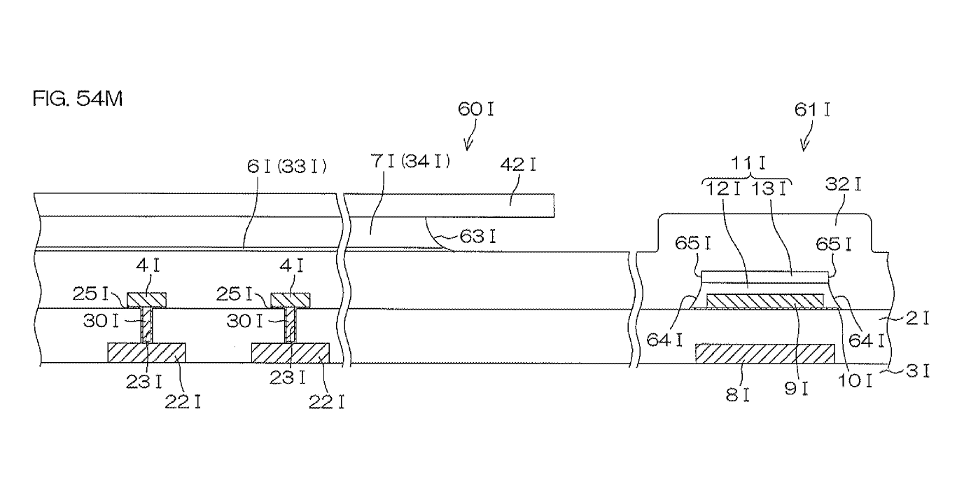

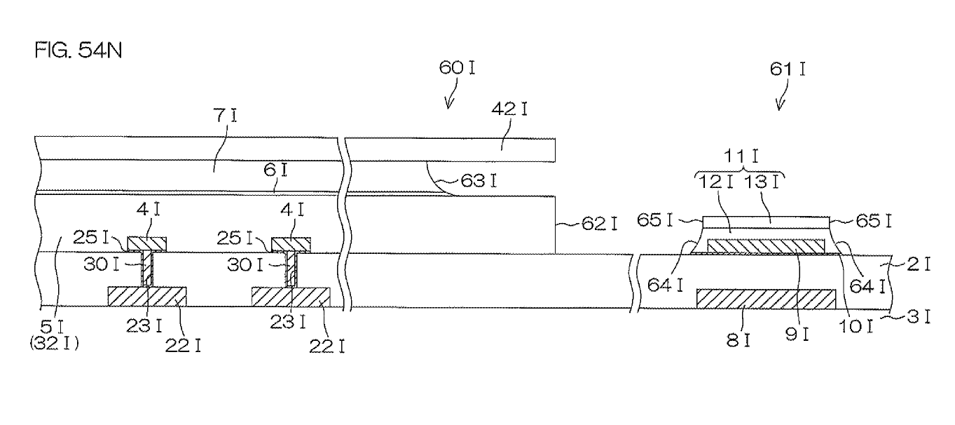

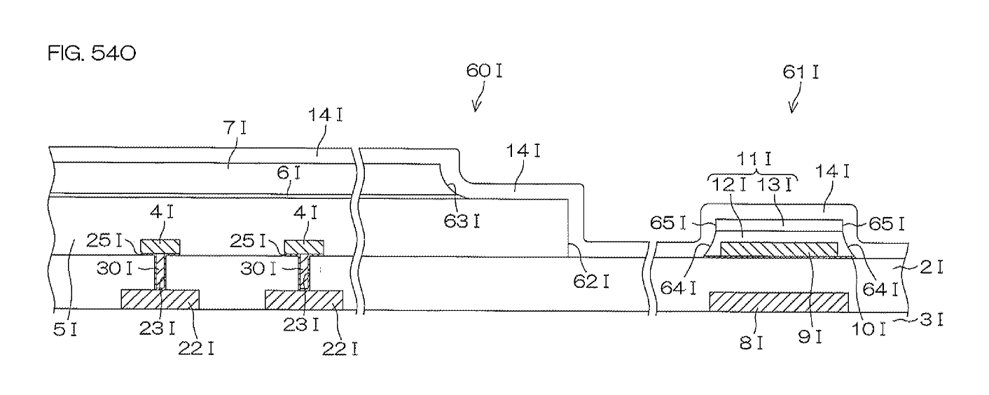

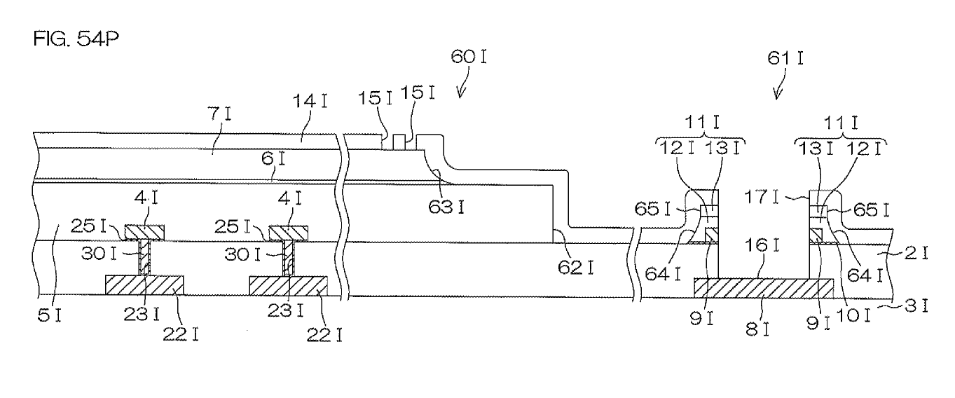

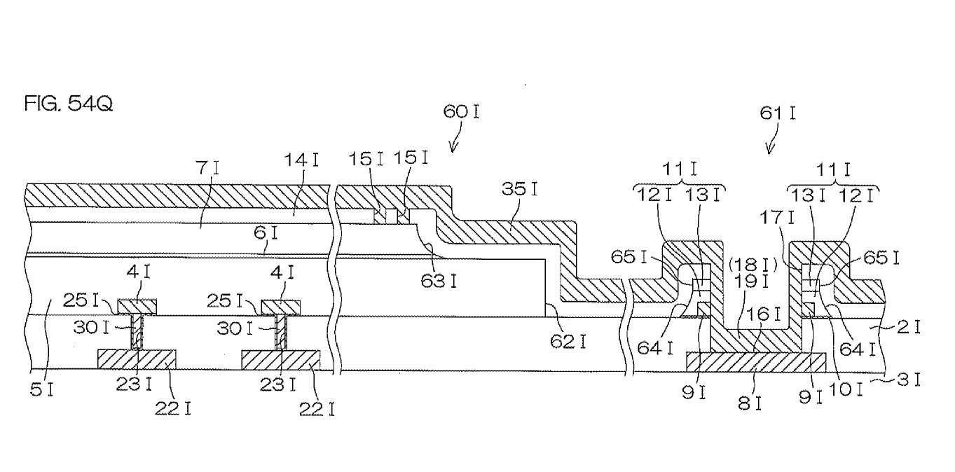

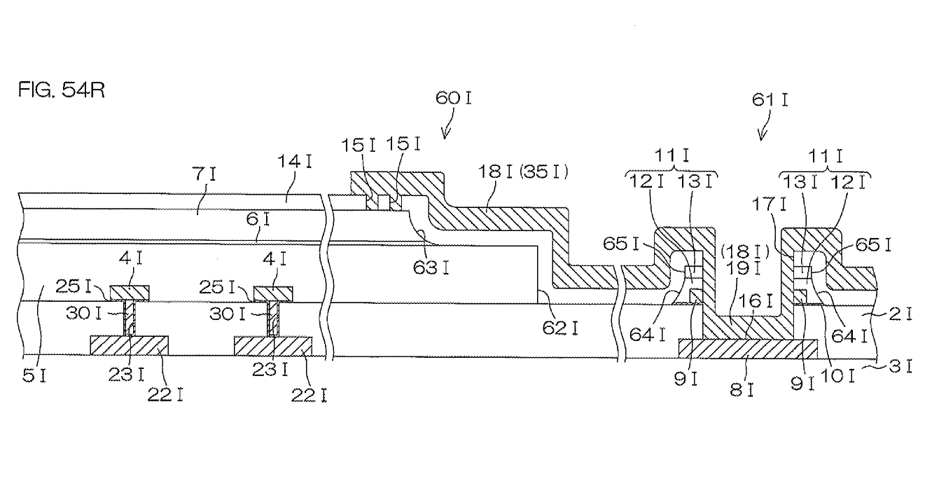

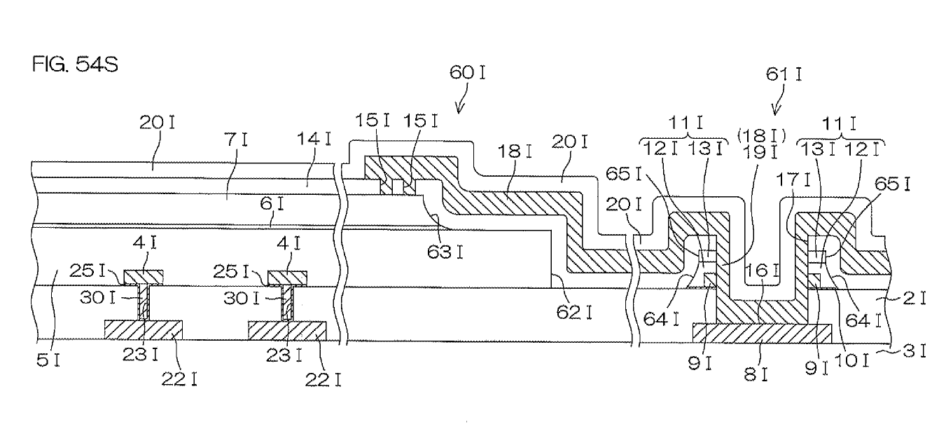

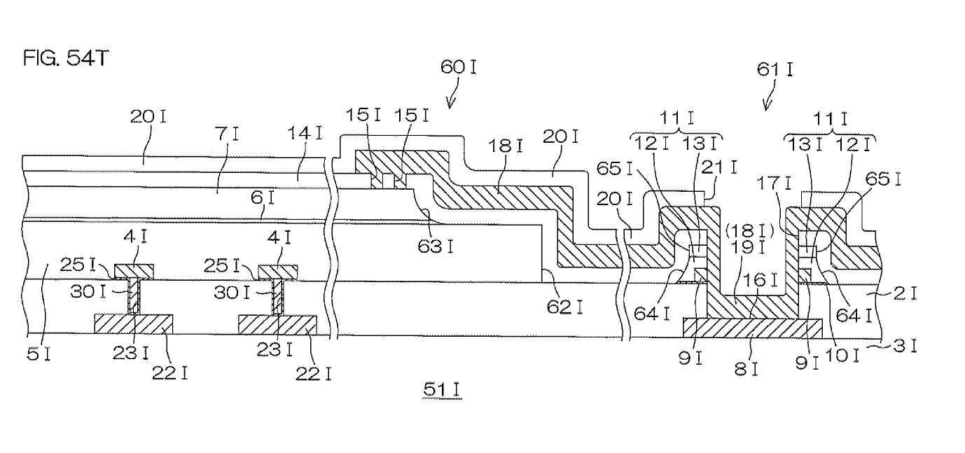

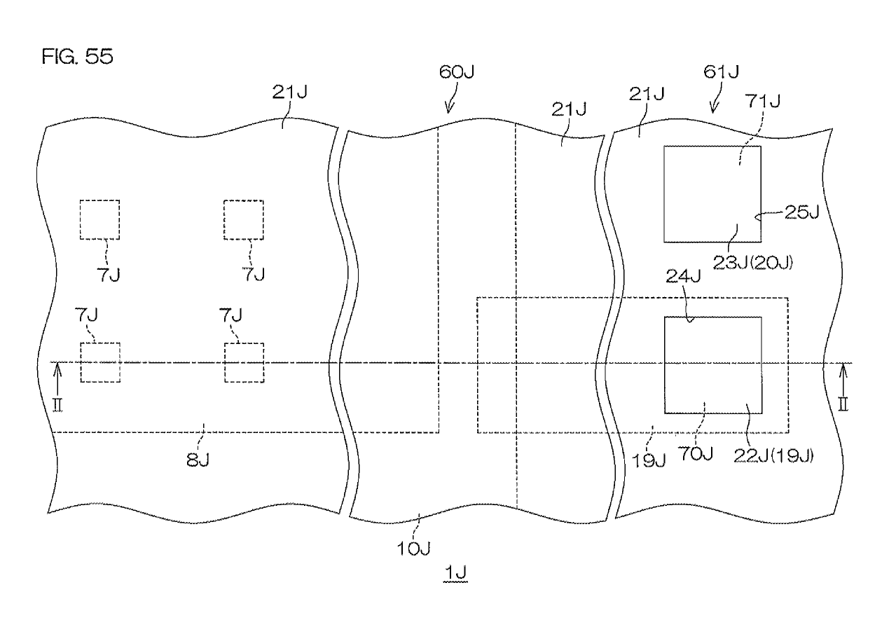

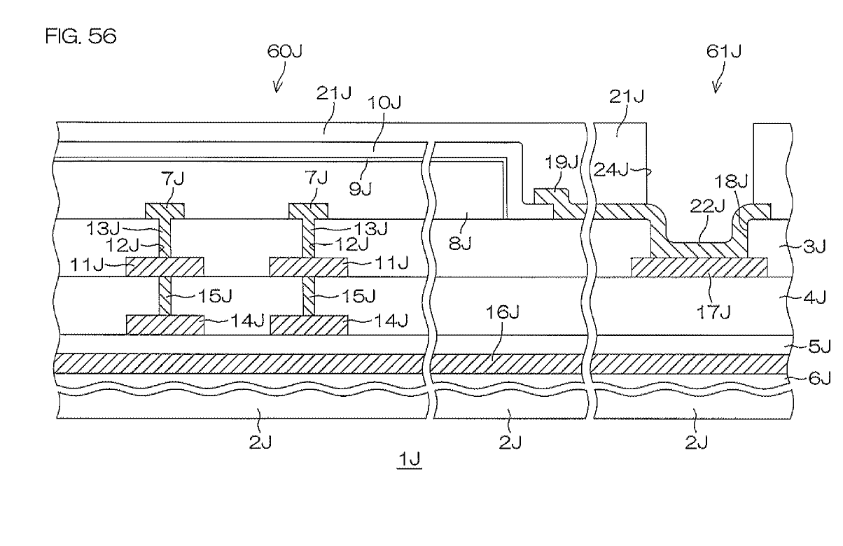

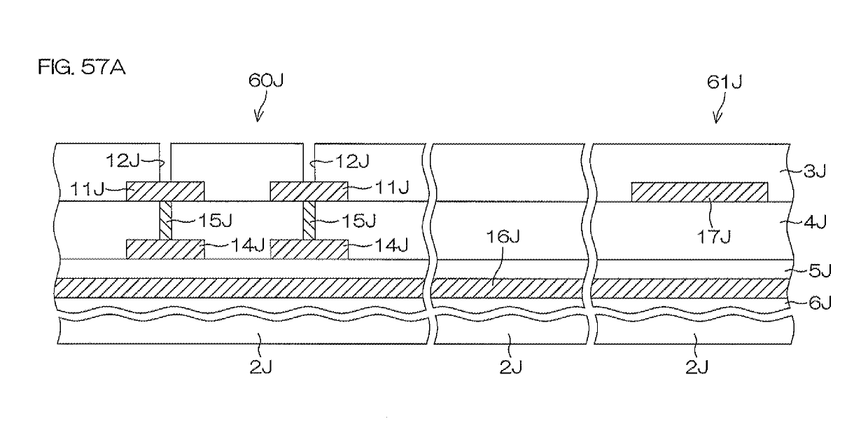

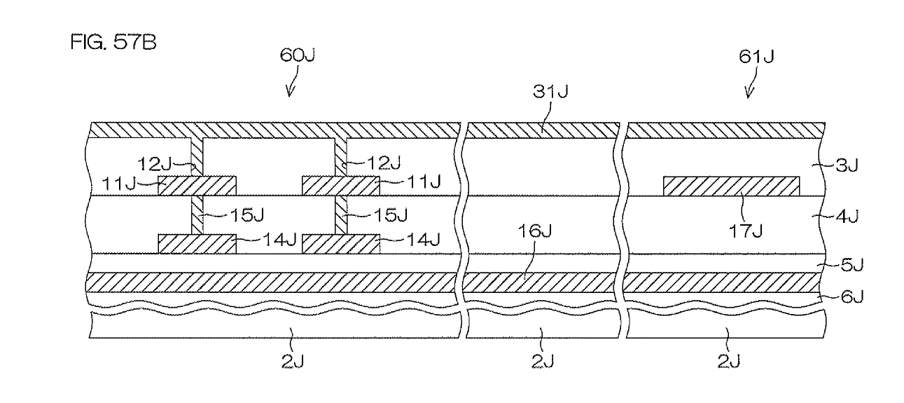

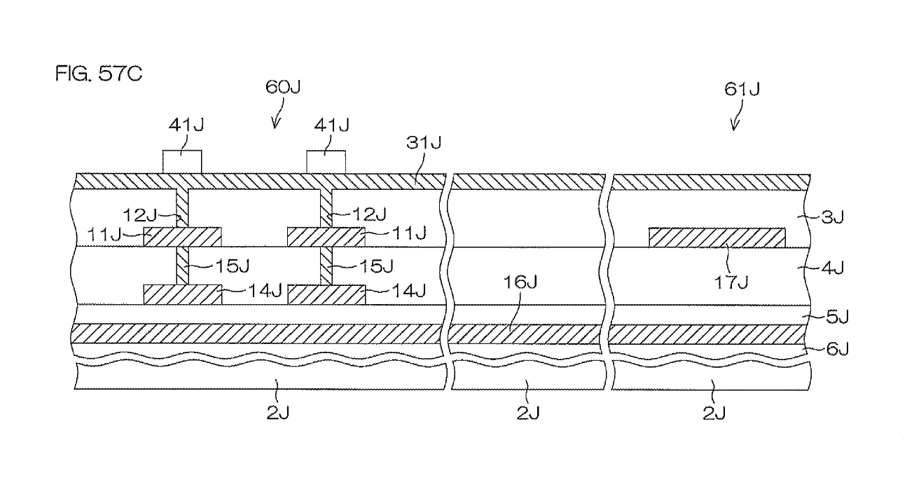

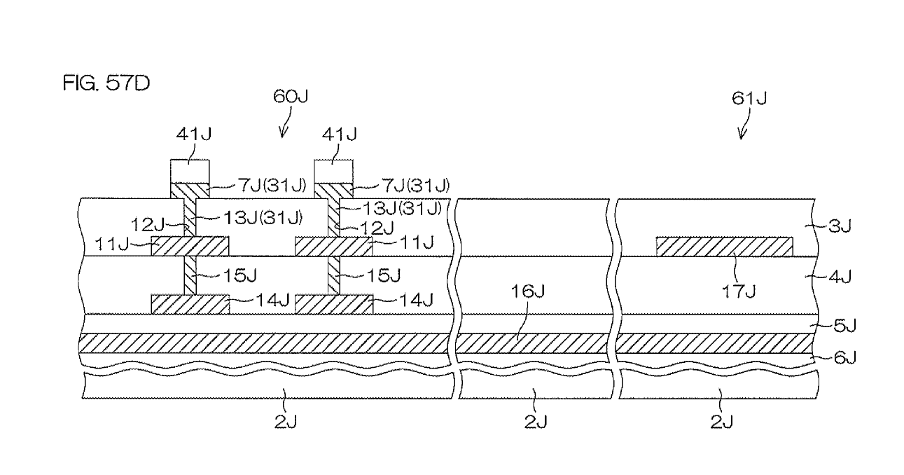

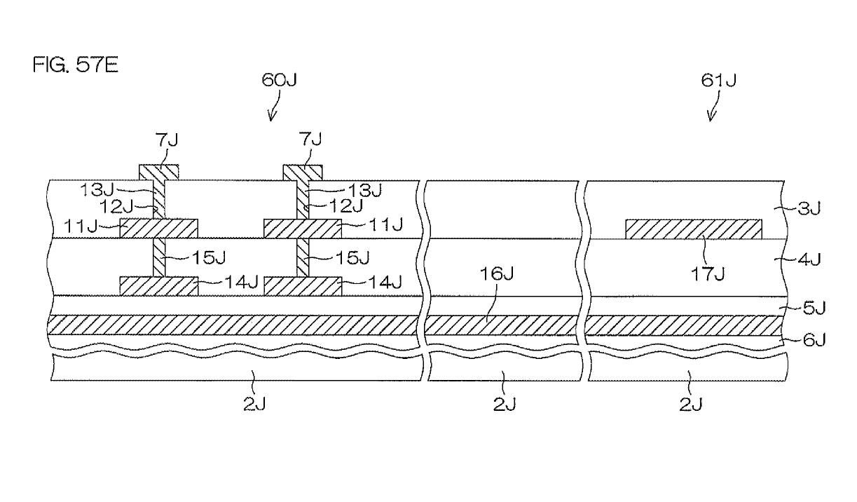

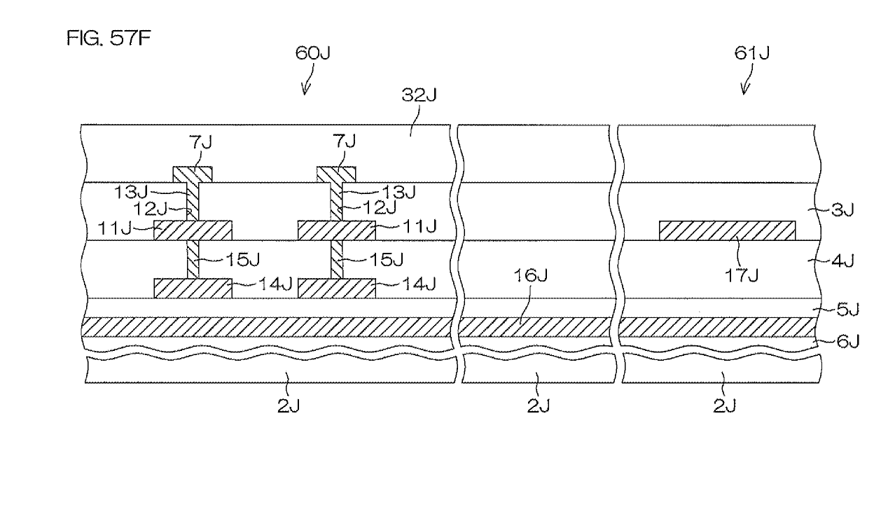

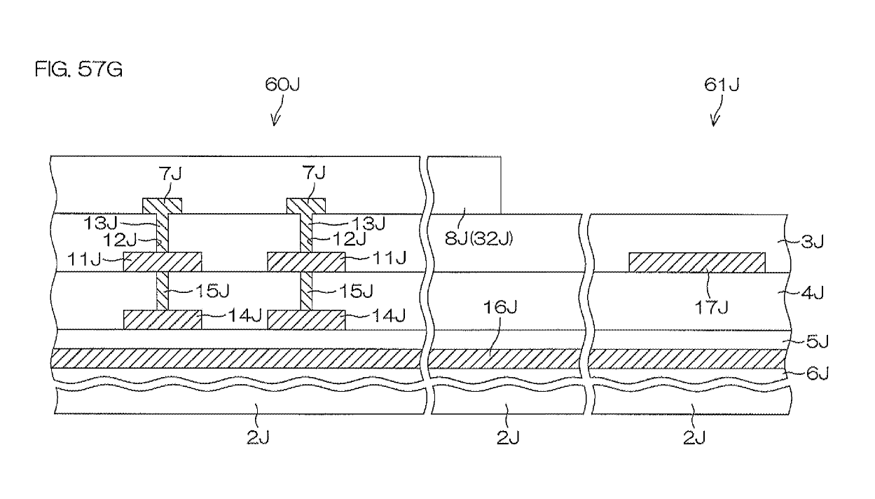

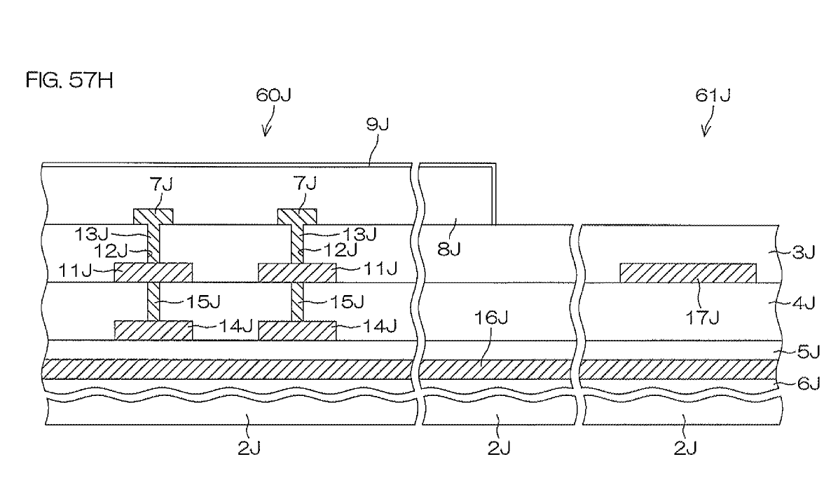

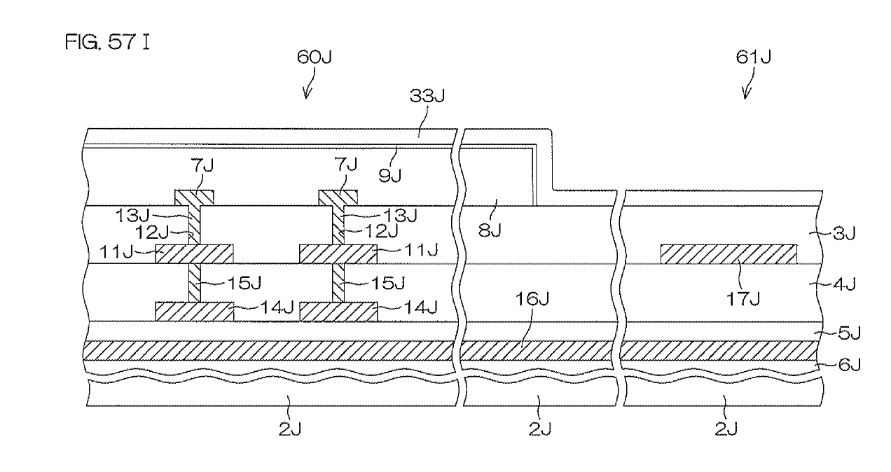

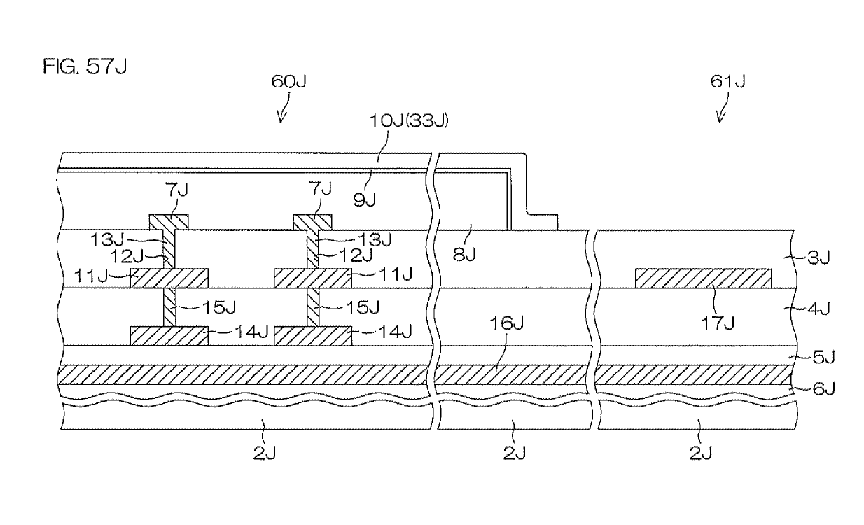

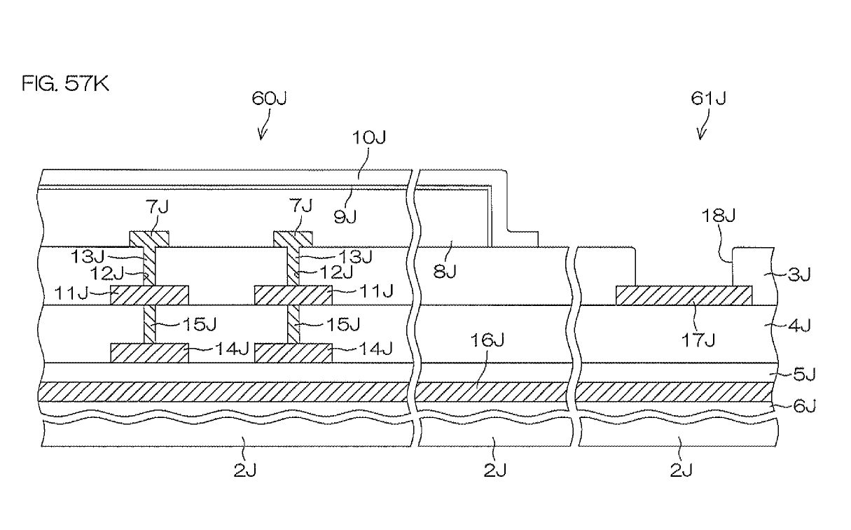

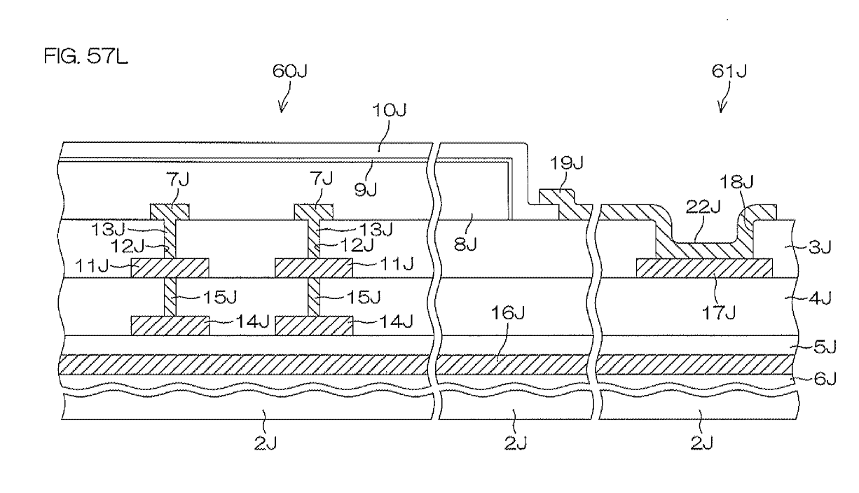

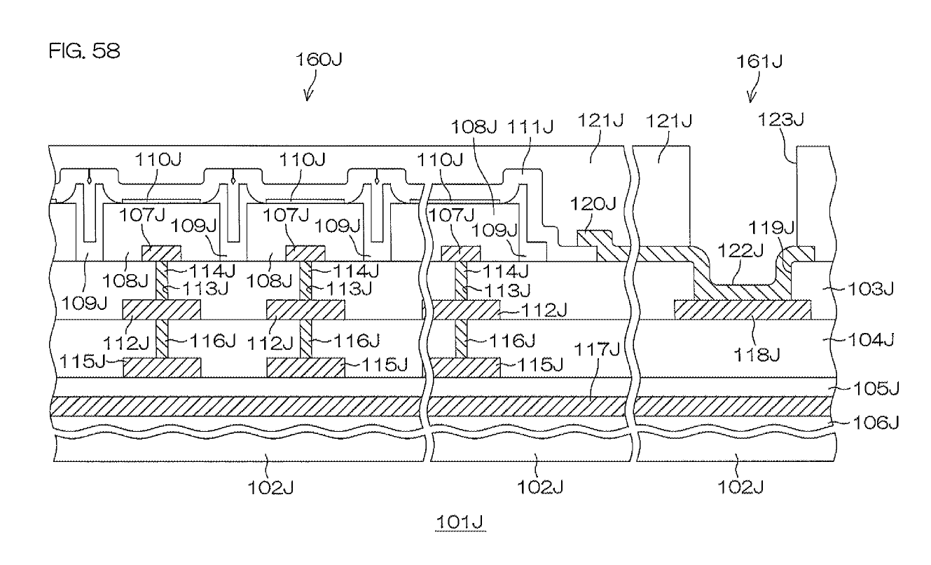

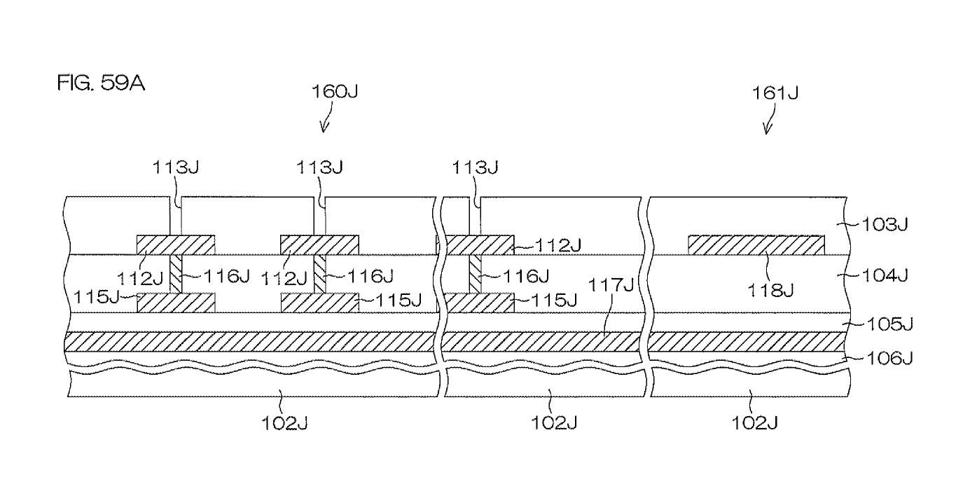

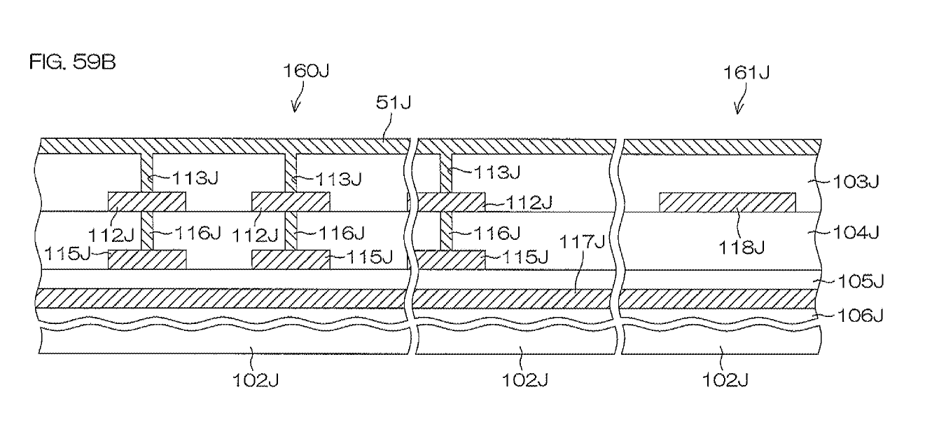

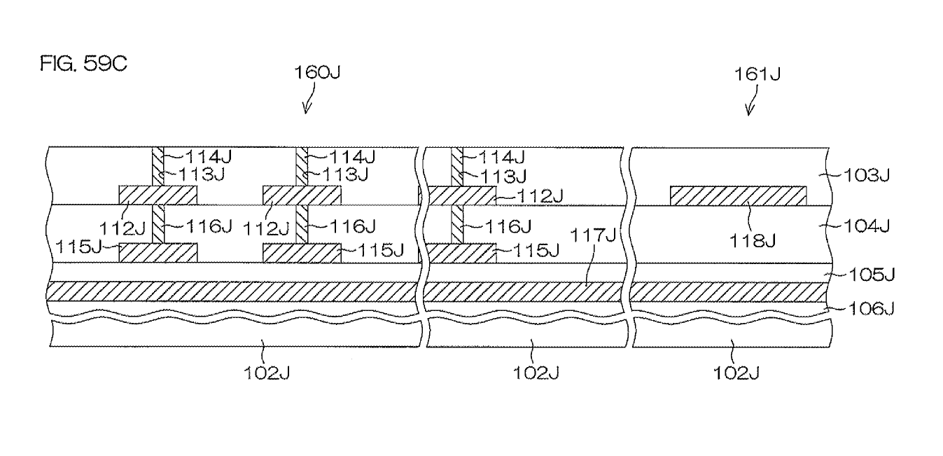

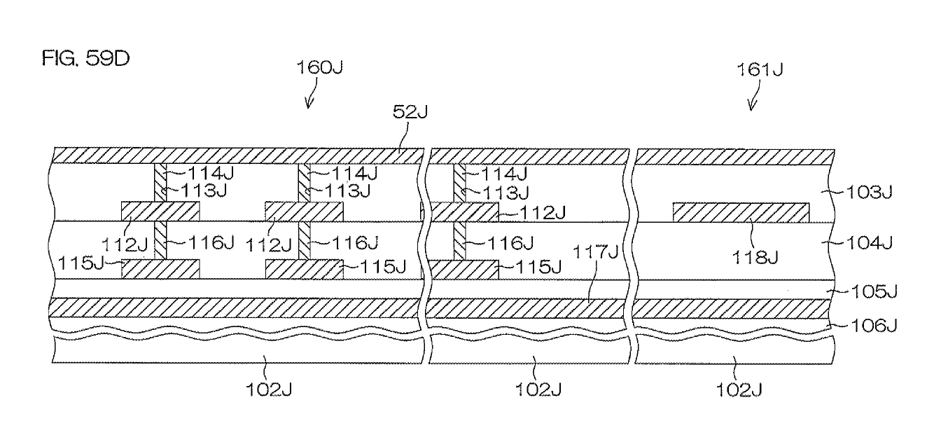

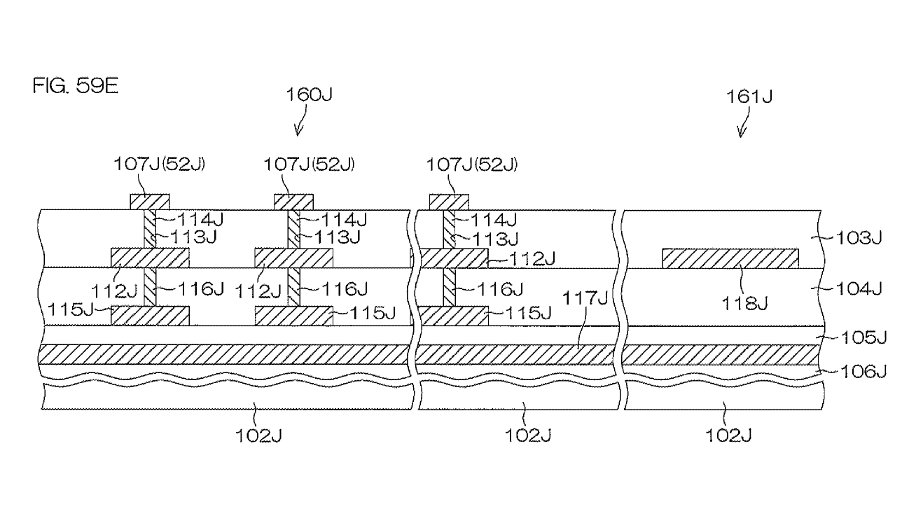

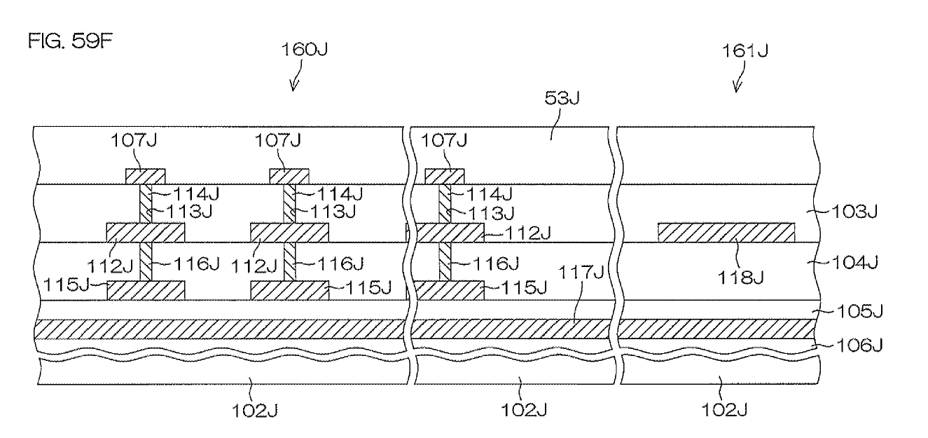

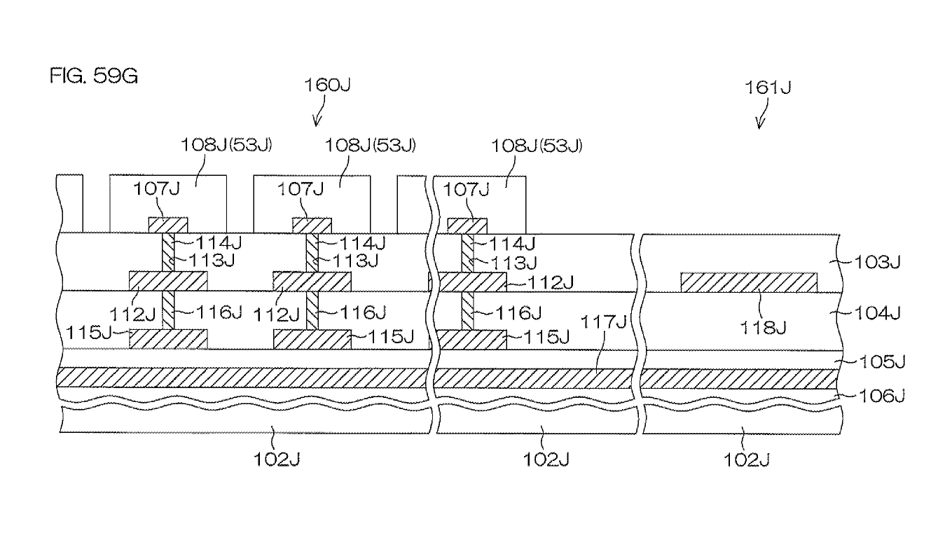

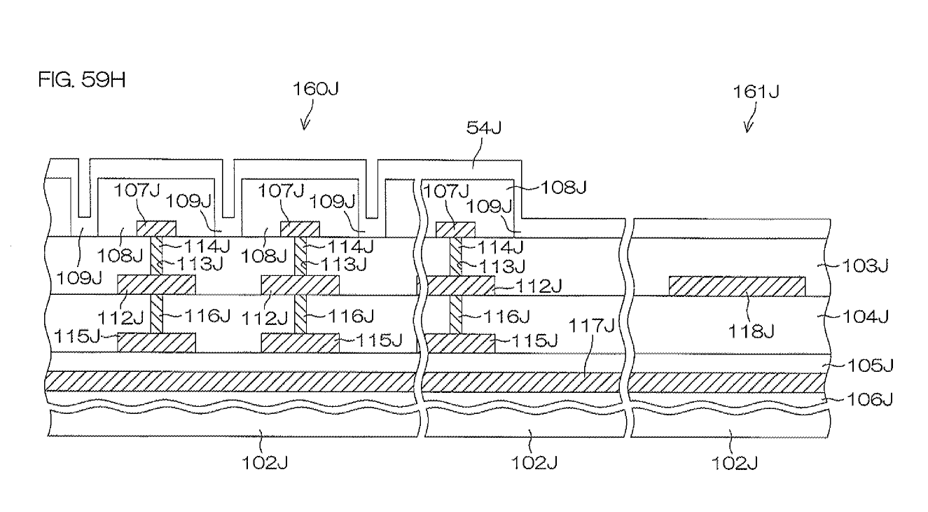

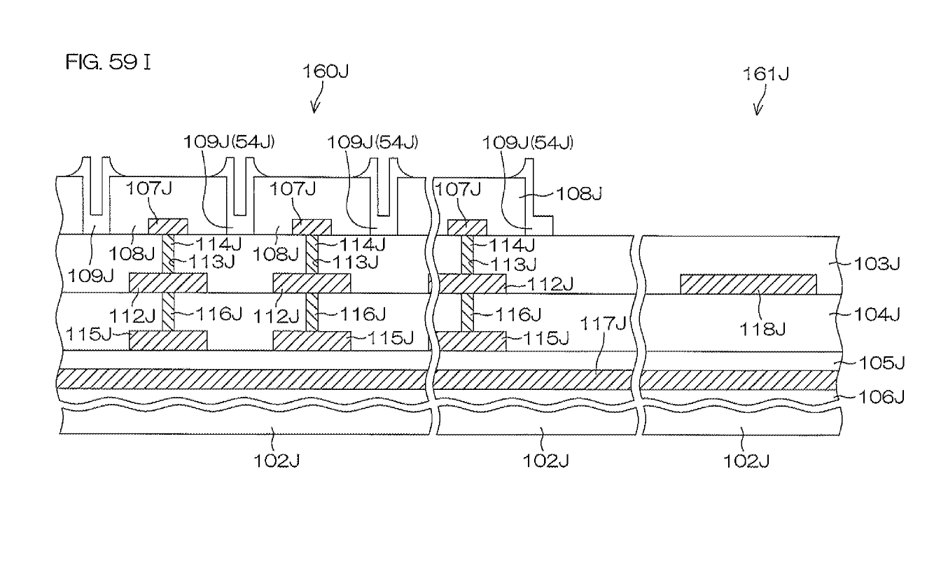

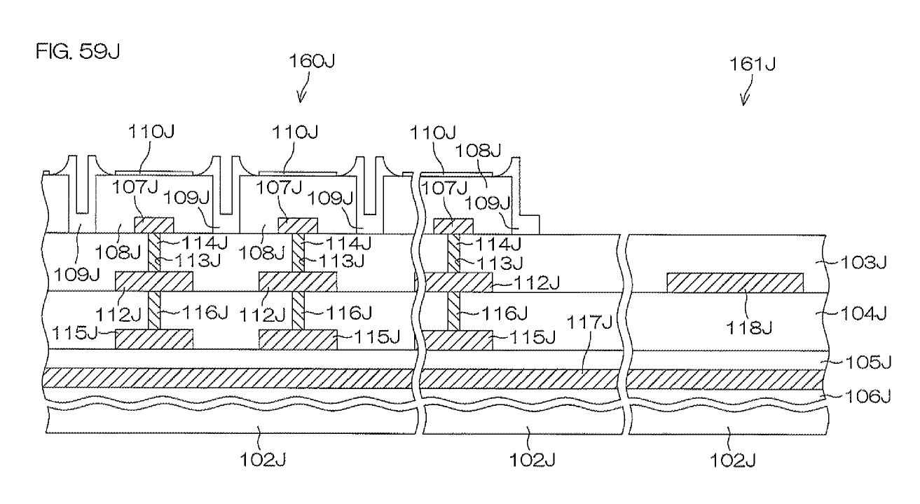

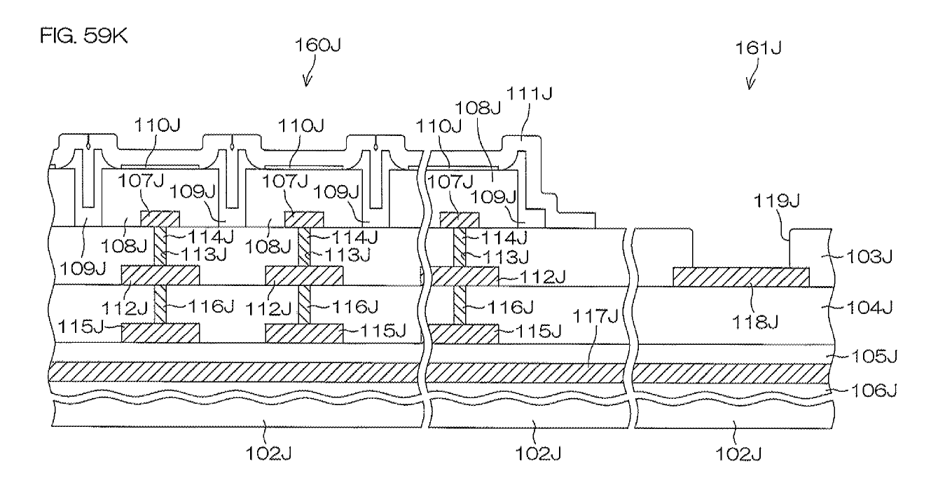

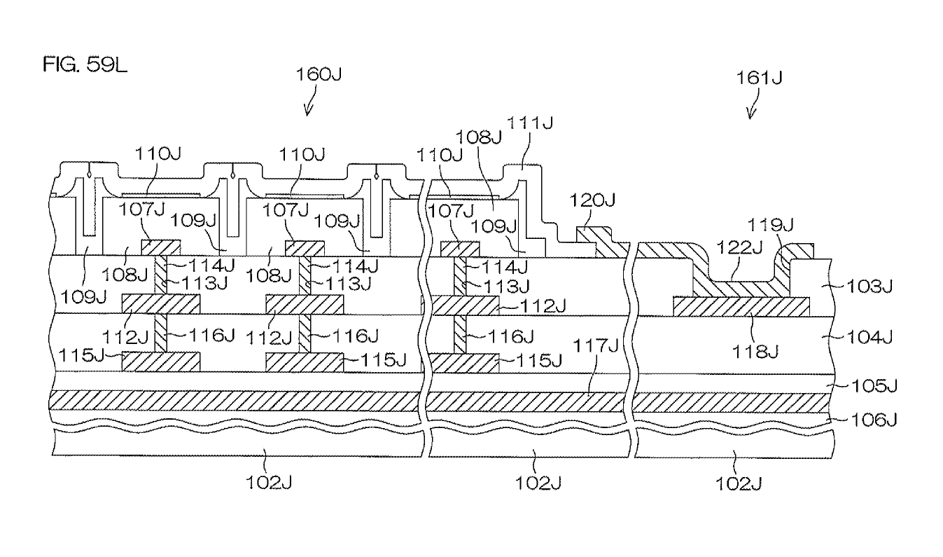

FIG. 54F is a schematic sectional view of a step subsequent to that of FIG. 51E.

FIG. 51G is a schematic sectional view of a step subsequent to that of FIG. 54F.

FIG. 54H is a schematic sectional view of a step subsequent to that of FIG. 54G.

FIG. 54I is a schematic sectional view of a step subsequent to that of FIG. 54H.

FIG. 54J is a schematic sectional view of a step subsequent to that of FIG. 54I.

FIG. 54K is a schematic sectional view of a step subsequent to that of FIG. 54J.

FIG. 54L is a schematic sectional view of a step subsequent to that of FIG. 54K.

FIG. 54M is a schematic sectional view of a step subsequent to that of FIG. 54L.

FIG. 54N is a schematic sectional view of a step subsequent to that of FIG. 54M.

FIG. 54O is a schematic sectional view of a step subsequent to that of FIG. 54N.

FIG. 54P is a schematic sectional view of a step subsequent to that of FIG. 54O.

FIG. 54Q is a schematic sectional view of a step subsequent to that of FIG. 54P.

FIG. 54R is a schematic sectional view of a step subsequent to that of FIG. 54Q.

FIG. 54S is a schematic sectional view of a step subsequent to that of FIG. 54R.

FIG. 54T is a schematic sectional view of a step subsequent to that of FIG. 54S.

FIG. 55 is a schematic plan view of an image sensor according to a first preferred embodiment of a tenth aspect of the present invention.

FIG. 56 is a schematic sectional view of the image sensor taken along sectioning line II-II in FIG. 55.

FIG. 57A is a schematic sectional view of a manufacturing process of the image sensor shown in FIG. 56.

FIG. 57B is a schematic sectional view of a step subsequent to that of FIG. 57A.

FIG. 57C is a schematic sectional view of a step subsequent to that of FIG. 57B.

FIG. 57D is a schematic sectional view of a step subsequent to that of FIG. 57C.

FIG. 57E is a schematic sectional view of a step subsequent to that of FIG. 57D.

FIG. 57F is a schematic sectional view of a step subsequent to that of FIG. 57E.

FIG. 57G is a schematic sectional view of a step subsequent to that of FIG. 57F.

FIG. 57H is a schematic sectional view of a step subsequent to that of FIG. 57G.

FIG. 57I is a schematic sectional view of a step subsequent to that of FIG. 57H.

FIG. 57J is a schematic sectional view of a step subsequent to that of FIG. 57I.

FIG. 57K is a schematic sectional view of a step subsequent to that of FIG. 57J.

FIG. 57L is a schematic sectional view of a step subsequent to that of FIG. 57K.

FIG. 58 is a schematic sectional view of an image sensor according to a second preferred embodiment of the tenth aspect of the present invention.

FIG. 59A is a schematic sectional view of a manufacturing process of the image sensor shown in FIG. 58.

FIG. 59B is a schematic sectional view of a step subsequent to that of FIG. 59A.

FIG. 59C is a schematic sectional view of a step subsequent to that of FIG. 59B.

FIG. 59D is a schematic sectional view of a step subsequent to that of FIG. 59C.

FIG. 59E is a schematic sectional view of a step subsequent to that of FIG. 59D.

FIG. 59F is a schematic sectional view of a step subsequent to that of FIG. 59E.

FIG. 59G is a schematic sectional view of a step subsequent to that of FIG. 59F.

FIG. 59H is a schematic sectional view of a step subsequent to that of FIG. 59G.

FIG. 59I is a schematic sectional view of a step subsequent to that of FIG. 59H.

FIG. 59J is a schematic sectional view of a step subsequent to that of FIG. 59I.

FIG. 59K is a schematic sectional view of a step subsequent to that of FIG. 59J.

FIG. 59L is a schematic sectional view of a step subsequent to that of FIG. 59K.

### PREFERRED EMBODIMENT(S) OF THE INVENTION

Preferred embodiments of the present invention shall now be described in detail with reference to the attached drawings.

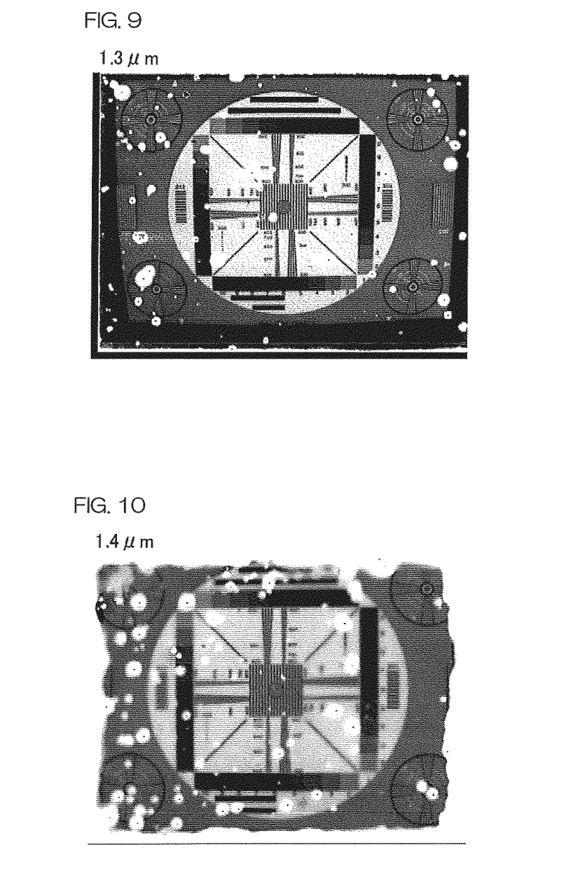

### Preferred Embodiment According to a First Aspect of the Invention FIG. 1 to FIG. 11

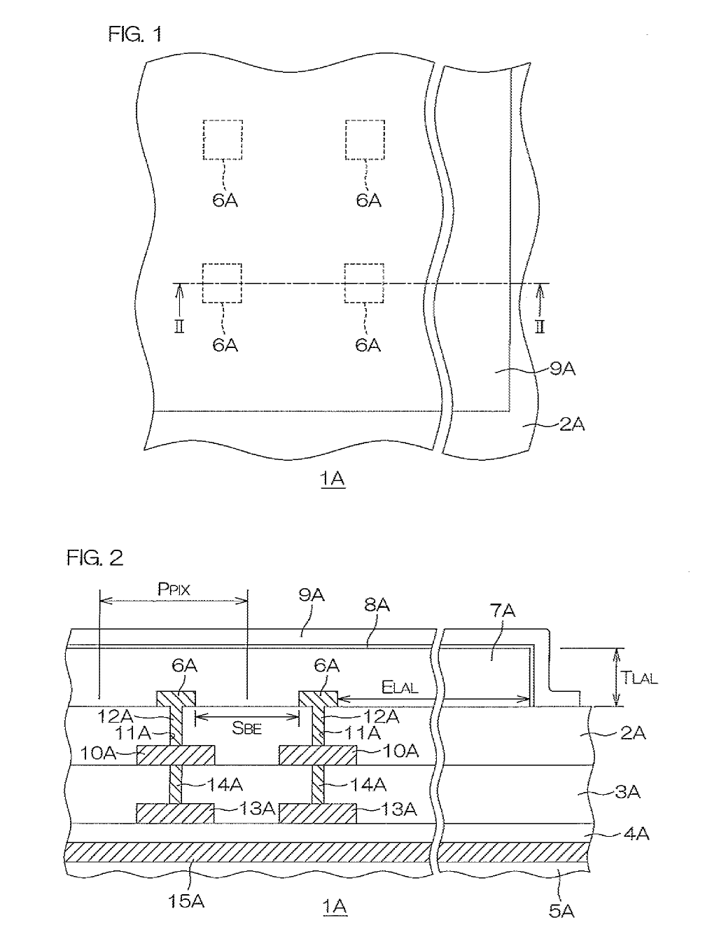

FIG. 1 is a schematic plan view of an image sensor according to a preferred embodiment of a first aspect of the present invention. FIG. 2 is a schematic sectional view of the image sensor taken along sectioning line II-II in FIG. 1. In FIG. 2, only portions made of metal materials are hatched and portions besides these are not hatched.

The image sensor 1A, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2A, 3A, 5A and a capacitor dielectric film 4A are laminated on the semiconductor substrate. The interlayer insulating films 2A, 3A, and 5A and the capacitor dielectric film 4A are made, for example, of silicon oxide (SiO₂).

Also, a sensor forming region and an annular pad forming region surrounding it are set on the semiconductor substrate.

In the sensor forming region, a plurality of lower electrodes 6A are arrayed in a matrix on the uppermost interlayer insulating film 2A. The lower electrodes 6A are made of tungsten (W). Each lower electrode 6A is formed to a square shape in a plan view. For example, in a case where a pixel pitch P_{PIX} to be described later is 7.5 μm, a length of one side of the lower electrode 6A in a plan view is no less than 2.0 μm and no more than 3.3 μm. The lower electrode 6A has a thickness of no less than 0.2 μm and no more than 0.4 μm. Also, mutually adjacent lower electrodes 6A are spaced apart at equal intervals S_{BE} (≧T_{LAL}×3) each set to no less than three times a thickness T_{LAL} of a photoabsorption layer 7A to be described below.

The photoabsorption layer 7A of rectangular shape in a plan view is formed on the interlayer insulating film 2A so as to cover all of the lower electrodes 6A together. Specifically, the photoabsorption layer 7A is formed integrally on a rectangular region on the interlayer insulating film 2A in which the lower electrodes 6A are formed and on a rectangular annular region of fixed width E_{LAL} at a periphery of the rectangular region. The photoabsorption layer 7A is made of CIGS and exhibits a p-type conductivity. The thickness T_{LAL} of the photoabsorption layer 7A is no less than 1.0 μm and no more than 1.4 μm. Also, the fixed width E_{LAL}, that is, the interval E_{LAL} between the lower electrode 6A disposed at the outermost periphery and a side surface of the photoabsorption layer 7A is no less than 50 μm and no more than 100 μm. In the photoabsorption layer 7A, each region of fixed area and rectangular shape in a plan view that is centered at each lower electrode 6A is used for reading of a single pixel. The pixel pitch P_{PIX} that is a width of this region is no less than 5 μm and no more than 10 μm.

An upper surface and side surfaces of the photoabsorption layer 7A are covered by a high-resistance buffer layer 8A. The high-resistance buffer layer 8A is made of cadmium sulfide (CdS). The high-resistance buffer layer 8A has a thickness of no less than 50 nm and no more than 60 nm.

On the high-resistance buffer layer 8A, a transparent conductive film 9A is formed so as to cover an upper surface and side surfaces of the high-resistance buffer layer 8A. The transparent conductive film 9A is made of zinc oxide (ZnO), which has a light transmitting property, and has conductivity imparted by addition of an n-type impurity (for example, Al₂O₃ (alumina)).

A peripheral edge portion of the transparent conductive film 9A is formed on the interlayer insulating film 2A. At a periphery of the transparent conductive film 9A, an upper electrode (not shown) is formed on the interlayer insulating film 2A. The upper electrode is made of aluminum (Al). One end of the upper electrode rides on top of the peripheral edge portion of the transparent conductive film 9A. The upper electrode extends above the interlayer insulating film 2A and another end portion thereof reaches the pad forming region. In the pad forming region, the interlayer insulating film 2A is removed selectively to partially expose a wiring (not shown) on the interlayer insulating film 3A and thereby form a pad (not shown). The other end portion of the upper electrode is connected to the pad.

Between the uppermost interlayer insulating film 2A and the interlayer insulating film 3A below it, wirings 10A are formed at positions opposing the respective lower electrodes 6A. A via hole 11A is formed penetratingly through the interlayer insulating film 2A between each lower electrode 6A and the opposing wiring 10A in the direction in which these oppose each other (thickness direction of the interlayer insulating film 2A). In each via hole 11A, a via 12A, made of the same material as the lower electrode 6A, is formed integral to the lower electrode 6A and without any gaps. Each lower electrode 6A is thereby electrically connected to the opposing wiring 10A via the via 12A. Each via hole 11A has an inner diameter of, for example, 0.4 μm.

Between the interlayer insulating film 3A and the capacitor dielectric film 4A below it, capacitor upper electrodes 13A are formed at positions opposing the respective wirings 10A. Each wiring 10A and the capacitor upper electrode 13A opposing it are electrically connected by a via 14A that penetrates through the interlayer insulating film 3A. The via 14A is made of tungsten.

Between the capacitor dielectric film 4A and the interlayer insulating film 5A below it, a capacitor lower electrode 15A is formed to oppose all of the capacitor upper electrodes 13A together. A capacitive element (MIM capacitor) having an MIM (metal-insulator-metal) structure, in which the capacitor dielectric film 4A is sandwiched as a capacitive film between the capacitor upper electrode 13A and the capacitor lower electrode 15A, is thereby formed according to each pixel. The lower electrode 6A and the capacitor upper electrode 13A of the MIM capacitor are electrically connected according to each pixel.

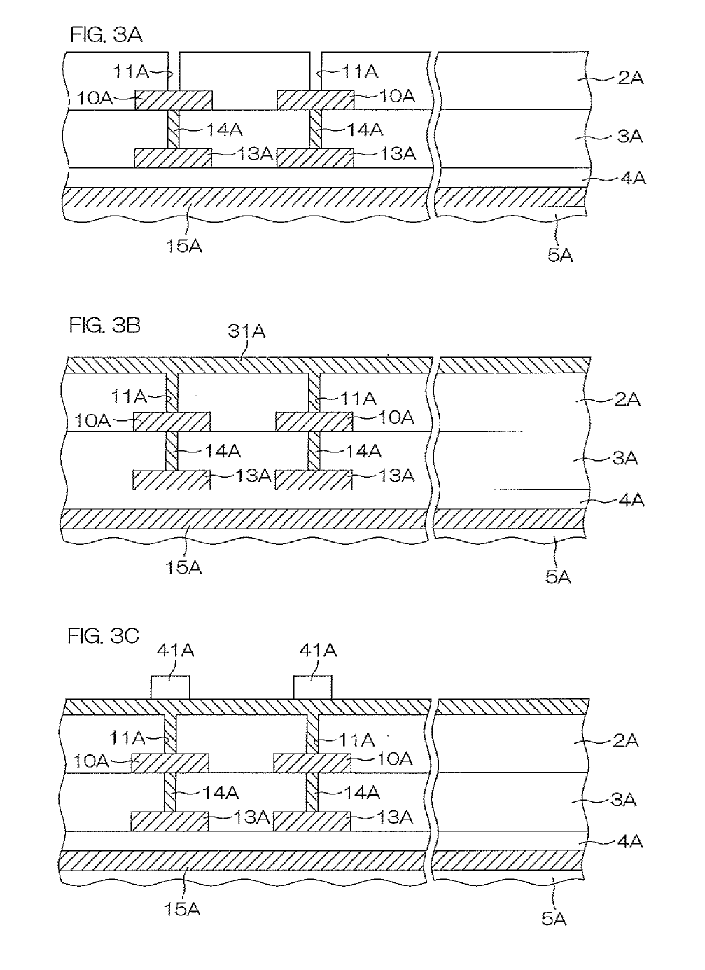

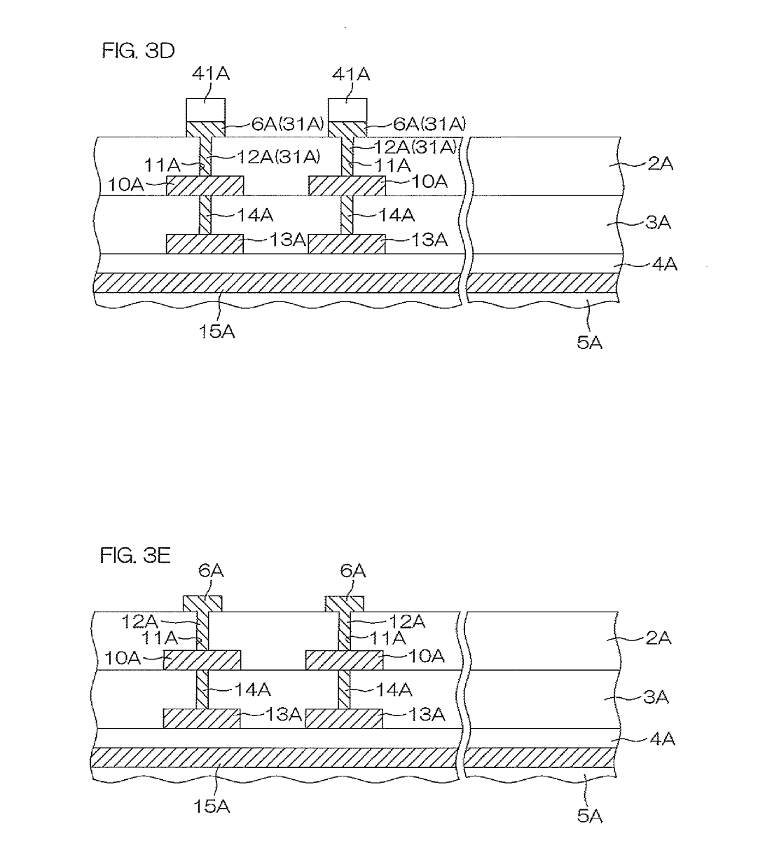

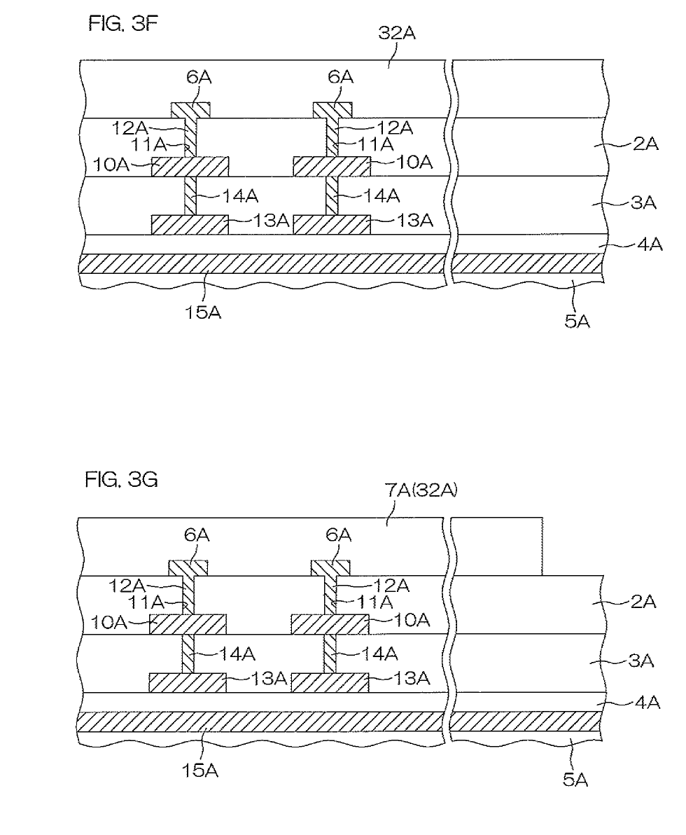

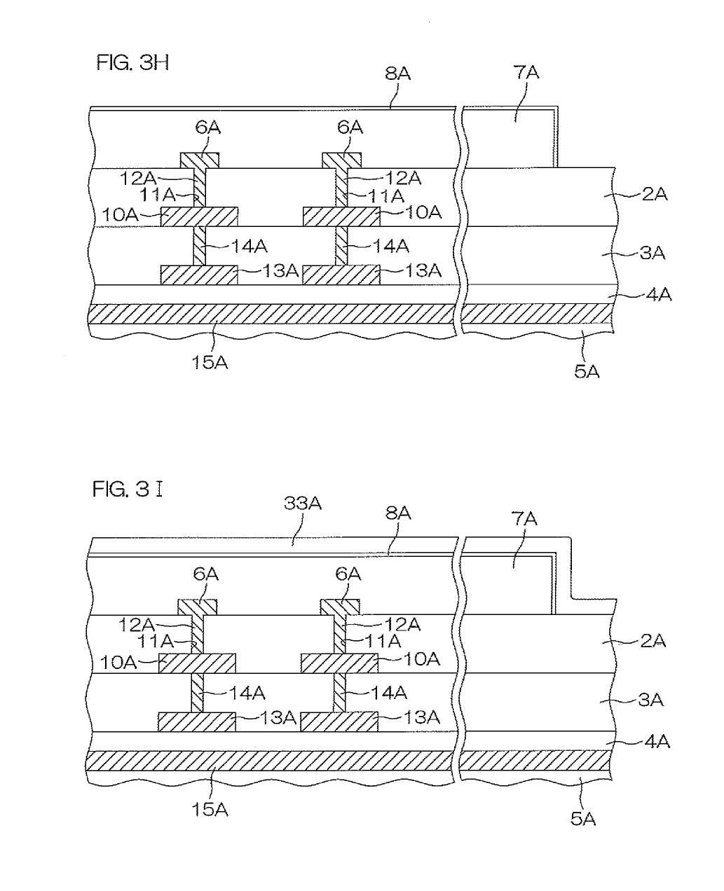

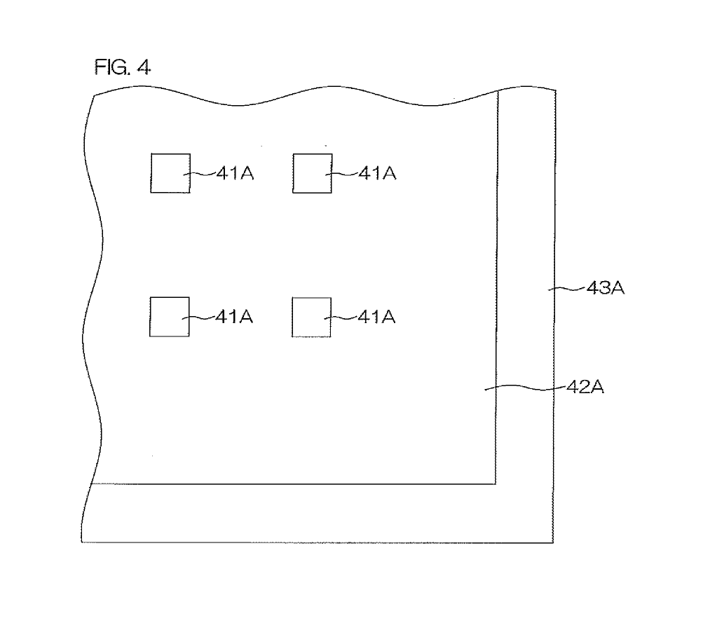

FIG. 3A to FIG. 3I are schematic sectional views that successively illustrate a manufacturing process of the image sensor shown in FIG. 2. FIG. 4 is a diagram for describing resist patterns used in the manufacturing process. In FIG. 3A to FIG. 3I, only portions made of metal materials are hatched and portions besides these are not hatched.

In the manufacturing process of the image sensor 1A, first, as shown in FIG. 3A, the interlayer insulating film 5A, the capacitor lower electrode 15A, the capacitor dielectric film 4A, the capacitor upper electrodes 13A, the interlayer insulating film 3A, the vias 14A, the wirings 10A, and the interlayer insulating film 2A are formed in that order on the semiconductor substrate (not shown). The via holes 11A penetrating through the interlayer insulating film 2A are then formed above the respective wirings 10A by photolithography and etching.

Thereafter, as shown in FIG. 3B, tungsten, which is the material of the lower electrodes 6A and the vias 12A, is deposited by a CVD method inside the via holes 11A and on the interlayer insulating film 2A to form a tungsten deposition layer 31A. A thickness of the tungsten deposition layer 31A on the interlayer insulating film 2A is 0.3 to 0.4 μm (3000 to 4000 Å).

Thereafter, as shown in FIG. 3C, a resist pattern 41A (see FIG. 4) that selectively covers only portions that become the lower electrodes 6A is formed by photolithography on the tungsten deposition layer 31A.

Then, as shown in FIG. 3D, portions of the tungsten deposition layer 31A exposed from the resist pattern 41A are removed by dry etching using the resist pattern 41A as a mask. A mixed gas of sulfur hexafluoride (SF₆) and argon (Ar) is used for the dry etching.

After the dry etching, the resist pattern 41A is removed as shown in FIG. 3E. The lower electrodes 6A and the vias 12A embedded in the via holes 11A are thereby obtained.

Thereafter, as shown in FIG. 3F, a CIGS film 32A is formed by an MBE method on the interlayer insulating film 2A and the lower electrodes 6A.

Thereafter, a resist pattern 42A (see FIG. 4) that selectively covers just the portion that becomes the photoabsorption layer 7A is formed by photolithography on the CIGS film 32A. By then performing dry etching using the resist pattern 42A as a mask, the photoabsorption layer 7A that covers all of the lower electrodes 6A together is obtained as shown in FIG. 3G. Thereafter, the resist pattern 42A is removed.

Thereafter, as shown in FIG. 3H, the high-resistance buffer layer 8A is formed by a CBD method on the upper surface and the side surfaces of the photoabsorption layer 7A.

Then, as shown in FIG. 3I, a zinc oxide film 33A is formed on the upper surface and the side surfaces of the high-resistance buffer layer 8A and on the interlayer insulating film 2A at the periphery by a sputtering method. Thereafter, a resist pattern 43A (see FIG. 4) is formed by photolithography on the zinc oxide film 33A. When the zinc oxide film 33A is then removed from above the pad forming region by dry etching using the resist pattern 43A as a mask, the zinc oxide film 33A becomes the transparent conductive film 9A. When the resist pattern 43A is thereafter removed, the image sensor 1A shown in FIG. 2 is obtained.

A method for manufacturing an image sensor according to a contrasting mode in which the photoabsorption layer is cut and divided individually so as to cover each lower electrode shall now be described.

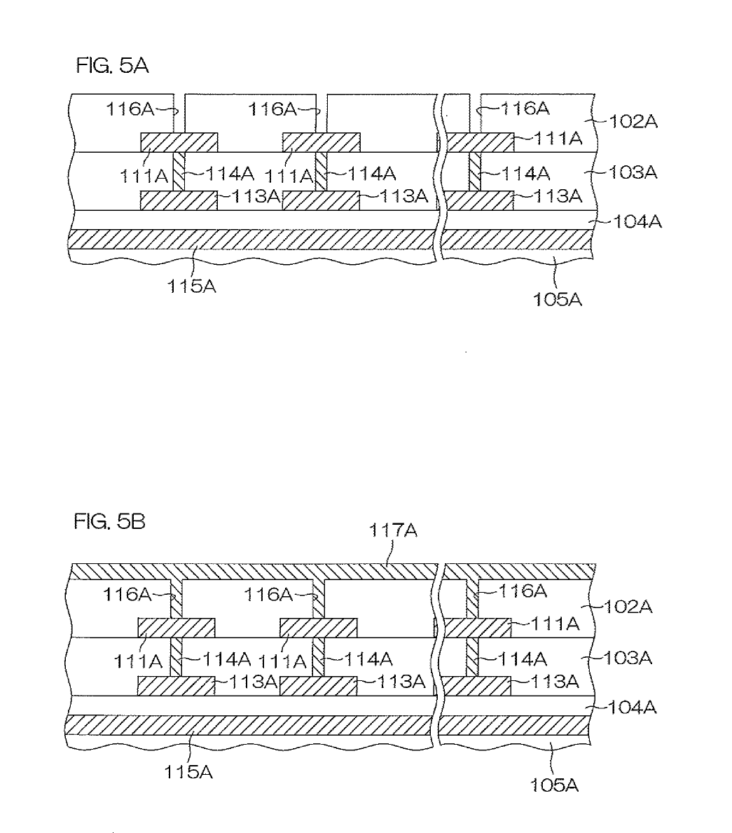

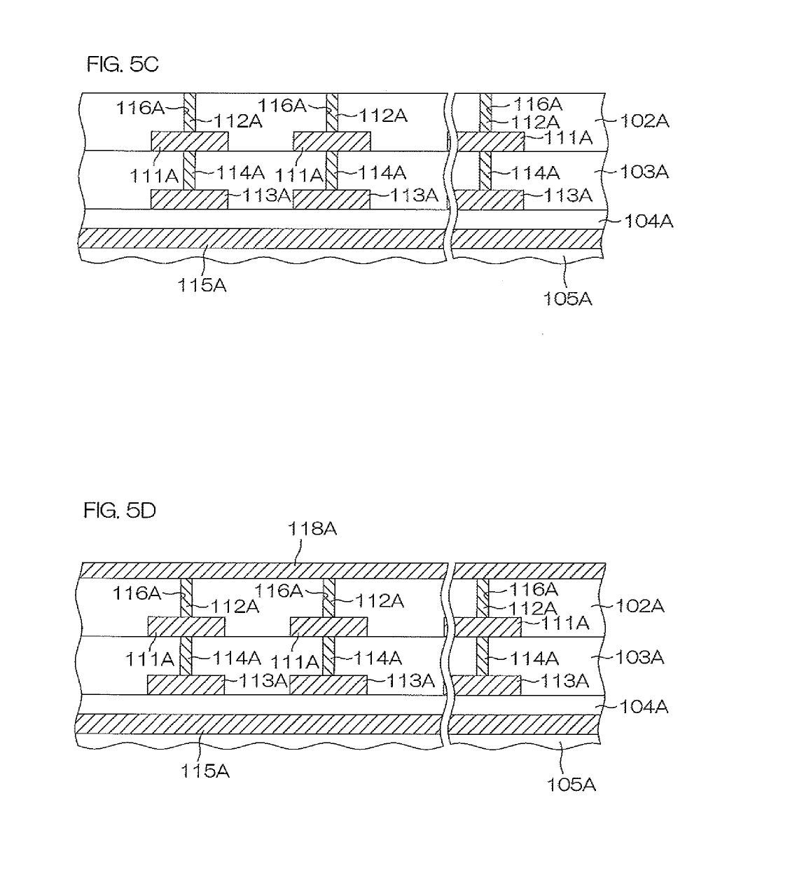

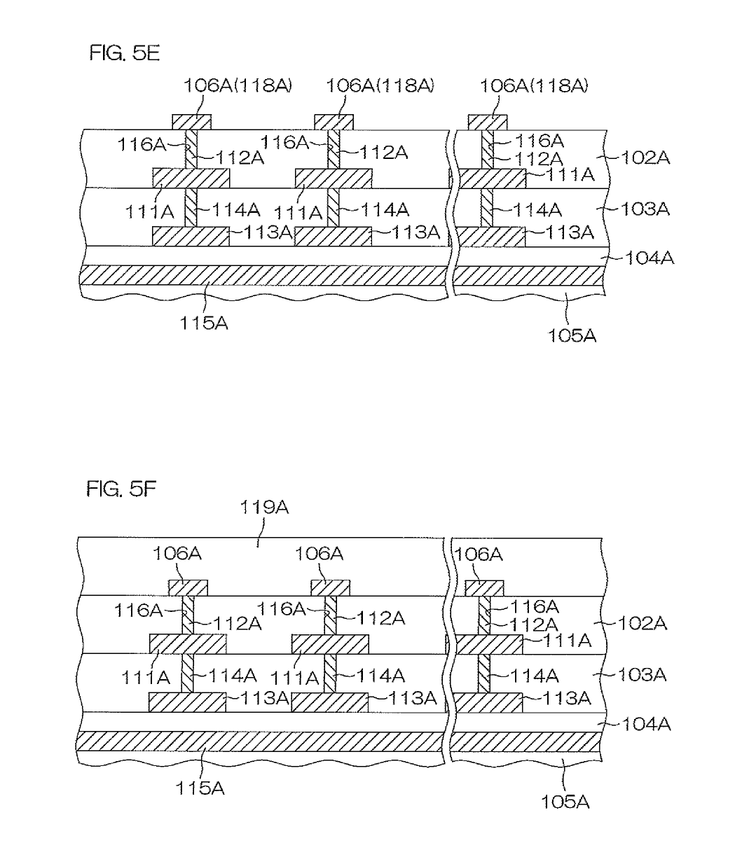

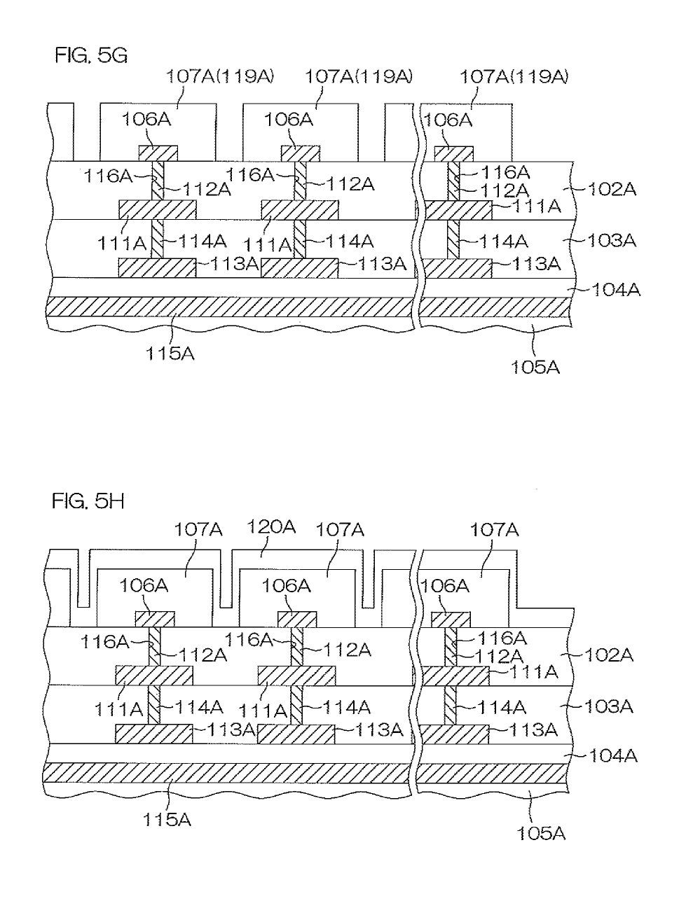

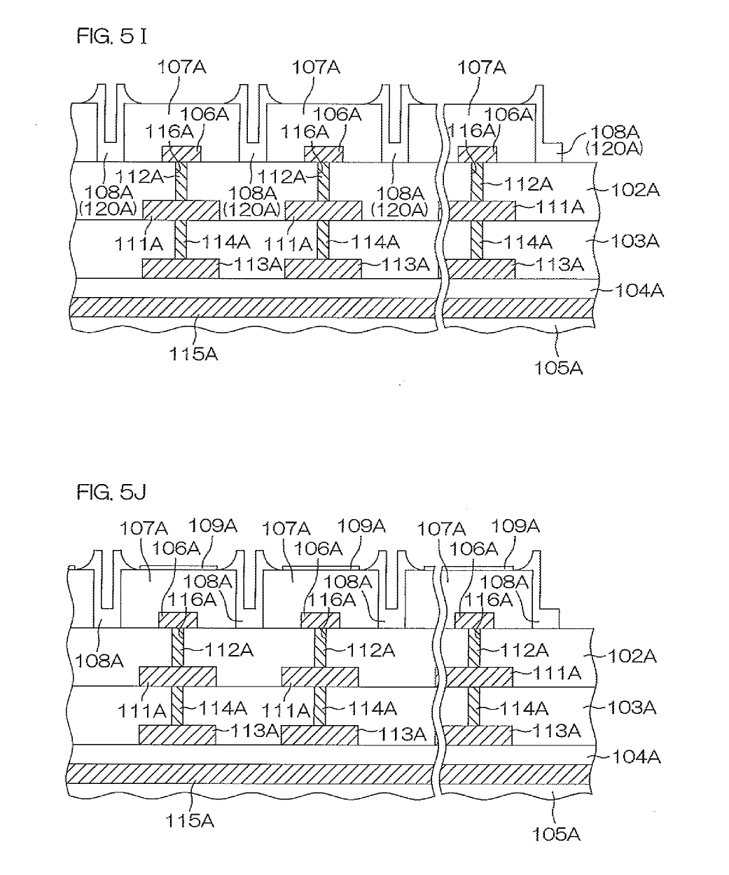

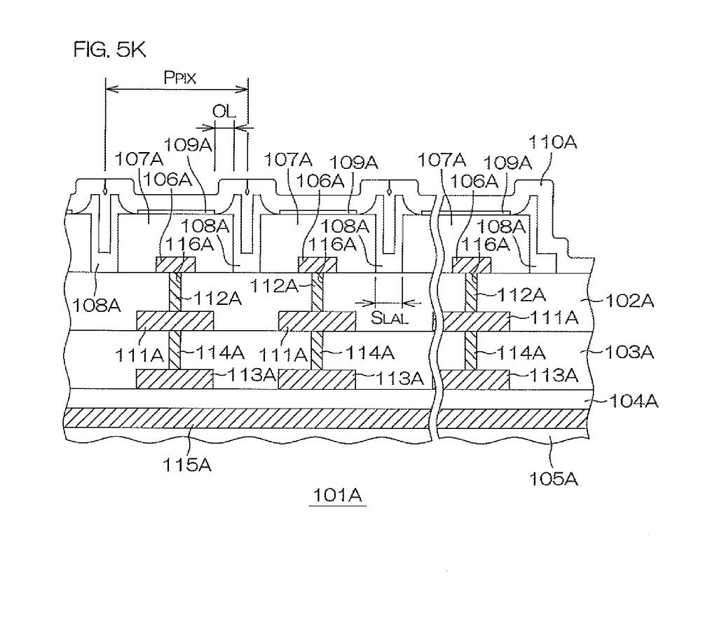

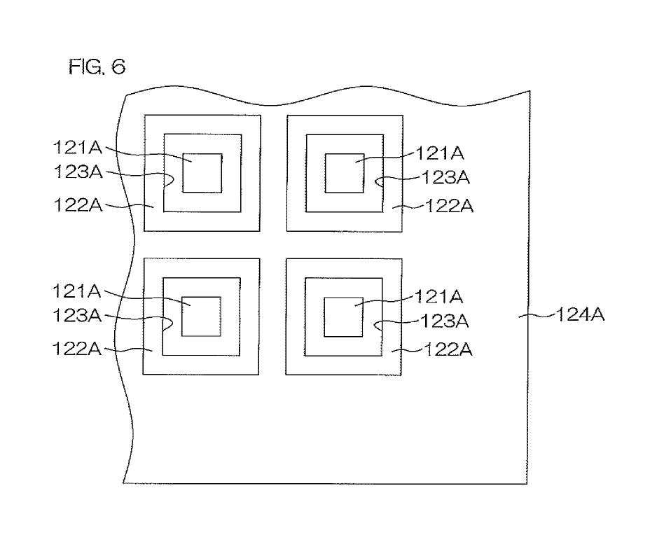

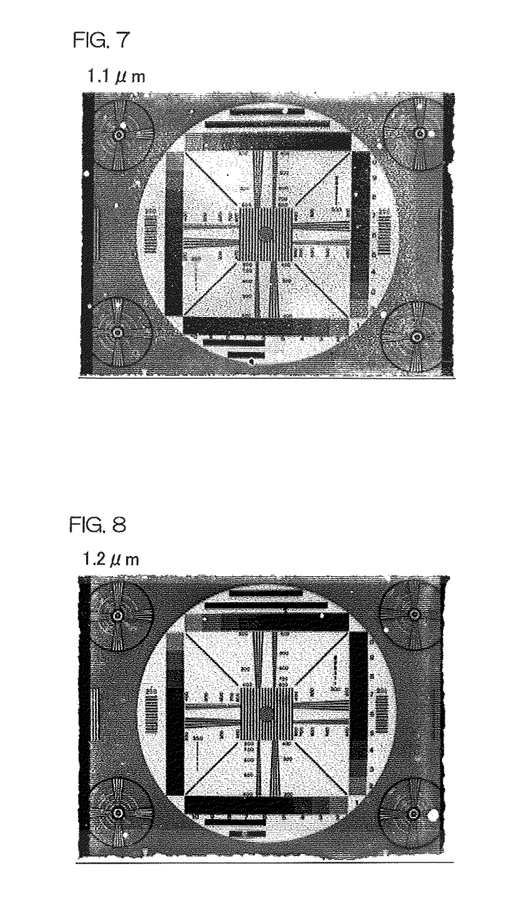

FIG. 5A to FIG. 5K are schematic sectional views of a manufacturing process of an image sensor. FIG. 6 is a diagram for describing resist patterns used in this manufacturing process. In FIG. 5A to FIG. 5K, only portions made of metal materials are hatched and portions besides these are not hatched.

First, as shown in FIG. 5A, an interlayer insulating film 105A, a capacitor lower electrode 115A, a capacitor dielectric film 104A, capacitor upper electrodes 113A, an interlayer insulating film 103A, vias 114A, wirings 111A, and an interlayer insulating film 102A are formed in that order on a semiconductor substrate (not shown). Via holes 116A penetrating through the interlayer insulating film 102A are then formed above the respective wirings 111A by photolithography and etching.

Thereafter, as shown in FIG. 5B, tungsten, which is the material of vias 112A, is deposited by the CVD method inside the via holes 116A and on the interlayer insulating film 102A to form a tungsten deposition layer 117A.

Thereafter, the tungsten deposition layer 117A is polished by a CMP (chemical mechanical polishing) method. The polishing of the tungsten deposition layer 117A is continued until an upper surface of the interlayer insulating film 102A is exposed. The vias 112A that are embedded in the via holes 116A are thereby obtained as shown in FIG. 5C.

After the forming of the vias 112A, a molybdenum film 118A is formed on the interlayer insulating film 102A by the sputtering method as shown in FIG. 5D.

A resist pattern 121A (see FIG. 6) that selectively covers only portions that become lower electrodes 106A is formed by photolithography on the molybdenum film 118A. Portions of the molybdenum film 118A exposed from the resist pattern 121A are then removed by dry etching using the resist pattern 121A as a mask, and the lower electrodes 106A are thereby formed as shown in FIG. 5E. After the forming of the lower electrodes 106A, the resist pattern 121A is removed.

Thereafter, as shown in FIG. 5F, a CIGS film 119A is formed by the MBE (molecular beam epitaxy) method on the interlayer insulating film 102A and the lower electrodes 106A.

Thereafter, a resist pattern 122A (see FIG. 6) that selectively covers just the portions that become photoabsorption layers 107A is formed by photolithography on the CIGS film 119A. By then performing dry etching using the resist pattern 122A as a mask, the portions of the CIGS film 119A that are exposed from the resist pattern 122A are removed and the CIGS film 119A is cut and divided into the photoabsorption layers 107A as shown in FIG. 5G. Thereafter, the resist pattern 122A is removed.

Thereafter, as shown in FIG. 5H, a TEOS film 120A is formed by a CVD (chemical vapor deposition) method using TEOS on the interlayer insulating film 102A and the photoabsorption layers 107A so as to cover these all together.

A resist pattern having openings 123A (see FIG. 6) at portions opposing the respective photoabsorption layers 107A is then formed by photolithography on the TEOS film 120A. The TEOS film 120A is then removed partially by wet etching using the resist pattern as a mask, and as shown in FIG. 5I, the TEOS film 120A becomes an isolation film 108A that exposes portions of the respective photoabsorption layers 107A besides peripheral edge portions of upper surfaces of the photoabsorption layers 107A. After the forming of the isolation film 108A, the resist pattern is removed.

Thereafter, as shown in FIG. 5J, high-resistance buffer layers 109A are formed by the CBD (chemical bath deposition) method on the respective photoabsorption layers 107A exposed from the isolation film 108A.

Thereafter, a zinc oxide film is formed on the isolation film 108A and the high-resistance buffer layers 109A by the sputtering method. A resist pattern 124A (see FIG. 6) is then formed by photolithography on the zinc oxide film. The zinc oxide film is then patterned to a transparent conductive film 110A by dry etching using the resist pattern 124A as a mask, and the image sensor 101A shown in FIG. 5K is thereby obtained.

In such a manufacturing process, the dry etching of the CIGS film 119A is a physical etching that accompanies hardly any chemical reactions. The photoabsorption layers 107A are thus influenced by dry etching, and the side surfaces (surfaces formed by the dry etching) of the photoabsorption layers 107A are roughened, etc. Consequently, variations arise in sizes of the photoabsorption layers 107A and variations in sensitivity may thus occur among pixels.

Also, with the image sensor 101A, a proportion of a pn junction area (light receiving area) with respect to a pixel area tends to be small. The following two reasons R1 and R2 are mainly the reasons why the proportion of the pn junction area with respect to the pixel area is small.

R1. Pixels must be separated from each other reliably to prevent mixing (crosstalk) of photocurrent among mutually adjacent pixels, and for this purpose, no less than 2.0 μm must be secured as an interval S_{LAL} (see FIG. 5K) between mutually adjacent photoabsorption layers 107A.

R2. From the step shown in FIG. 5H to the step shown in FIG. 5I, the method for selectively removing the TEOS film 120A is restricted to wet etching. This is because with dry etching, etching damage is applied to the upper surfaces of the photoabsorption layers 107A, thereby degrading photoelectric conversion characteristics provided by the pn junction of each photoabsorption layer 107A and the transparent conductive film 110A that is to be formed thereafter. Meanwhile, to reliably coat the peripheral edge portions of the photoabsorption layers 107A, no less than 0.5 μm must be secured as the thickness of the TEOS film 120A (isolation film 108A). Thus, in consideration of a margin for deviation of forming position of the resist pattern 124A (see FIG. 6) and a margin for over-etching by wet etching, an overlap amount OL of the upper surface of a photoabsorption layer 107A and the isolation film 108A is set to no less than 1.0 μm (see FIG. 5K).

For example, in a case where the pixel pitch P_{PIX}, which is the width of the region used for reading of a single pixel (see FIG. 5K), is 7.5 μm, the width of the pn junction area (area of a region of the upper surface of the photoabsorption layer 107A that is exposed from the isolation film 108A) is 3.5 μm, and the pn junction area is thus 3.5×3.5=12.25 μm². A pixel aperture ratio, which is the proportion (pn junction area/pixel area) of the pn junction area with respect to the pixel area (area of the region used for reading of a single pixel), is thus 12.25/56.25≈0.22 (=22%).

Also, with the sputtering method, the transparent conductive film 110A cannot be formed so as to completely fill a groove of the isolation film 108A that forms between mutually adjacent photoabsorption layers 107A, and a shrinkage cavity (gap) 131A may form on the groove as shown in FIG. 5K. Zinc oxide is known to undergo degradation with time due to moisture in air, and when a shrinkage cavity 131A is formed, the shrinkage cavity 131A may cause degradation with time of the transparent conductive film 110A even if a topmost surface of the image sensor 101A is covered with a top surface protective film. To prevent the forming of the shrinkage cavity 131A, the thickness of the isolation film 108A may be increased so that a groove of the isolation film 108A does not form between the photoabsorption layers 107A. However, in this case, the overlap amount OL of the upper surface of each photoabsorption layer 107A and the isolation film 108A increases further and the pixel aperture ratio decreases further.

In contrast, with the image sensor 1A shown in FIG. 1 and FIG. 2, the plurality of mutually-spaced lower electrodes 6A disposed on the interlayer insulating film 2A are covered all together by the photoabsorption layer 7A made of CIGS. That is, the photoabsorption layer 7A made of CIGS is not cut and divided so as to individually cover the respective lower electrodes 6A. In other words, the photoabsorption layer 7A made of CIGS is not cut and divided according to each pixel that includes a single lower electrode 6A but is provided in common to a plurality of pixels. The transparent conductive film 9A is formed on the photoabsorption layer 7A so as to cover the photoabsorption layer 7A.

The photoabsorption layer 7A is not cut and divided according to each pixel and thus variation of sensitivity among pixels is not influenced by dry etching for cutting and dividing.

Also, grooves for cutting and dividing the photoabsorption layer 7A are not formed and an isolation film for isolating the photoabsorption layer 7A according to each pixel is not provided because the photoabsorption layer 7A is not cut and divided according to each pixel. The pixel aperture ratio (pn junction area/pixel area) is thus 100%. A large number of carriers can thereby be generated even with weak light and dramatic improvement of sensitivity can be achieved.

Further, a shrinkage cavity does not form during forming of the transparent conductive film 9A because grooves for cutting and dividing the photoabsorption layer 7A are not formed. Degradation with time of the transparent conductive film 9A can thus be prevented and reliability can be improved.

Also, a step of forming an isolation film is unnecessary and the manufacturing process is thus simpler than that of the conventional photoelectric converter and time and cost required for manufacture can be reduced.

The thickness of the photoabsorption layer 7A is no less than 1.0 μm and no more than 1.4 μm. CIGS has an optical absorption coefficient of 1 μm⁻¹ and thus if the thickness of the photoabsorption layer 7A is no less than 1.0 μm, light can be absorbed adequately by the photoabsorption layer 7A and satisfactory photoelectric conversion can be achieved. Meanwhile, by making the thickness of the photoabsorption layer 7A no more than 1.4 μm, an electric field in a direction of a normal (vertical direction) with respect to an interface of the photoabsorption layer 7A and the transparent conductive film 9A (pn junction surface) can be strengthened. By the electric field in the vertical direction being strengthened, carriers generated by the photoelectric conversion are satisfactorily taken into the lower electrode 6A disposed at the portion at which the carriers are generated. Occurrence of so-called crosstalk, in which carriers become mixed in the lower electrode 6A at the portion of carrier generation and an adjacent lower electrode 6A, can thus be prevented.

The lower electrodes 6A are disposed in a matrix and spaced at equal intervals. The interval between mutually adjacent lower electrodes 6A is no less than three times the film thickness of the photoabsorption layer 7A. The strength of the vertical direction electric field is thereby made no less than three times the strength of an electric field in a horizontal direction orthogonal to the vertical direction. In other words, the strength of the horizontal direction electric field is no more than ⅓ the strength of the vertical direction electric field. Occurrence of crosstalk can thus be prevented.

Also, the interval between a lower electrode 6A disposed at an outermost periphery and a side surface of the photoabsorption layer 7A is no less than 50 μm and no more than 100 μm. The side surface of the photoabsorption layer 7A is damaged by dry etching and a dark current may be generated due to the damage. By setting the interval between the lower electrode 6A disposed at the outermost periphery and the side surface of the photoabsorption layer 7A to no less than 50 μm, the dark current can be prevented from being taken into the lower electrode 6A disposed at the outermost periphery. Also, the lower electrode 6A exhibits an anchor effect of preventing peeling of the photoabsorption layer 7A from the interlayer insulating film 2A. By setting the interval between the lower electrode 6A disposed at the outermost periphery and the side surface of the photoabsorption layer 7A to no more than 100 μm, the anchor effect of the lower electrode 6A can be secured and peeling of the photoabsorption layer 7A from the interlayer insulating film 2A can be prevented.

Also, the wirings 10A are disposed at the positions opposing the lower electrodes 6A across the interlayer insulating film 2A and the vias 12A electrically connecting these are formed penetratingly through the interlayer insulating film 2A. The lower electrodes 6A and the vias 12A are made of the same material. The lower electrodes 6A and the vias 12A can be formed in the same step because the material of the lower electrodes 6A and the material of the vias 12A are the same. Thus, the step of polishing the deposition layer of the material of the vias 12A by the CMP method and the step of forming the film made of the material of the lower electrodes 6A by the sputtering method, which are deemed to be required in the manufacture of the conventional photoelectric converter, can be omitted. Consequently, the time and cost required for manufacture can be reduced. Moreover, secure connection of the lower electrodes 6A and the vias 12A can be achieved, and the reliability of electrical connection of the lower electrodes 6A and the vias 12A can be improved.

### EXAMPLES

Although the first aspect of the present invention shall now be described based on examples and comparative examples, the present invention is not restricted to the following examples.

### Example 1

An image sensor with the structure shown in FIG. 2 was prepared with the thickness of the photoabsorption layer being 1.1 μm.

### Example 2

An image sensor with the structure shown in FIG. 2 was prepared with the thickness of the photoabsorption layer being 1.2 μm.

### Example 3

An image sensor with the structure shown in FIG. 2 was prepared with the thickness of the photoabsorption layer being 1.3 μm.

### Example 4

An image sensor with the structure shown in FIG. 2 was prepared with the thickness of the photoabsorption layer being 1.4 μm.

### Comparative Example 1

An image sensor with the structure shown in FIG. 2 was prepared with the thickness of the photoabsorption layer being 1.5 μm.

### <Evaluation of Image Pickup>

Image pickup of the same test pattern was performed using the image sensors of Examples 1 to 4 and Comparative Example 1. Results of image pickup by the image sensors of Examples 1 to 4 are shown respectively in FIG. 7 to FIG. 10. A result of image pickup by the image sensor of Comparative Example 1 is shown in FIG. 11.

As shown in FIG. 7 to FIG. 9, with each of the image sensors of Examples 1 to 3, image pickup results enabling clear recognition of the test pattern were obtained.

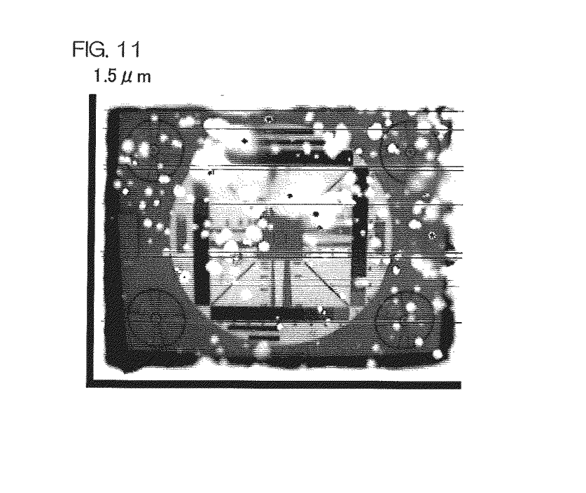

As shown in FIG. 10, although a somewhat unclear image pickup result was obtained with the image sensor of Example 4, details of the test pattern were made recognizable by application of image processing.

As shown in FIG. 11, with the image sensor of Comparative Example 1, an image pickup result that was unclear to a degree such that details of the test pattern could not be made recognizable even upon application of image processing was obtained.

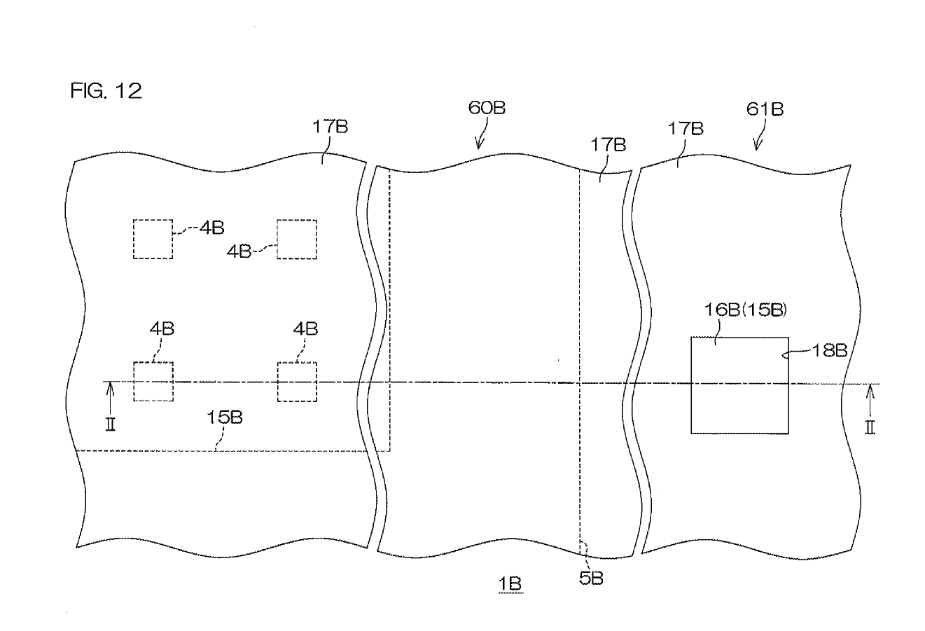

### Preferred Embodiment According to a Second Aspect of the Invention FIG. 12 to FIG. 16

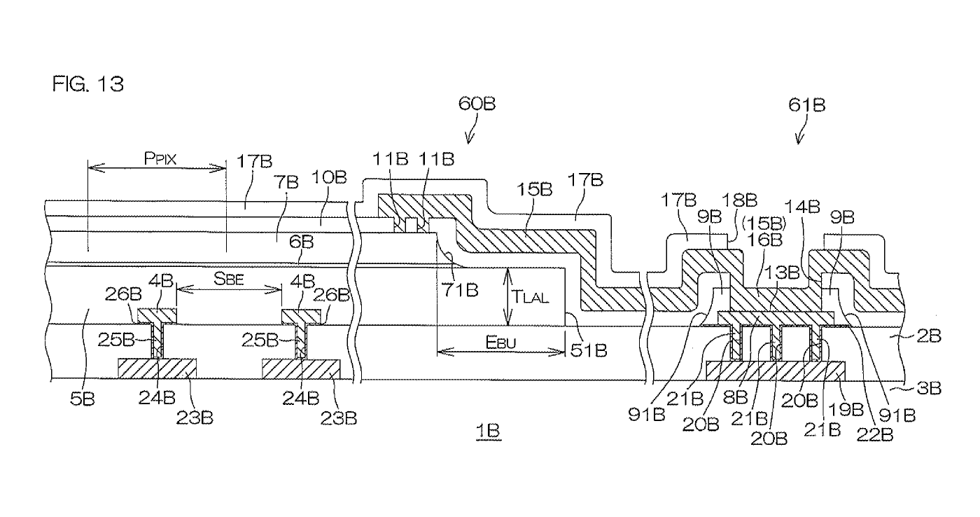

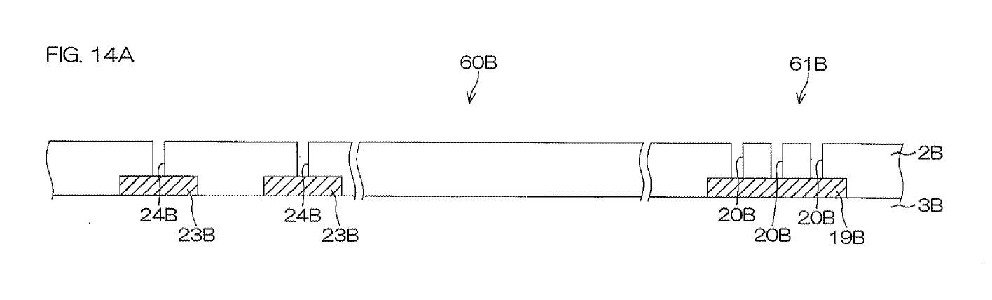

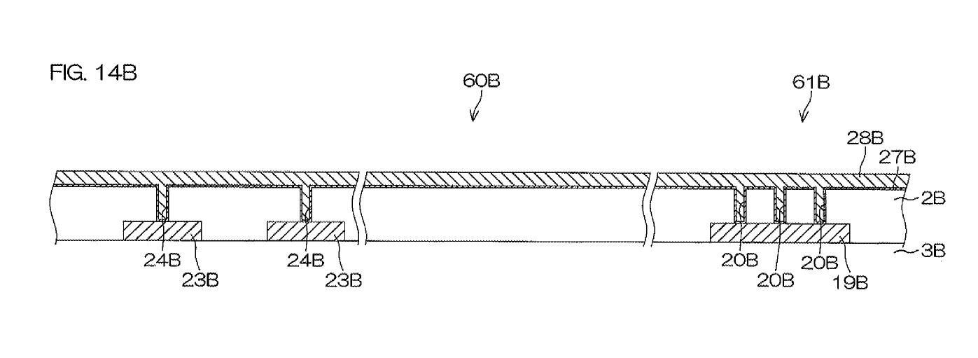

FIG. 12 is a schematic plan view of an image sensor according to a preferred embodiment of a second aspect of the present invention. FIG. 13 is a schematic sectional view of the image sensor taken along sectioning line II-II in FIG. 12. In FIG. 13, only portions made of metal materials are hatched and portions besides these are not hatched.

The image sensor 1B, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2B and 3B are laminated on the semiconductor substrate. The interlayer insulating films 2B and 3B are made, for example, of silicon oxide (SiO₂).

Also, as shown in FIG. 12, a sensor forming region 60B and an annular pad forming region 61B surrounding it are set on the semiconductor substrate.

In the sensor forming region 60B, a plurality of lower electrodes 4B are arrayed in a matrix on the uppermost interlayer insulating film 2B. The lower electrodes 4B are made of tungsten (W). Each lower electrode 4B is formed to a square shape in a plan view. For example, in the case of 7.5 μm pitch, a length of one side of the lower electrode 4B in a plan view is no less than 2.0 μm and no more than 3.3 μm. The lower electrode 4B has a thickness of no less than 0.2 μm and no more than 0.4 μm. Also, as shown in FIG. 13, mutually adjacent lower electrodes 4B are spaced apart at equal intervals S_{BE} (≧T_{LAL}×3) each set to no less than three times the thickness T_{LAL} of a photoabsorption layer 5B to be described below.

The photoabsorption layer 5B of rectangular shape in a plan view is formed on the interlayer insulating film 2B so as to cover all of the lower electrodes 4B together. Specifically, the photoabsorption layer 5B is formed integrally on a rectangular region on the interlayer insulating film 2B in which the lower electrodes 4B are formed and on a rectangular annular region of fixed width at a periphery of the rectangular region. The photoabsorption layer 5B is made of CIGS and exhibits a p-type conductivity. The thickness T_{LAL} of the photoabsorption layer 5B is no less than 1.0 μm and no more than 1.4 μm. In the photoabsorption layer 5B, each region of fixed area and rectangular shape in a plan view that is centered at each lower electrode 4B is used for reading of a single pixel. The pixel pitch P_{PIX} that is the width of this region is no less than 5 μm and no more than 10 μm.

An upper surface of the photoabsorption layer 5B, with the exception of a peripheral edge portion thereof, is covered by a high-resistance buffer layer 6B. The high-resistance buffer layer 6B is made of cadmium sulfide (CdS). The high-resistance buffer layer 6B has a thickness, for example, of 0.05 μm.

On the high-resistance buffer layer 6B, a transparent conductive film 7B is formed so as to cover an entire upper surface of the high-resistance buffer layer 6B. The transparent conductive film 7B is made of zinc oxide (ZnO), which has a light transmitting property, and has conductivity imparted by addition of an n-type impurity (for example, Al₂O₃ (alumina)). The transparent conductive film 7B has a thickness, for example, of 0.6 μm.

A side surface 71B of the transparent conductive film 7B is formed to a cross-sectional shape that is downwardly (inwardly) concavely curved and inclined so that as its lower end is approached, a side surface 51B of the photoabsorption layer 5B is approached. A lower end of the side surface 71B is continuous with a peripheral edge of the high-resistance buffer layer 6B. An upper end of the side surface 71B is positioned inward with respect to the side surface 51B of the photoabsorption layer 5B by just a horizontal distance E_{BU}. The horizontal distance E_{BU} is no less than 5 μm and no more than 10 μm.

In the pad forming region 61B, a relay electrode 8B is formed on the uppermost interlayer insulating film 2B. The relay electrode 8B is made of the same material (tungsten) as the lower electrode 4B. The relay electrode 8B is formed to a square shape in a plan view. A length of one side of the relay electrode 8B in a plan view is no less than 60 μm and no more than 120 μm. The relay electrode 8B has a thickness of no less than 0.2 μm and no more than 0.4 μm.

Also, in the pad forming region 61B, a protective film 9B is formed on the uppermost interlayer insulating film 2B so as to cover a peripheral edge portion of the relay electrode 8B. The protective film 9B is made of silicon oxide (SiO₂). A side surface 91B of the protective film 9B is formed to a cross-sectional shape that is curved so as to be downwardly (inwardly) concave as its lower end is approached. The protective film 9B has a thickness of no less than 4000 Å and no more than 6000 Å.

An interlayer insulating film 10B is formed on a portion of the interlayer insulating film 2B exposed from the photoabsorption layer 5B, on a peripheral edge portion of the photoabsorption layer 5B, on the transparent conductive film 7B, and on the protective film 9B so as to spread across these portions and films. The interlayer insulating film 10B is made of silicon nitride (SiN). The interlayer insulating film 10B has a thickness, for example, of 0.4 μm. Above a peripheral edge portion of the transparent conductive film 7B, a plurality of via holes 11B are penetratingly formed in the interlayer insulating film 10B. The via holes 11B form, for example, two columns and are mutually spaced and disposed along the peripheral edge of the transparent conductive film 7B.

Also, in the pad forming region 61B, a pad opening 14B, exposing a portion of the relay electrode 8B as a pad 13B, is formed in the interlayer insulating film 10B and the protective film 9B so as to continuously penetrate through these films. The pad opening 14B has a depth of no less than 5000 Å and no more than 6000 Å.

On the interlayer insulating film 10B, an upper electrode 15B is formed so as to cover entire peripheries of peripheral edge portions of the photoabsorption layer 5B and the transparent conductive film 7B. The upper electrode 15B is made of aluminum (Al). An extending portion 16B, extending toward the pad forming region 61B, is formed integral to the upper electrode 15B. An end portion of the extending portion 16B enters inside the pad opening 14B and is connected to the pad 13B (relay electrode 8B) inside the pad opening 14B.

Also, a top surface protective film 17B is formed on a topmost surface of the image sensor 1B. The top surface protective film 17B is made, for example, of silicon nitride. In the top surface protective film 17B, an opening 18B for exposing the portion of the extending portion 16B of the upper electrode 15B that enters into the pad opening 14B is formed at a position opposing the pad opening 14B.

Also, in the pad forming region 61B and between the interlayer insulating film 2B and the interlayer insulating film 3B below it, a first wiring 19B is formed at a position opposing the relay electrode 8B. A plurality of first via holes 20B are formed penetratingly through the interlayer insulating film 2B between the relay electrode 8B and the opposing first wiring 19B in the direction in which these oppose each other (thickness direction of the interlayer insulating film 2B). Each first via hole 20B has an inner diameter of, for example, 0.4 μm.

In each first via hole 20B, a first via 21B, made of the same material as the relay electrode 8B, is formed integral to the relay electrode 8B and without any gaps.

Also, a barrier film 22B is interposed between the relay electrode 8B plus the first vias 21B and the interlayer insulating film 2B. The barrier film 22B is made of titanium nitride (TiN). The relay electrode 8B is electrically connected to the opposing first wiring 19B via the first vias 21B and the barrier film 22B.

Also, in the sensor forming region 60B and between the uppermost interlayer insulating film 2B and the interlayer insulating film 3B below it, second wirings 23B are formed at positions opposing the respective lower electrodes 4B. A second via hole 24B is formed penetratingly through the interlayer insulating film 2B between each lower electrode 4B and the opposing second wiring 23B in the direction in which these oppose each other (thickness direction of the interlayer insulating film 2B). In each second via hole 24B, a second via 25B, made of the same material as the lower electrode 4B, is formed integral to the lower electrode 4B and without any gaps. Each lower electrode 4B is thereby electrically connected to the opposing second wiring 23B via the second via 25B. Each second via hole 24B has an inner diameter of, for example, 0.4 μm.

Also, a barrier film 26B is interposed between each lower electrode 4B plus the second via 25B and the interlayer insulating film 2B. The barrier films 26B are made of titanium nitride (TiN). Each lower electrode 4B is electrically connected to the opposing second wiring 23B via the second vias 25B and the barrier film 26B.

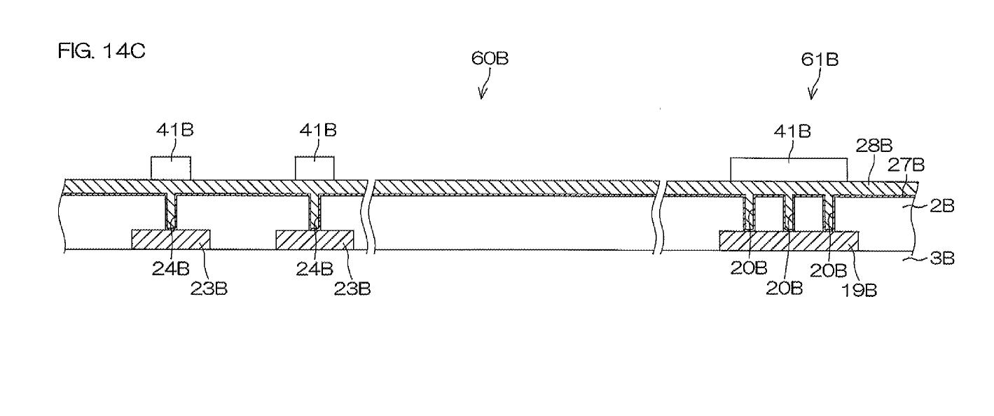

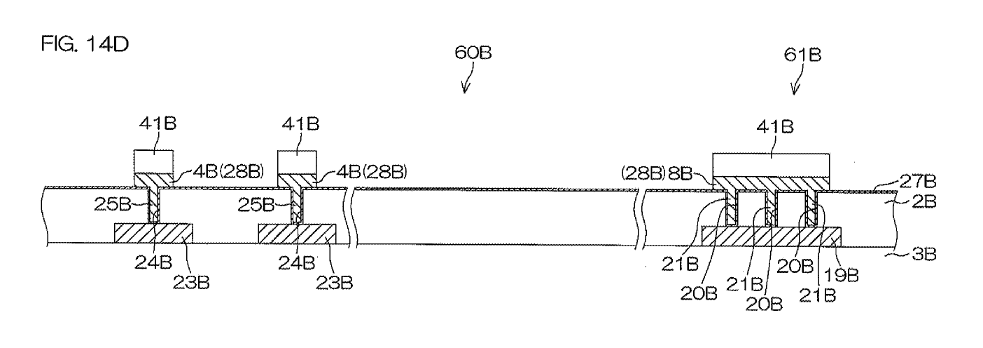

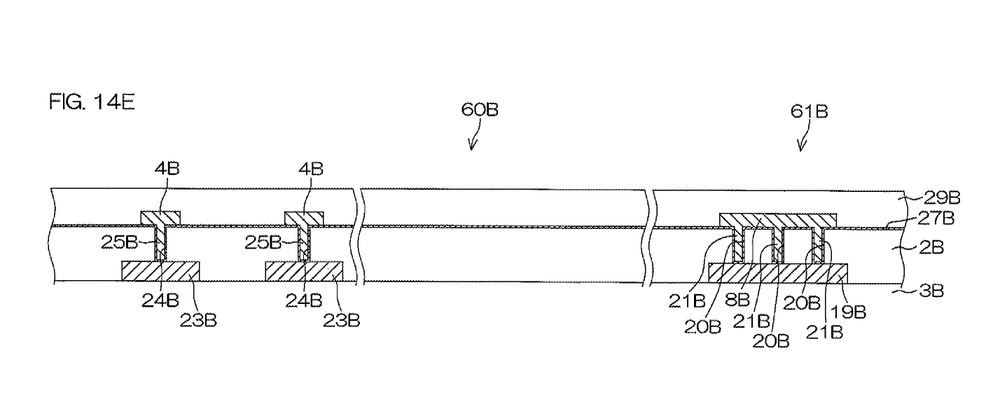

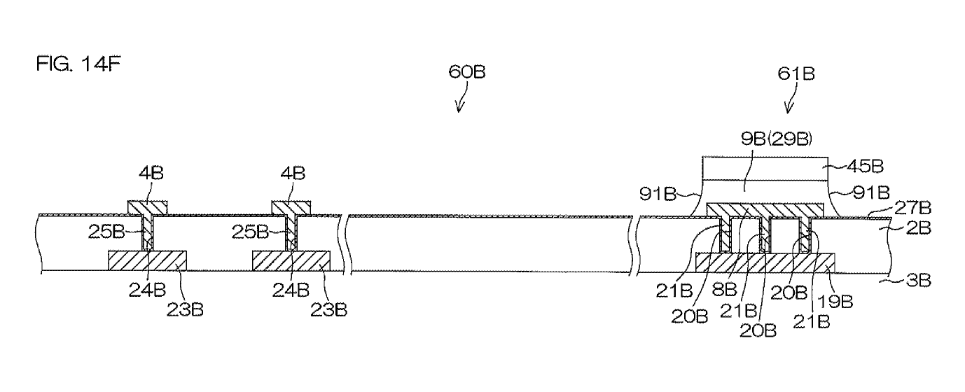

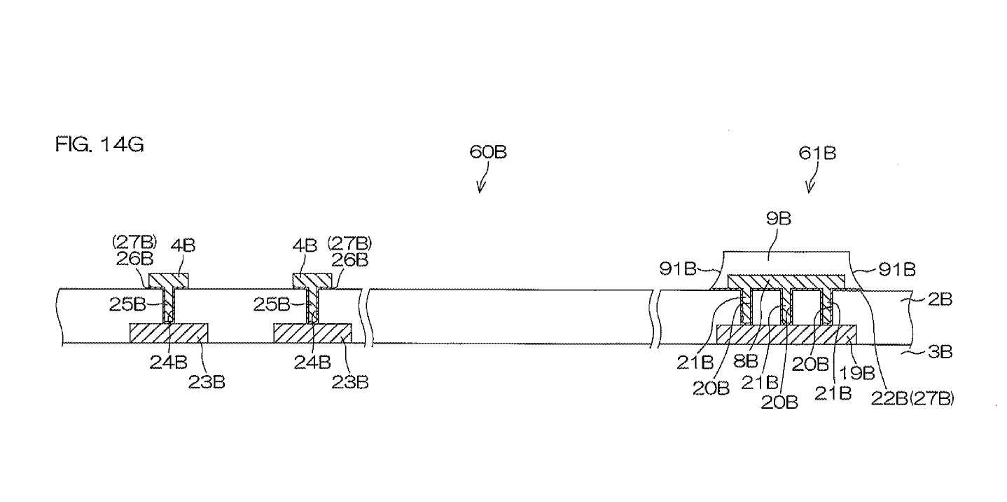

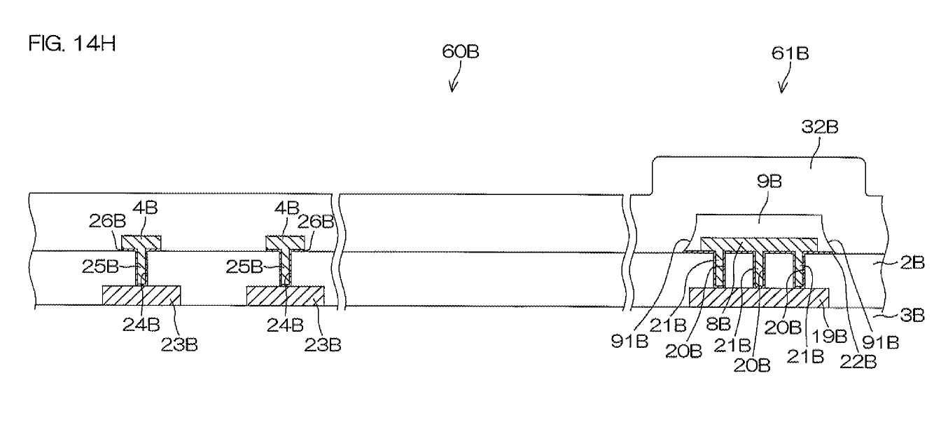

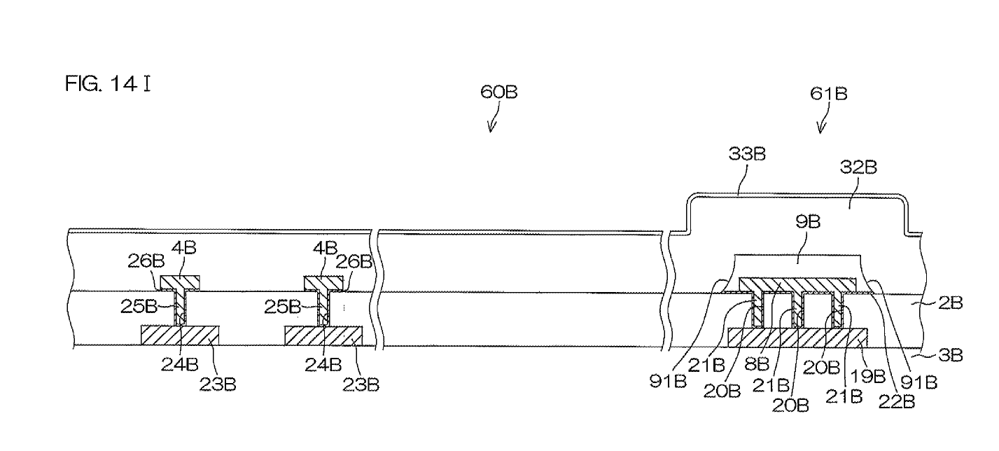

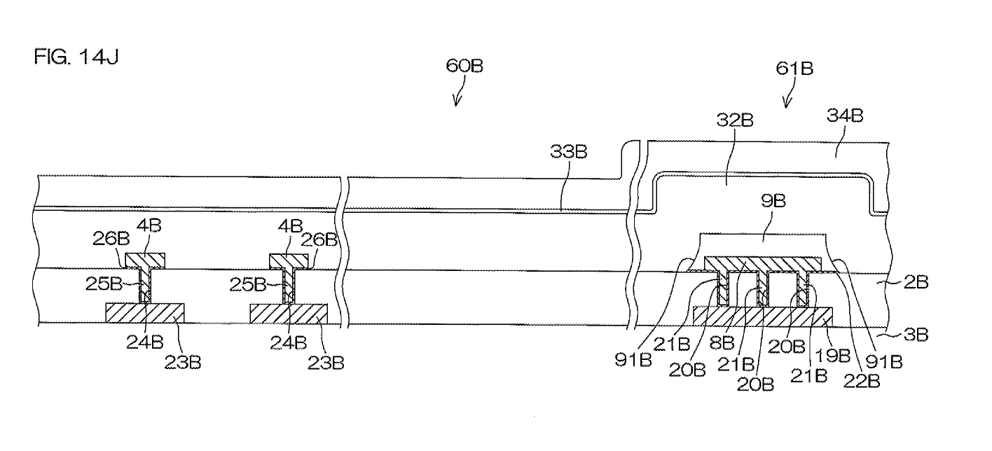

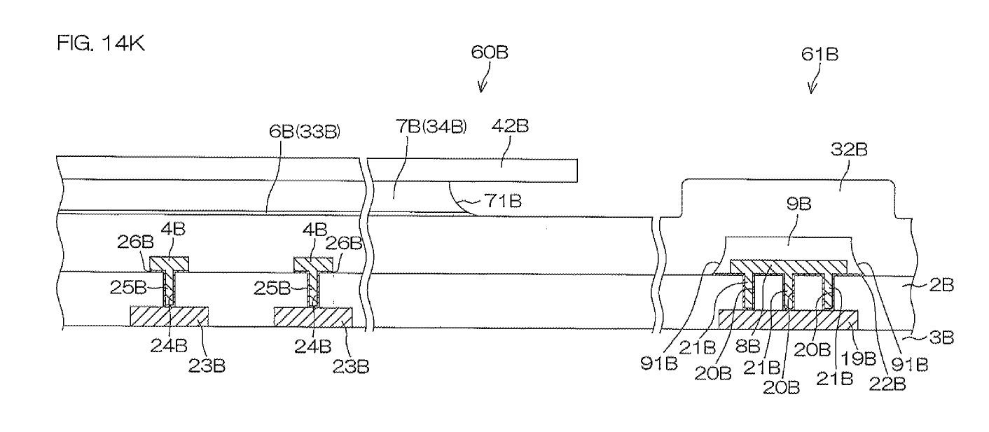

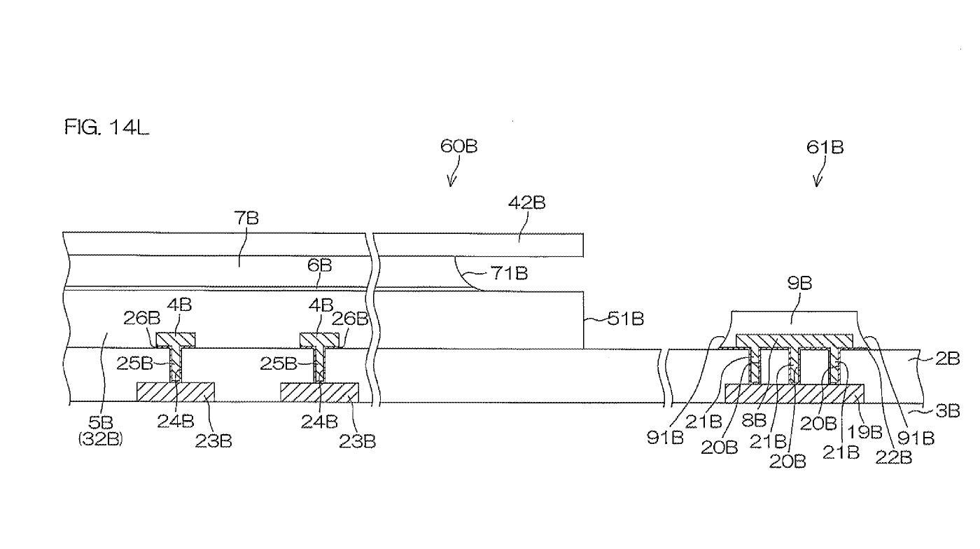

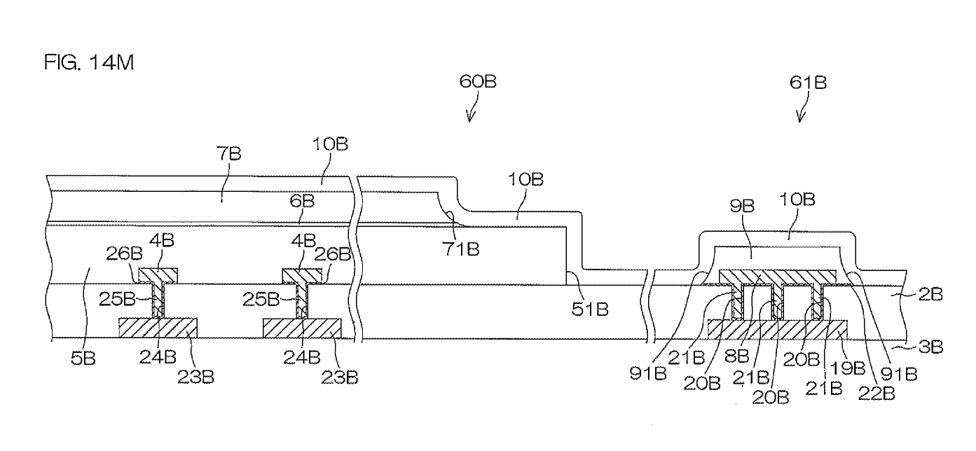

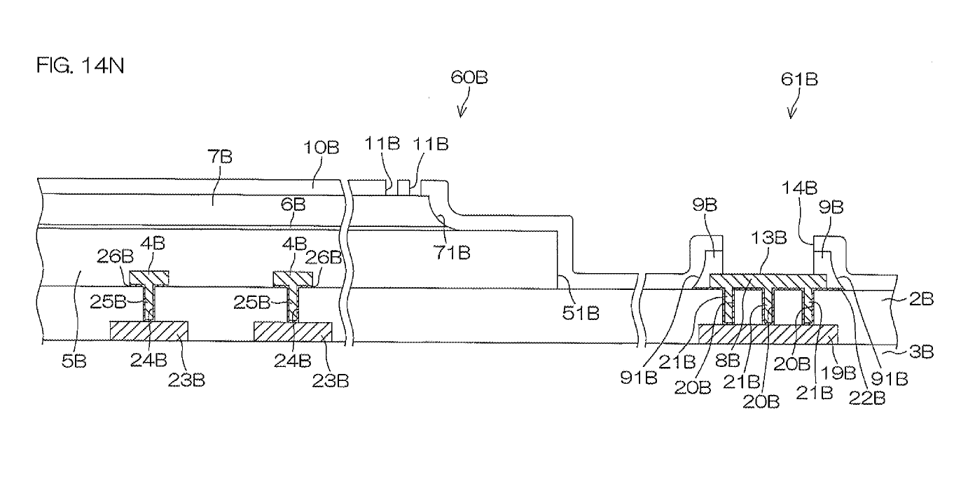

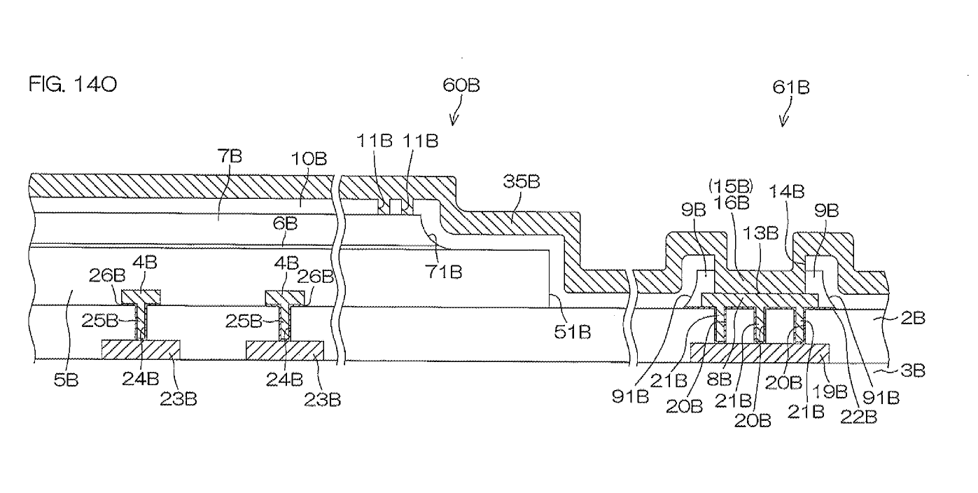

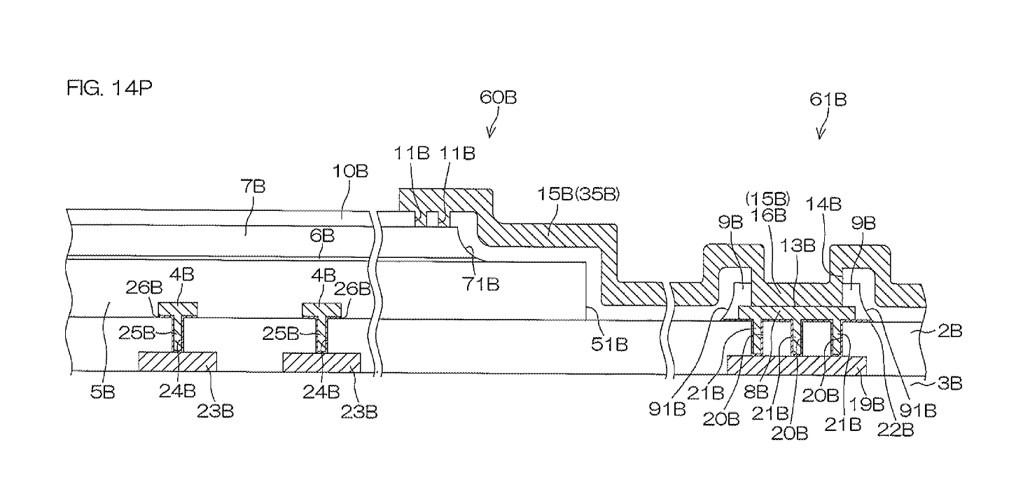

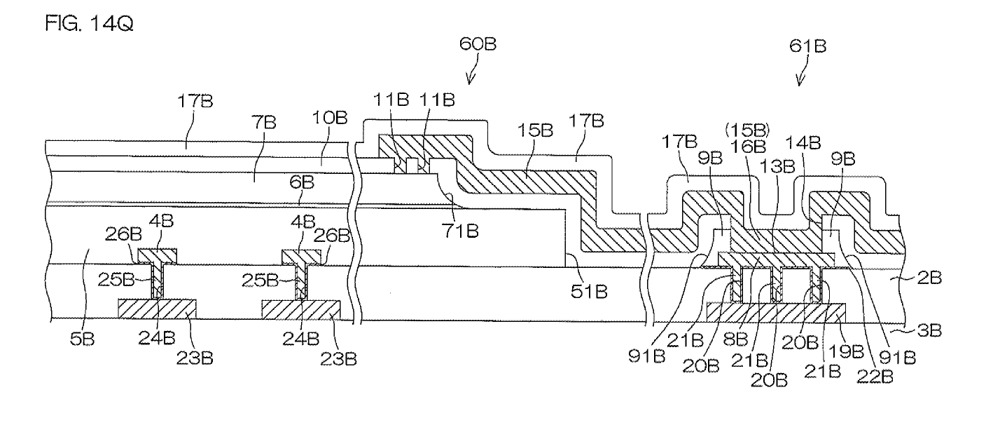

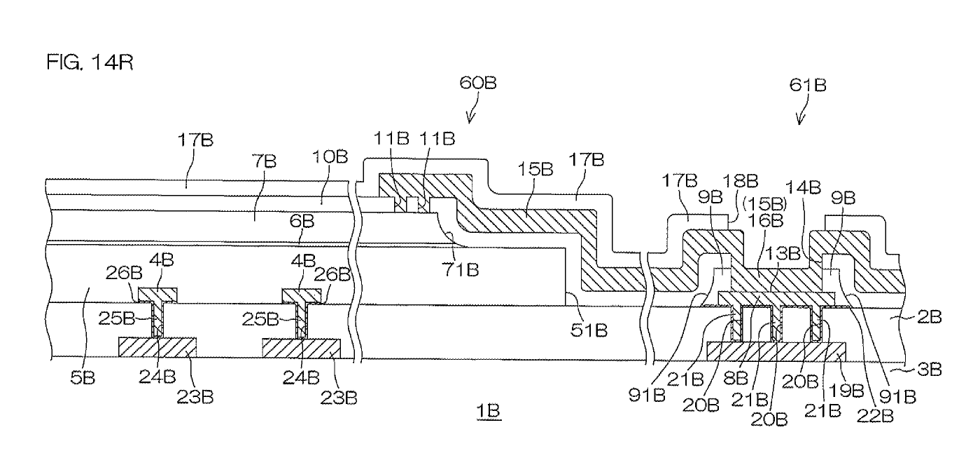

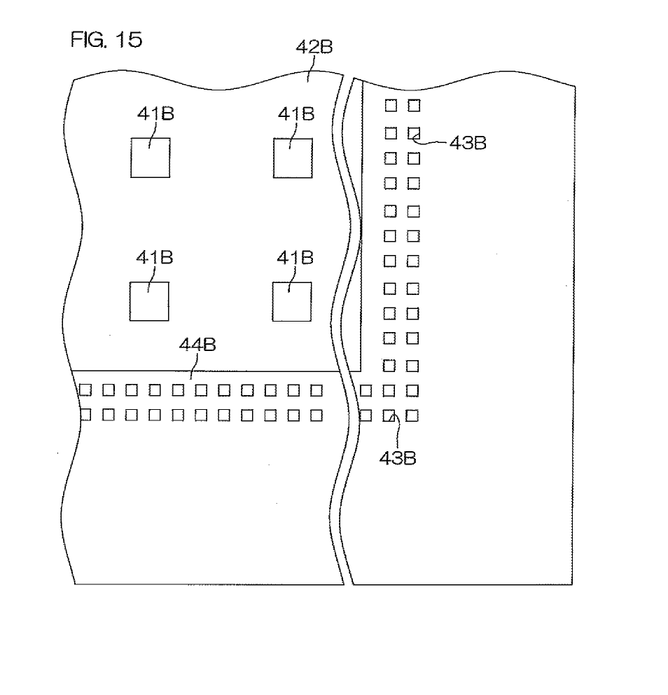

FIG. 14A to FIG. 14R are schematic sectional views that successively illustrate a manufacturing process of the image sensor shown in FIG. 13. FIG. 15 is a diagram for describing resist patterns used in the manufacturing process. In FIG. 14A to FIG. 14R, only portions made of metal materials are hatched and portions besides these are not hatched.

In the manufacturing process of the image sensor 1B, first, as shown in FIG. 14A, the interlayer insulating film 3B, the first wiring 19B plus the second wirings 23B, and the interlayer insulating film 2B are formed in that order on the semiconductor substrate (not shown). The first via holes 20B penetrating through the interlayer insulating film 2B are then formed above the first wiring 19B and, at the same time, the second via holes 24B penetrating through the interlayer insulating film 2B are formed above the second wirings 23B, respectively, by photolithography and etching.

Thereafter, as shown in FIG. 14B, a barrier film 27B is formed on the interlayer insulating film 2B by the sputtering method. The barrier film 27B is made of a material (for example, titanium nitride) having etch selectivity with respect to a TEOS film 29B (to be described below). The barrier film 27B is also formed inside the first via holes 20B and the second via holes 24B. Thereafter, tungsten, which is the material of the lower electrodes 4B, the relay electrode 8B, the first vias 21B, and the second vias 25B, is deposited by the CVD method inside the first via holes 20B and the second via holes 24B and on the interlayer insulating film 2B to form a tungsten deposition layer 28B. A thickness of the tungsten deposition layer 28B on the interlayer insulating film 2B is 0.2 to 0.4 μm (2000 to 4000 Å).

Thereafter, as shown in FIG. 14C, a resist pattern 41B (see FIG. 15; in FIG. 15, a portion covering the relay electrode 8B is omitted) that selectively covers only portions that become the lower electrodes 4B and a portion that becomes the relay electrode 8B is formed by photolithography on the tungsten deposition layer 28B.

Then, as shown in FIG. 14D, portions of the tungsten deposition layer 28B exposed from the resist pattern 41B are removed by dry etching using the resist pattern 41B as a mask. The mixed gas of sulfur hexafluoride (SF₆) and argon (Ar) is used for the dry etching. The second vias 25B embedded in the second via holes 24B, the lower electrodes 4B, the first vias 21B embedded in the first via holes 20B, and the relay electrode 8B are thereby obtained at the same time.

After the dry etching, the resist pattern 41B is removed as shown in FIG. 14E. Thereafter, by the CVD (chemical vapor deposition) method using TEOS, the TEOS film 29B is formed on the interlayer insulating film 2B so as to cover the lower electrodes 4B and the relay electrode 8B all together.

Then, as shown in FIG. 14F, a resist pattern 45B is formed to selectively cover only the portion that becomes the protective film 9B. By then performing wet etching using the resist pattern 45B as a mask, the portion of the TEOS film 29B that is exposed from the resist pattern 45B is removed. Hydrofluoric acid (HF) is used for the wet etching. Here, the barrier film 27B is formed on the interlayer insulating film 2B, and the barrier film 27B acts as an etching stopper film and contact of the etching liquid (hydrofluoric acid) with the interlayer insulating film 2B is prevented. The TEOS film 29B thereby becomes the protective film 9B that exposes the lower electrodes 4B and covers the relay electrode 8B and the curved side surface 91B of the protective film 9B is obtained.

Thereafter, as shown in FIG. 14G, portions of the barrier film 27B exposed from the lower electrodes 4B and the relay electrode 8B are removed by dry etching. A chlorine (Cl₂) based gas is used for the dry etching. The barrier film 27B thereby becomes the barrier films 26B that prevent contact of the lower electrodes 4B plus the second vias 25B with the interlayer insulating film 2B and the barrier film 22B that prevents contact of the relay electrode 8B plus the first vias 21B with the interlayer insulating film 2B.

Thereafter, as shown in FIG. 14H, a CIGS film 32B is formed by the MBE method on the interlayer insulating film 2B and the lower electrodes 4B.

Thereafter, as shown in FIG. 14I, a cadmium sulfide film 33B is formed by the CBD method on the CIGS film 32B.

Further in succession, a zinc oxide film 34B is formed by the sputtering method on the cadmium sulfide film 33B as shown in FIG. 14J.

Then, as shown in FIG. 14K, a resist pattern 42B (see FIG. 15) is formed by photolithography on the zinc oxide film 34B. The resist pattern 42B opposes a portion of the CIGS film 32B that is to become the photoabsorption layer 5B. Then, using the resist pattern 42B as a mask, the zinc oxide film 34B and the cadmium sulfide film 33B are removed selectively by wet etching by hydrofluoric acid (HF). The wet etching is continued for a predetermined time even after the portion of the zinc oxide film 34B that does not oppose the resist pattern 42B has been removed. The zinc oxide film 34B is thereby removed from below a peripheral edge portion of the resist pattern 42B as well. Consequently, the zinc oxide film 34B and the cadmium sulfide film 33B become the transparent conductive film 7B and the high-resistance buffer layer 6B, respectively, and the curved side surface 71B of the transparent conductive film 7B is obtained.

Then, while leaving the resist pattern 42B, dry etching using the resist pattern 42B as a mask is performed to selectively remove the CIGS film 32B as shown in FIG. 14L. The CIGS film 32B is left only at the portion opposing the resist pattern 42B. The CIGS film 32B thereby becomes the photoabsorption layer 5B. Thereafter, the resist pattern 42B is removed.

Thereafter, as shown in FIG. 14M, the interlayer insulating film 10B is formed coveringly by the plasma CVD method on the portion of the interlayer insulating film 2B exposed from the photoabsorption layer 5B, on the peripheral edge portion of the photoabsorption layer 5B, on the transparent conductive film 7B, and on the protective film 9B.

A resist pattern 44B having openings 43B (see FIG. 15) that selectively expose portions at which the via holes 11B and the pad opening 14B are to be formed is formed by photolithography on the interlayer insulating film 10B. By then performing dry etching using the resist pattern 44B as a mask, the via holes 11B that penetrate through the interlayer insulating film 10B are formed as shown in FIG. 14N. Also, the pad opening 14B that penetrates continuously through the interlayer insulating film 10B and the protective film 9B is formed.

Thereafter, as shown in FIG. 14O, an aluminum film 35B made of aluminum is formed by the sputtering method on the interlayer insulating film 10B. The aluminum film 35B is also formed inside the via holes 11B and the pad opening 14B. The via holes 11B are completely filled with the aluminum film 35B.

A resist pattern 44B (see FIG. 15) that covers a portion that is to become the upper electrode 15B is formed by photolithography on the aluminum film 35B. The aluminum film 35B is then removed selectively by dry etching using the resist pattern 44B as a mask, and the aluminum film 35B is thereby processed to the upper electrode 15B as shown in FIG. 14P. Thereafter, as shown in FIG. 14Q, the top surface protective film 17B is formed by the plasma CVD method, and when the opening 18B is formed by photolithography and etching as shown in FIG. 14R, the image sensor 1B shown in FIG. 13 is obtained.

As described above, with the image sensor 1B, the plurality of mutually-spaced lower electrodes 4B disposed on the interlayer insulating film 2B are covered all together by the photoabsorption layer 5B made of CIGS. That is, the photoabsorption layer 5B is not cut and divided according to each pixel, and thus, as in the preferred embodiment according to the first aspect of the present invention, variation of sensitivity among pixels is not influenced by damage due to dry etching.

Also, as in the preferred embodiment according to the first aspect of the present invention, the pixel aperture ratio (pn junction area/pixel area) can be made 100% because the photoabsorption layer 5B is not cut and divided according to each pixel. A large number of carriers can thereby be generated even with weak light and dramatic improvement of sensitivity can be achieved.

Further, a shrinkage cavity does not form during forming of the transparent conductive film 7B because grooves for cutting and dividing the photoabsorption layer 5B are not formed. Degradation with time of the transparent conductive film 7B can thus be prevented and reliability can be improved.

Also, a step of forming an isolation film is unnecessary and the manufacturing process is thus simpler than that of the conventional photoelectric converter and time and cost required for manufacture can be reduced.

Also, with the manufacturing method described above, the TEOS film 29B is formed to cover the relay electrode 8B before dry etching of the CIGS film 32B. Then, after processing of the TEOS film 29B to the protective film 9B, the CIGS film 32B is dry etched to form the photoabsorption layer 5B in the state where the relay electrode 8B is covered by the protective film 9B. The relay electrode 8B is thus not exposed to the etching gas during the dry etching of the CIGS film 32B. Consequently, the relay electrode 8B that is maintained in a satisfactory surface state can be left on the interlayer insulating film 2B. Wire bonding strength can thus be improved.

Also, by the etching gas used in the dry etching of the CIGS film 32B, the protective film 9B that covers the relay electrode 8B is made thinner than it was when it was formed. For example, it becomes 4000 Å to 1000 Å and thus approximately 3000 Å thinner. A difference between the thickness of the interlayer insulating film 10B that covers the transparent conductive film 7B and the total thickness of the protective film 9B and the interlayer insulating film 10B that cover the relay electrode 8B is thus comparatively small. The etching time necessary for forming the pad opening 14B is thus made substantially the same as the etching time necessary for forming the via holes 11B, with which there is no need to etch the protective film 9B. Consequently, damage of the transparent conductive film 7B due to etching during the forming of the via holes 11B and the pad opening 14B can be reduced. Lowering of reliability of the image sensor 1B can thus be suppressed.

Further, by the protective film 9B being made thinner than when it was formed, the total thickness of the protective film 9B and the interlayer insulating film 10B is decreased and thus the depth of the pad opening 14B can be decreased. The upper electrode 15B can thus be deposited with good coating property even at a step portion between the interior and the exterior of the pad opening 14B.

Also, the lower electrodes 4B, the relay electrode 8B, the first vias 21B, and the second vias 25B are all made of the same material and thus the lower electrodes 4B, the relay electrode 8B, the first vias 21B, and the second vias 25B can be formed in the same step. Thus, the step of polishing the deposition layer of the material of the vias by the CMP method and the step of forming the film made of the material of the lower electrodes by the sputtering method, which are deemed to be required in the manufacture of the conventional image sensor, can be omitted. The time and cost required for manufacture can be reduced thereby as well. Also, secure connection of the lower electrodes 4B and the second vias 25B and secure connection of the relay electrode 8B and the first vias 21B can be achieved, and the reliability of electrical connection of the lower electrodes 4B and the second vias 25B and the reliability of electrical connection of the relay electrode 8B and the first vias 21B can be improved.

Also, if the removal of the TEOS film 29B is executed by dry etching, the top surfaces of the lower electrodes 4B may be damaged by the etching gas during the etching. However, by executing the removal by wet etching as described above, the damaging of the lower electrodes 4B can be reduced. The surface states of the lower electrodes 4B can thus be maintained in satisfactory states. Consequently, lowering of reliability of the image sensor 1B can be suppressed.

Further, the barrier film 27B formed in the step of FIG. 14B has etch selectivity with respect to the TEOS film 29B, and the barrier film 27B can thus be used as the etching stopper film when wet etching of the TEOS film 29B is performed in the step of FIG. 14F. A step of forming an etching stopper film can thus be eliminated. Consequently, the time and cost required for manufacture can be reduced.

Also, in the manufacturing process of the image sensor 1B, the resist pattern 42B used in the wet etching for processing the zinc oxide film 34B to the transparent conductive film 7B is also used in the dry etching for processing the CIGS film 32B to the photoabsorption layer 5B and a mask (resist pattern) used exclusively for the dry etching is not formed. The manufacturing process of the image sensor 1B can thus be simplified.

Also, as shown in FIG. 14H to FIG. 14J, the CIGS film 32B, the cadmium sulfide film 33B, and the zinc oxide film 34B are formed consecutively. The time from the forming of the CIGS film 32B to the completion of forming of the zinc oxide film 34B can thus be made short, and the CIGS film 32B, the cadmium sulfide film 33B, and the zinc oxide film 34B can be respectively improved in film quality.

Further, the pad opening 14B and the via holes 11B are formed in the same step (step shown in FIG. 14N) and thus in comparison to a case where these are formed in separate steps, the number of masks required for forming these can be reduced and the manufacturing process of the image sensor 1B can be simplified.

Although the preferred embodiment of the second aspect of the present invention has been described above, the present preferred embodiment may also be changed as follows.

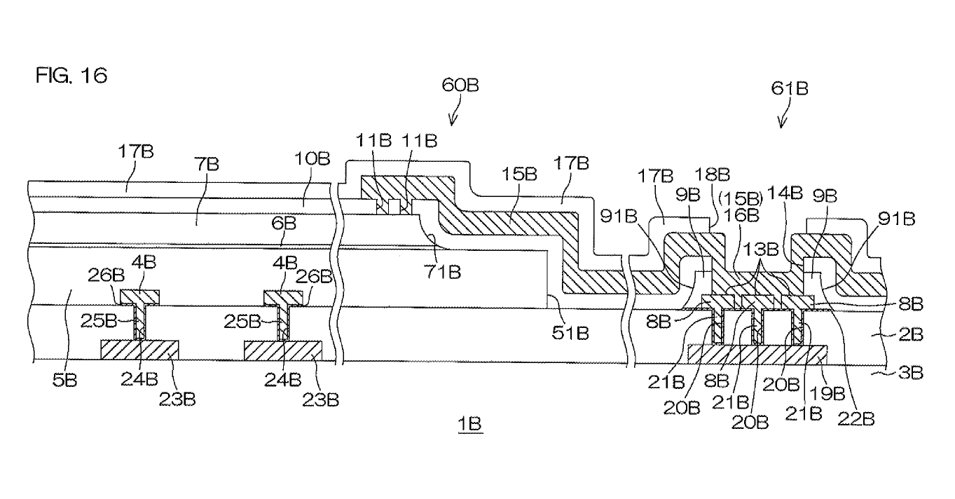

For example, as shown in FIG. 16, a plurality (for example, three) of mutually-spaced relay electrodes 8B may be provided and the relay electrodes 8B may be electrically connected all together to the first wiring 19B. The upper electrode 15B can thereby be inserted between mutually adjacent relay electrodes 8B. The upper electrode 15B can thereby be put in contact not only with upper surfaces of the relay electrodes 8B but also with side surfaces of the relay electrodes 8B. An area of contact of the relay electrodes 8B and the upper electrode 15B is thereby increased, and adhesion of the upper electrode 15B with the relay electrodes 8B can be improved.

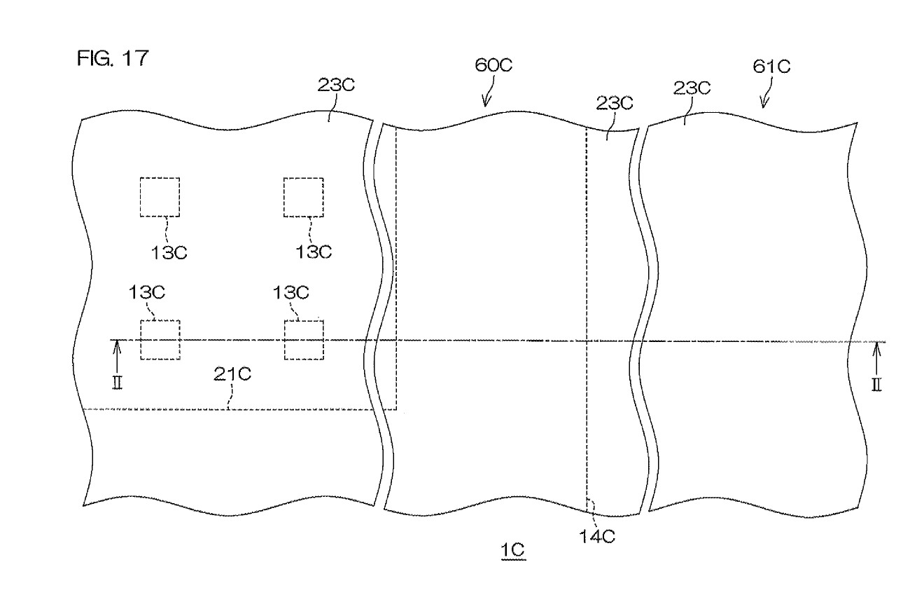

### Preferred Embodiment According to a Third Aspect of the Invention FIG. 17 to FIG. 20

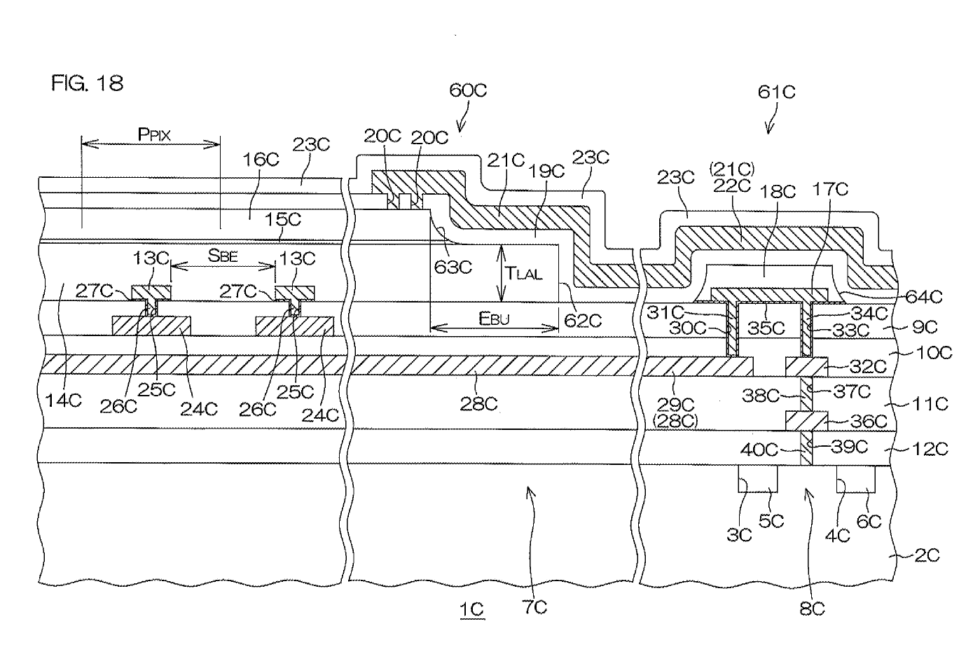

FIG. 17 is a schematic plan view of an image sensor according to a preferred embodiment of a third aspect of the present invention. FIG. 18 is a schematic sectional view of the image sensor taken along sectioning line II-II in FIG. 17. In FIG. 18, only portions made of metal materials are hatched and portions besides these are not hatched.

The image sensor 1C, which is an example of a photoelectric converter, includes a semiconductor substrate 2C as a substrate thereof. A plurality of trenches 3C and 4C are formed in a top layer portion of the semiconductor substrate 2C. The trenches 3C and 4C are formed by digging in comparatively shallowly from the top surface of the semiconductor substrate 2C. Silicon oxides 5C and 6C are embedded in the trenches 3C and 4C. The semiconductor substrate 2C is thereby made to have a substrate contact region 8C that is isolated by the trenches 3C and 4C from a device forming region 7C on which a semiconductor device, such as a MISFET (metal insulator semiconductor field effect transistor), etc., is formed.

Interlayer insulating films 9C to 12C are laminated on the semiconductor substrate 2C. The interlayer insulating films 9C to 12C are made, for example, of silicon oxide (SiO₂).

Also, as shown in FIG. 17, a sensor forming region 60C and an annular peripheral wiring region 61C surrounding it are set on the semiconductor substrate 2C.

In the sensor forming region 60C, a plurality of lower electrodes 13C are arrayed in a matrix on the uppermost interlayer insulating film 9C. The lower electrodes 13C are made of tungsten (W). Each lower electrode 13C is formed to a square shape in a plan view. For example, in the case of 7.5 μm pitch, a length of one side of the lower electrode 13C in a plan view is no less than 2.0 μm and no more than 3.3 μm. The lower electrode 13C has a thickness of no less than 0.2 μm and no more than 0.4 μm. Also, as shown in FIG. 18, mutually adjacent lower electrodes 13C are spaced apart at equal intervals S_{BE} (≧T_{LAL}×3) each set to no less than three times the thickness T_{LAL} of a photoabsorption layer 14C to be described below.

The photoabsorption layer 14C of rectangular shape in a plan view is formed on the interlayer insulating film 9C so as to cover all of the lower electrodes 13C together. Specifically, the photoabsorption layer 14C is formed integrally on a rectangular region on the interlayer insulating film 9C in which the lower electrodes 13C are formed and on a rectangular annular region of fixed width at a periphery of the rectangular region. The photoabsorption layer 14C is made of CIGS and exhibits a p-type conductivity. The thickness T_{LAL} of the photoabsorption layer 14C is no less than 1.0 μm and no more than 1.4 μm. In the photoabsorption layer 14C, each region of fixed area and rectangular shape in a plan view that is centered at each lower electrode 13C is used for reading of a single pixel. The pixel pitch P_{PIX} that is the width of this region is no less than 5 μm and no more than 10 μm.

An upper surface of the photoabsorption layer 14C, with the exception of a peripheral edge portion thereof, is covered by a high-resistance buffer layer 15C. The high-resistance buffer layer 15C is made of cadmium sulfide (CdS). The high-resistance buffer layer 15C has a thickness, for example, of 0.05 μm.

On the high-resistance buffer layer 15C, a transparent conductive film 16C is formed so as to cover an entire upper surface of the high-resistance buffer layer 15C. The transparent conductive film 16C is made of zinc oxide (ZnO), which has a light transmitting property, and has conductivity imparted by addition of an n-type impurity (for example, Al₂O₃ (alumina)). The transparent conductive film 16C has a thickness, for example, of 0.6 μm.

A side surface 63C of the transparent conductive film 16C is formed to a cross-sectional shape that is downwardly (inwardly) concavely curved and inclined so that as its lower end is approached, a side surface 62C of the photoabsorption layer 14C is approached. A lower end of the side surface 63C is continuous with a peripheral edge of the high-resistance buffer layer 15C. An upper end of the side surface 63C is positioned inward with respect to the side surface 62C of the photoabsorption layer 14C by just a horizontal distance E_{BU}. The horizontal distance E_{BU} is no less than 5 μm and no more than 10 μm.

In the peripheral wiring region 61C, a first wiring 17C is formed on the uppermost interlayer insulating film 9C. The first wiring 17C is made of the same material (tungsten) as the lower electrode 13C. The first wiring 17C is formed to a predetermined pattern. The first wiring 17C has a thickness of no less than 0.2 μm and no more than 0.4 μm.

Also, in the peripheral wiring region 61C, a protective film 18C is formed on the uppermost interlayer insulating film 9C so as to cover a peripheral edge portion of the first wiring 17C. The protective film 18C is made of silicon oxide (SiO₂). A side surface 64C of the protective film 18C is formed to a cross-sectional shape that is curved so as to be downwardly (inwardly) concave as its lower end is approached. The protective film 18C has a thickness of no less than 4000 Å and no more than 6000 Å.

An interlayer insulating film 19C is formed on a portion of the interlayer insulating film 9C exposed from the photoabsorption layer 14C, on a peripheral edge portion of the photoabsorption layer 14C, on the transparent conductive film 16C, and on the protective film 18C so as to spread across these portions and films. The interlayer insulating film 19C is made of silicon nitride (SiN). The interlayer insulating film 19C has a thickness, for example, of 0.4 μm. Above a peripheral edge portion of the transparent conductive film 16C, a plurality of via holes 20C are penetratingly formed in the interlayer insulating film 19C. The via holes 20C form, for example, two columns and are mutually spaced and disposed along the peripheral edge of the transparent conductive film 16C.

On the interlayer insulating film 19C, an upper electrode 21C is formed so as to cover entire peripheries of peripheral edge portions of the photoabsorption layer 14C and the transparent conductive film 16C. The upper electrode 21C is made of aluminum (Al). An extending portion 22C, extending toward the peripheral wiring region 61C, is formed integral to the upper electrode 21C. An end portion of the extending portion 22C is formed so as to cover the protective film 18C.

Also, a top surface protective film 23C is formed on a topmost surface of the image sensor 1C. The top surface protective film 23C is made, for example, of silicon nitride.

Between the uppermost interlayer insulating film 9C and the interlayer insulating film 10C below it, capacitor upper electrodes 24C are formed at positions opposing the respective lower electrodes 13C. A via hole 25C is formed penetratingly through the interlayer insulating film 9C between each lower electrode 13C and the opposing capacitor upper electrode 24C in the direction in which these oppose each other (thickness direction of the interlayer insulating film 9C). Each via hole 25C has an inner diameter of, for example, 0.4 μm. In each via hole 25C, a via 26C, made of the same material as the lower electrode 13C, is formed integral to the lower electrode 13C and without any gaps.

Also, a barrier film 27C is interposed between each lower electrode 13C plus the via 26C and the interlayer insulating film 9C. The barrier film 27C is made of titanium nitride (TiN). Each lower electrode 13C is electrically connected to the opposing capacitor upper electrode 24C via the via 26C and the barrier film 27C.

Between the interlayer insulating film 10C and the interlayer insulating film 11C below it, a capacitor lower electrode 28C is formed to oppose all of the capacitor upper electrodes 24C together. A capacitive element (MIM capacitor) having an MIM (metal-insulator-metal) structure, in which the interlayer insulating film 10C is sandwiched as a capacitive film (capacitor dielectric film) between the capacitor upper electrode 24C and the capacitor lower electrode 28C, is thereby formed according to each pixel. The lower electrode 13C and the capacitor upper electrode 24C of the MIM capacitor are electrically connected according to each pixel.

An extending portion 29C extending toward the peripheral wiring region 61C is formed integral to the capacitor lower electrode 28C. An end portion of the extending portion 29C is disposed at a position opposing the first wiring 17C.

A via hole 30C is formed continuously penetratingly through the interlayer insulating films 9C and 10C between the first wiring 17C and the opposing extending portion 29C (capacitor lower electrode 28C) in the direction in which these oppose each other (thickness direction of the interlayer insulating films 9C and 10C).

Also, in the peripheral wiring region 61C and between the interlayer insulating film 10C and the interlayer insulating film 11C below it, a second wiring 32C is formed at a position opposing the first wiring 17C. Between the first wiring 17C and the second wiring 32C opposing it, the second wiring 32C is formed so as to be spaced apart from the extending portion 29C of the capacitor lower electrode 28C. A first via hole 33C is formed continuously penetratingly through the interlayer insulating films 9C and 10C in the direction in which the first wiring 17C and the second wiring 32C oppose each other (thickness direction of the interlayer insulating films 9C and 10C).

In the via hole 30C and the first via hole 33C, a via 31 and a first via 34C, made of the same material as the first wiring 17C, are respectively formed integral to the first wiring 17C and without any gaps.

Also, a barrier film 35C is interposed between the first wiring 17C plus the via 31C plus the first via 34C and the interlayer insulating films 9C and 10C. The barrier film 35C is made of titanium nitride (TiN). The first wiring 17C is electrically connected to the opposing extending portion 29C (capacitor lower electrode 28C) via the via 31C and the barrier film 35C and electrically connected to the opposing second wiring 32C via the first via 34C and the barrier film 35C.

Between the interlayer insulating film 11C and the interlayer insulating film 12C below it, a third wiring 36C is formed at a position opposing the second wiring 32C. The third wiring 36C is formed to a pattern opposing the substrate contact region 8C of the semiconductor substrate 2C. A second via hole 37C is penetratingly formed through the interlayer insulating film 11C between the second wiring 32C and the opposing third wiring 36C in the direction in which these oppose each other (thickness direction of the interlayer insulating film 11C). A second via 38C is formed in the second via hole 37c. The second wiring 32C is thereby electrically connected to the opposing third wiring 36C via the second via 38C.

A contact hole 39 is formed penetratingly through the interlayer insulating film 12C between the third wiring 36C and the opposing substrate contact region 8C of the semiconductor substrate 2C in the direction in which these oppose each other. A contact 40C is formed in the contact hole 39C. The third wiring 36C is thereby electrically connected to the opposing substrate contact region 8C via the contact 40C. The extending portion 29C (capacitor lower electrode 28C) is thus electrically connected to the substrate contact region 8C via the first to third wirings 17C, 32C, and 36C, and the capacitor lower electrode 28C is set at a potential (substrate potential) of the semiconductor substrate 2C.

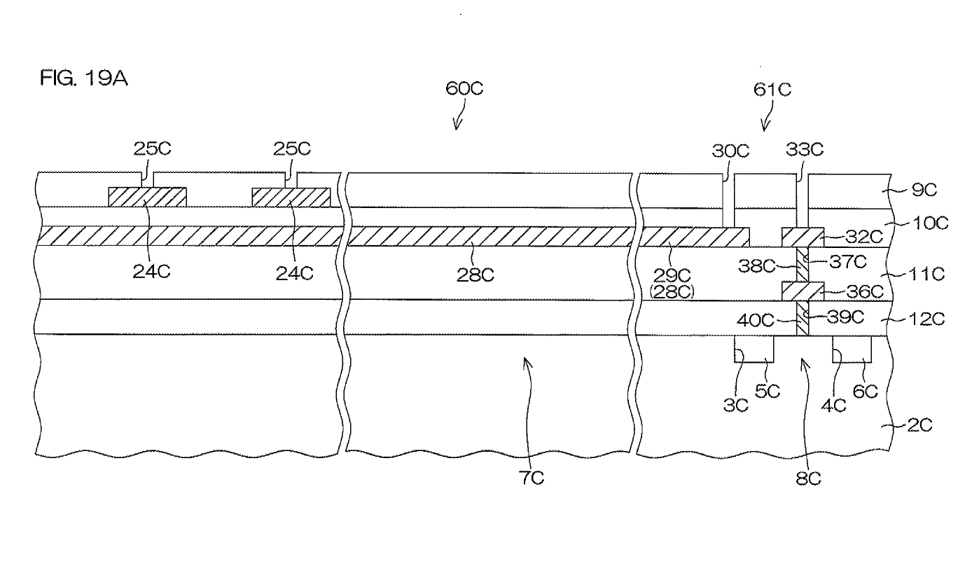

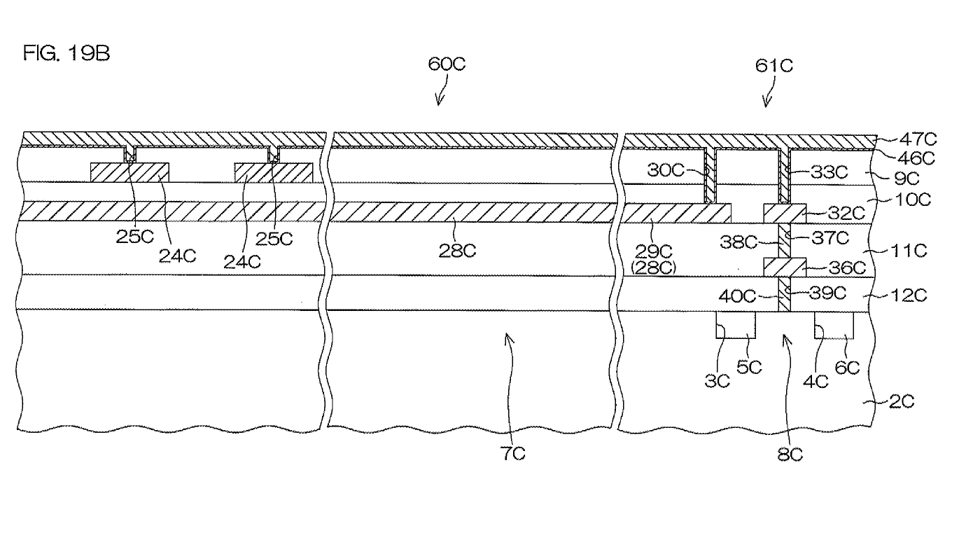

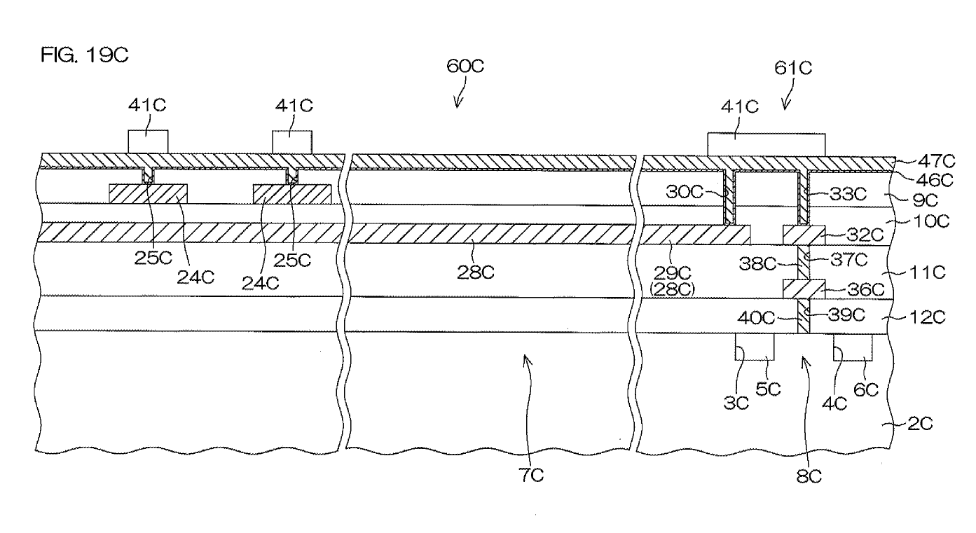

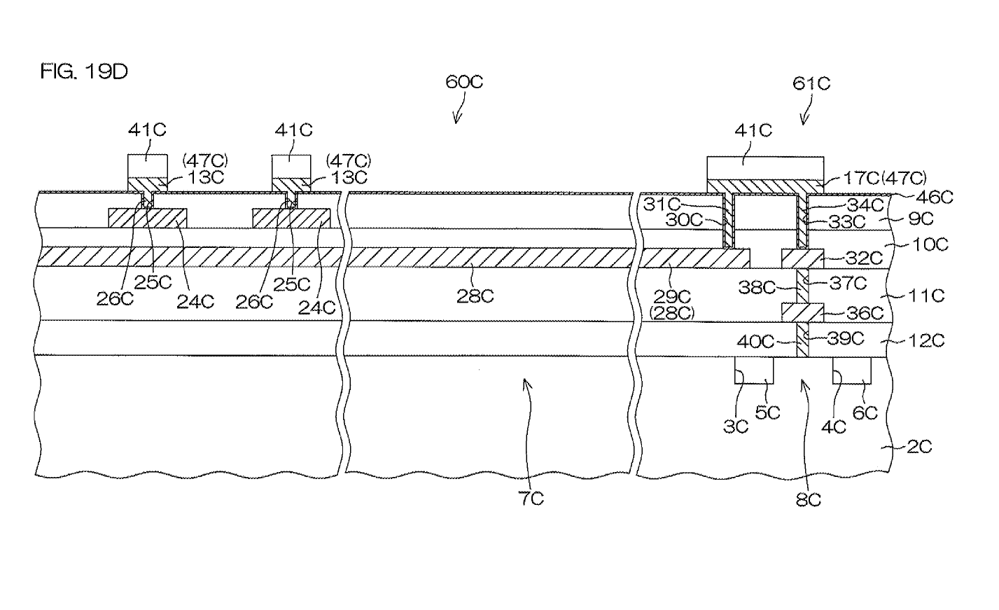

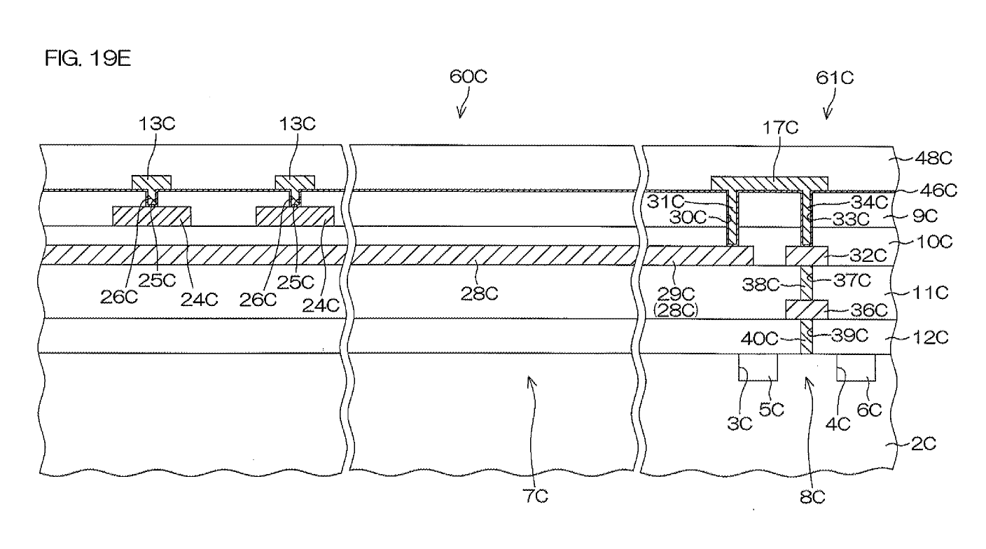

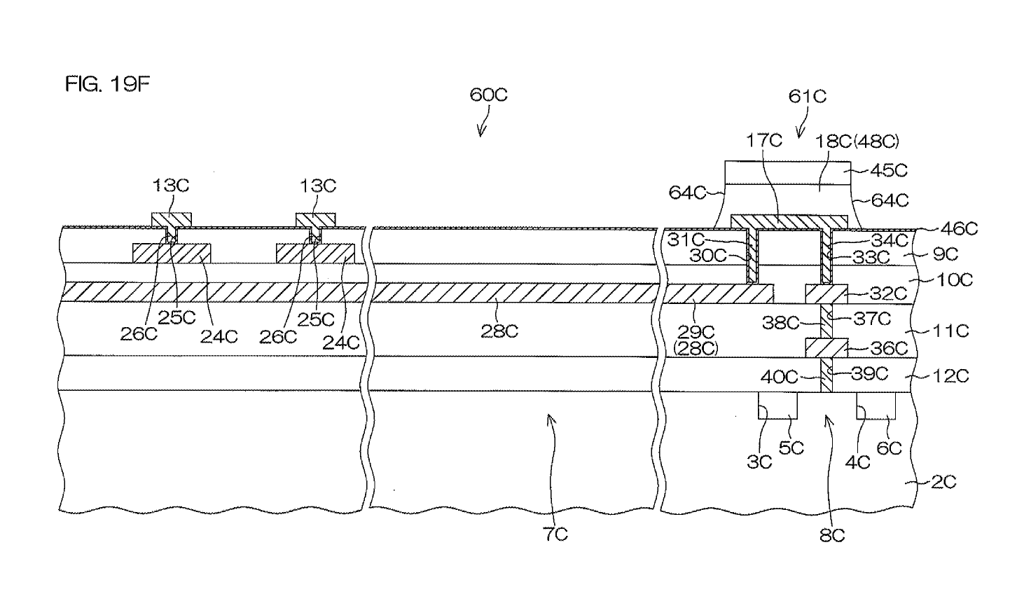

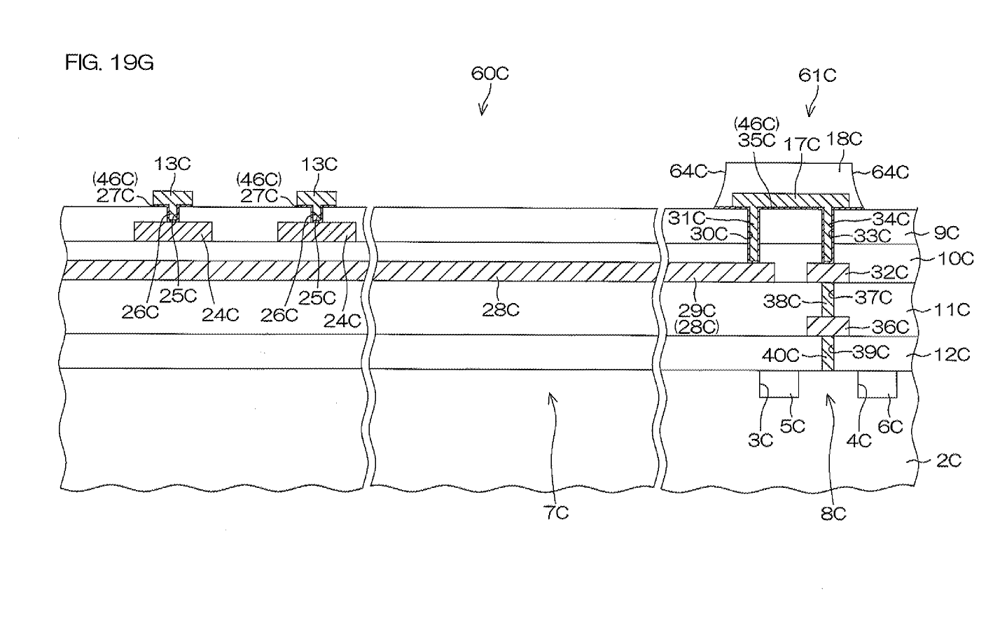

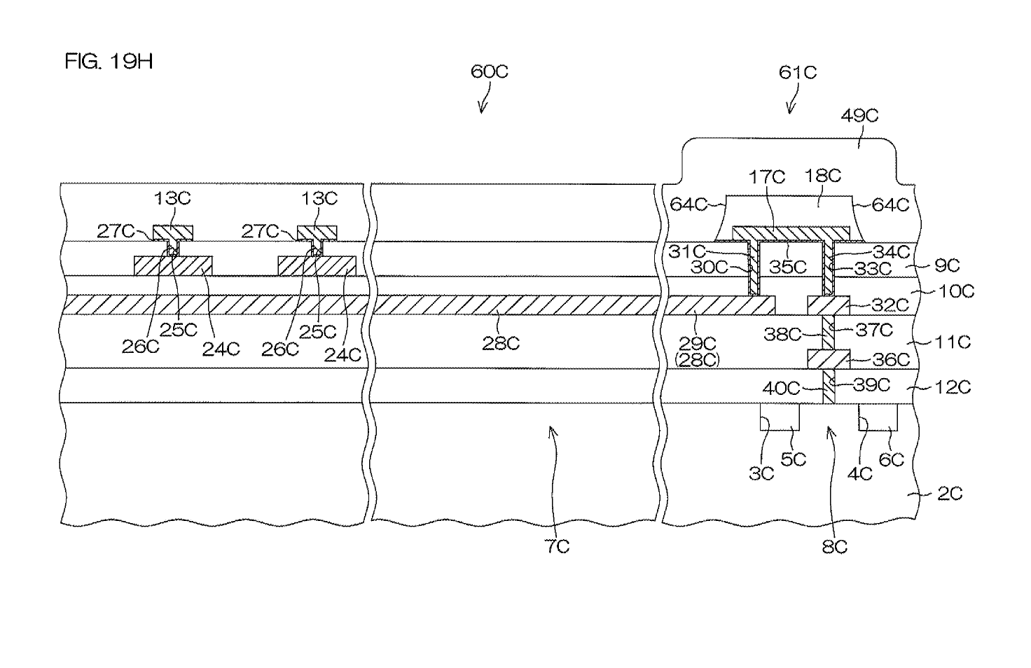

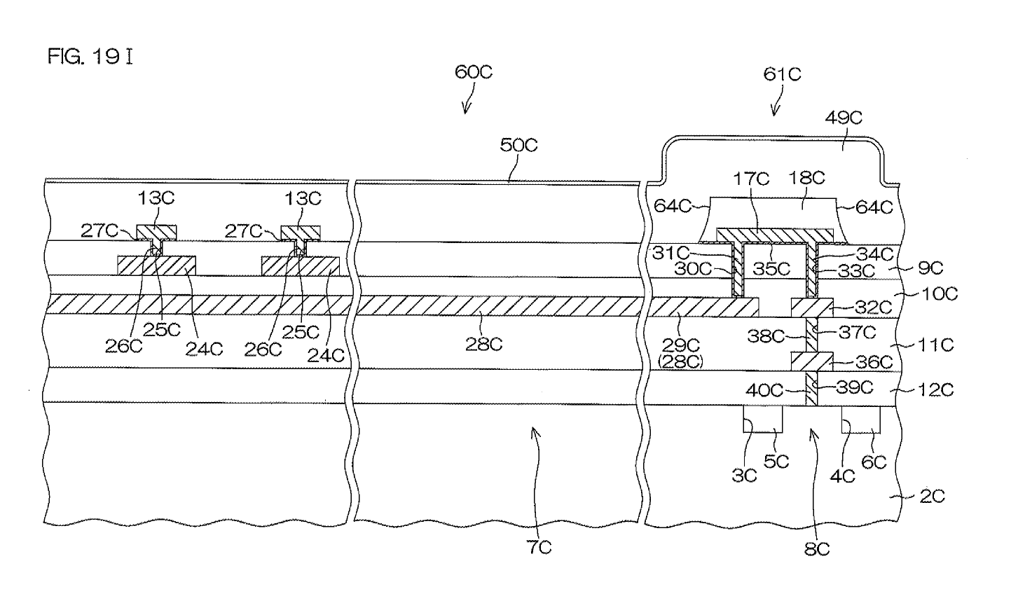

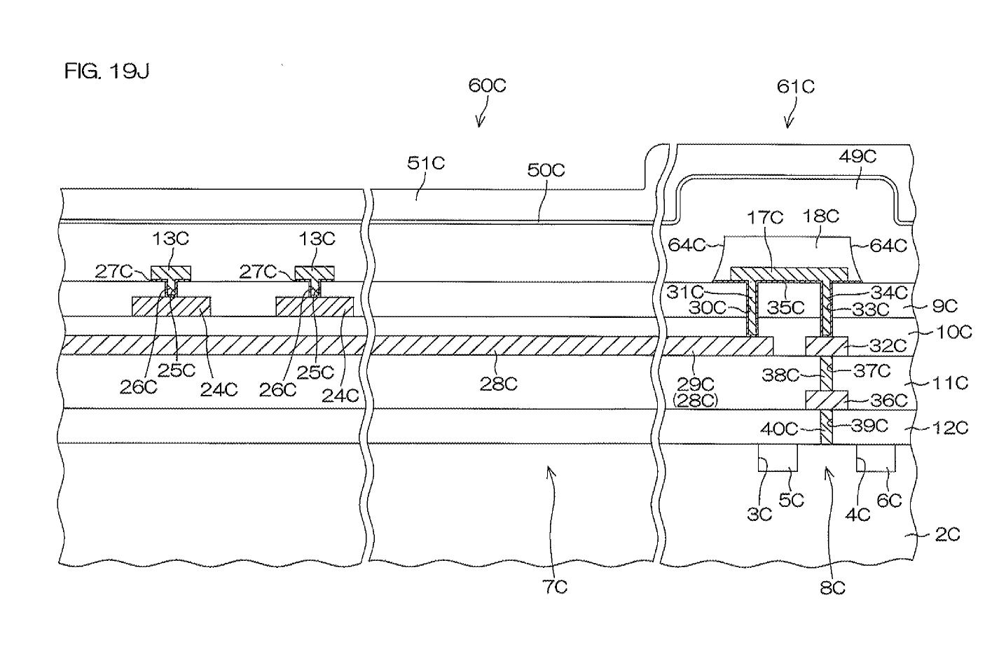

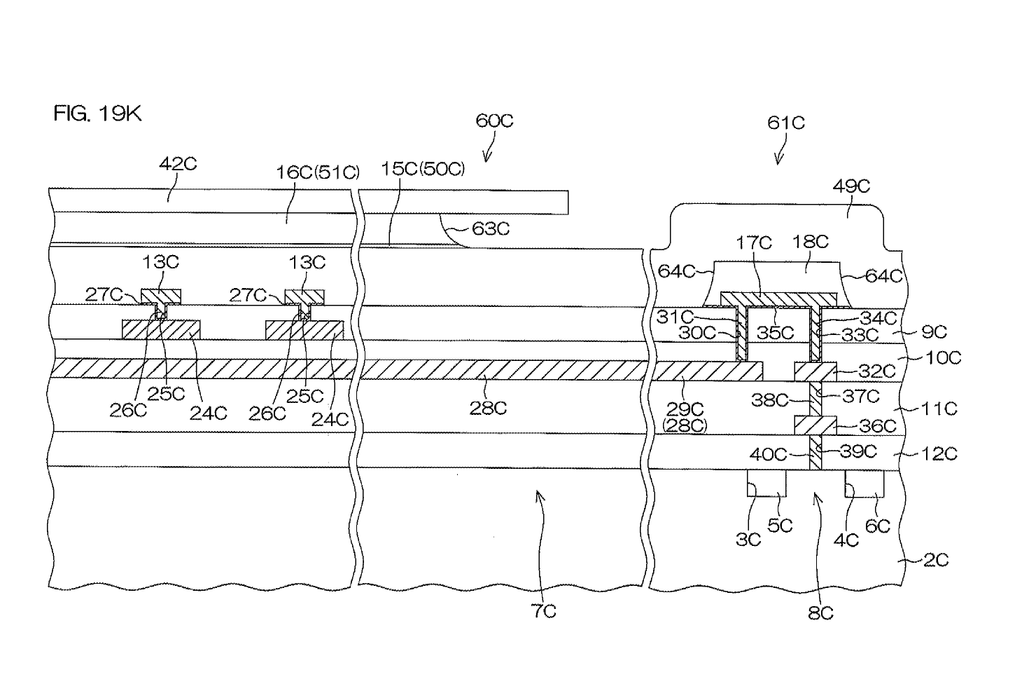

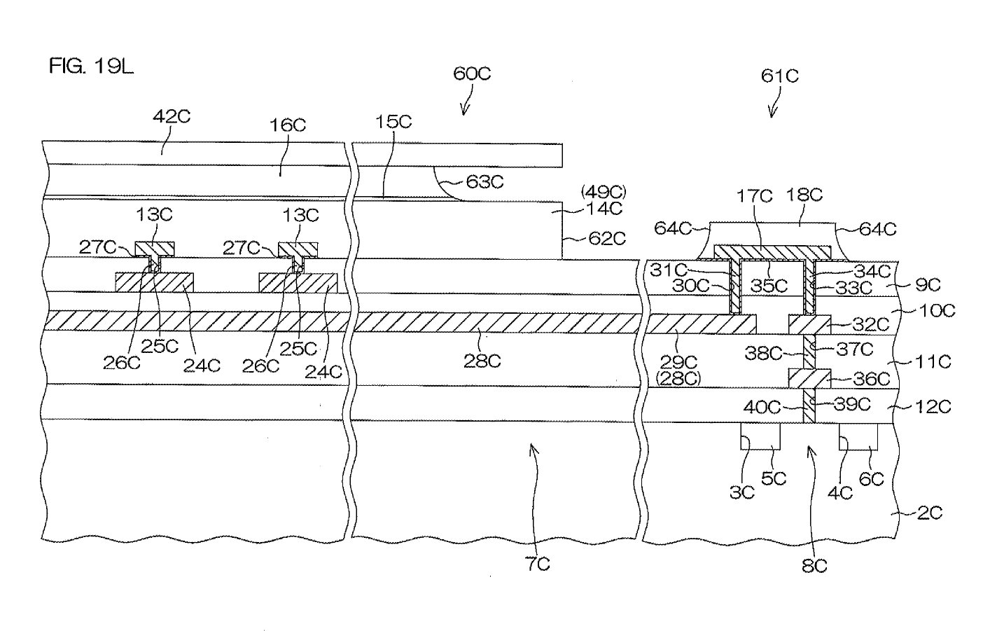

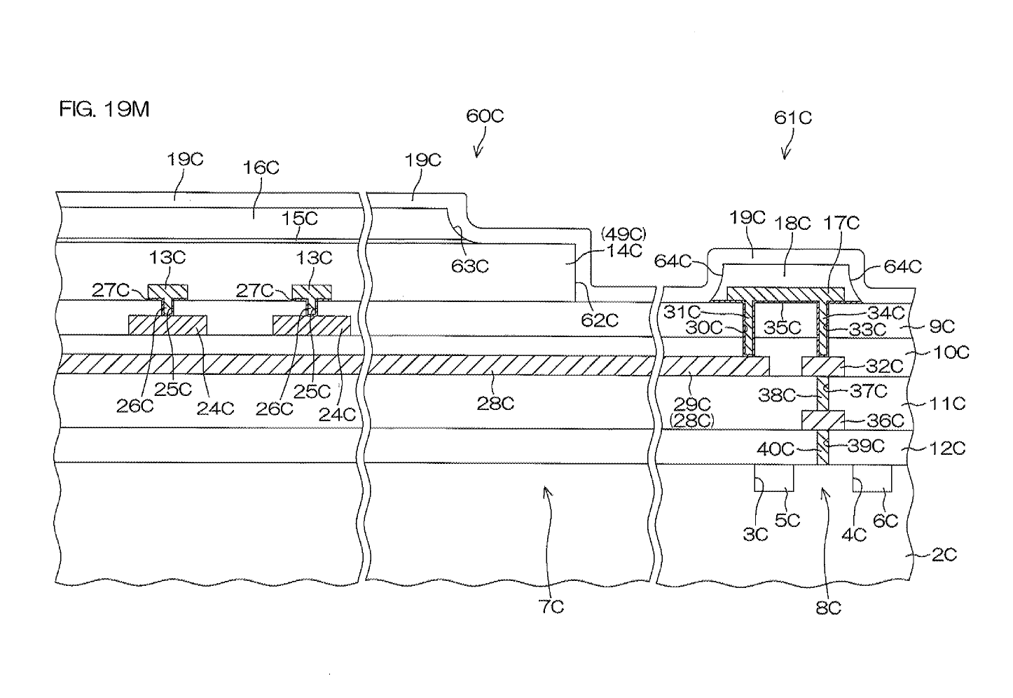

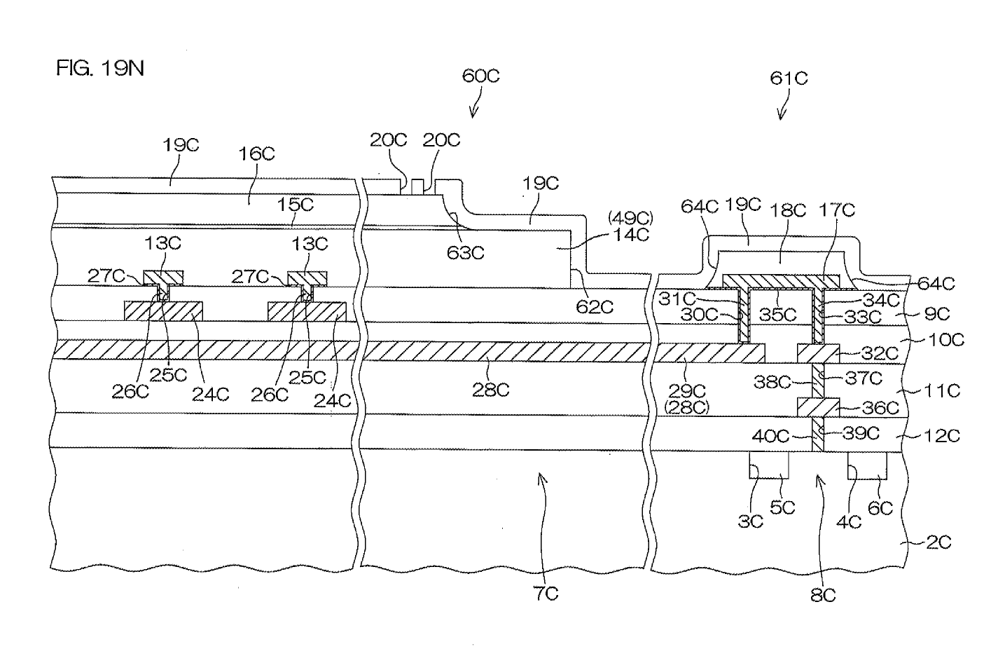

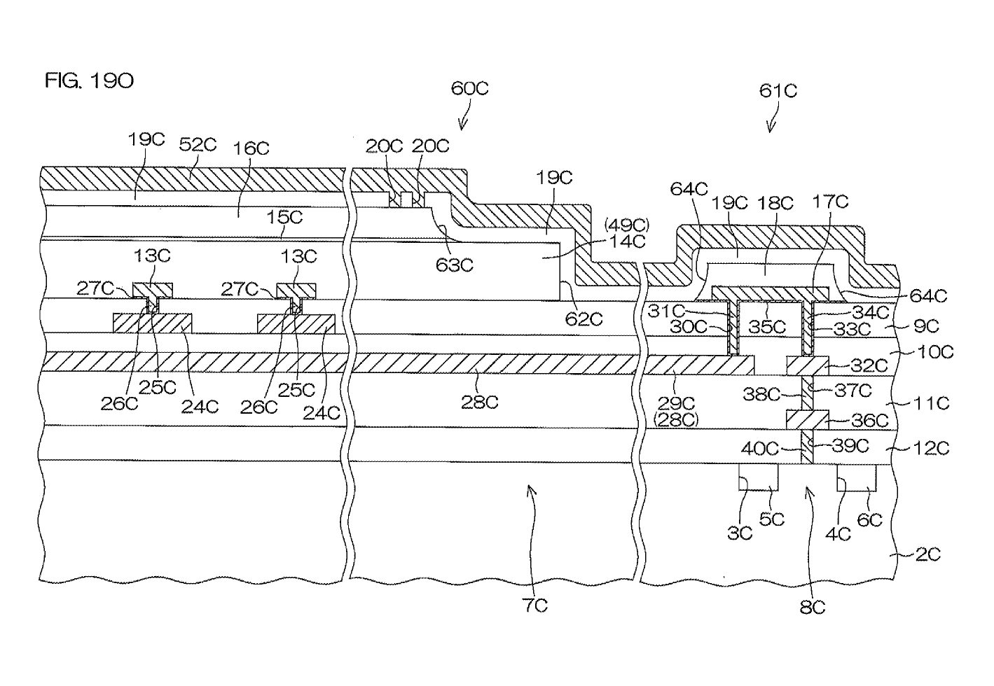

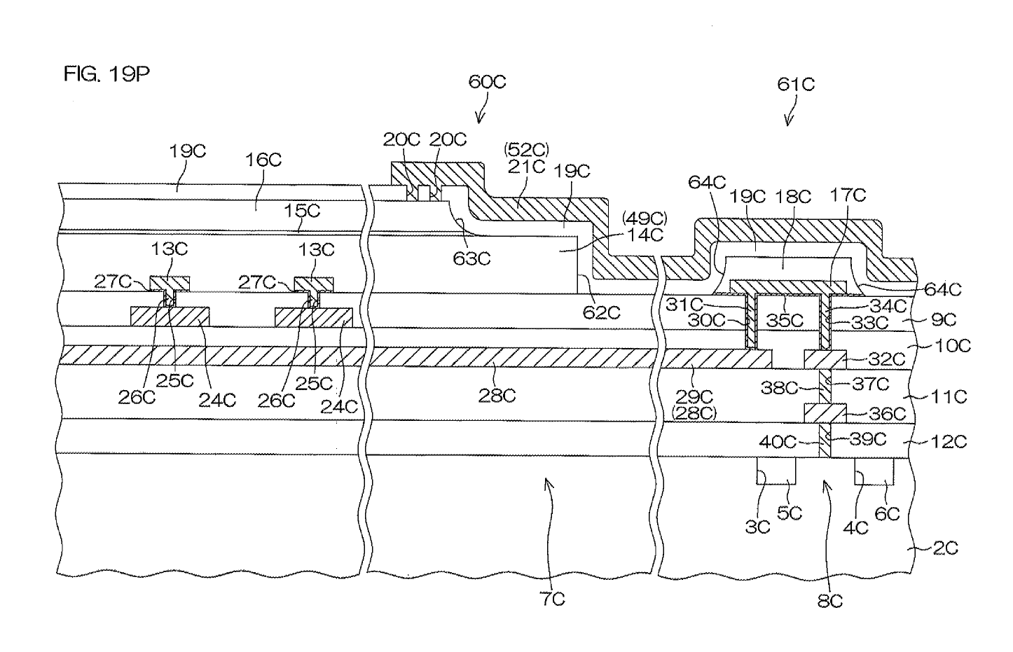

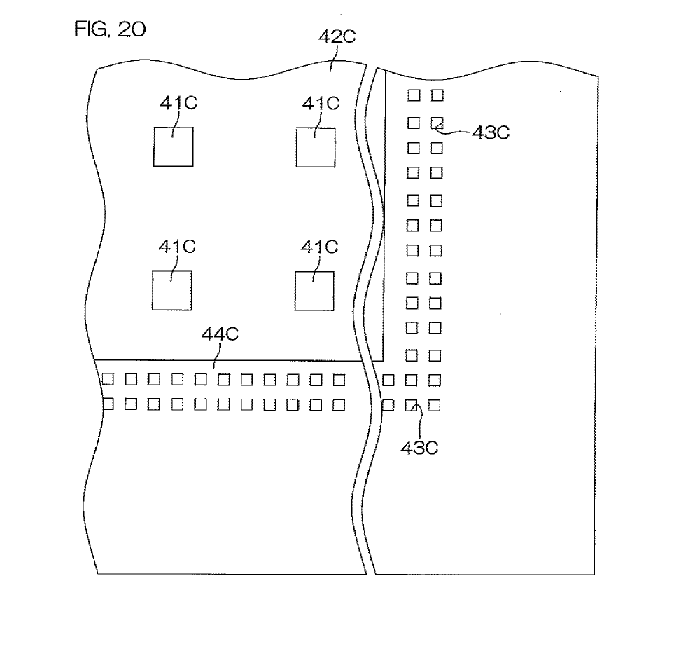

FIG. 19A to FIG. 19P are schematic sectional views that successively illustrate a manufacturing process of the image sensor shown in FIG. 18. FIG. 20 is a diagram for describing resist patterns used in the manufacturing process. In FIG. 19A to FIG. 19P, only portions made of metal materials are hatched and portions besides these are not hatched.

In the manufacturing process of the image sensor 1C, first, as shown in FIG. 19A, the interlayer insulating film 12C, the contact 40C, the third wiring 36C, the interlayer insulating film 11C, the second via 38C, the capacitor lower electrode 28C plus the second wiring 32C, the interlayer insulating film 10C, the capacitor upper electrodes 24C, and the interlayer insulating film 9C are formed in that order on the semiconductor substrate 2C, in which the device forming region 7C and the substrate contact region 8C are isolated from each other. The via holes 25C penetrating through the interlayer insulating film 9C are formed above the respective capacitor upper electrodes 24C, the via hole 30C penetrating continuously through the interlayer insulating films 9C and 10C is formed above the extending portion 29C of the capacitor lower electrode 28C, and the first via hole 33C penetrating continuously through the interlayer insulating films 9C and 10C is formed above the second wiring 32C at the same time by photolithography and etching.

Thereafter, as shown in FIG. 19B, a barrier film 46C is formed on the interlayer insulating film 9C by the sputtering method. The barrier film 46C is made of a material (for example, titanium nitride) having etch selectivity with respect to a TEOS film 48C (to be described below). The barrier film 46C is also formed inside the via holes 25C, the via hole 30C and the first via hole 33C. Thereafter, tungsten, which is the material of the lower electrodes 13C, the first wiring 17C, the vias 26C, the via 31C, and the first via 34C, is deposited by the CVD method inside the via holes 25C, the via holes 30C, and the first via hole 33C and on the interlayer insulating film 9C to form a tungsten deposition layer 47C. A thickness of the tungsten deposition layer 47C on the interlayer insulating film 9C is 0.2 to 0.4 μm (2000 to 4000 Å).

Thereafter, as shown in FIG. 19C, a resist pattern 41C (see FIG. 20; in FIG. 20, a portion covering the first wiring 17C is omitted) that selectively covers only portions that become the lower electrodes 13C and a portion that becomes the first wiring 17C is formed by photolithography on the tungsten deposition layer 47C.

Then, as shown in FIG. 19D, portions of the tungsten deposition layer 47C exposed from the resist pattern 41C are removed by dry etching using the resist pattern 41C as a mask. The mixed gas of sulfur hexafluoride (SF₆) and argon (Ar) is used for the dry etching. The lower electrodes 13C plus the vias 26C embedded in the via holes 25C, the via 31C embedded in the via hole 30C, the first via 34C embedded in the first via hole 33C, and the first wiring 17C are thereby obtained at the same time.

After the dry etching, the resist pattern 41C is removed as shown in FIG. 19E. Thereafter, by the CVD (chemical vapor deposition) method using TEOS, the TEOS film 48C is formed on the interlayer insulating film 9C so as to cover the lower electrodes 13C and the first wiring 17C all together.

Then, as shown in FIG. 19F, a resist pattern 45C is formed to selectively cover only the portion that becomes the protective film 18C. By then performing wet etching using the resist pattern 45C as a mask, the portion of the TEOS film 48C that is exposed from the resist pattern 45C is removed. Hydrofluoric acid (HF) is used for the wet etching. Here, the barrier film 46C is formed on the interlayer insulating film 9C, and the barrier film 46C acts as an etching stopper film and contact of the etching liquid (hydrofluoric acid) with the interlayer insulating film 9C is prevented. The TEOS film 48C thereby becomes the protective film 18C that exposes the lower electrodes 13C and covers the first wiring 17C and the curved side surface 64C of the protective film 18C is obtained.

Thereafter, as shown in FIG. 19G, portions of the barrier film 46C exposed from the lower electrodes 13C and the first wiring 17C are removed by dry etching. The chlorine (Cl₂) based gas is used for the dry etching. The barrier film 46C thereby becomes the barrier films 27C that prevent contact of the lower electrodes 13C plus the vias 26C with the interlayer insulating film 9C and the barrier film 35C that prevents contact of the first wiring 17C plus the via 31C plus the first via 34C with the interlayer insulating film 9C.

Thereafter, as shown in FIG. 19H, a CIGS film 49C is formed by the MBE method on the interlayer insulating film 9C, the lower electrodes 13C, and the protective film 18C.

Thereafter, as shown in FIG. 19I, a cadmium sulfide film 50C is formed by the CBD method on the CIGS film 49C.

Further in succession, a zinc oxide film 51C is formed by the sputtering method on the cadmium sulfide film 50C as shown in FIG. 19J.

Then, as shown in FIG. 19K, a resist pattern 42C (see FIG. 20) is formed by photolithography on the zinc oxide film 51C. The resist pattern 42C opposes a portion of the CIGS film 49C that is to become the photoabsorption layer 14C. Then, using the resist pattern 42C as a mask, the zinc oxide film 51C and the cadmium sulfide film 50C are removed selectively by wet etching by hydrofluoric acid (HF). The wet etching is continued for a predetermined time even after the portion of the zinc oxide film 51C that does not oppose the resist pattern 42C has been removed. The zinc oxide film 51C is thereby removed from below a peripheral edge portion of the resist pattern 42C as well. Consequently, the zinc oxide film 51C and the cadmium sulfide film 50C become the transparent conductive film 16C and the high-resistance buffer layer 15C, respectively, and the curved side surface 63C of the transparent conductive film 16C is obtained.

Then, while leaving the resist pattern 42C, dry etching using the resist pattern 42C as a mask is performed to selectively remove the CIGS film 49C as shown in FIG. 19L. The CIGS film 49C is left only at the portion opposing the resist pattern 42C. The CIGS film 49C thereby becomes the photoabsorption layer 14C. Thereafter, the resist pattern 42C is removed.

Thereafter, as shown in FIG. 19M, the interlayer insulating film 19C is formed coveringly by the plasma CVD method on the portion of the interlayer insulating film 9C exposed from the photoabsorption layer 14C, on the peripheral edge portion of the photoabsorption layer 14C, on the transparent conductive film 16C, and on the protective film 18C.

A resist pattern having openings 43C (see FIG. 20) that selectively expose portions at which the via holes 20C are to be formed is formed by photolithography on the interlayer insulating film 19C. By then performing dry etching using the resist pattern as a mask, the via holes 20C that penetrate through the interlayer insulating film 19C are formed as shown in FIG. 19N.

Thereafter, as shown in FIG. 19O, an aluminum film 52C made of aluminum is formed by the sputtering method on the interlayer insulating film 19C. The aluminum film 52C is also formed inside the via holes 20C. The via holes 20C are completely filled with the aluminum film 52C.

A resist pattern 44C (see FIG. 20) that covers a portion that is to become the upper electrode 21C is formed by photolithography on the aluminum film 52C. The aluminum film 52C is then removed selectively by dry etching using the resist pattern as a mask, and the aluminum film 52C is thereby processed to the upper electrode 21C as shown in FIG. 19P. When the top surface protective film 23C is thereafter formed by the plasma CVD method, the image sensor 1C shown in FIG. 18 is obtained.

As described above, with the image sensor 1C, the plurality of mutually-spaced lower electrodes 13C disposed on the interlayer insulating film 9C are covered all together by the photoabsorption layer 14C made of CIGS. That is, the photoabsorption layer 14C is not cut and divided according to each pixel, and thus as in the preferred embodiment according to the first aspect of the present invention, variation of sensitivity among pixels is not influenced by damage due to dry etching.

Also, as in the preferred embodiment according to the first aspect of the present invention, the pixel aperture ratio (pn junction area/pixel area) can be made 100% because the photoabsorption layer 14C is not cut and divided according to each pixel. A large number of carriers can thereby be generated even with weak light and dramatic improvement of sensitivity can be achieved.

Further, a shrinkage cavity does not form during forming of the transparent conductive film 16C because grooves for cutting and dividing the photoabsorption layer 14C are not formed. Degradation with time of the transparent conductive film 16C can thus be prevented and reliability can be improved.

Also, a step of forming an isolation film is unnecessary and the manufacturing process is thus simpler than that of the conventional photoelectric converter and time and cost required for manufacture can be reduced.

Also, with the manufacturing method described above, the TEOS film 48C is formed to cover the first wiring 17C before dry etching of the CIGS film 49C. Then, after processing of the TEOS film 48C to the protective film 18C, the CIGS film 49C is dry etched to form the photoabsorption layer 14C in the state where the first wiring 17C is covered by the protective film 18C. The first wiring 17C is thus not exposed to the etching gas during the dry etching of the CIGS film 49C. Consequently, the first wiring 17C, with which a satisfactory surface state is maintained, can be left on the interlayer insulating film 9C. The first wiring 17C can thus be put to any use.

With the image sensor 1C, the first wiring 17C is set at a substrate potential by the first wiring 17C being connected to the substrate contact region 8C (substrate potential) using the first and second vias 34C and 38C and the contact 40C, and the capacitor lower electrode 28C (extended portion 29C) is lead to the first wiring 17C using the via 31C. The capacitor lower electrode 28C is thereby electrically connected to the substrate contact region 8C and the potential of the capacitor lower electrode 28C can thus be maintained at the substrate potential.

Also, if the capacitor lower electrode 28C is connected to the substrate potential when the interlayer insulating films 9C and 10C are dry-etched in the step of FIG. 19A, a potential difference between the capacitor upper electrodes 24C and the capacitor lower electrode 28C increases due to a radio-frequency plasma of the etching gas. Consequently, the interlayer insulating film 10C that is to be the capacitive film of the MIM capacitor becomes charged by the radio-frequency plasma on the basis of the substrate potential and leads to a problem of occurrence of dielectric breakdown of the interlayer insulating film 10C or lowering of reliability of the MIM capacitor, even if dielectric breakdown does not occur.

On the other hand, with the manufacturing method described above, the capacitor lower electrode 28C and the second wiring 32C, which is electrically connected to the substrate potential, are isolated by the interlayer insulating film 10C until being electrically connected by the first wiring 17C, the via 31C, and the first via 34C in the steps of FIG. 19C and FIG. 19D. Thus, even if the capacitor upper electrodes 24C and the capacitor lower electrode 28C are exposed to the radio-frequency plasma of the etching gas when the via holes 25C and the via hole 30C are formed at the same time, the electrodes are maintained at the same potential. Consequently, occurrence of dielectric breakdown of the interlayer insulating film 10C or lowering of the reliability of the MIM capacitor due to lowering of withstand voltage of the interlayer insulating film 10C can be suppressed.

Also, the capacitor lower electrode 28C is formed to oppose all of the capacitor upper electrodes 24C together. Thus, in comparison to a case where a plurality of capacitor lower electrodes are formed in respective correspondence to the capacitor upper electrodes 24C, the step of forming the capacitor lower electrode 28C can be simplified.

Further, the lower electrodes 13C, the vias 26C, the first wiring 17C, the via 31C, and the first via 34C are all made of the same material and these can thus be formed in the same step. Thus, in comparison to a case where these are formed in separate steps, the number of manufacturing steps of the image sensor 1C can be reduced and the number of masks necessary for forming these can be reduced. Consequently, increase of the time and cost required for manufacture can be suppressed.

Also, the step of polishing the deposition layer of the material of the vias by the CMP method and the step of forming the film made of the material of the lower electrodes by the sputtering method, which are deemed to be required in the manufacture of the conventional image sensor, can be omitted. The time and cost required for manufacture can be reduced thereby as well. Also, secure connection of the lower electrodes 13C with the vias 26C and secure connection of the first wiring 17C with the via 31C and the first via 34C can be achieved. The reliability of electrical connection of the lower electrodes 13C with the vias 26C and the reliability of electrical connection of the first wiring 17C with the via 31C and the first via 34C can thus be improved.

Also, in the manufacturing process of the image sensor 1C, the resist pattern 42C used in the wet etching for processing the zinc oxide film 51C to the transparent conductive film 16C is also used in the dry etching for processing the CIGS film 49C to the photoabsorption layer 14C and a mask (resist pattern) used exclusively for the dry etching is not formed. The manufacturing process of the image sensor 1C can thus be simplified.

Also, as shown in FIG. 19H to FIG. 19J, the CIGS film 49C, the cadmium sulfide film 50C, and the zinc oxide film 51C are formed consecutively. The time from the forming of the CIGS film 49C to the completion of forming of the zinc oxide film 51C can thus be made short, and the CIGS film 49C, the cadmium sulfide film 50C, and the zinc oxide film 51C can be respectively improved in film quality.

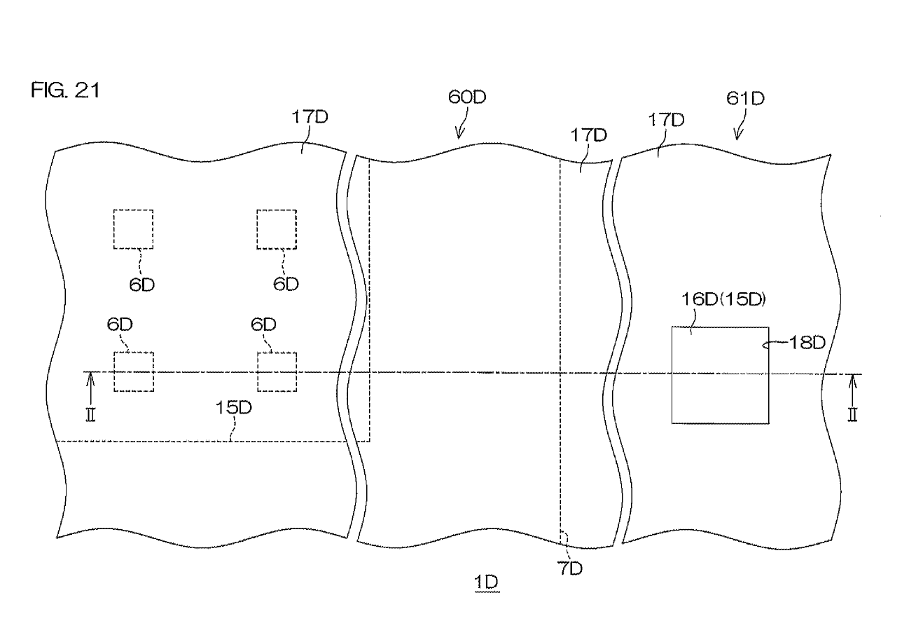

### Preferred Embodiment According to a Fourth Aspect of the Invention FIG. 21 to FIG. 24

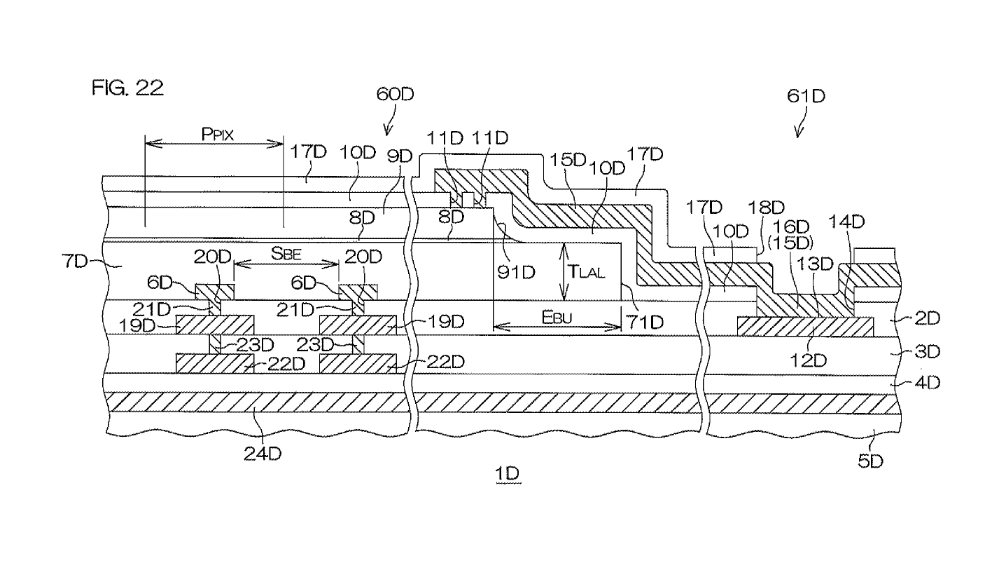

FIG. 21 is a schematic plan view of an image sensor according to a preferred embodiment of a fourth aspect of the present invention. FIG. 22 is a schematic sectional view of the image sensor taken along sectioning line II-II in FIG. 21. In FIG. 22, only portions made of metal materials are hatched and portions besides these are not hatched.

The image sensor 1D, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2D, 3D, and 5D and a capacitor dielectric film 4D are laminated on the semiconductor substrate. The interlayer insulating films 2D, 3D, and 5D and the capacitor dielectric film 4D are made, for example, of silicon oxide (SiO₂).

Also, as shown in FIG. 21, a sensor forming region 60D and an annular pad forming region 61D surrounding it are set on the semiconductor substrate.

In the sensor forming region 60D, a plurality of lower electrodes 6D are arrayed in a matrix on the uppermost interlayer insulating film 2D. The lower electrodes 6D are made of tungsten (W). Each lower electrode 6D is formed to a square shape in a plan view. For example, in a case where the pixel pitch P_{PIX}, to be described below, is 7.5 μm, a length of one side of the lower electrode 6D in a plan view is no less than 2.0 μm and no more than 3.3 μm. The lower electrode 6D has a thickness of no less than 0.2 μm and no more than 0.4 μm. Also, as shown in FIG. 22, mutually adjacent lower electrodes 6D are spaced apart at equal intervals S_{BE} (≧T_{LAL}×3) each set to no less than three times the thickness T_{LAL} of a photoabsorption layer 7D to be described below.

The photoabsorption layer 7D of rectangular shape in a plan view is formed on the interlayer insulating film 2D so as to cover all of the lower electrodes 6D together. Specifically, the photoabsorption layer 7D is formed integrally on a rectangular region on the interlayer insulating film 2D in which the lower electrodes 6D are formed and on a rectangular annular region of fixed width at a periphery of the rectangular region. The photoabsorption layer 7D is made of CIGS and exhibits a p-type conductivity. The thickness T_{LAL} of the photoabsorption layer 7D is no less than 1.0 μm and no more than 1.4 μm. In the photoabsorption layer 7D, each region of fixed area and rectangular shape in a plan view that is centered at each lower electrode 6D is used for reading of a single pixel. The pixel pitch P_{PIX} that is the width of this region is no less than 5 μm and no more than 10 μm.

An upper surface of the photoabsorption layer 7D, with the exception of a peripheral edge portion thereof, is covered by a high-resistance buffer layer 8D. The high-resistance buffer layer 8D is made of cadmium sulfide (CdS). The high-resistance buffer layer 8D has a thickness, for example, of 0.05 μm.

On the high-resistance buffer layer 8D, a transparent conductive film 9D is formed so as to cover an entire upper surface of the high-resistance buffer layer 8D. The transparent conductive film 9D is made of zinc oxide (ZnO), which has a light transmitting property, and has conductivity imparted by addition of an n-type impurity (for example, Al₂O₃ (alumina)). The transparent conductive film 9D has a thickness, for example, of 0.6 μm.

A side surface 91D of the transparent conductive film 9D is formed to a cross-sectional shape that is downwardly (inwardly) concavely curved and inclined so that as its lower end is approached, a side surface 71D of the photoabsorption layer 7D is approached. A lower end of the side surface 91D is continuous with a peripheral edge of the high-resistance buffer layer 8D. An upper end of the side surface 91D is positioned inward with respect to the side surface 71D of the photoabsorption layer 7D by just a horizontal distance E_{BU}. The horizontal distance E_{BU} is no less than 5 μm and no more than 10 μm.

An interlayer insulating film 10D is formed on a portion of the interlayer insulating film 2D exposed from the photoabsorption layer 7D, on a peripheral edge portion of the photoabsorption layer 7D, and on the transparent conductive film 9D so as to spread across these portions and films. The interlayer insulating film 10D is made of silicon nitride (SiN). The interlayer insulating film 10D has a thickness, for example, of 0.4 μm. Above a peripheral edge portion of the transparent conductive film 9D, a plurality of via holes 11D are penetratingly formed in the interlayer insulating film 10D. The via holes 11D form, for example, two columns and are mutually spaced and disposed along the peripheral edge of the transparent conductive film 9D.

Also, in the pad forming region 61D, a wiring 12D is formed between the uppermost interlayer insulating film 2D and the interlayer insulating film 3D below it. A pad opening 14D, exposing a portion of the wiring 12D as a pad 13D, is formed continuously penetratingly in the interlayer insulating films 2D and 10D.

On the interlayer insulating film 10D, an upper electrode 15D is formed so as to cover entire peripheries of peripheral edge portions of the photoabsorption layer 7D and the transparent conductive film 9D. The upper electrode 15D is made of aluminum (Al). An extending portion 16D, extending toward the pad forming region 61D, is formed integral to the upper electrode 15D. An end portion of the extending portion 16D enters inside the pad opening 14D and is connected to the pad 13D (wiring 12D) inside the pad opening 14D.

Also, a top surface protective film 17D is formed on a topmost surface of the image sensor 1D. The top surface protective film 17D is made, for example, of silicon nitride. In the top surface protective film 17D, an opening 18D for exposing the portion of the extending portion 16D of the upper electrode 15D that enters into the pad opening 14D is formed at a position opposing the pad opening 14D.

Between the uppermost interlayer insulating film 2D and the interlayer insulating film 3D below it, wirings 19D are formed at positions opposing the respective lower electrodes 6D. A via hole 20D is formed penetratingly through the interlayer insulating film 2D between each lower electrode 6D and the opposing wiring 19D in the direction in which these oppose each other (thickness direction of the interlayer insulating film 2D). In each via hole 20D, a via 21D, made of the same material as the lower electrode 6D, is formed integral to the lower electrode 6D and without any gaps. Each lower electrode 6D is thereby electrically connected to the opposing wiring 19D via the via 21D. Each via hole 20D has an inner diameter of, for example, 0.4 μm.

Between the interlayer insulating film 3D and the capacitor dielectric film 4D below it, capacitor upper electrodes 22D are formed at positions opposing the respective wirings 19D. Each wiring 19D and the opposing capacitor upper electrode 22D are electrically connected by a via 23D that penetrates through the interlayer insulating film 3D. The via 23D is made of tungsten.

Between the capacitor dielectric film 4D and the interlayer insulating film 5D below it, a capacitor lower electrode 24D is formed to oppose all of the capacitor upper electrodes 22D together. A capacitive element (MIM capacitor) having an MIM (metal-insulator-metal) structure, in which the capacitor dielectric film 4D is sandwiched as a capacitive film between the capacitor upper electrode 22D and the capacitor lower electrode 24D, is thereby formed according to each pixel. The lower electrode 6D and the capacitor upper electrode 22D of the MIM capacitor are electrically connected according to each pixel.

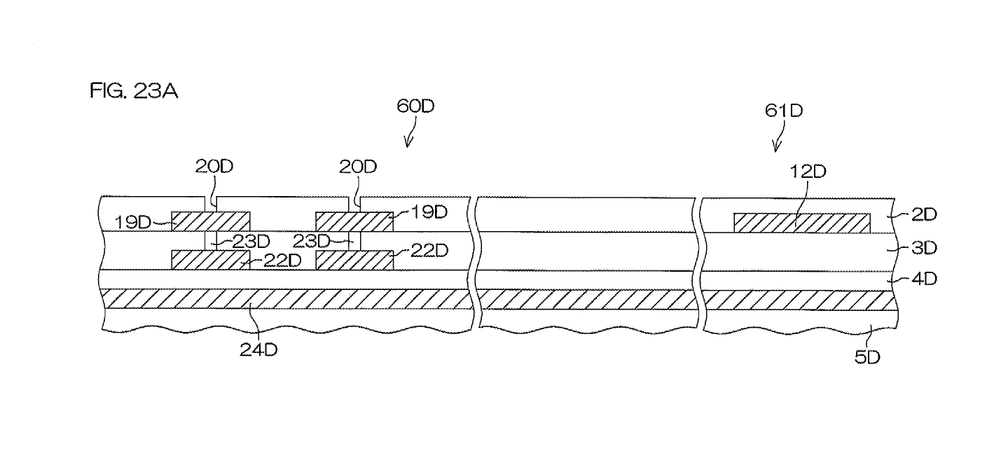

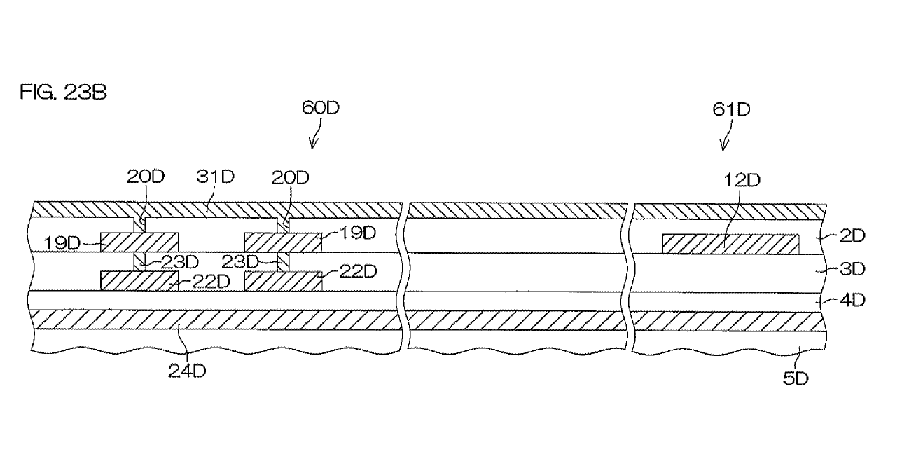

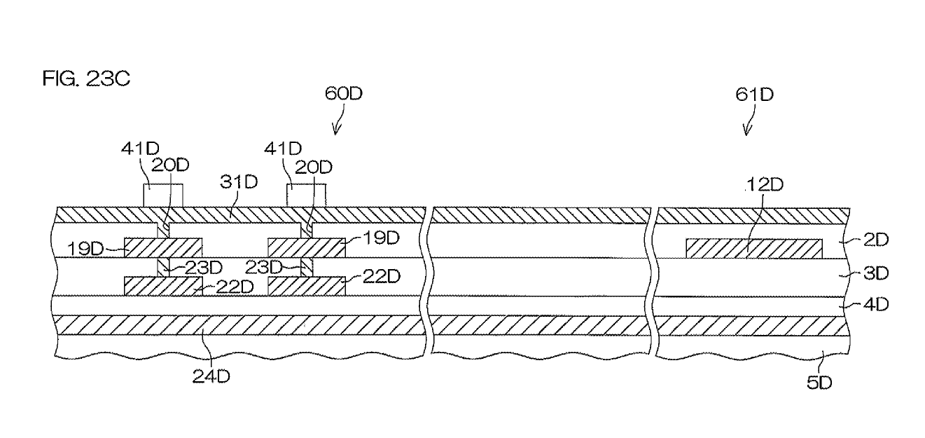

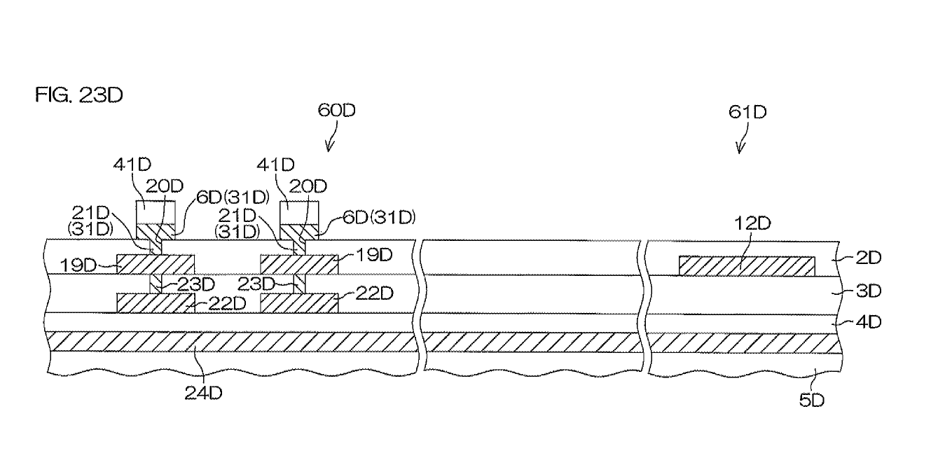

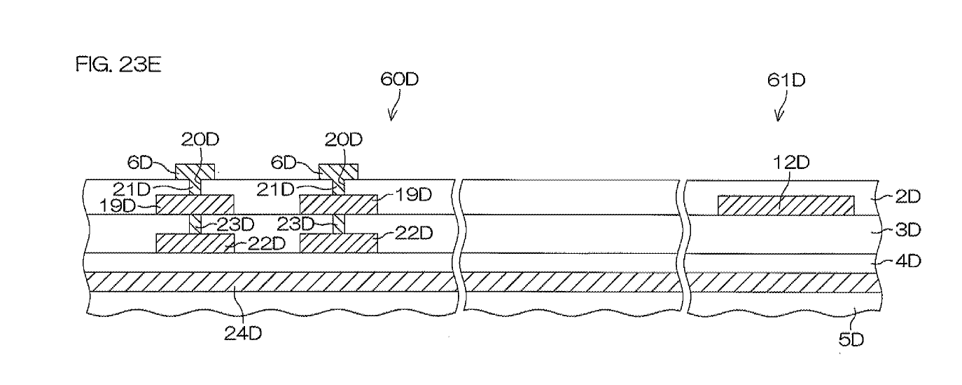

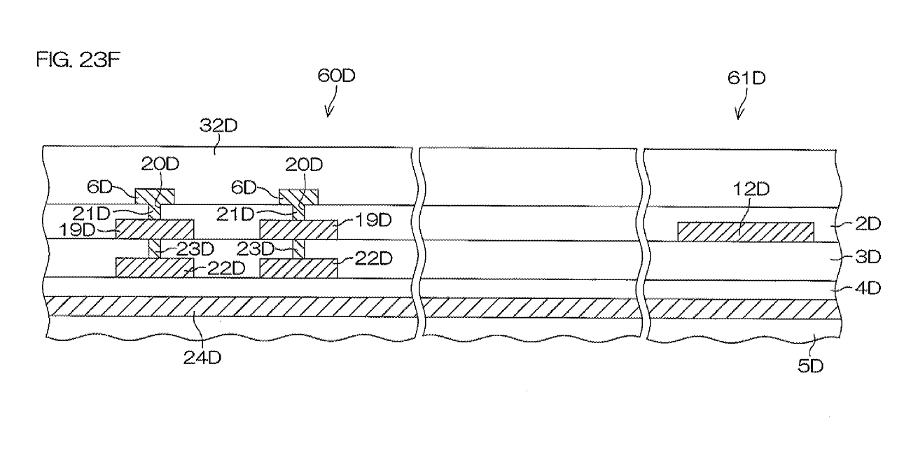

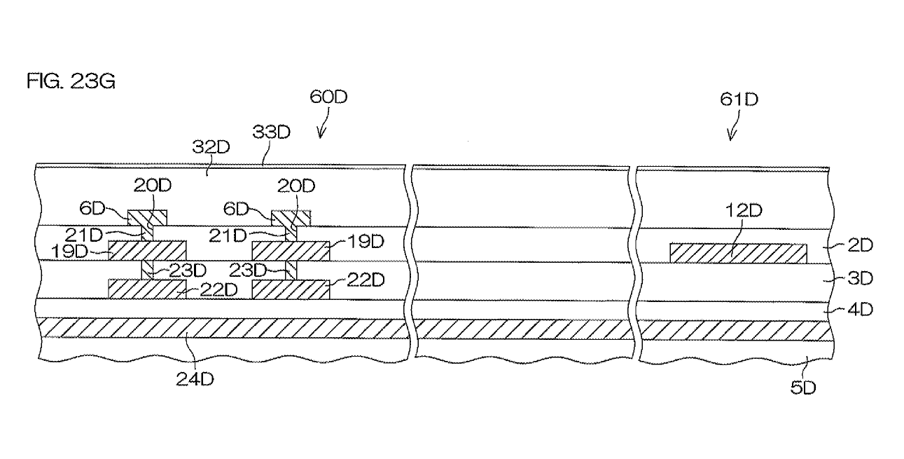

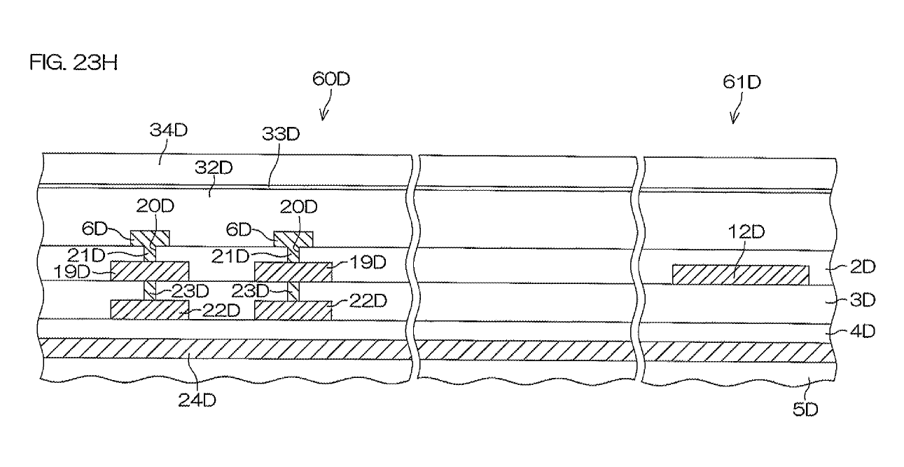

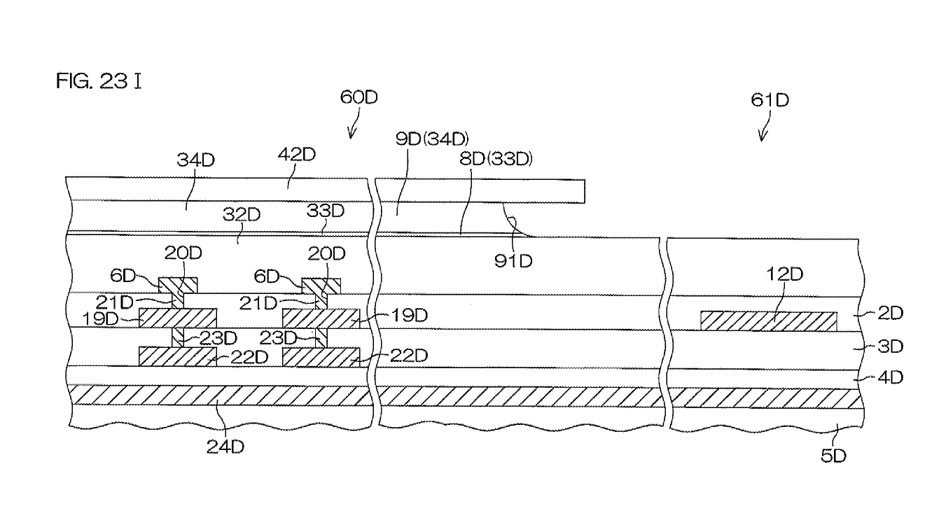

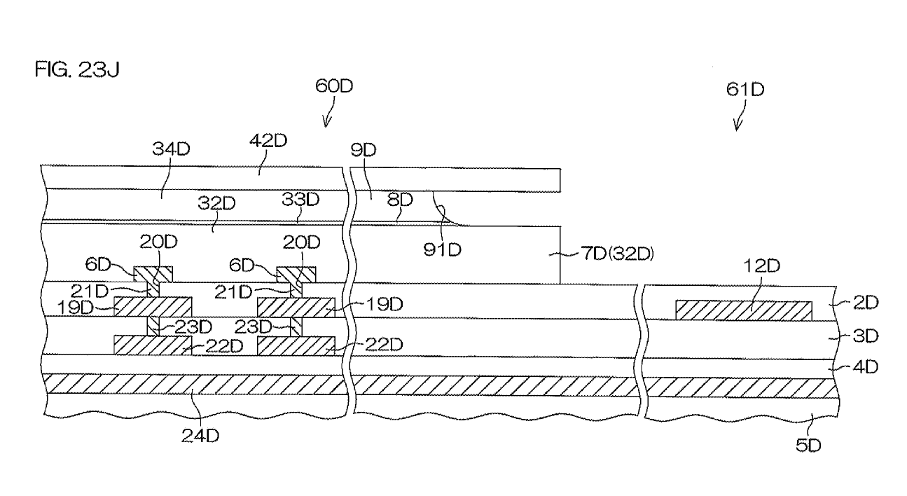

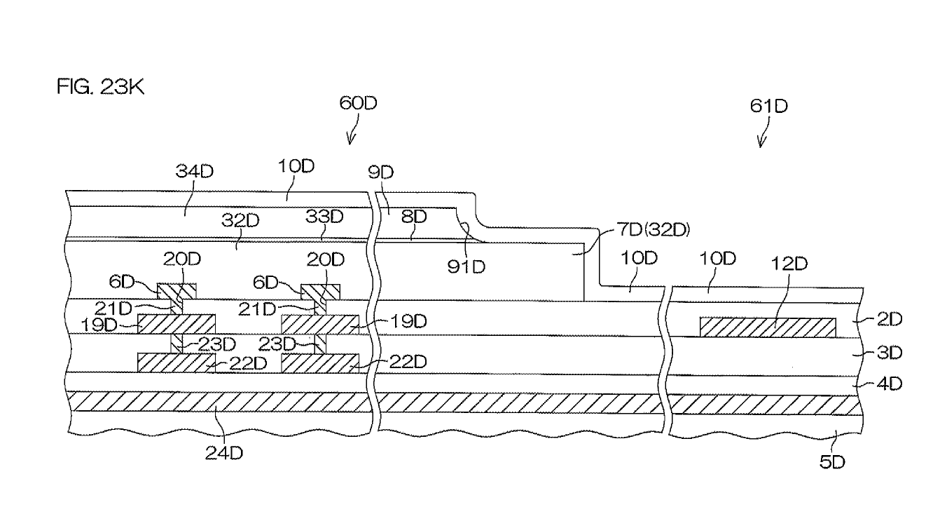

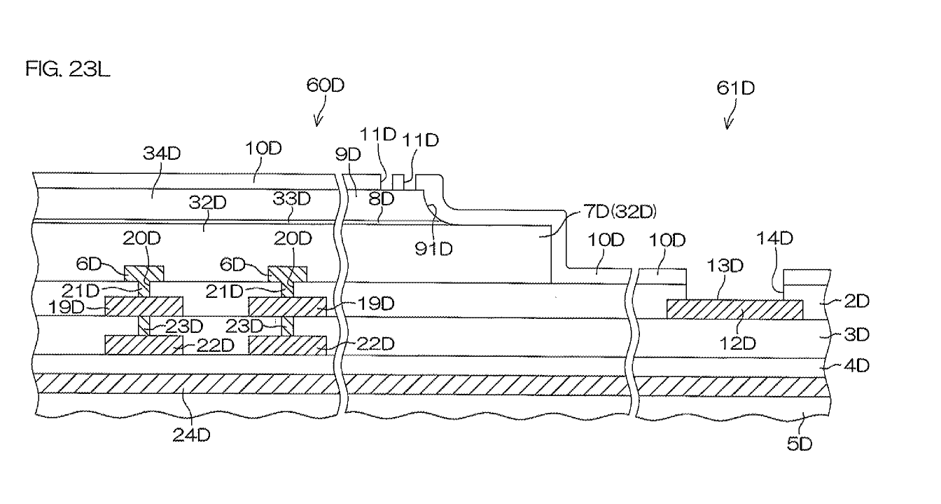

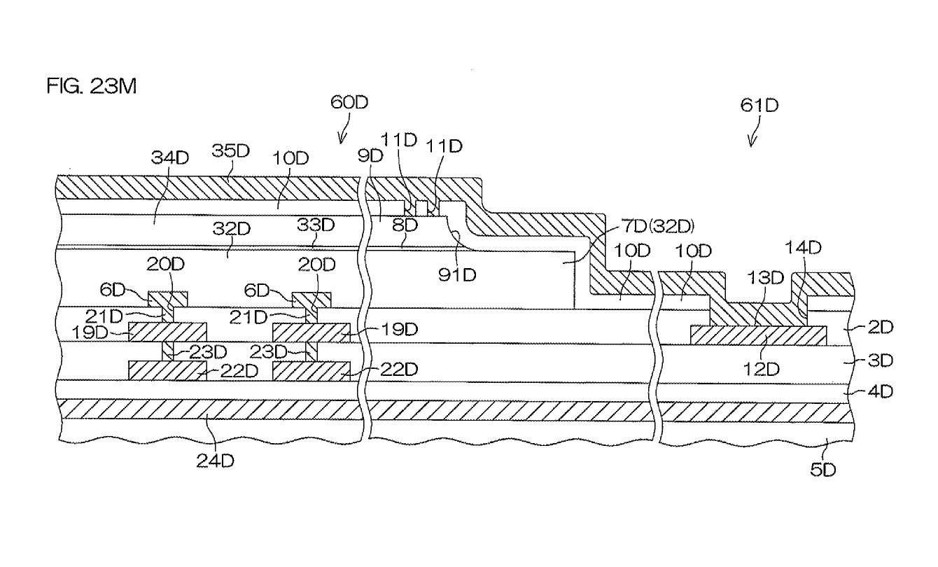

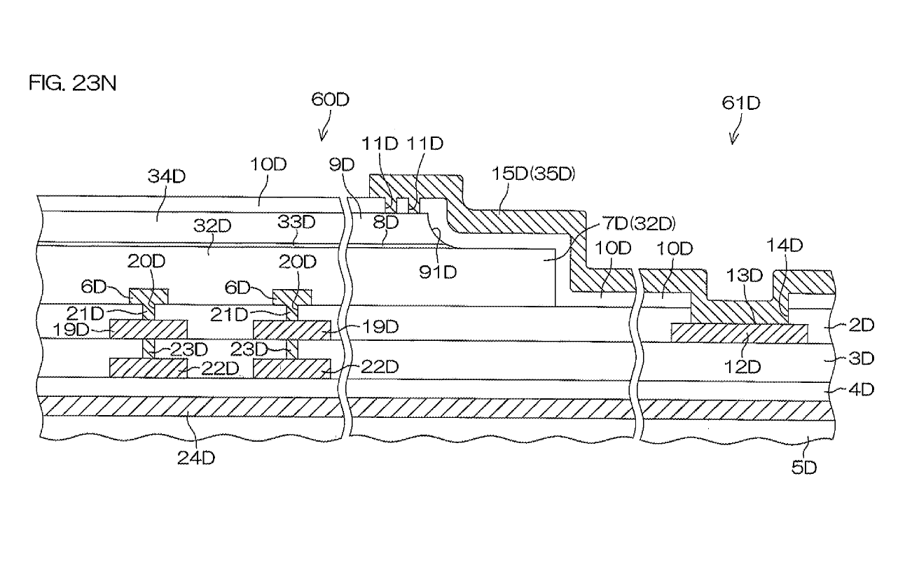

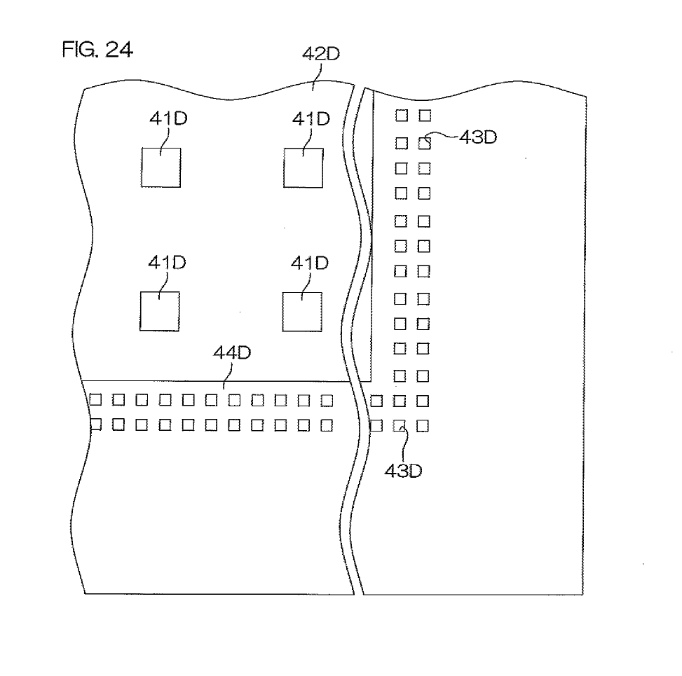

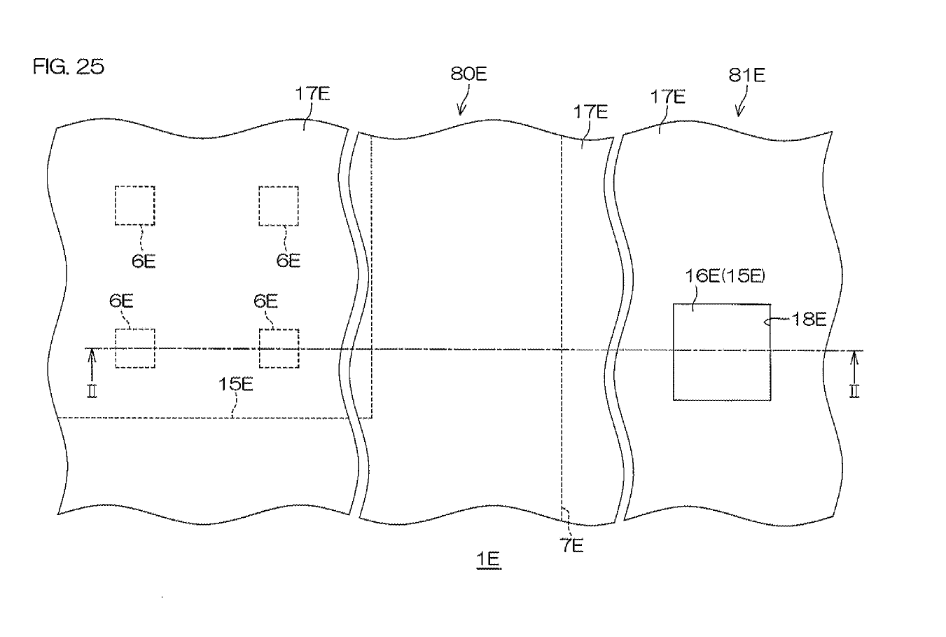

FIG. 23A to FIG. 23N are schematic sectional views that successively illustrate a manufacturing process of the image sensor shown in FIG. 22. FIG. 24 is a diagram for describing resist patterns used in the manufacturing process. In FIG. 23A to FIG. 23N, only portions made of metal materials are hatched and portions besides these are not hatched.

In the manufacturing process of the image sensor 1D, first, as shown in FIG. 23A, the interlayer insulating film 5D, the capacitor lower electrode 24D, the capacitor dielectric film 4D, the capacitor upper electrodes 22D, the interlayer insulating film 3D, the vias 23D, the wirings 12D and 19D, and the interlayer insulating film 2D are formed in that order on the semiconductor substrate (not shown). The via holes 20D penetrating through the interlayer insulating film 2D are then formed above the respective wirings 19D by photolithography and etching.

Thereafter, as shown in FIG. 23B, tungsten, which is the material of the lower electrodes 6D and the vias 21D, is deposited by the CVD method inside the via holes 20D and on the interlayer insulating film 2D to form a tungsten deposition layer 31D. A thickness of the tungsten deposition layer 31D on the interlayer insulating film 2D is 0.3 to 0.4 μm (3000 to 4000 Å).

Thereafter, as shown in FIG. 23C, a resist pattern 41D (see FIG. 24) that selectively covers only portions that become the lower electrodes 6D is formed by photolithography on the tungsten deposition layer 31D.

Then, as shown in FIG. 23D, portions of the tungsten deposition layer 31D exposed from the resist pattern 41D are removed by dry etching using the resist pattern 41D as a mask. The mixed gas of sulfur hexafluoride (SF₆) and argon (Ar) is used for the dry etching.

After the dry etching, the resist pattern 41D is removed as shown in FIG. 23E. The lower electrodes 6D and the vias 21D embedded in the via holes 20D are thereby obtained.

Thereafter, as shown in FIG. 23F, a CIGS film 32D is formed by the MBE method on the interlayer insulating film 2D and the lower electrodes 6D.

Thereafter, as shown in FIG. 23G, a cadmium sulfide film 33D is formed by the CBD method on the CIGS film 32D.

Further in succession, a zinc oxide film 34D is formed by the sputtering method on the cadmium sulfide film 33D as shown in FIG. 23H.

Then, as shown in FIG. 23I, a resist pattern 42D (see FIG. 24) is formed by photolithography on the zinc oxide film 34D. The resist pattern 42D opposes a portion of the CIGS film 32D that is to become the photoabsorption layer 7D. Then, using the resist pattern 42D as a mask, the zinc oxide film 34D and the cadmium sulfide film 33D are removed selectively by wet etching by hydrofluoric acid (HF). The wet etching is continued for a predetermined time even after the portion of the zinc oxide film 34D that does not oppose the resist pattern 42D has been removed. The zinc oxide film 34D is thereby removed from below a peripheral edge portion of the resist pattern 42D as well. Consequently, the zinc oxide film 34D and the cadmium sulfide film 33D become the transparent conductive film 9D and the high-resistance buffer layer 8D, respectively, and the curved side surface 91D of the transparent conductive film 9D is obtained.

Then, while leaving the resist pattern 42D, dry etching using the resist pattern 42D as a mask is performed to selectively remove the CIGS film 32D as shown in FIG. 23J. The CIGS film 32D is left only at the portion opposing the resist pattern 42D. The CIGS film 32D thereby becomes the photoabsorption layer 7D. Thereafter, the resist pattern 42D is removed.

Thereafter, as shown in FIG. 23K, the interlayer insulating film 10D is formed coveringly by the plasma CVD method on the portion of the interlayer insulating film 2D exposed from the photoabsorption layer 7D, on the peripheral edge portion of the photoabsorption layer 7D, and on the transparent conductive film 9D.

Thereafter, a resist pattern having openings 43D (see FIG. 24) that selectively expose portions at which the via holes 11D and the pad opening 14D are to be formed is formed by photolithography on the interlayer insulating film 10D. By then performing dry etching using the resist pattern as a mask, the via holes 11D that penetrate through the interlayer insulating film 10D are formed as shown in FIG. 23L. Also, the pad opening 14D that penetrates continuously through the interlayer insulating films 10D and 2D is formed.

Thereafter, as shown in FIG. 23M, an aluminum film 35D made of aluminum is formed by the sputtering method on the interlayer insulating film 10D. The aluminum film 35D is also formed inside the via holes 11D and the pad opening 14D. The via holes 11D are completely filled with the aluminum film 35D.

Thereafter, a resist pattern 44D (see FIG. 24) that covers a portion that is to become the upper electrode 15D is formed by photolithography on the aluminum film 35D. The aluminum film 35D is then removed selectively by dry etching using the resist pattern as a mask, and the aluminum film 35D is thereby processed to the upper electrode 15D as shown in FIG. 23N. Thereafter, the top surface protective film 17D is formed by the plasma CVD method, and when the opening 18D is formed by photolithography and etching, the image sensor 1D shown in FIG. 22 is obtained.

As described above, with the image sensor 1D, the plurality of mutually-spaced lower electrodes 6D disposed on the interlayer insulating film 2D are covered all together by the photoabsorption layer 7D made of CIGS. That is, the photoabsorption layer 7D is not cut and divided according to each pixel, and thus as in the preferred embodiment according to the first aspect of the present invention, there is no influence of dry etching performed for cutting and dividing on the variation of sensitivity among pixels.

Also, as in the preferred embodiment according to the first aspect of the present invention, the pixel aperture ratio (pn junction area/pixel area) can be made 100% because the photoabsorption layer 7D is not cut and divided according to each pixel. A large number of carriers can thereby be generated even with weak light and dramatic improvement of sensitivity can be achieved.

Further, a shrinkage cavity does not form during forming of the transparent conductive film 9D because grooves for cutting and dividing the photoabsorption layer 7D are not formed. Degradation with time of the transparent conductive film 9D can thus be prevented and reliability can be improved.

Also, a step of forming an isolation film is unnecessary and the manufacturing process is thus simpler than that of the conventional photoelectric converter and time and cost required for manufacture can be reduced.

The side surface 71D of the photoabsorption layer 7D is damaged by the dry etching during processing of the CIGS film 32D to the photoabsorption layer 7D and thus if a pn junction is formed on the side surface 71D of the photoabsorption layer 7D, a dark current due to the damage may arise. However, with the image sensor 1D, the side surface 91D of the transparent conductive film 9D is positioned further inward than the side surface 71D of the photoabsorption layer 7D in a plan view. The transparent conductive film 9D is thus not in contact with the side surface 71D of the photoabsorption layer 7D and a pn junction due to the photoabsorption layer 7D and the transparent conductive film 9D is not formed on the side surface 71D of the photoabsorption layer 7D. Generation of a dark current due to damage of the side surface 71D of the photoabsorption layer 7D can thus be prevented.

Also, with the image sensor 1D, the photoabsorption layer 7D and the upper electrode 15D can be isolated from each other and short-circuiting of the photoabsorption layer 7D and the transparent conductive film 9D via the upper electrode 15D can be prevented because the interlayer insulating film 10D is interposed between the photoabsorption layer 7D and the upper electrode 15D.

Further, contact of the upper electrode 15D with the side surface of the photoabsorption layer 7D can be prevented reliably because the interlayer insulating film 10D borders the side surface of the photoabsorption layer 7D.

The side surface of the transparent conductive film 9D is inclined so that as its lower end is approached, the side surface approaches the side surface of the photoabsorption layer 7D. Improvement of coverage of the side surface of the transparent conductive film 9D by the interlayer insulating film 10D can thus be achieved.

Also, in the manufacturing process of the image sensor 1D, the resist pattern 42D used in the wet etching for processing the zinc oxide film 34D to the transparent conductive film 9D is also used in the dry etching for processing the CIGS film 32D to the photoabsorption layer 7D and a mask (resist pattern) used exclusively for the dry etching is not formed. The manufacturing process of the image sensor 1D can thus be simplified.

Also, as shown in FIG. 23F to FIG. 23H, the CIGS film 32D, the cadmium sulfide film 33D, and the zinc oxide film 34D are formed consecutively. The time from the forming of the CIGS film 32D to the completion of forming of the zinc oxide film 34D can thus be made short, and the CIGS film 32D, the cadmium sulfide film 33D, and the zinc oxide film 34D can be respectively improved in film quality.

Further, the pad opening 14D and the via holes 11D are formed in the same step (step shown in FIG. 23L) and thus in comparison to a case where these are formed in separate steps, the number of masks required for forming these can be reduced and the manufacturing process of the image sensor 1D can be simplified.

### Preferred Embodiment According to a Fifth Aspect of the Invention FIG. 25 to FIG. 31

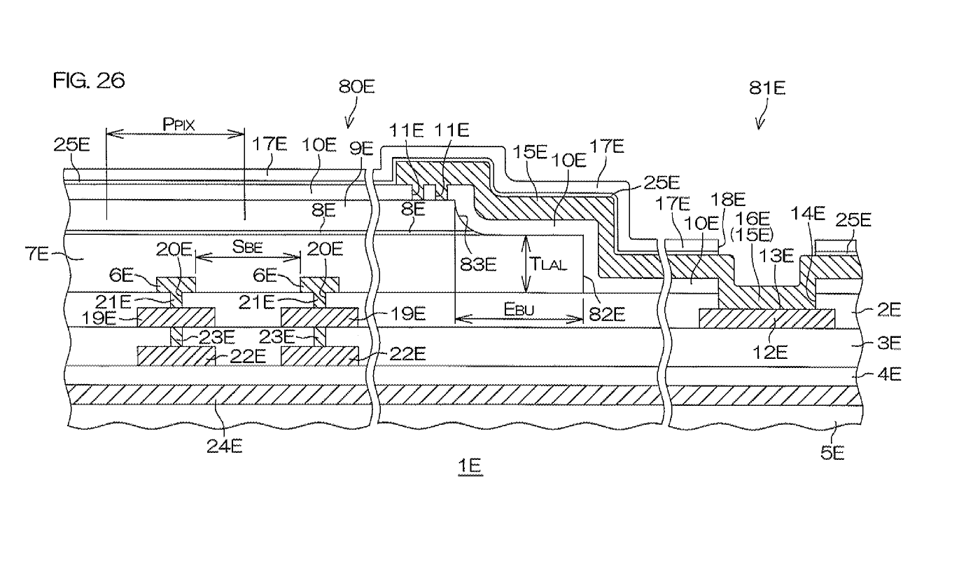

FIG. 25 is a schematic plan view of an image sensor according to a preferred embodiment of a fifth aspect of the present invention. FIG. 26 is a schematic sectional view of the image sensor taken along sectioning line II-II in FIG. 25. In FIG. 26, only portions made of metal materials are hatched and portions besides these are not hatched.

The image sensor 1E, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2E to 5E are laminated on the semiconductor substrate. The interlayer insulating films 2E to 5E are made, for example, of silicon oxide (SiO₂).

Also, as shown in FIG. 25, a sensor forming region 80E and an annular pad forming region 81E surrounding it are set on the semiconductor substrate.

In the sensor forming region 80E, a plurality of lower electrodes 6E are arrayed in a matrix on the uppermost interlayer insulating film 2E. The lower electrodes 6E are made of tungsten (W). Each lower electrode 6E is formed to a square shape in a plan view. A length of one side of the lower electrode 6E in a plan view is no less than 1 μm and no more than 10 μm. The lower electrode 6E has a thickness of no less than 0.2 μm and no more than 0.5 μm. Also, as shown in FIG. 26, mutually adjacent lower electrodes 6E are spaced apart at equal intervals S_{BE} (≧T_{LAL}×3) each set to no less than three times the thickness T_{LAL} of a photoabsorption layer 7E to be described below.

The photoabsorption layer 7E of rectangular shape in a plan view is formed on the interlayer insulating film 2E so as to cover all of the lower electrodes 6E together. Specifically, the photoabsorption layer 7E is formed integrally on a rectangular region on the interlayer insulating film 2E in which the lower electrodes 6E are formed and on a rectangular annular region of fixed width at a periphery of the rectangular region. The photoabsorption layer 7E is made of CIGS and exhibits a p-type conductivity. The thickness T_{LAL} of the photoabsorption layer 7E is no less than 1.0 μm and no more than 1.4 μm. In the photoabsorption layer 7E, each region of fixed area and rectangular shape in a plan view that is centered at each lower electrode 6E is used for reading of a single pixel. The pixel pitch P_{PIX} that is the width of this region is no less than 5 μm and no more than 10 μm.

An upper surface of the photoabsorption layer 7E, with the exception of a peripheral edge portion thereof, is covered by a high-resistance buffer layer 8E. The high-resistance buffer layer 8E is made of cadmium sulfide (CdS). The high-resistance buffer layer 8E has a thickness, for example, of 0.05 μm.

On the high-resistance buffer layer 8E, a transparent conductive film 9E is formed so as to cover an entire upper surface of the high-resistance buffer layer 8E. The transparent conductive film 9E is made of zinc oxide (ZnO), which has a light transmitting property, and has conductivity imparted by addition of an n-type impurity (for example, P (phosphorus) or As (arsenic)). The transparent conductive film 9E has a thickness, for example, of 0.6 μm.

A side surface 83E of the transparent conductive film 9E is formed to a cross-sectional shape that is downwardly (inwardly) concavely curved and inclined so that as its lower end is approached, a side surface 82E of the photoabsorption layer 7E is approached. A lower end of the side surface 83E is continuous with a peripheral edge of the high-resistance buffer layer 8E. An upper end of the side surface 83E is positioned inward with respect to the side surface 82E of the photoabsorption layer 7E by just a horizontal distance E_{BU}. The horizontal distance E_{BU} is no less than 5 μm and no more than 10 μm.

An interlayer insulating film 10E is formed on a portion of the interlayer insulating film 2E exposed from the photoabsorption layer 7E, on a peripheral edge portion of the photoabsorption layer 7E, and on the transparent conductive film 9E so as to spread across these portions. The interlayer insulating film 10E is made of silicon nitride (SiN). The interlayer insulating film 10E has a thickness, for example, of 0.4 μm. Above a peripheral edge portion of the transparent conductive film 9E, a plurality of via holes 11E are penetratingly formed in the interlayer insulating film 10E. The via holes 11E form, for example, two columns and are mutually spaced and disposed along the peripheral edge of the transparent conductive film 9E.

Also, in the pad forming region 81E, a wiring 12E is formed between the uppermost interlayer insulating film 2E and the interlayer insulating film 3E below it. A pad opening 14E, exposing a portion of the wiring 12E as a pad 13E, is formed so as to continuously penetrate through the interlayer insulating films 2E and 10E.

On the interlayer insulating film 10E, an upper electrode 15E is formed so as to cover entire peripheries of peripheral edge portions of the photoabsorption layer 7E and the transparent conductive film 9E. The upper electrode 15E is made of aluminum (Al). An extending portion 16E, extending toward the pad forming region 81E, is formed integral to the upper electrode 15E. An end portion of the extending portion 16E enters inside the pad opening 14E and is connected to the pad 13E (wiring 12E) inside the pad opening 14E.

Also, a water-impermeable thin film 25E and a top surface protective film 17E are formed as protective films on a topmost surface of the image sensor 1E. The water-impermeable thin film 25E and the top surface protective film 17E are laminated in that order from the semiconductor substrate (not shown) side.

The water-impermeable thin film 25E is made of aluminum oxide (Al₂O₃). A thickness of the water-impermeable thin film 25E is of a value such that the water-impermeable thin film 25E has a light transmitting property and is, for example, 400 Å.

The top surface protective film 17E is made, for example, of silicon nitride (SiN). The top surface protective film 17E has a thickness that is greater than the thickness of the water-impermeable thin film 25E, is of value such that the top surface protective film 17E has a light transmitting property, and is, for example, 1 μm.

In the water-impermeable thin film 25E and the top surface protective film 17E, an opening 18E for exposing the portion of the extending portion 16E of the upper electrode 15E that enters into the pad opening 14E is formed at a position opposing the pad opening 14E.

Between the uppermost interlayer insulating film 2E and the interlayer insulating film 3E below it, wirings 19E are formed at positions opposing the respective lower electrodes 6E. A via hole 20E is formed penetratingly through the interlayer insulating film 2E between each lower electrode 6E and the opposing wiring 19E in the direction in which these oppose each other (thickness direction of the interlayer insulating film 2E). In each via hole 20E, a via 21E, made of the same material as the lower electrode 6E, is formed integral to the lower electrode 6E and without any gaps. Each lower electrode 6E is thereby electrically connected to the opposing wiring 19E via the via 21E. Each via hole 20E has an inner diameter of, for example, 0.4 μm.

Between the interlayer insulating film 3E and the capacitor dielectric film 4E below it, capacitor upper electrodes 22E are formed at positions opposing the respective wirings 19E. Each wiring 19E and the opposing capacitor upper electrode 22E are electrically connected by a via 23E that penetrates through the interlayer insulating film 3E. The via 23E is made of tungsten.

Between the interlayer insulating film 4E and the interlayer insulating film 5E below it, a capacitor lower electrode 24E is formed to oppose all of the capacitor upper electrodes 22E together. A capacitive element (MIM capacitor) having an MIM (metal-insulator-metal) structure, in which the interlayer insulating film 4E is sandwiched as a capacitive film between the capacitor upper electrode 22E and the capacitor lower electrode 24E, is thereby formed according to each pixel. The lower electrode 6E and the capacitor upper electrode 22E of the MIM capacitor are electrically connected according to each pixel.

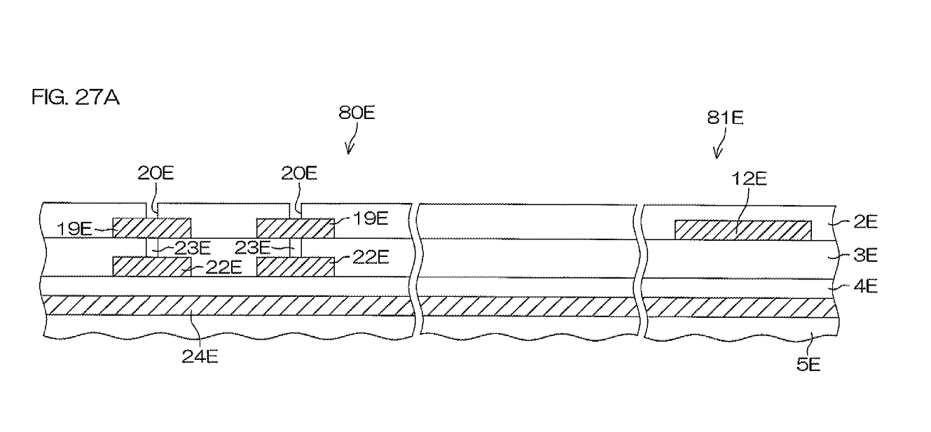

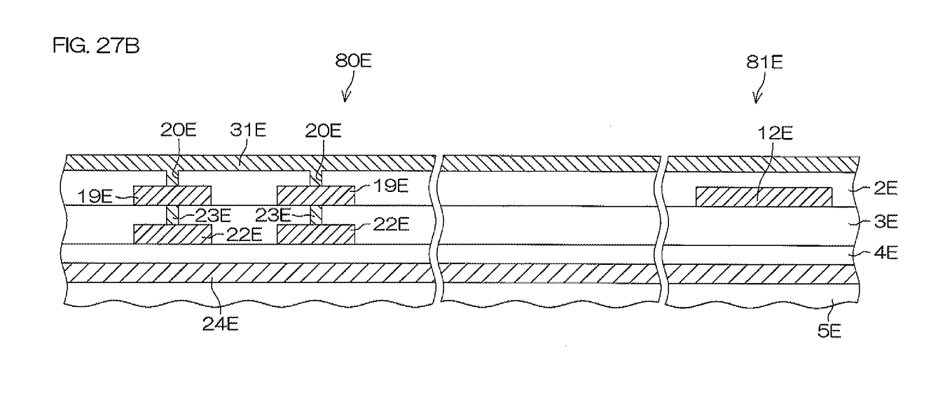

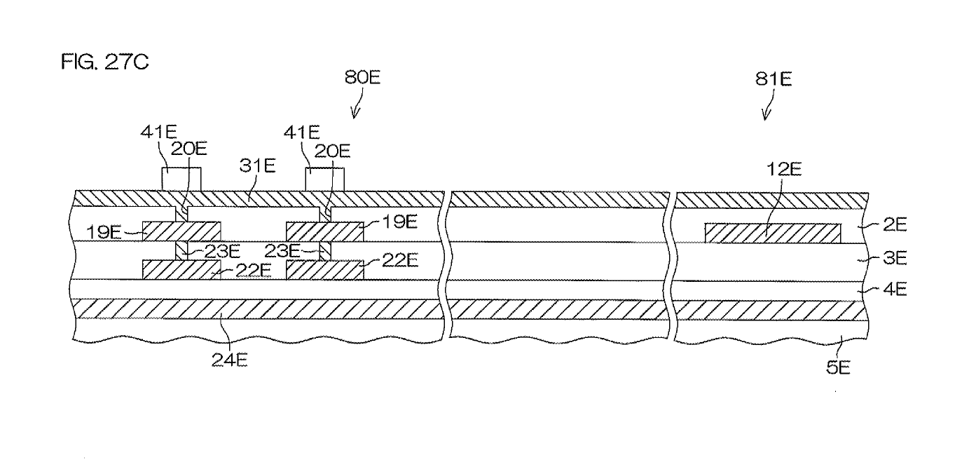

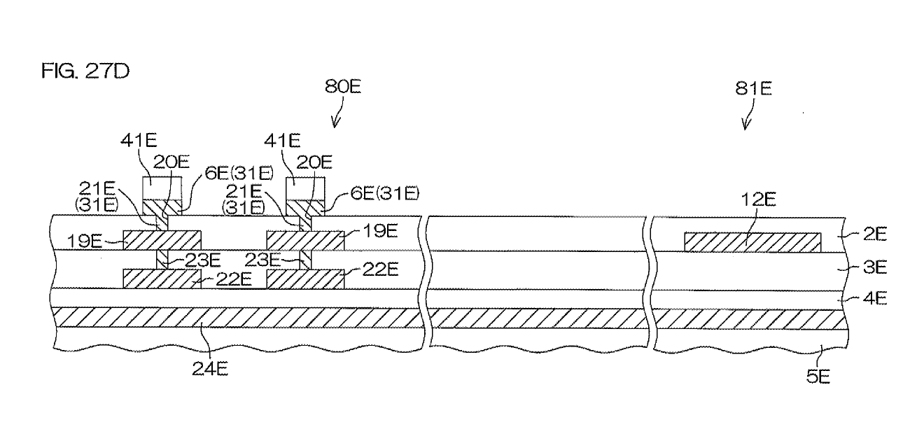

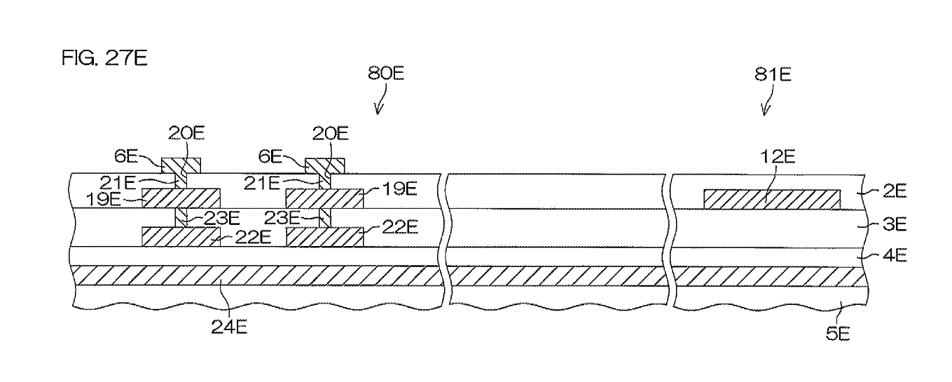

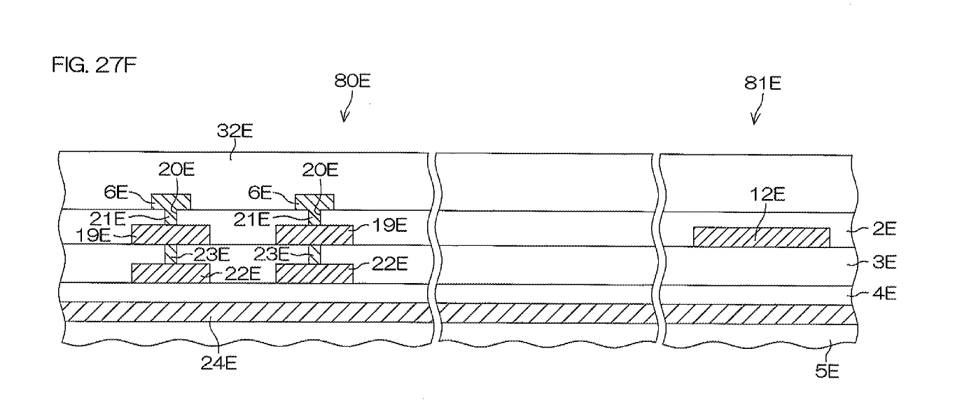

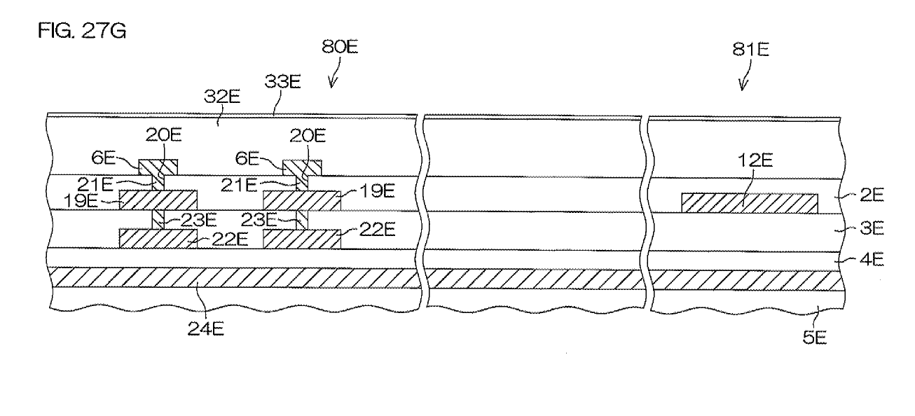

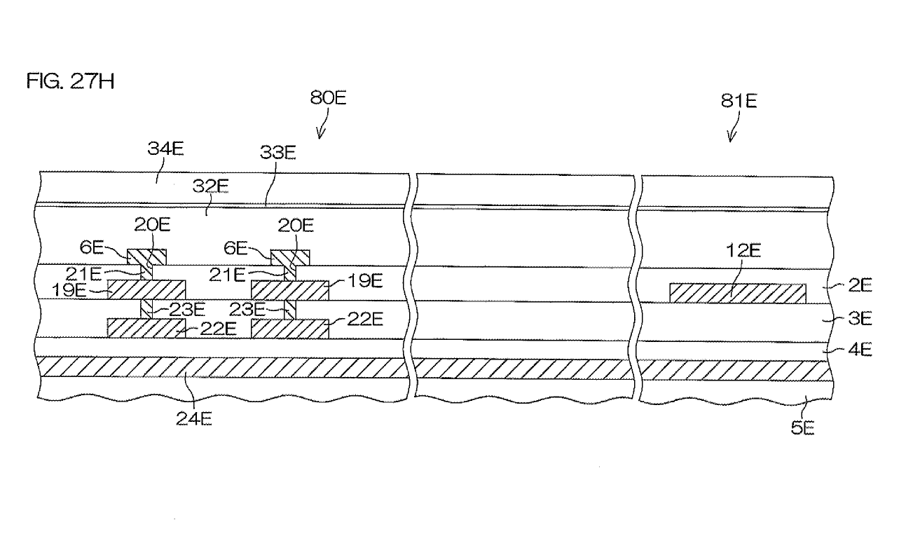

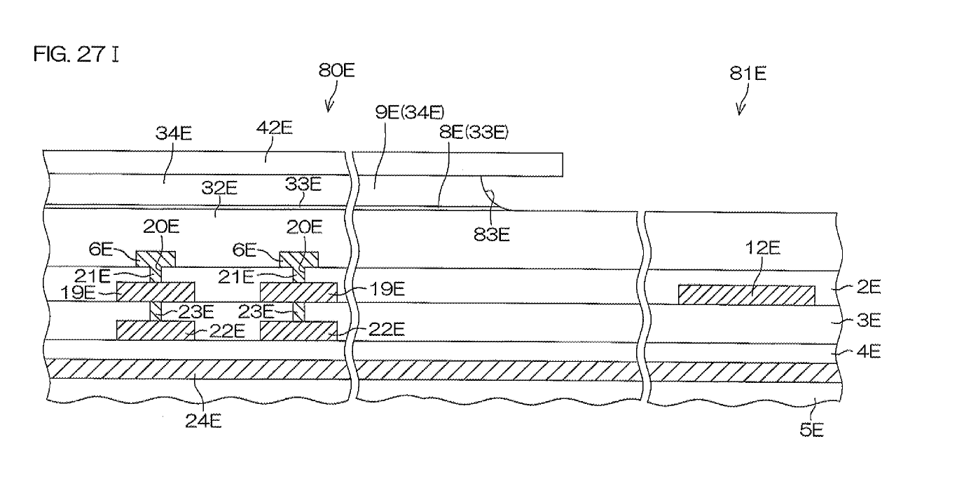

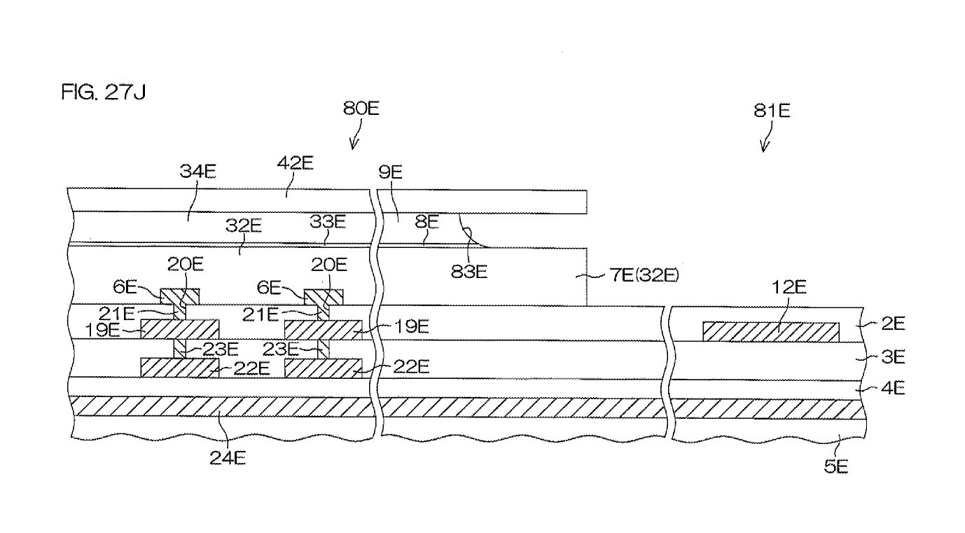

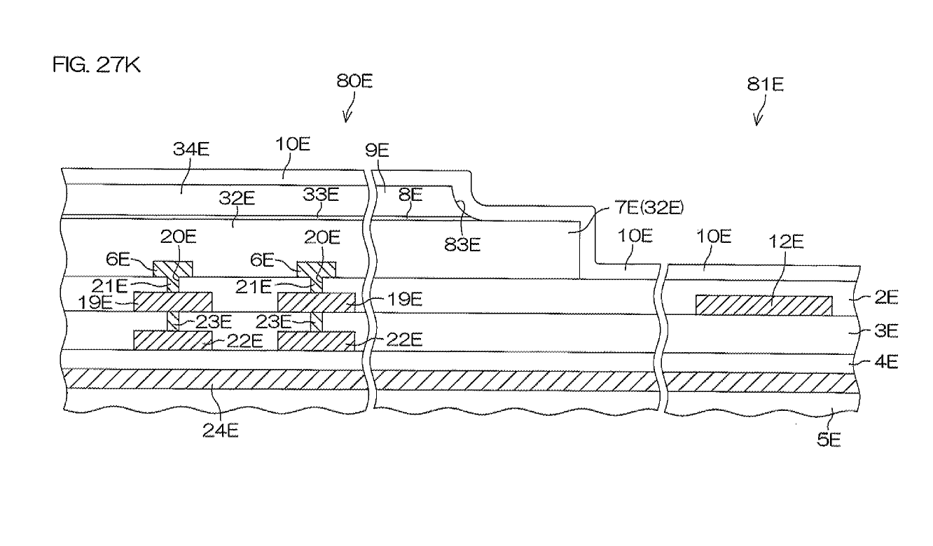

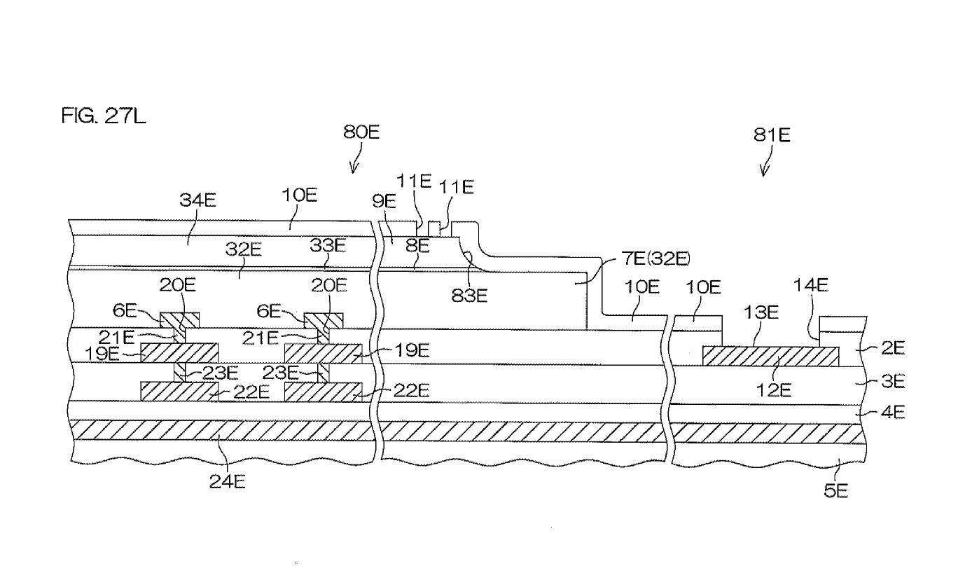

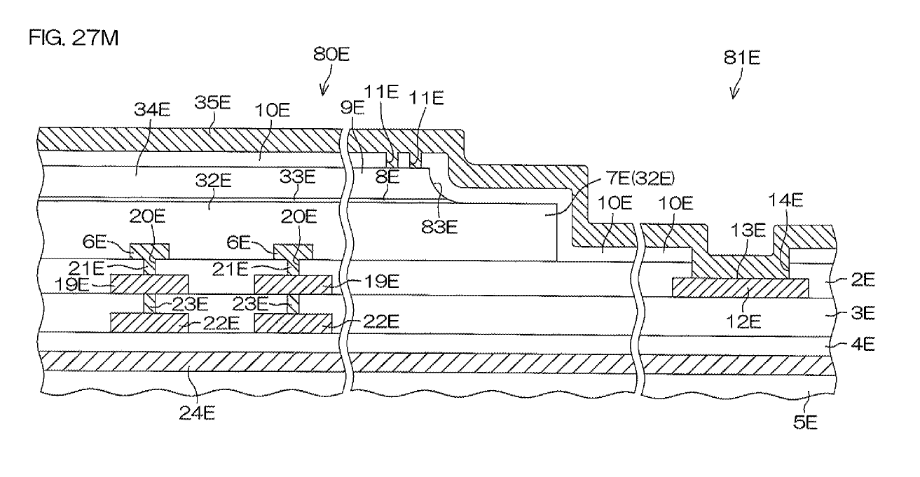

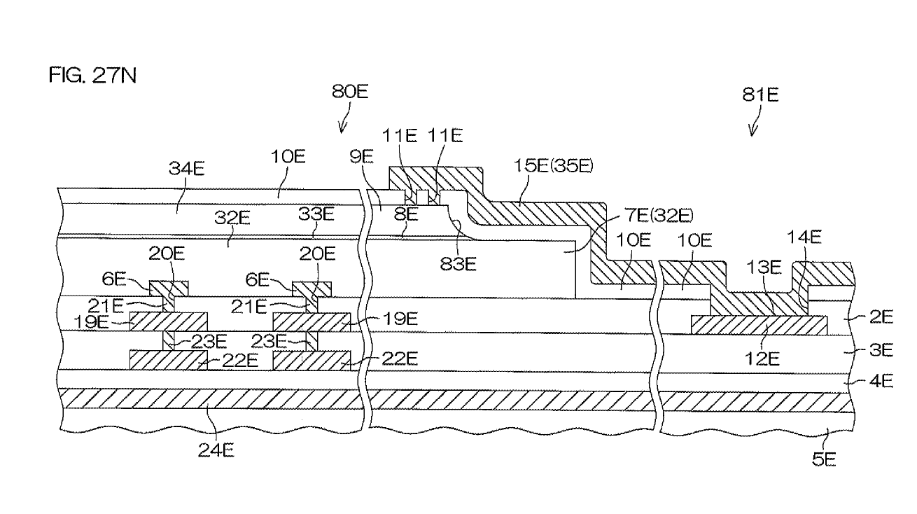

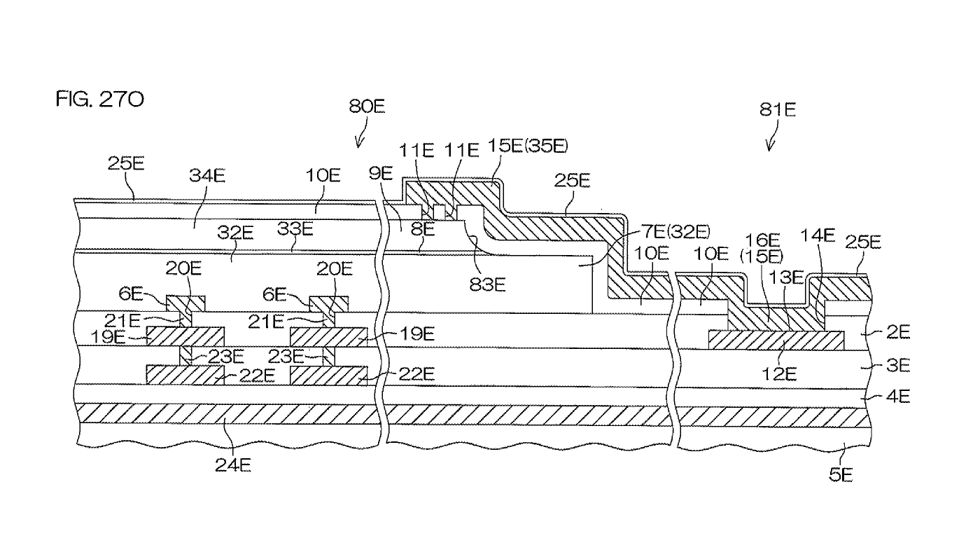

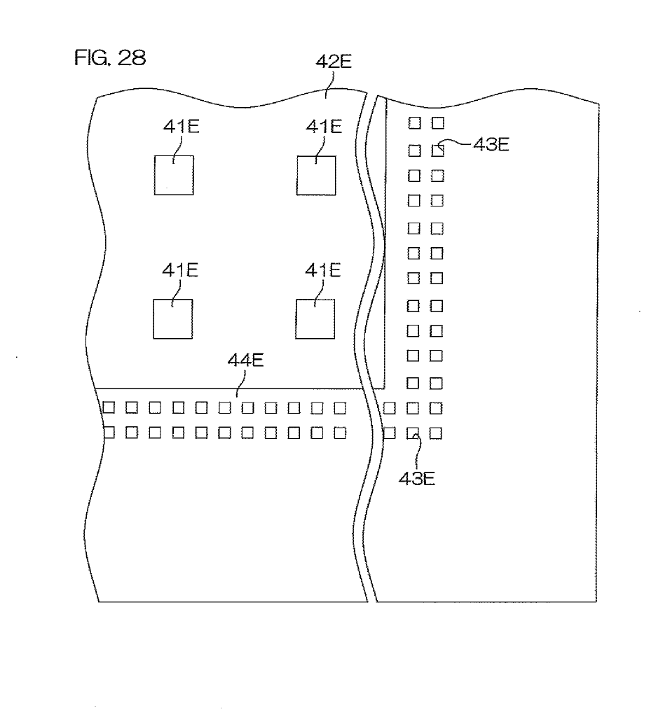

FIG. 27A to FIG. 27O are schematic sectional views that successively illustrate a manufacturing process of the image sensor shown in FIG. 26. FIG. 28 is a diagram for describing resist patterns used in the manufacturing process. In FIG. 27A to FIG. 27O, only portions made of metal materials are hatched and portions besides these are not hatched.

In the manufacturing process of the image sensor 1E, first, as shown in FIG. 27A, the interlayer insulating film 5E, the capacitor lower electrode 24E, the interlayer insulating film 4E, the capacitor upper electrodes 22E, the interlayer insulating film 3E, the vias 23E, the wirings 12E and 19E, and the interlayer insulating film 2E are formed in that order on the semiconductor substrate (not shown). The via holes 20E penetrating through the interlayer insulating film 2E are then formed above the respective wirings 19E by photolithography and etching.

Thereafter, as shown in FIG. 27B, tungsten, which is the material of the lower electrodes 6E and the vias 21E, is deposited by the CVD method inside the via holes 20E and on the interlayer insulating film 2E to form a tungsten deposition layer 31E. A thickness of the tungsten deposition layer 31E on the interlayer insulating film 2E is 0.3 to 0.4 μm (3000 to 4000 Å).

Thereafter, as shown in FIG. 27C, a resist pattern 41E (see FIG. 28) that selectively covers only portions that become the lower electrodes 6E is formed by photolithography on the tungsten deposition layer 31E.

Then, as shown in FIG. 27D, portions of the tungsten deposition layer 31E exposed from the resist pattern 41E are removed by dry etching using the resist pattern 41E as a mask. The mixed gas of sulfur hexafluoride (SF₆) and argon (Ar) is used for the dry etching.

After the dry etching, the resist pattern 41E is removed as shown in FIG. 27E. The lower electrodes 6E and the vias 21E embedded in the via holes 20E are thereby obtained.

Thereafter, as shown in FIG. 27F, a CIGS film 32E is formed by the MBE method on the interlayer insulating film 2E and the lower electrodes 6E.

Thereafter, as shown in FIG. 27G, a cadmium sulfide film 33E is formed by the CBD method on the CIGS film 32E.

Further in succession, a zinc oxide film 34E is formed by the sputtering method on the cadmium sulfide film 33E as shown in FIG. 27H.

Then, as shown in FIG. 27I, a resist pattern 42E (see FIG. 28) is formed by photolithography on the zinc oxide film 34E. The resist pattern 42E opposes a portion of the CIGS film 32E that is to become the photoabsorption layer 7E. Then, using the resist pattern 42E as a mask, the zinc oxide film 34E and the cadmium sulfide film 33E are removed selectively by wet etching by hydrofluoric acid (HF). The wet etching is continued for a predetermined time even after the portion of the zinc oxide film 34E that does not oppose the resist pattern 42E has been removed. The zinc oxide film 34E is thereby removed from below a peripheral edge portion of the resist pattern 42E as well. Consequently, the zinc oxide film 34E and the cadmium sulfide film 33E become the transparent conductive film 9E and the high-resistance buffer layer 8E, respectively, and the curved side surface 83E of the transparent conductive film 9E is obtained.

Then, while leaving the resist pattern 42E, dry etching using the resist pattern 42E as a mask is performed to selectively remove the CIGS film 32E as shown in FIG. 27J. The CIGS film 32E is left only at the portion opposing the resist pattern 42E. The CIGS film 32E thereby becomes the photoabsorption layer 7E. Thereafter, the resist pattern 42E is removed.

Thereafter, as shown in FIG. 27K, the interlayer insulating film 10E is formed coveringly by the plasma CVD method on the portion of the interlayer insulating film 2E exposed from the photoabsorption layer 7E, on the peripheral edge portion of the photoabsorption layer 7E, and on the transparent conductive film 9E.

Thereafter, a resist pattern having openings 43E (see FIG. 28) that selectively expose portions at which the via holes 11E and the pad opening 14E are to be formed is formed by photolithography on the interlayer insulating film 10E. By then performing dry etching using the resist pattern as a mask, the via holes 11E that penetrate through the interlayer insulating film 10E are formed as shown in FIG. 27L. Also, the pad opening 14E that penetrates continuously through the interlayer insulating films 10E and 2E is formed.

Thereafter, as shown in FIG. 27M, an aluminum film 35E made of aluminum is formed by the sputtering method on the interlayer insulating film 10E. The aluminum film 35E is also formed inside the via holes 11E and the pad opening 14E. The via holes 11E are completely filled with the aluminum film 35E.

Thereafter, a resist pattern 44E (see FIG. 28) that covers a portion that is to become the upper electrode 15E is formed by photolithography on the aluminum film 35E. The aluminum film 35E is then removed selectively by dry etching using the resist pattern as a mask, and the aluminum film 35E is thereby processed to the upper electrode 15E as shown in FIG. 27N.

Thereafter, as shown in FIG. 27O, aluminum oxide is deposited by an RF sputtering method under ordinary temperature on an entire top surface of the structure on the semiconductor substrate (not shown) and the water-impermeable thin film 25E is thereby formed.

Thereafter, the top surface protective film 17E is formed on the water-impermeable thin film 25E by the plasma CVD method under a temperature of no more than 200°, and when the opening 18E that penetrates continuously through the water-impermeable thin film 25E and the top surface protective film 17E is formed by photolithography and etching, the image sensor 1E shown in FIG. 26 is obtained.

As described above, with the image sensor 1E, the plurality of mutually-spaced lower electrodes 6E disposed on the interlayer insulating film 2E are covered all together by the photoabsorption layer 7E made of CIGS. That is, the photoabsorption layer 7E is not cut and divided according to each pixel, and thus as in the preferred embodiment according to the first aspect of the present invention, there is no variation of sensitivity among pixels.

Also, as in the preferred embodiment according to the first aspect of the present invention, the pixel aperture ratio (pn junction area/pixel area) can be made 100% because the photoabsorption layer 7E is not cut and divided according to each pixel. A large number of carriers can thereby be generated even with weak light and dramatic improvement of sensitivity can be achieved.

Further, a shrinkage cavity does not form during forming of the transparent conductive film 9E because grooves for cutting and dividing the photoabsorption layer 7E are not formed. Degradation with time of the transparent conductive film 9E can thus be prevented and reliability can be improved.

Also, a step of forming an isolation film is unnecessary and the manufacturing process is thus simpler than that of the conventional photoelectric converter and time and cost required for manufacture can be reduced.

The zinc oxide that is the material of the transparent conductive film 9E is not high in heat resistance and degrades readily under high temperature (for example, in the excess of 200° C.). Thus, after the forming of the transparent conductive film 9E, processing under a temperature exceeding 200° C. cannot be performed.

In the present preferred embodiment, after the forming of the zinc oxide film 34E that is the material of the transparent conductive film 9E (step of FIG. 27H), the environmental temperature of the respective steps executed in the manufacturing process of the image sensor 1E is constantly restricted to no more than 200° C. For example, the forming of the interlayer insulating film 10E (step of FIG. 27K) and the forming of the top surface protective film 17E are both executed by the plasma CVD method at no more than 200° C., and the forming of the water-impermeable thin film 25E (step of FIG. 27O) is executed by the RF sputtering method at ordinary temperature. Thermal damage is thus not applied to the transparent conductive film 9E even after the forming of the transparent conductive film 9E. Degradation of the transparent conductive film 9E due to thermal damage can thus be suppressed.

Meanwhile, when the top surface protective film 17E is formed by the plasma CVD method at no more than 200° C., the top surface protective film 17E is rough in film structure and the top surface protective film 17E may not exhibit adequate water impermeability.

However, in the present preferred embodiment, the water-impermeable thin film 25E (Al₂O₃ film) is provided, and the film structure of Al₂O₃ can be made dense even by the RF sputtering method executed under ordinary temperature. The water-impermeable thin film 25E (Al₂O₃ film) of dense structure exhibits excellent water impermeability and thus regardless of the film quality of the top surface protective film 17E, entry of water into portions below (transparent conductive film 9E side of) the water-impermeable thin film 25E can be suppressed satisfactorily. Consequently, degradation of the photoabsorption layer 7E and the transparent conductive film 9E due to entry of water, etc., can be suppressed.

Also, SiN has a good insulating property and thus a lower side of the top surface protective film 17E at which the transparent conductive film 9E and the photoabsorption layer 7E are disposed is isolated satisfactorily across the top surface protective film 17E from an upper side of the top surface protective film 17E. Electrical influences on the transparent conductive film 9E and the photoabsorption layer 7E can thus be suppressed. Consequently, the image sensor 1E can be made to operate with stability.

That is, with the image sensor 1E, good insulating property and water impermeability can be realized by the transparent conductive film 9E and the photoabsorption layer 7E being covered by both the water-impermeable thin film 25E made of Al₂O₃ and the top surface protective film 17E made of SiN.

Also, in the manufacturing process of the image sensor 1E, the resist pattern 42E used in the wet etching for processing the zinc oxide film 34E to the transparent conductive film 9E is also used in the dry etching for processing the CIGS film 32E to the photoabsorption layer 7E and a mask (resist pattern) used exclusively for the dry etching is not formed. The manufacturing process of the image sensor 1E can thus be simplified.

Also, as shown in FIG. 27F to FIG. 27H, the CIGS film 32E, the cadmium sulfide film 33E, and the zinc oxide film 34E are formed consecutively. The time from the forming of the CIGS film 32E to the completion of forming of the zinc oxide film 34E can thus be made short, and the CIGS film 32E, the cadmium sulfide film 33E, and the zinc oxide film 34E can be respectively improved in film quality.

Further, the pad opening 14E and the via holes 11E are formed in the same step (step shown in FIG. 27L) and thus in comparison to a case where these are formed in separate steps, the number of masks required for forming these can be reduced and the manufacturing process of the image sensor 1E can be simplified.

Although the preferred embodiment of the fifth aspect of the present invention has been described above, the present preferred embodiment may also be changed as follows.

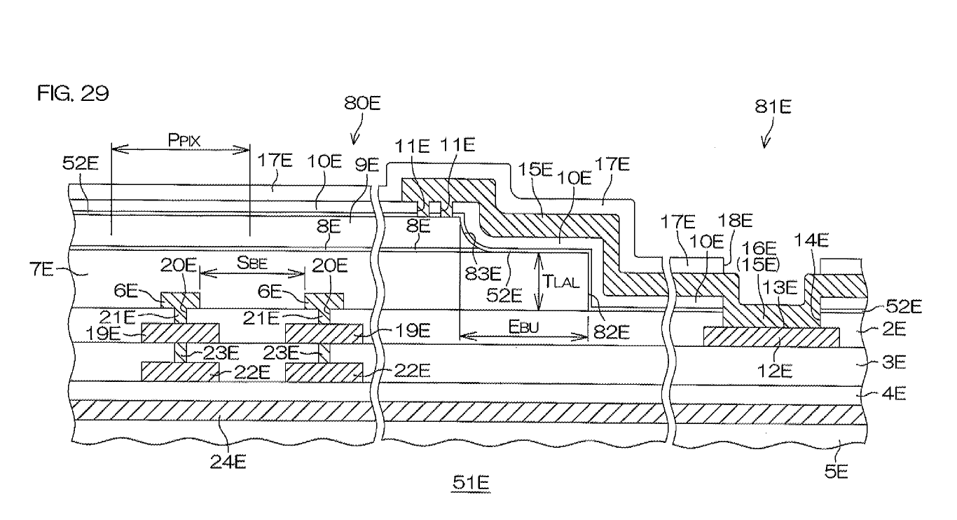

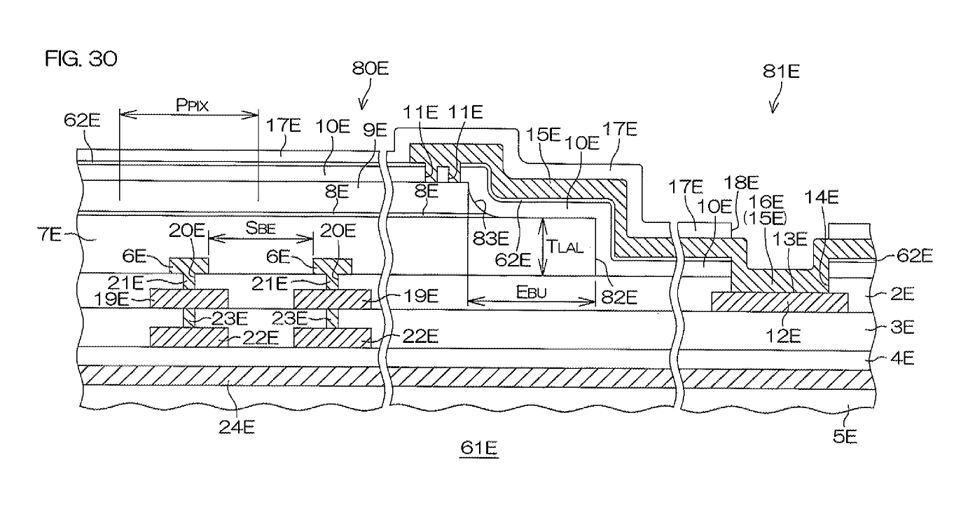

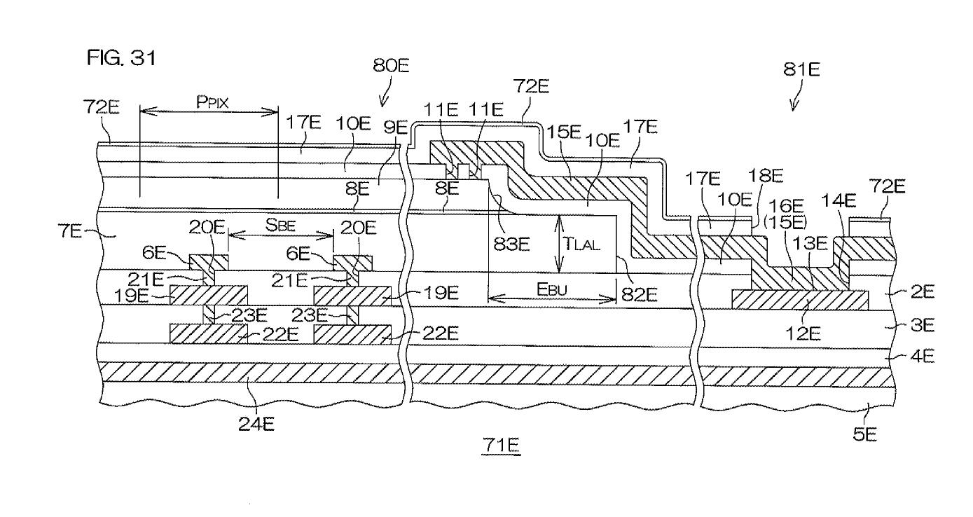

For example, the position of the water-impermeable thin film 25E in the image sensor 1E may be changed as suited as long as the water-impermeable thin film 25E is formed so as to cover the photoabsorption layer 7E and the transparent conductive film 9E. An image sensor ME shown in FIG. 29, an image sensor 61E shown in FIG. 30, and an image sensor 71E shown in FIG. 31 can be given as specific examples of modification of the image sensor 1E.

With the image sensor ME of FIG. 29, a water-impermeable thin film 52E is formed on the portion of the interlayer insulating film 2E exposed from the photoabsorption layer 7E, on the peripheral edge portion of the photoabsorption layer 7E, and on the transparent conductive film 9E so as to spread across these portions. The interlayer insulating film 10E is formed on the water-impermeable thin film 52E. To form the water-impermeable thin film 52E at the above position, after removing the CIGS film 32E by dry etching (step of FIG. 27J), the water-impermeable thin film 52E is formed by the same method as the method illustrated in FIG. 27O before forming the interlayer insulating film 10E (step of FIG. 27K).

With the image sensor 61E of FIG. 30, the water-impermeable thin film 62E is laminated on the interlayer insulating film 10E formed to cover the photoabsorption layer 7E and the transparent conductive film 9E. The upper electrode 15E is formed on the water-impermeable thin film 62E. To form the water-impermeable thin film 62E at the above position, after the forming of interlayer insulating film 10E (step of FIG. 27K), the water-impermeable thin film 52E is formed by the same method as the method illustrated in FIG. 27O before forming the via holes 11E (step of FIG. 27L).

With the image sensor 71E of FIG. 31, the water-impermeable thin film 72E is laminated on the top surface protective film 17E, that is, the topmost surface of the image sensor 1E. To form the water-impermeable thin film 72E at the above position, after the forming of top surface protective film 17E, the water-impermeable thin film 72F is formed by the same method as the method illustrated in FIG. 27O before forming the opening 18E.

Also, the photoabsorption layer 7E does not have to be formed to cover all of the lower electrodes 6E together and may instead be formed in plurality to cover the respective lower electrodes 6E individually.

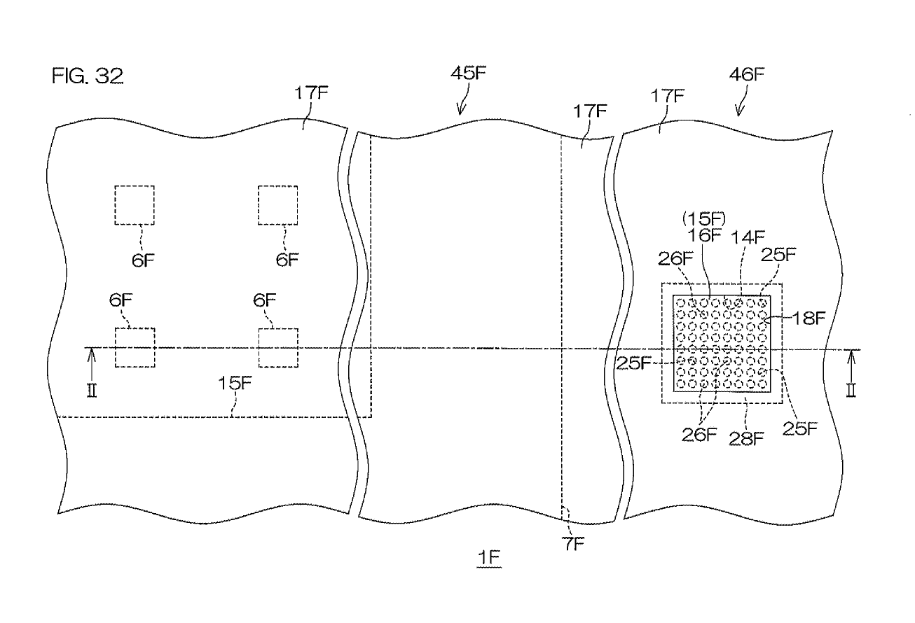

### Preferred Embodiments According to a Sixth Aspect of the Invention FIG. 32 to FIG. 42

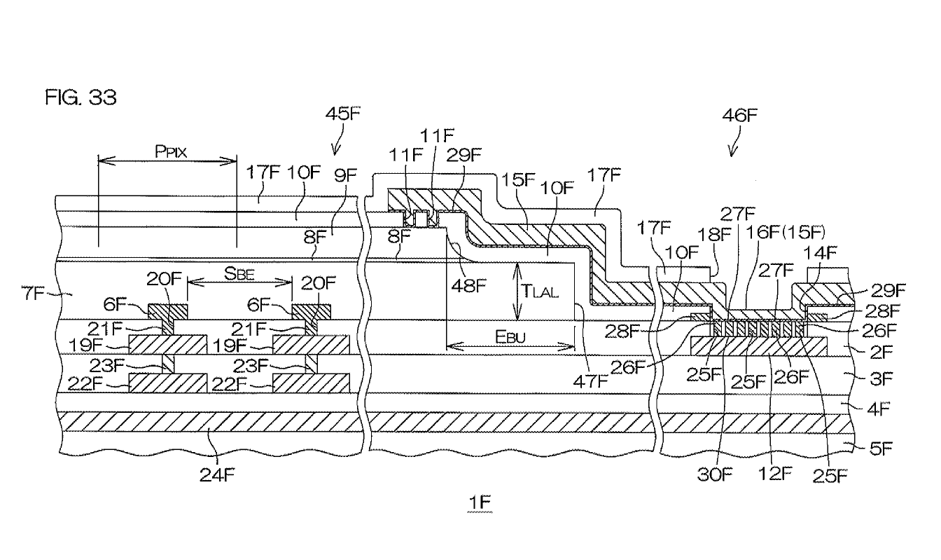

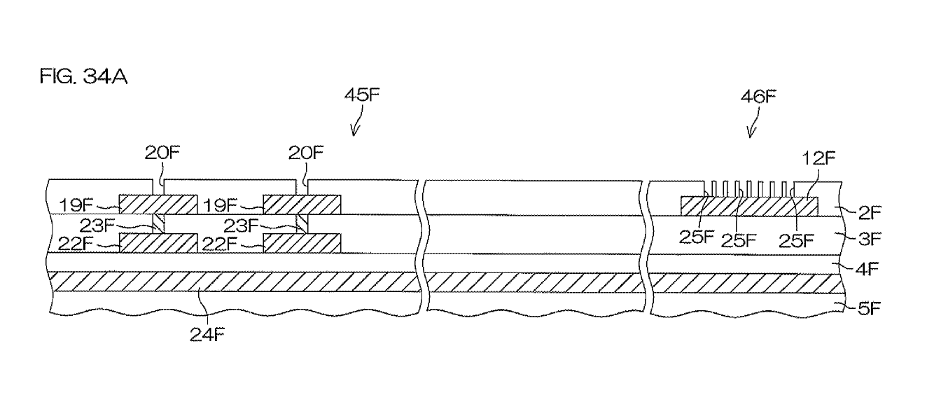

FIG. 32 is a schematic plan view of an image sensor according to a preferred embodiment of a sixth aspect of the present invention. FIG. 33 is a schematic sectional view of the image sensor taken along sectioning line II-II in FIG. 32. In FIG. 33, only portions made of metal materials are hatched and portions besides these are not hatched.

The image sensor 1F, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2F to 5F are laminated on the semiconductor substrate. The interlayer insulating films 2F to 5F are made, for example, of silicon oxide (SiO₂).

Also, as shown in FIG. 32, a sensor forming region 45F and an annular pad forming region 46F surrounding it are set on the semiconductor substrate.

In the sensor forming region 45F, a plurality of lower electrodes 6F are arrayed in a matrix on the uppermost interlayer insulating film 2F. The lower electrodes 6F are made of tungsten (W). Each lower electrode 6F is formed to a square shape in a plan view. A length of one side of the lower electrode 6F in a plan view is no less than 1 μm and no more than 10 μm. The lower electrode 6F has a thickness of no less than 0.2 μm and no more than 1 μm. Also, as shown in FIG. 33, mutually adjacent lower electrodes 6F are spaced apart at equal intervals S_{BE} (≧T_{LAL}×3) each set to no less than three times the thickness T_{LAL} of a photoabsorption layer 7F to be described below.

The photoabsorption layer 7F of rectangular shape in a plan view is formed on the interlayer insulating film 2F so as to cover all of the lower electrodes 6F together. Specifically, the photoabsorption layer 7F is formed integrally on a rectangular region on the interlayer insulating film 2F in which the lower electrodes 6F are formed and on a rectangular annular region of fixed width at a periphery of the rectangular region. The photoabsorption layer 7F is made of CIGS and exhibits a p-type conductivity. The thickness T_{LAL} of the photoabsorption layer 7F is no less than 1.0 μm and no more than 1.4 μm. In the photoabsorption layer 7F, each region of fixed area and rectangular shape in a plan view that is centered at each lower electrode 6F is used for reading of a single pixel. The pixel pitch P_{PIX} that is the width of this region is no less than 5 μm and no more than 10 μm.

An upper surface of the photoabsorption layer 7F, with the exception of a peripheral edge portion thereof, is covered by a high-resistance buffer layer 8F. The high-resistance buffer layer 8F is made of cadmium sulfide (CdS). The high-resistance buffer layer 8F has a thickness, for example, of 0.05 μm.

On the high-resistance buffer layer 8F, a transparent conductive film 9F is formed so as to cover an entire upper surface of the high-resistance buffer layer 8F. The transparent conductive film 9F is made of zinc oxide (ZnO), which has a light transmitting property, and has conductivity imparted by addition of an n-type impurity (for example, P (phosphorus) or As (arsenic)). The transparent conductive film 9F has a thickness, for example, of 0.6 μm.

A side surface 48F of the transparent conductive film 9F is formed to a cross-sectional shape that is downwardly (inwardly) concavely curved and inclined so that as its lower end is approached, a side surface 47F of the photoabsorption layer 7F is approached. A lower end of the side surface 48F is continuous with a peripheral edge of the high-resistance buffer layer 8F. An upper end of the side surface 48F is positioned inward with respect to the side surface 47F of the photoabsorption layer 7F by just a horizontal distance E_{BU}. The horizontal distance E_{BU} is no less than 5 μm and no more than 10 μm.

An interlayer insulating film 10F is formed on a portion of the interlayer insulating film 2F exposed from the photoabsorption layer 7F, on a peripheral edge portion of the photoabsorption layer 7F, and on the transparent conductive film 9F so as to spread across these portions. The interlayer insulating film 10F is made of silicon nitride (SiN). The interlayer insulating film 10F has a thickness, for example, of 0.4 μm. Above a peripheral edge portion of the transparent conductive film 9F, a plurality of via holes 11F are penetratingly formed in the interlayer insulating film 10F. The via holes 11F form, for example, two columns and are mutually spaced and disposed along the peripheral edge of the transparent conductive film 9F.

Also, in the pad forming region 46F, an electrode pad 12F is formed between the uppermost interlayer insulating film 2F and the interlayer insulating film 3F below it.

A pad opening 14F of approximately square shape in a plan view is formed at a position of the interlayer insulating film 10F that opposes the electrode pad 12F. The pad opening 14F penetrates through the interlayer insulating film 10F in the thickness direction. A top surface of the interlayer insulating film 2F is thereby exposed inside the pad opening 14F.

Between the electrode pad 12F and the opposing pad opening 14F, a plurality of via holes 25F are formed in the interlayer insulating film 2F. The plurality of via holes 25F are disposed in a matrix inside the pad opening 14F. Each via hole 25F is formed to a circular shape in a plan view. Also, each via hole 25F has an inner diameter, for example, of no more than 0.5 μm. In each via hole 25F, a via 26F, made of the same material (tungsten) as the lower electrode 6F, is formed without any gaps. A lower end 30F of each via 26F is thereby connected to the electrode pad 12F and an upper surface 27F of the via 26F is exposed inside the pad opening 14F.

Also, a sacrificial layer residue 28F that surrounds the pad opening 14F is also formed between the interlayer insulating film 10F and the interlayer insulating film 2 below it. The sacrificial layer residue 28F is exposed inside the pad opening 14F along an entire periphery of side surfaces of the pad opening 14F. Also, the sacrificial layer residue 28F is made of the same material (tungsten) as the lower electrode 6F.

On the interlayer insulating film 10F, an upper wiring 15F is formed so as to cover entire peripheries of peripheral edge portions of the photoabsorption layer 7F and the transparent conductive film 9F. The upper wiring 15F is made of aluminum (Al). An extending portion 16F, extending toward the pad forming region 46F, is formed integral to the upper wiring 15F. An end portion of the extending portion 16F enters inside the pad opening 14F and is connected to all of the vias 26F inside the pad opening 14F.

Also, on the interlayer insulating film 10F, a conductive barrier film 29F, made of Ti/TiN (a laminated structure of titanium (upper layer) and titanium nitride (lower layer)) is formed so as to cover entire peripheries of peripheral edge portions of the photoabsorption layer 7F and the transparent conductive film 9F. The conductive barrier film 29F is interposed between the upper wiring 15F and the upper surfaces 27F of the vias 26F inside the pad opening 14F and is interposed between the upper wiring 15F and the interlayer insulating film 10F outside the pad opening 14F.

Also, a top surface protective film 17F is formed on a topmost surface of the image sensor 1F. The top surface protective film 17F is made, for example, of silicon nitride. In the top surface protective film 17F, an opening 18F for exposing the portion of the extending portion 16F of the upper wiring 15F that enters into the pad opening 14F is formed at a position opposing the pad opening 14F.

Between the uppermost interlayer insulating film 2F and the interlayer insulating film 3F below it, lower wirings 19F are formed at positions opposing the respective lower electrodes 6F. A via hole 20F is formed penetratingly through the interlayer insulating film 2F between each lower electrode 6F and the opposing lower wiring 19F in the direction in which these oppose each other (thickness direction of the interlayer insulating film 2F).

In each via hole 20F, a via 21F, made of the same material as the lower electrode 6F, is formed integral to the lower electrode 6F and without any gaps. Each lower electrode 6F is thereby electrically connected to the opposing lower wiring 19F via the via 21F. Each via hole 20F has an inner diameter of, for example, 0.4 μm.

Between the interlayer insulating film 3F and the interlayer insulating film 4F below it, capacitor upper electrodes 22F are formed at positions opposing the respective lower wirings 19F. Each lower wiring 19F and the opposing capacitor upper electrode 22F are electrically connected by a via 23F that penetrates through the interlayer insulating film 3F. The via 23F is made of tungsten.

Between the interlayer insulating film 4F and the interlayer insulating film 5F below it, a capacitor lower electrode 24F is formed to oppose all of the capacitor upper electrodes 22F together. A capacitive element (MIM capacitor) having an MIM (metal-insulator-metal) structure, in which the interlayer insulating film 4F is sandwiched as a capacitive film between the capacitor upper electrode 22F and the capacitor lower electrode 24E, is thereby formed according to each pixel. The lower electrode 6F and the capacitor upper electrode 22F of the MIM capacitor are electrically connected according to each pixel.

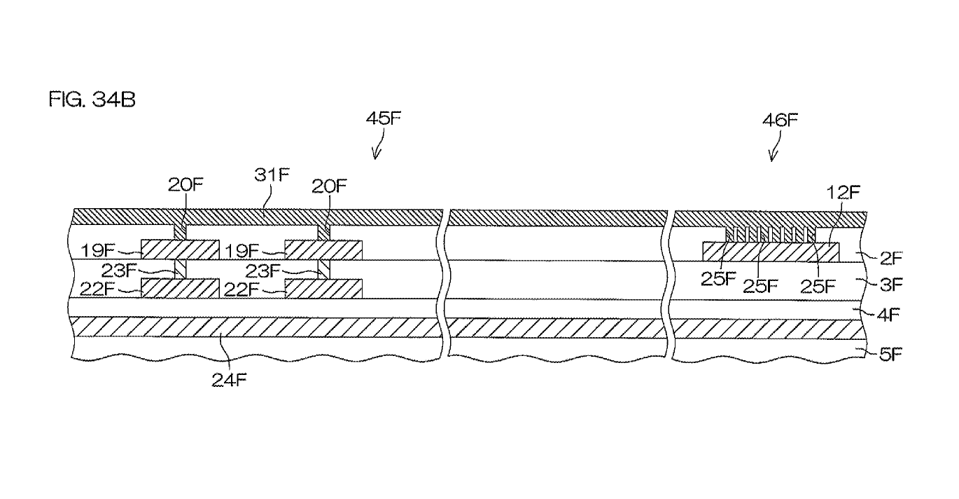

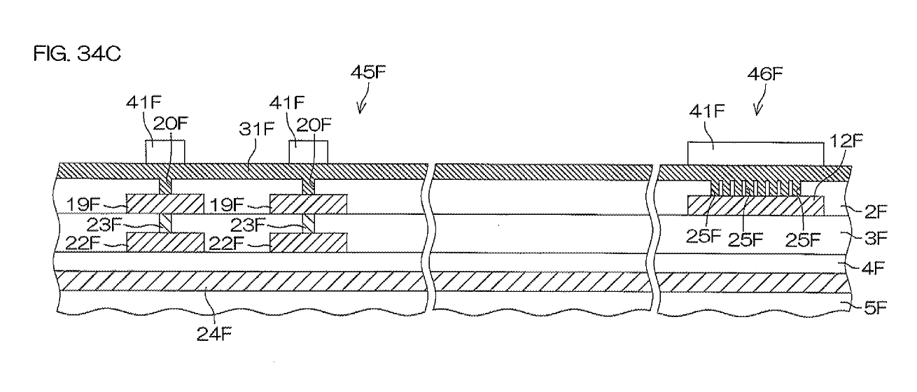

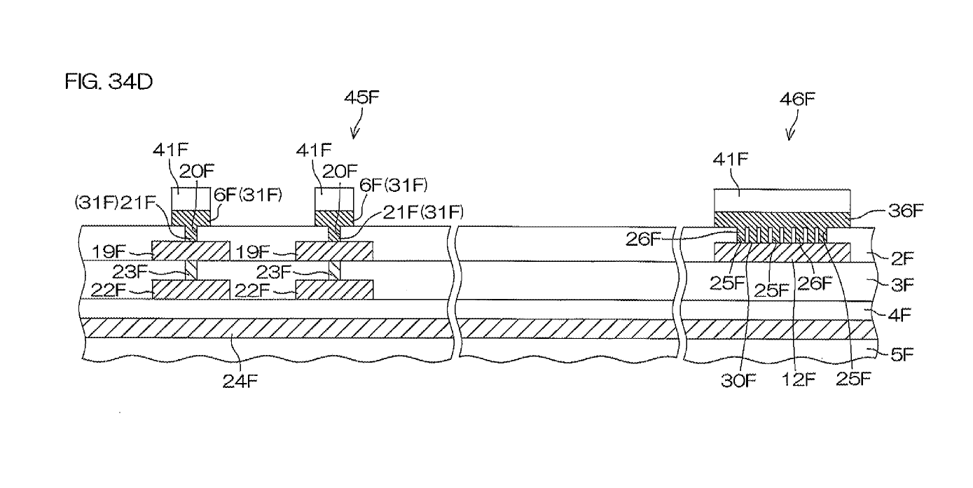

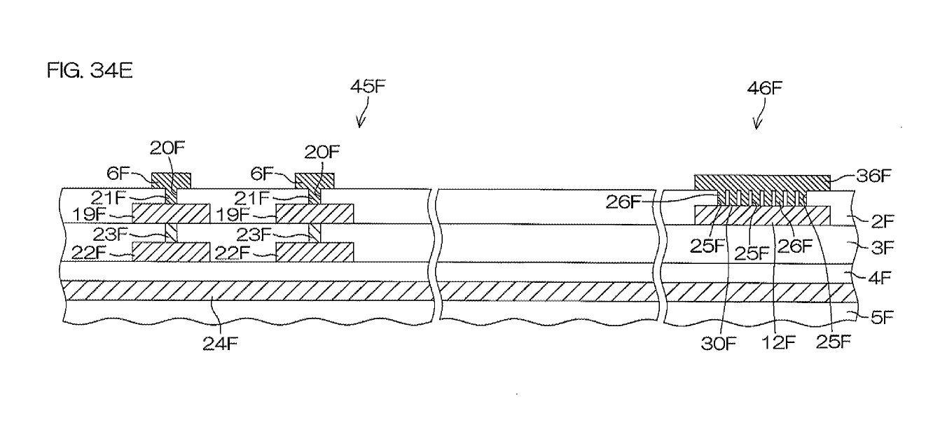

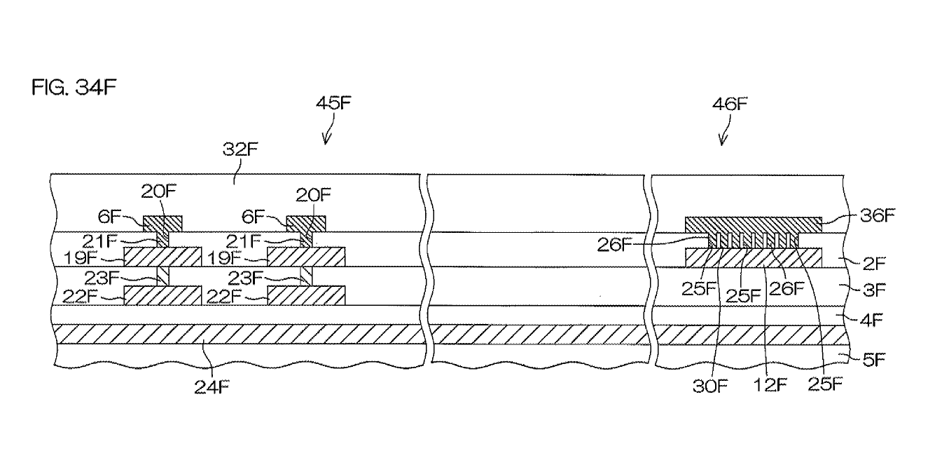

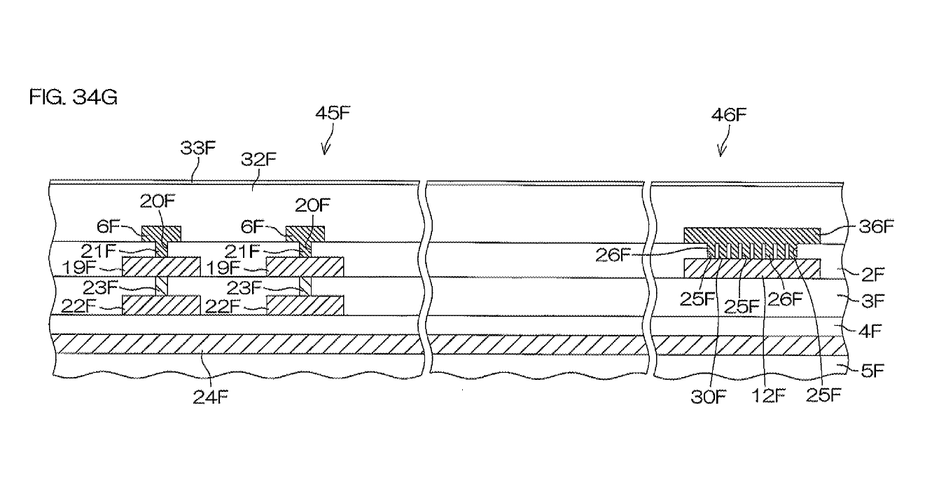

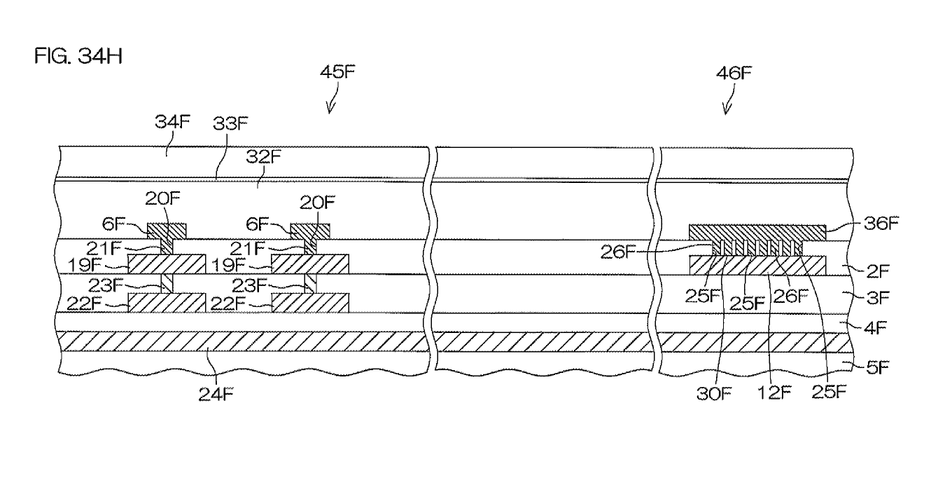

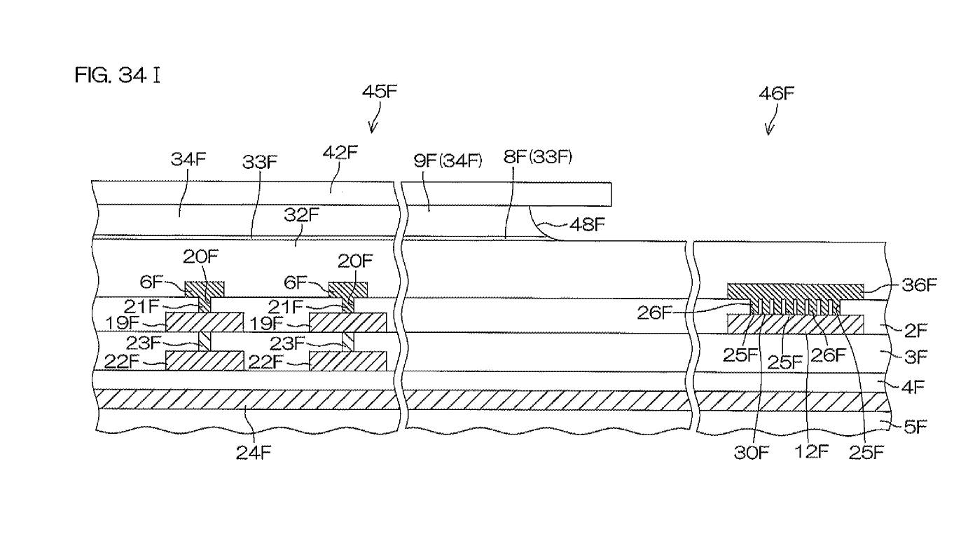

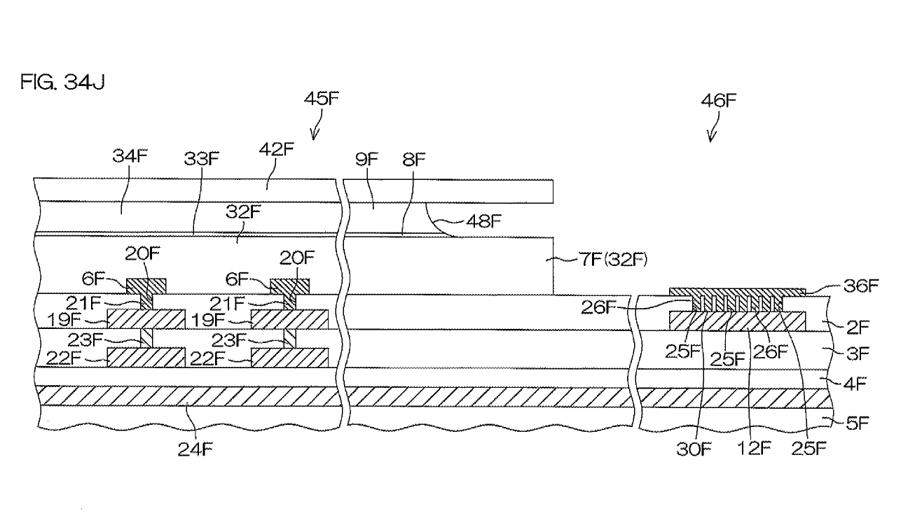

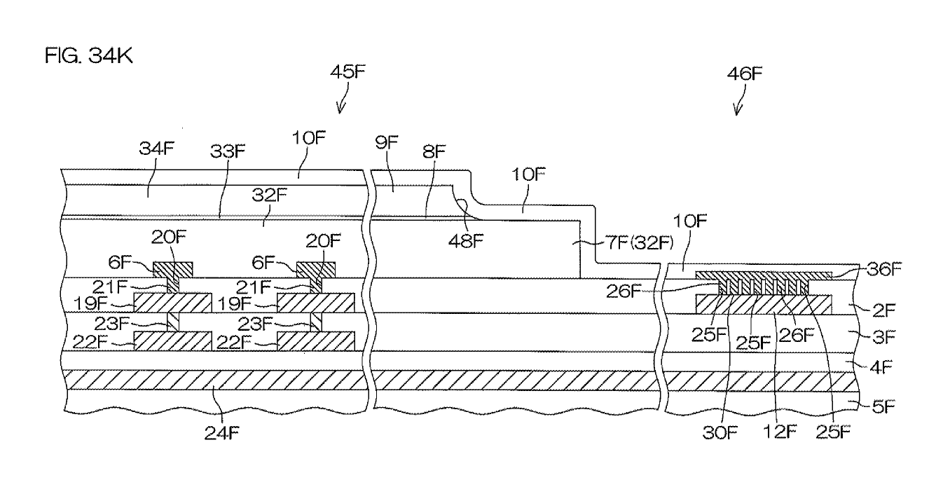

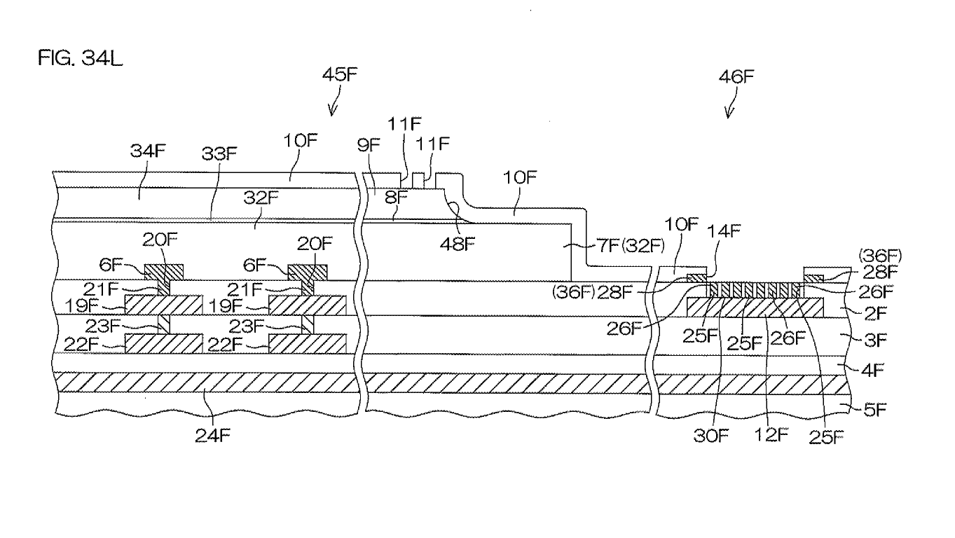

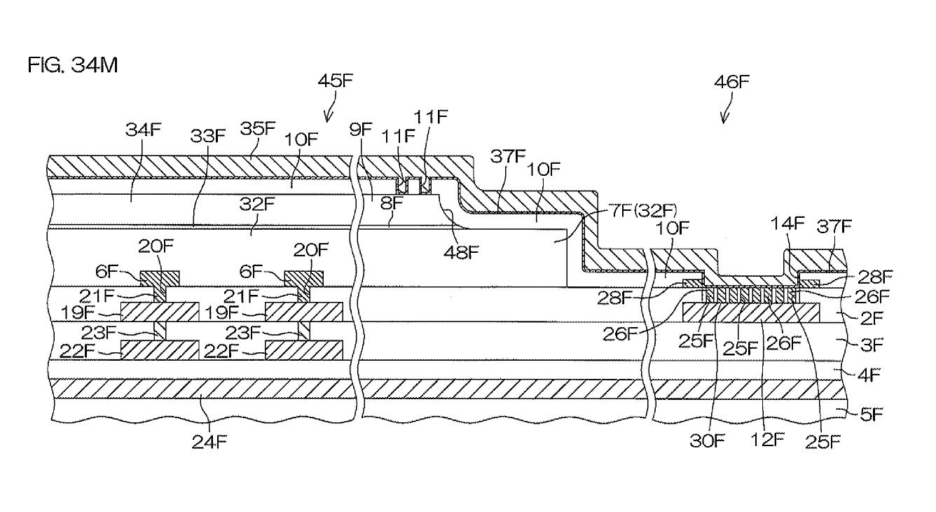

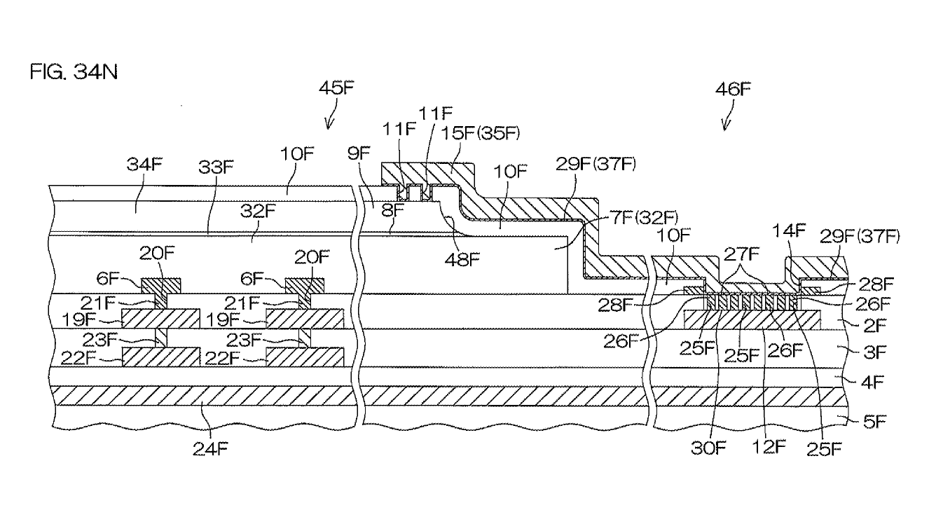

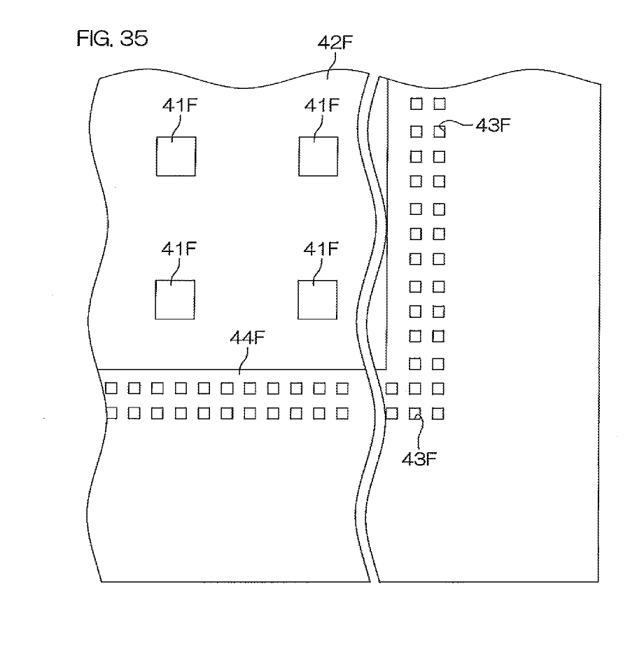

FIG. 34A to FIG. 34N are schematic sectional views that successively illustrate a manufacturing process of the image sensor shown in FIG. 33. FIG. 35 is a diagram for describing resist patterns used in the manufacturing process. In FIG. 34A to FIG. 34N, only portions made of metal materials are hatched and portions besides these are not hatched.

In the manufacturing process of the image sensor 1F, first, as shown in FIG. 34A, the interlayer insulating film 5F, the capacitor lower electrode 24F, the interlayer insulating film 4F, the capacitor upper electrodes 22F, the interlayer insulating film 3F, the vias 23F (the electrode pad 12F, the lower wirings 19F), and the interlayer insulating film 2F are formed in that order on the semiconductor substrate (not shown). The via holes 20F penetrating through the interlayer insulating film 2F are then formed above the respective lower wirings 19F and the via holes 25F penetrating through the interlayer insulating film 2F are formed above the electrode pad 12F by photolithography and etching.

Thereafter, as shown in FIG. 34B, tungsten, which is the material of the lower electrodes 6F, the vias 21F and 26F, and a sacrificial layer 36F (described below), is deposited by the CVD method inside the via holes 20F and 25F and on the interlayer insulating film 2F to form a tungsten deposition layer 31F. A thickness of the tungsten deposition layer 31F on the interlayer insulating film 2F is 0.3 to 0.4 μm (3000 to 4000 Å).

Thereafter, as shown in FIG. 34C, a resist pattern 41F (see FIG. 35; in FIG. 35, a portion covering the sacrificial layer 36F is omitted) that selectively covers only portions that become the lower electrodes 6F and the sacrificial layer 36F (described below) is formed by photolithography on the tungsten deposition layer 31F.

Then, as shown in FIG. 34D, portions of the tungsten deposition layer 31F exposed from the resist pattern 41F are removed by dry etching using the resist pattern 41F as a mask. The mixed gas of sulfur hexafluoride (SF₆) and argon (Ar) is used for the dry etching.

After the dry etching, the resist pattern 41F is removed as shown in FIG. 34E. The lower electrodes 6F, the vias 21F embedded in the via holes 20F, the sacrificial layer 36F, and the vias 26F embedded in the via holes 25F are thereby obtained.

Thereafter, as shown in FIG. 34F, a CIGS film 32F is formed by the MBE method on the interlayer insulating film 2F, the lower electrodes 6F, and the sacrificial layer 36F.

Thereafter, as shown in FIG. 34G, a cadmium sulfide film 33F is formed by the CBD method on the CIGS film 32F.

Further in succession, a zinc oxide film 34F is formed by the sputtering method on the cadmium sulfide film 33F as shown in FIG. 34H.

Then, as shown in FIG. 34I, a resist pattern 42F (see FIG. 35) is formed by photolithography on the zinc oxide film 34F. The resist pattern 42F opposes a portion of the CIGS film 32F that is to become the photoabsorption layer 7F. Then, using the resist pattern 42F as a mask, the zinc oxide film 34F and the cadmium sulfide film 33F are removed selectively by wet etching by hydrofluoric acid (HF). The wet etching is continued for a predetermined time even after the portion of the zinc oxide film 34F that does not oppose the resist pattern 42F has been removed. The zinc oxide film 34F is thereby removed from below a peripheral edge portion of the resist pattern 42F as well. Consequently, the zinc oxide film 34F and the cadmium sulfide film 33F become the transparent conductive film 9F and the high-resistance buffer layer 8F, respectively, and the curved side surface 48F of the transparent conductive film 9F is obtained.

Then, while leaving the resist pattern 42F, dry etching using the resist pattern 42F as a mask is performed to selectively remove the CIGS film 32F as shown in FIG. 34J. The CIGS film 32F is left only at the portion opposing the resist pattern 42F. The CIGS film 32F thereby becomes the photoabsorption layer 7F and the sacrificial layer 36F is exposed on the interlayer insulating film 2F. In this step, the sacrificial layer 36F is slightly etched by the etching gas during the dry etching of the CIGS film 32F and thus becomes thinner than when it was formed. For example, its thickness changes from 3000 to 4000 Å to 1000 to 2000 Å. Thereafter, the resist pattern 42F is removed.

Thereafter, as shown in FIG. 34K, the interlayer insulating film 10F is formed coveringly by the plasma CVD method on the portion of the interlayer insulating film 2F exposed from the photoabsorption layer 7F, on the sacrificial layer 36F, on the peripheral edge portion of the photoabsorption layer 7F, and on the transparent conductive film 9F.

Thereafter, a resist pattern having openings 43F (see FIG. 35) that selectively expose portions at which the via holes 11F and the pad opening 14F are to be formed is formed by photolithography on the interlayer insulating film 10F. By then performing dry etching using the resist pattern as a mask, the via holes 11F that penetrate through the interlayer insulating film 10F are formed as shown in FIG. 34L. Also, the pad opening 14F that penetrates continuously through the interlayer insulating film 10F and the sacrificial layer 36F is formed. All portions of the sacrificial layer 36F that oppose the vias 26F are thereby removed and the upper surfaces 27F of the vias 26F become exposed inside the pad opening 14F. Meanwhile, the sacrificial layer residue 28F is formed by just the portion of the sacrificial layer 36F surrounding the pad opening 14F being left.

Thereafter, as shown in FIG. 34M, a Ti/TiN film 37F is formed by the sputtering method on the interlayer insulating film 10F. The Ti/TiN film 37F is also formed inside the via holes 11F and the pad opening 14F. A bottom surface and a side surface of each via hole 11F are coated by the Ti/TiN film 37F. Thereafter, an aluminum film 35F made of aluminum is formed by the sputtering method on the Ti/TiN film 37F. The aluminum film 35F is also formed inside the via holes 11F and the pad opening 14F. The via holes 11F are completely filled with the aluminum film 35F.

Thereafter, a resist pattern 44F (see FIG. 35) that covers a portion that is to become the upper wiring 15F is formed by photolithography on the aluminum film 35F. The aluminum film 35F and the Ti/TiN film 37F are then removed selectively and continuously by dry etching using the resist pattern as a mask, and the aluminum film 35F is thereby processed to the upper wiring 15F and the Ti/TiN film 37F is processed to the conductive barrier film 29F as shown in FIG. 34N. Thereafter, the top surface protective film 17F is formed by the plasma CVD method, and when the opening 18F is formed by photolithography and etching, the image sensor 1F shown in FIG. 33 is obtained.

As described above, with the present manufacturing method, in the middle of manufacturing the image sensor 1F, the lower electrodes 6F electrically connected to the lower wirings 19F and the sacrificial layer 36F, which is electrically connected via the vias 26F to the electrode pad 12F at the same layer as the lower wirings 19F, are formed at the same time on the interlayer insulating film 2F (steps of FIG. 34A to FIG. 34E).

Thus, for example, by applying a positive voltage, on basis of a potential (substrate potential) at the lower electrodes 6F, to the sacrificial layer 36F after the step of FIG. 34E, a voltage can be applied to the electrode pad 12F via the vias 26F even in the middle of manufacture of the image sensor 1F. An isolation state of the lower electrodes 6F can thereby be measured.

That is, a voltage does not have to be applied to the upper wiring 15F to measure the isolation state of the lower electrodes 6F, and thus the isolation state of the lower electrodes 6F can be measured before completion (in the middle of manufacture) of the image sensor 1F to eliminate defective products at an early stage.

The sacrificial layer 36F that can be used for measurement is formed on the interlayer insulating film 2F and is thus exposed to the etching gas during the dry etching of the CIGS film 32F and may thereby receive damage on its top surface. It is thus difficult to connect wiring, etc., to the sacrificial layer 36F with satisfactory adhesion. Thus, if the upper wiring 15F and the electrode pad 12F are electrically connected by connecting the upper wiring 15F to the sacrificial layer 36F, adhesion of the sacrificial layer 36F and the upper wiring 15F is not strong and it is thus difficult to maintain reliability of electrical connection of the upper wiring 15F and the electrode pad 12F satisfactorily.

On the other hand, with the present manufacturing method, the sacrificial layer 36F is removed during the forming of the pad opening 14F (step of FIG. 34L), and the upper surfaces 27F of the vias 26F, the lower ends 30F of which are connected to the electrode pad 12F, are thereby exposed inside the pad opening 14F. The vias 26F are covered by the sacrificial layer 36F during the dry etching of the CIGS film 32F (step of FIG. 34J) and are thus not exposed to the etching gas. Thus, unlike the top surface of the sacrificial layer 36F after the dry etching, the upper surfaces 27F of the vias 26F that are exposed inside the pad opening 14F are maintained in satisfactory states. The upper wiring 15F can thus be connected with good adhesion to the vias 26F inside the pad opening 14F. Consequently, the reliability of electrical connection of the upper wiring 15F and the electrode pad 12F can be maintained satisfactorily.

Also, tungsten oxidizes readily and thus if a contact area of tungsten and the upper wiring 15F is large, the upper wiring 15F may separate from the tungsten due to vibration generated during wire bonding onto the upper wiring 15F.

However, with the image sensor 1F, the upper wiring 15F is connected not to an electrode or other conductive member of comparatively large area but to vias 26F of comparatively small area. The contact area of tungsten and the upper wiring 15F is thus small. Separation of the upper wiring 15F can thus be suppressed even if vibration is generated during wire bonding. Further, the plurality of vias 26F are disposed in a matrix inside the pad opening 14F and thus the vias 26F can be put in uniform contact with the upper wiring 15F. Adhesion of the upper wiring 15F and the vias 26F can thus be improved.

Also, with the image sensor 1F, the plurality of mutually-spaced lower electrodes 6F disposed on the interlayer insulating film 2F are covered all together by the photoabsorption layer 7F made of CIGS. That is, the photoabsorption layer 7F is not cut and divided according to each pixel, and thus as in the preferred embodiment according to the first aspect of the present invention, there is no variation of sensitivity among pixels.

Also, as in the preferred embodiment according to the first aspect of the present invention, the pixel aperture ratio (pn junction area/pixel area) can be made 100% because the photoabsorption layer 7F is not cut and divided according to each pixel. A large number of carriers can thereby be generated even with weak light and dramatic improvement of sensitivity can be achieved.

Further, a shrinkage cavity does not form during forming of the transparent conductive film 9F because grooves for cutting and dividing the photoabsorption layer 7F are not formed. Degradation with time of the transparent conductive film 9F can thus be prevented and reliability can be improved.

Also, a step of forming an isolation film is unnecessary and the manufacturing process is thus simpler than that of the conventional photoelectric converter and time and cost required for manufacture can be reduced.

Also, in the manufacturing process of the image sensor 1F, the resist pattern 42F used in the wet etching for processing the zinc oxide film 34F to the transparent conductive film 9F is also used in the dry etching for processing the CIGS film 32F to the photoabsorption layer 7F and a mask (resist pattern) used exclusively for the dry etching is not formed. The manufacturing process of the image sensor 1F can thus be simplified.

Also, as shown in FIG. 34F to FIG. 34H, the CIGS film 32F, the cadmium sulfide film 33F, and the zinc oxide film 34F are formed consecutively. The time from the forming of the CIGS film 32F to the completion of forming of the zinc oxide film 34F can thus be made short, and the CIGS film 32F, the cadmium sulfide film 33F, and the zinc oxide film 34F can be respectively improved in film quality.

Further, the pad opening 14F and the via holes 11F are formed in the same step (step shown in FIG. 34L) and thus in comparison to a case where these are formed in separate steps, the number of masks required for forming these can be reduced and the manufacturing process of the image sensor 1F can be simplified.

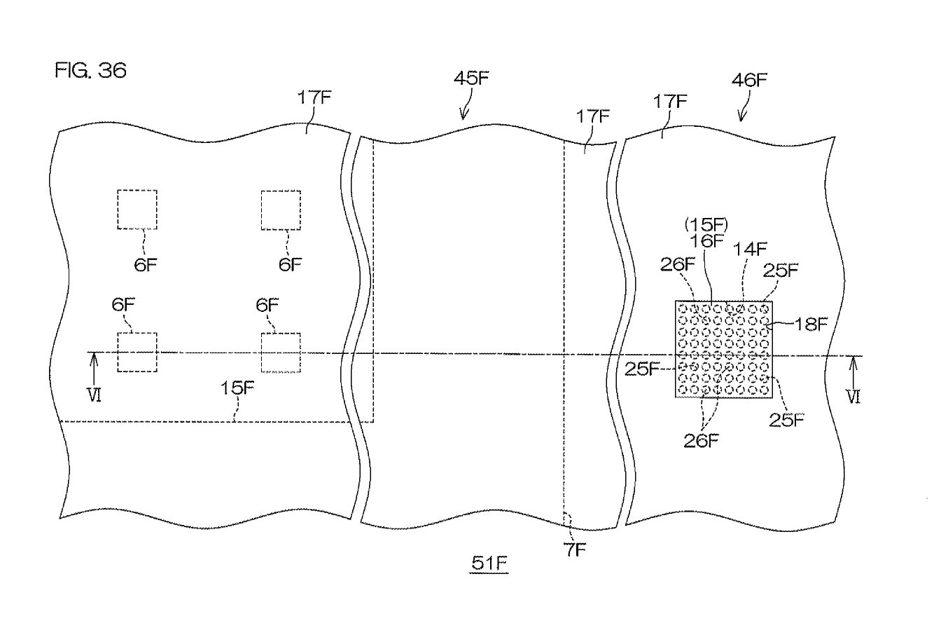

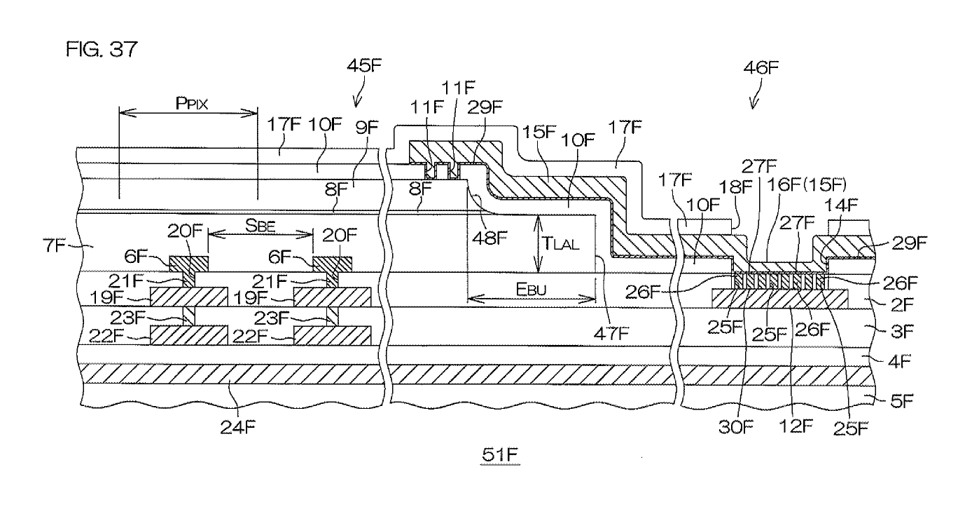

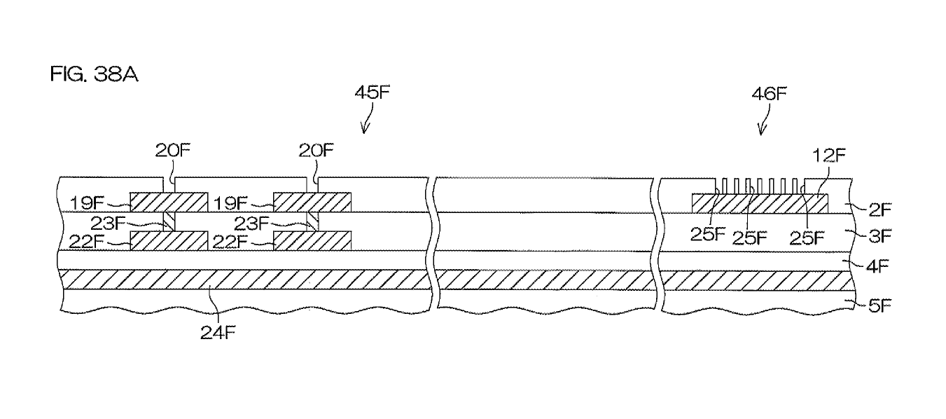

FIG. 36 is a schematic plan view of an image sensor according to a second preferred embodiment of the sixth aspect of the present invention. FIG. 37 is a schematic sectional view of the image sensor taken along sectioning line II-II in FIG. 36. In FIG. 36 and FIG. 37, portions corresponding to respective portions shown in FIG. 32 and FIG. 33 are provided with the same reference symbols. Also, in the following description, detailed description of the portions provided with the same reference symbols shall be omitted.

Although in the first preferred embodiment, the sacrificial layer residue 28F that surrounds the pad opening 14F is formed between the interlayer insulating film 10F and the interlayer insulating film 2F below it, in the image sensor 51F according to the second preferred embodiment, the sacrificial layer residue 28F is not formed and the entirety of the side surfaces of the pad opening 14F is formed by the interlayer insulating film 10F. Besides this, the arrangement is the same as that of the first preferred embodiment.

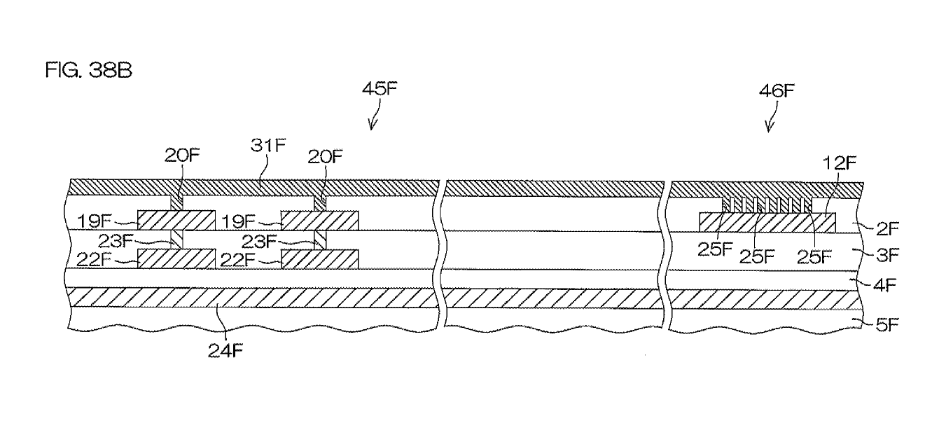

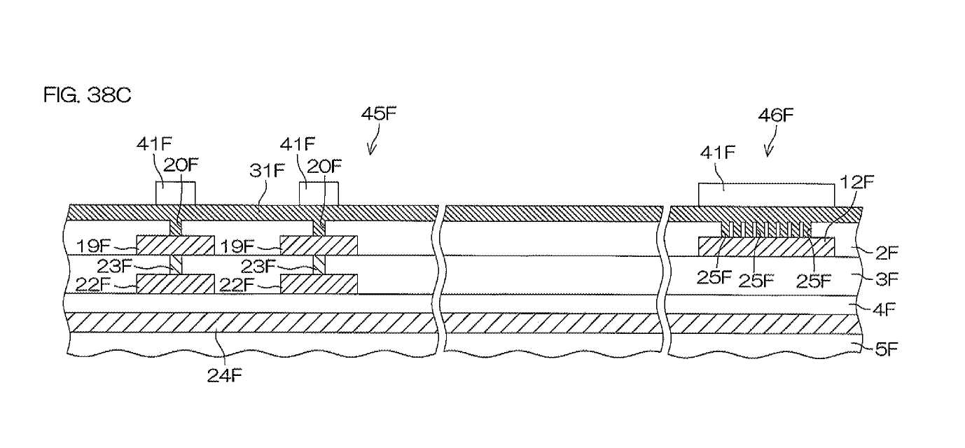

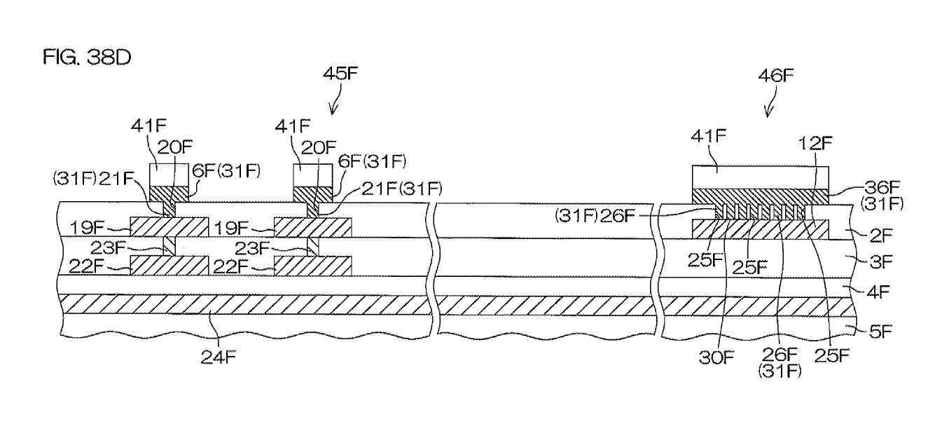

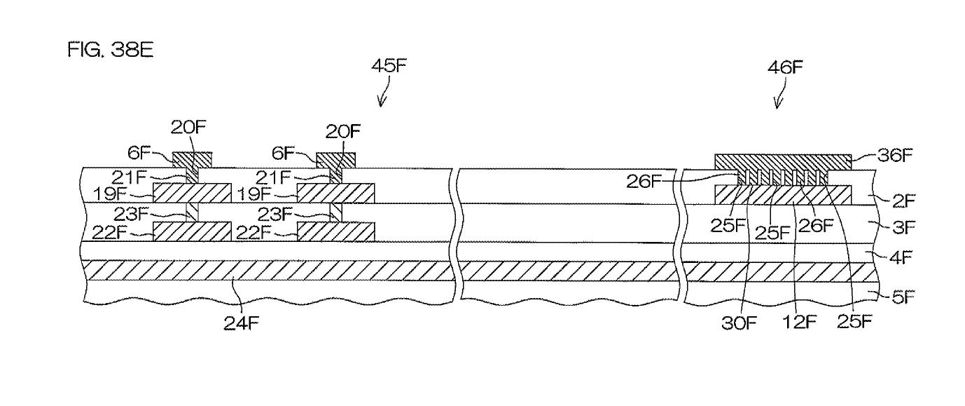

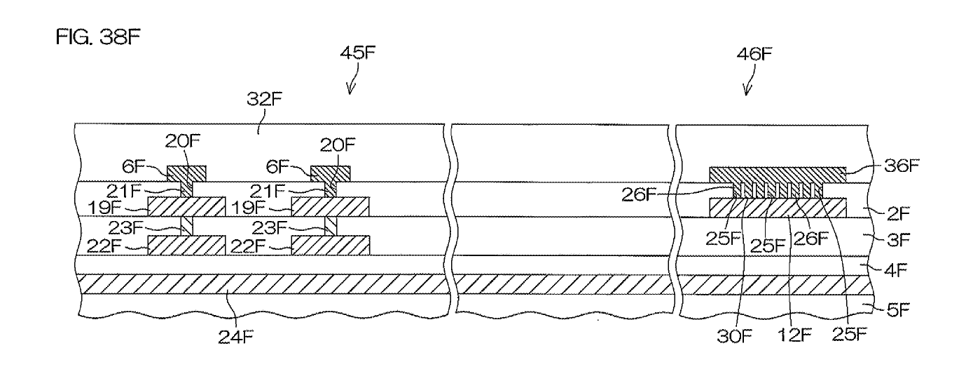

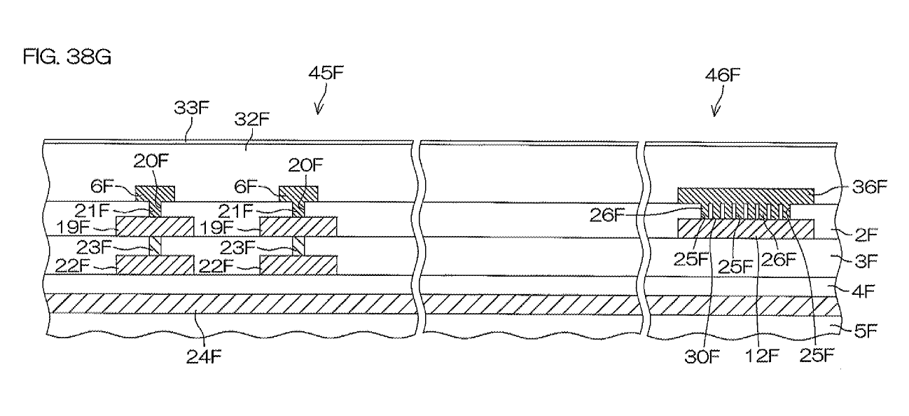

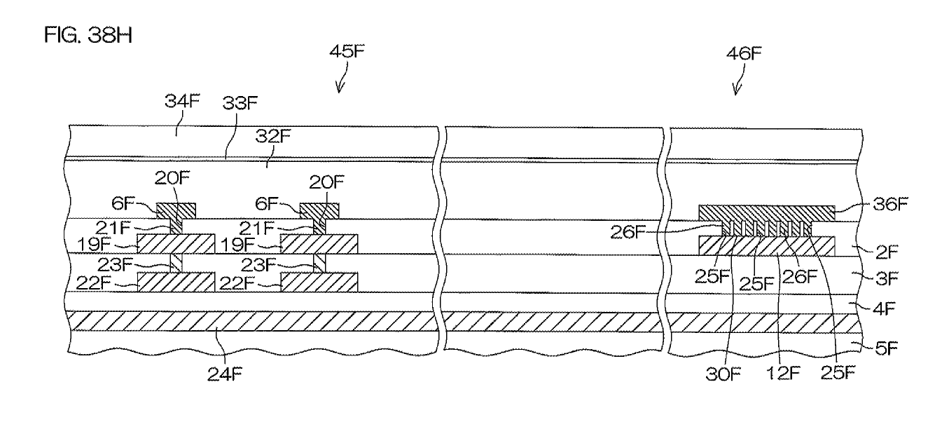

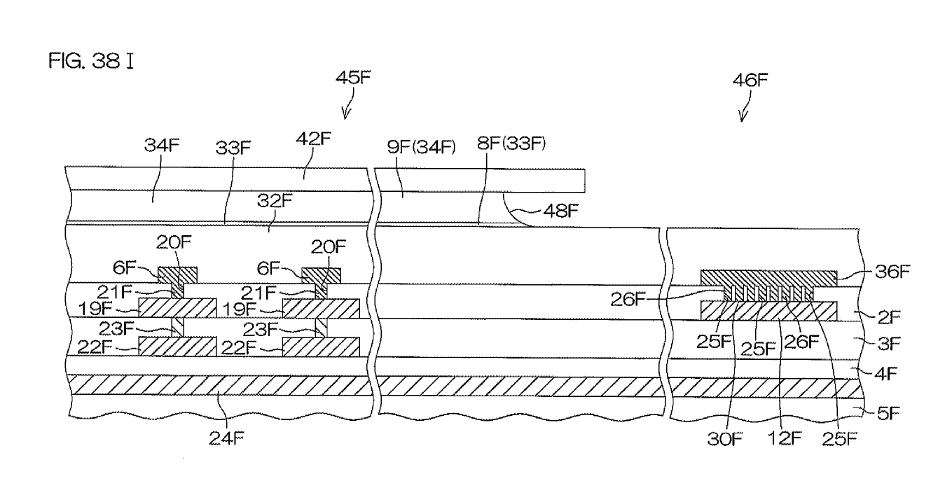

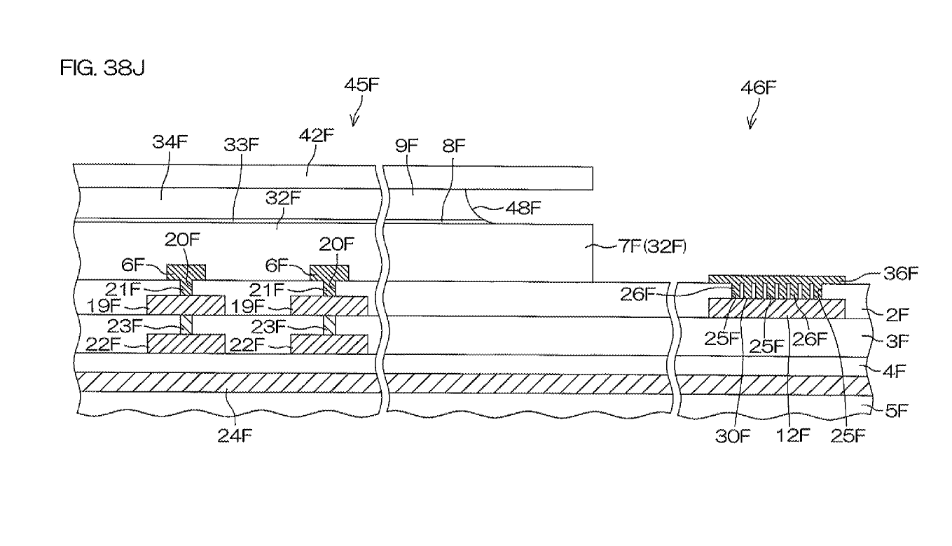

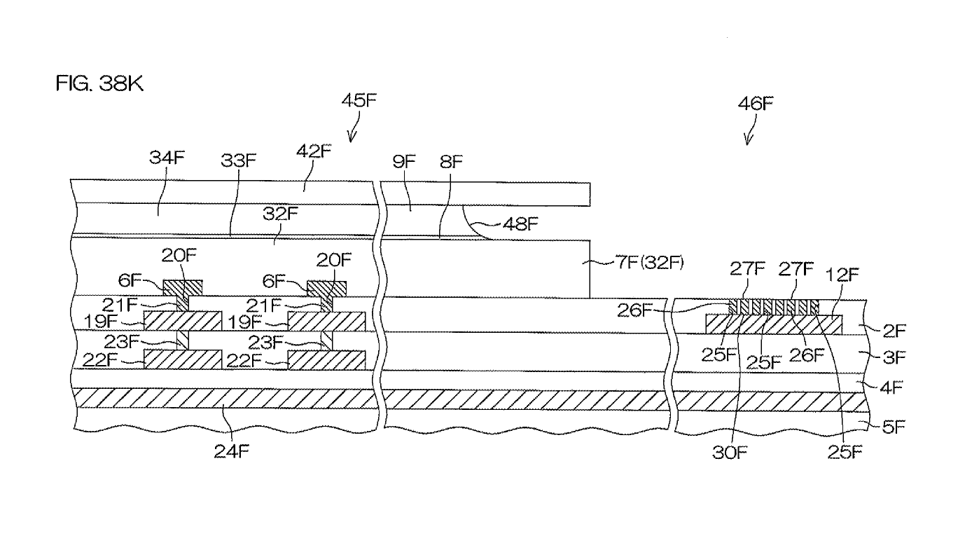

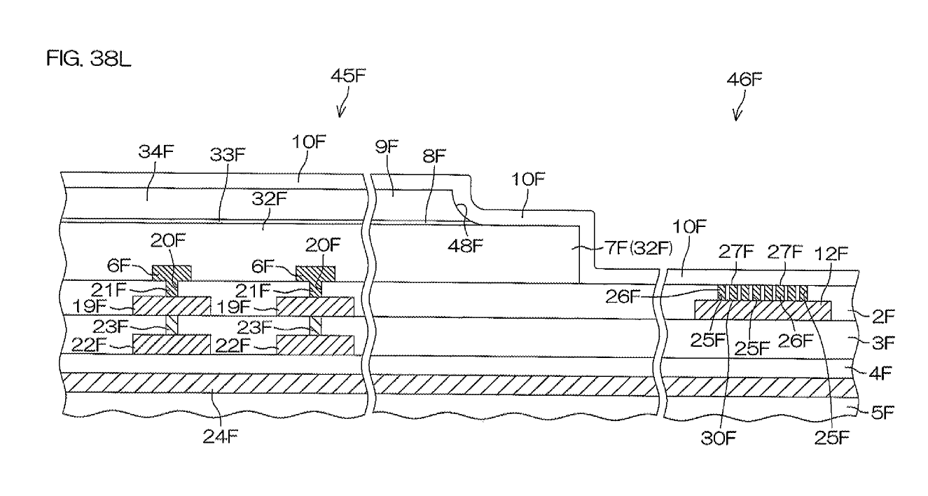

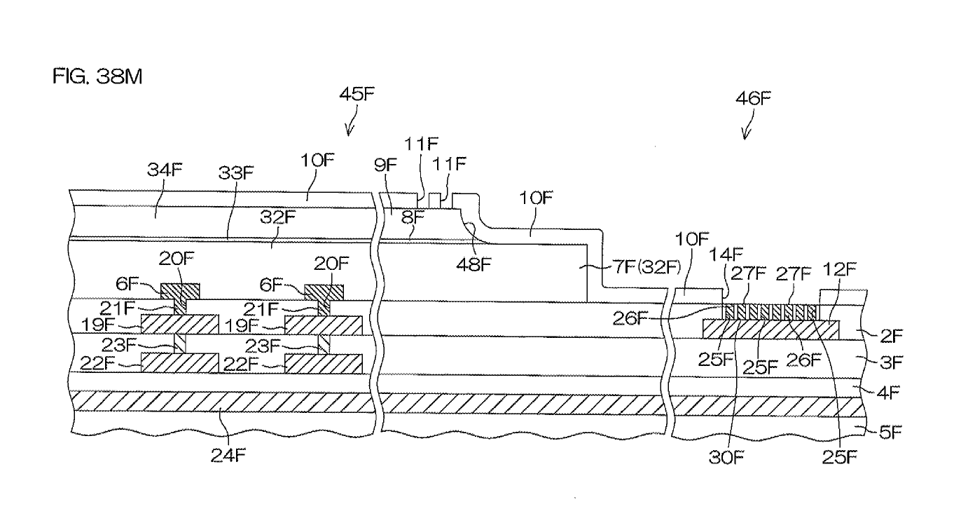

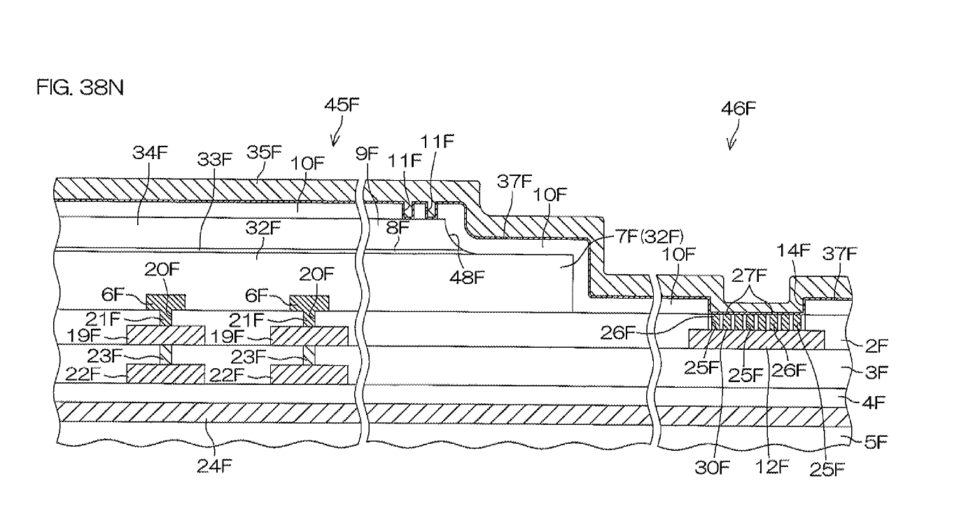

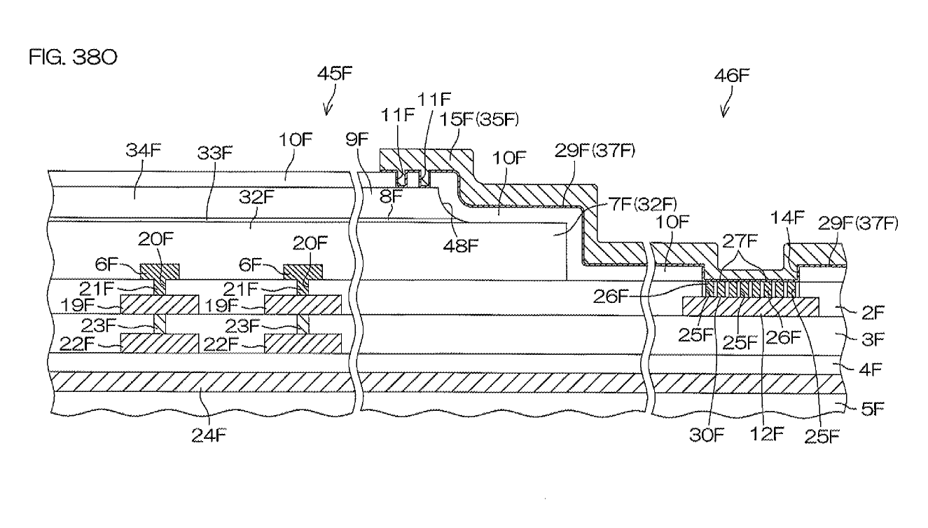

FIG. 38A to FIG. 38O are schematic sectional views that successively illustrate a manufacturing process of the image sensor shown in FIG. 37.

As shown in FIG. 38A to FIG. 38J, in the manufacturing process of the image sensor 51F, the lower electrodes 6F, the transparent conductive film 9F, the high-resistance buffer layer 8F, and the photoabsorption layer 7F are formed in that order on the interlayer insulation layer 2F in the sensor forming region 45F by the same steps as those of FIG. 34A to FIG. 34J being executed in the same order. Meanwhile, in the pad forming region 46F, the vias 26F and the sacrificial layer 36F are formed at the same time, and by the forming of the photoabsorption layer 7F (dry etching), the sacrificial layer 36F becomes exposed on the interlayer insulating film 2F.

After the forming of the photoabsorption layer 7F, the resist pattern 42F is left as it is and all of the sacrificial layer 36F is removed as shown in FIG. 38K by dry etching using the resist pattern 42F as a mask. The mixed gas of sulfur hexafluoride (SF₆) and argon (Ar) is used for the dry etching. The upper surfaces 27F of the vias 26F thereby become exposed on the top surface of the interlayer insulating film 2F.

Thereafter, as shown in FIG. 38L to FIG. 38O, the interlayer insulating film 10F, the via holes 11F plus the pad opening 14F, the upper wiring 15F, and the conductive barrier film 29F are formed in that order by the same steps as those of FIG. 34K to FIG. 34N being executed in the same order. After the forming of the conductive barrier film 29F, the top surface protective film 17F is formed by the plasma CVD method, and when the opening 18F is formed by photolithography and etching, the image sensor 51F shown in FIG. 37 is obtained.

Description of actions and effects of the image sensor 51F according to the second preferred embodiment shall be omitted because the actions and effects of the image sensor 51F are the same as the actions and effects of the image sensor 1F (first preferred embodiment).

Although the preferred embodiments of the sixth aspect of the present invention have been described above, the present preferred embodiments may also be changed as follows.

For example, the number and shape of the vias 26F (via holes 25F) in the image sensor 1F may be changed as suited as long as the upper wiring 15F is electrically connected to the electrode pad 12F via the vias 26F.

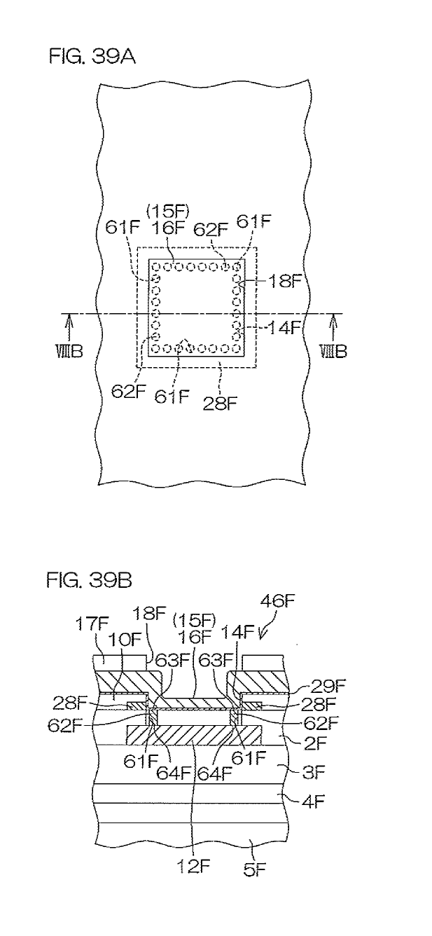

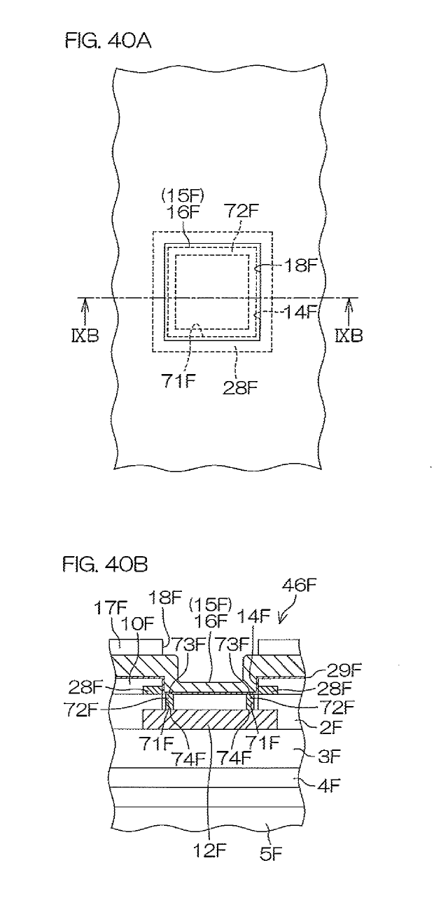

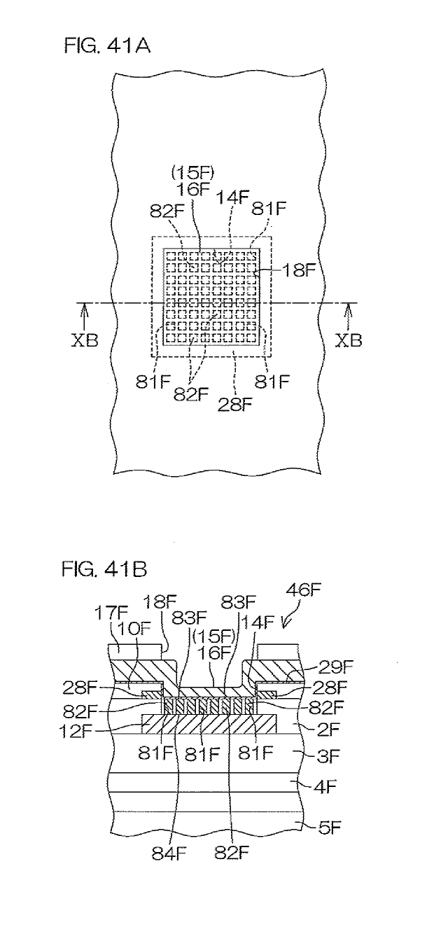

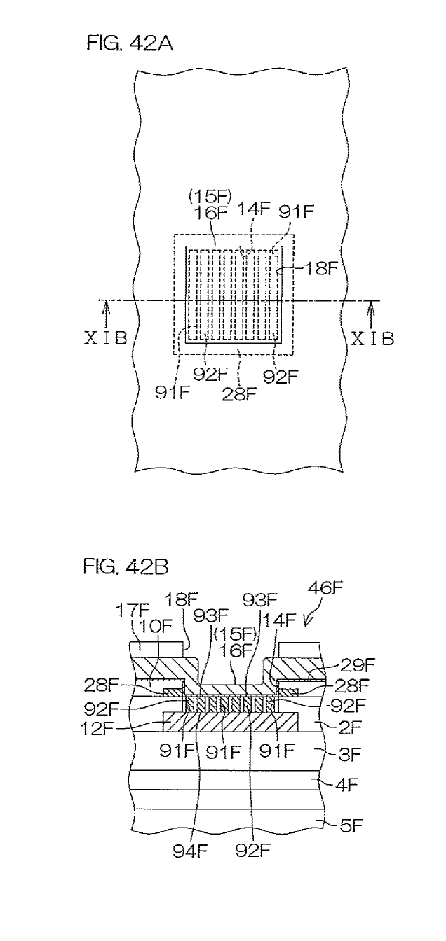

Via holes 61F and vias 62F shown in FIG. 39A and FIG. 39B, via hole 71F and via 72F shown in FIG. 40A and FIG. 40B, via holes 81F and vias 82F shown in FIG. 41A and FIG. 41B, and via holes 91F and vias 92F shown in FIG. 42A and FIG. 42B can be given as specific examples of modifications of the via holes 25F and the vias 26F.

In FIG. 39A and FIG. 39B, the plurality of via holes 61F are formed in the interlayer insulating film 2F between the electrode pad 12F and the opposing pad opening 14F. The plurality of via holes 61F are mutually spaced at equal intervals in a rectangular annular form in a plan view along peripheral edges of the pad opening 14F. Each via hole 61F is formed to a circular shape in a plan view. Also, each via hole 61F has an inner diameter, for example, of no more than 0.5 μm. In each via hole 61F, the via 62F, made of the same material (tungsten) as the lower electrodes 6F, is formed without any gaps. A lower end 64F of each via 62F is thereby connected to the electrode pad 12F and an upper surface 63F of the via 62F is exposed inside the pad opening 14F.

In FIG. 40A and FIG. 40B, a via hole 71F is formed in the interlayer insulating film 2F between the electrode pad 12F and the opposing pad opening 14F. The via hole 71F has a rectangular annular shape in a plan view and just one via hole 71F is disposed in a manner such that respective sides thereof are parallel to respective edges of the pad opening 14F. In the via hole 71F, the via 72F, made of the same material (tungsten) as the lower electrodes 6F, is formed without any gaps. A lower end 74F of the via 72F is thereby connected to the electrode pad 12F and an upper surface 73F of the via 72F is exposed inside the pad opening 14F.

In FIG. 41A and FIG. 41B, the plurality of via holes 81F are formed in the interlayer insulating film 2F between the electrode pad 12F and the opposing pad opening 14F. The plurality of via holes 81F are disposed in a matrix inside the pad opening 14F. Each via hole 81F is formed to a square shape in a plan view. Also, an inner diameter (length of each side) of each via hole 81F is, for example, of no more than 0.5 μm. In each via hole 81F, the via 82F, made of the same material (tungsten) as the lower electrodes 6F, is formed without any gaps. A lower end 84F of each via 82F is thereby connected to the electrode pad 12F and an upper surface 83F of the via 82F is exposed inside the pad opening 14F.

In FIG. 42A and FIG. 42B, the plurality of via holes 91F are formed in the interlayer insulating film 2F between the electrode pad 12F and the opposing pad opening 14F. The plurality of via holes 91F are formed in rectilinear forms in a plan view that are mutually spaced at equal intervals in parallel to one edge of the pad opening 14F. Each via hole 91F has a width, for example, of no more than 0.5 μm. In each via hole 91F, the via 92F, made of the same material (tungsten) as the lower electrodes 6F, is formed without any gaps. A lower end 94F of each via 92F is thereby connected to the electrode pad 12F and an upper surface 93F of the via 92F is exposed inside the pad opening 14F.

Also, the photoabsorption layer 7F does not have to be formed to cover all of the lower electrodes 6F together and may instead be formed in plurality to cover the respective lower electrodes 6F individually.

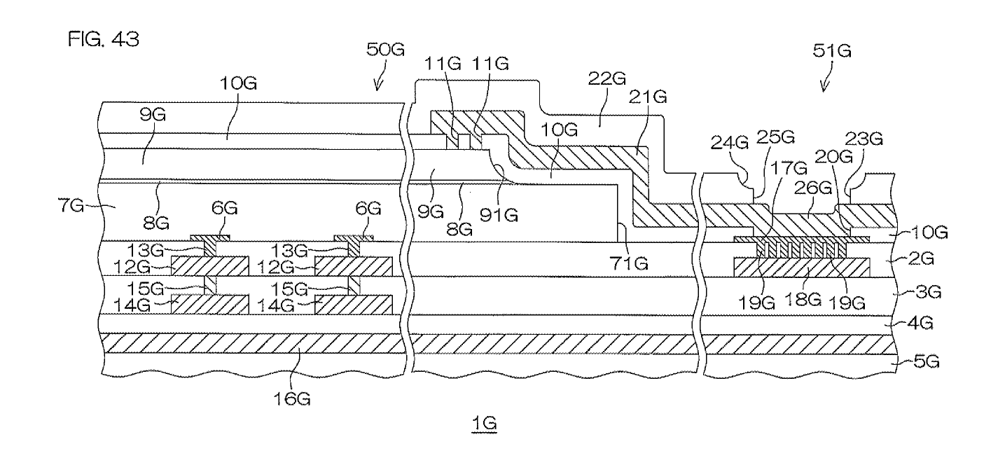

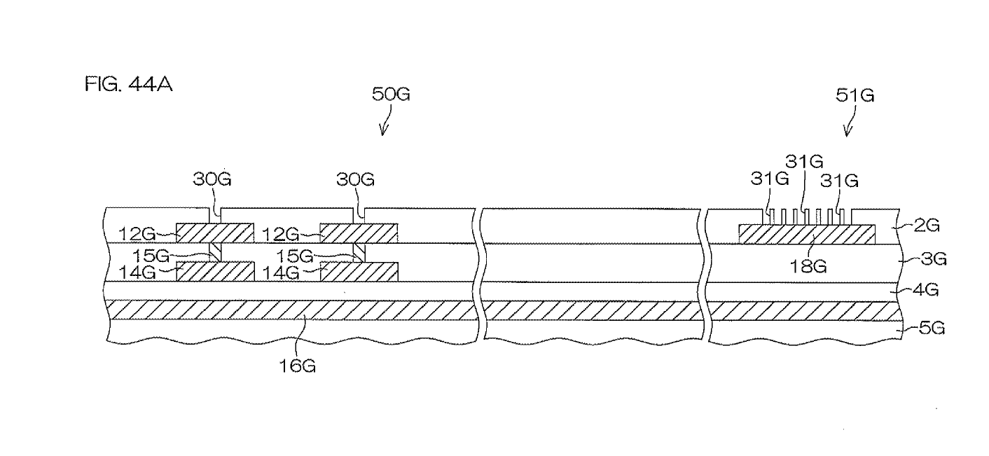

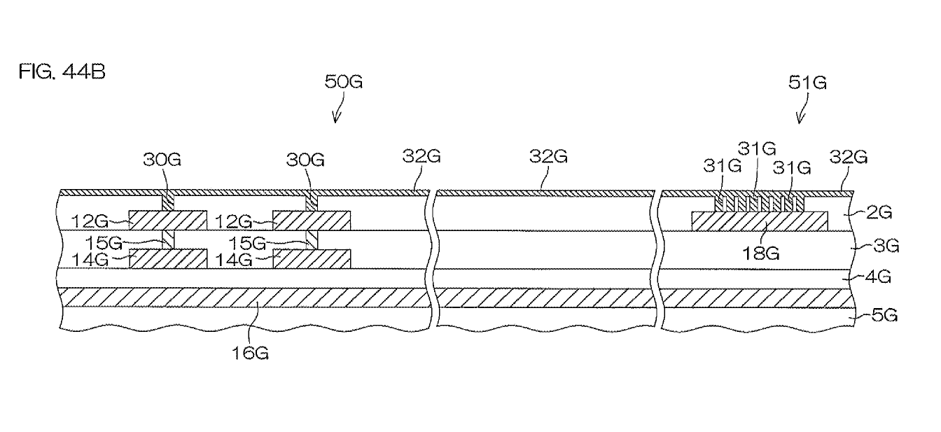

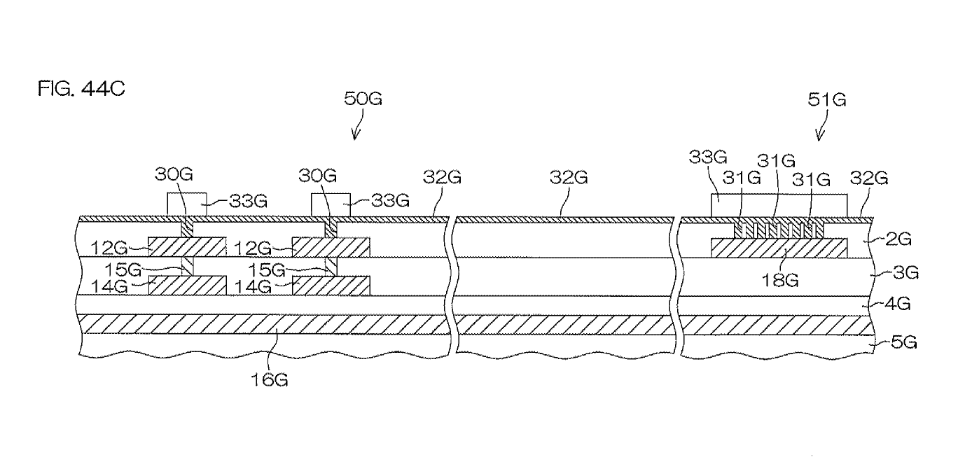

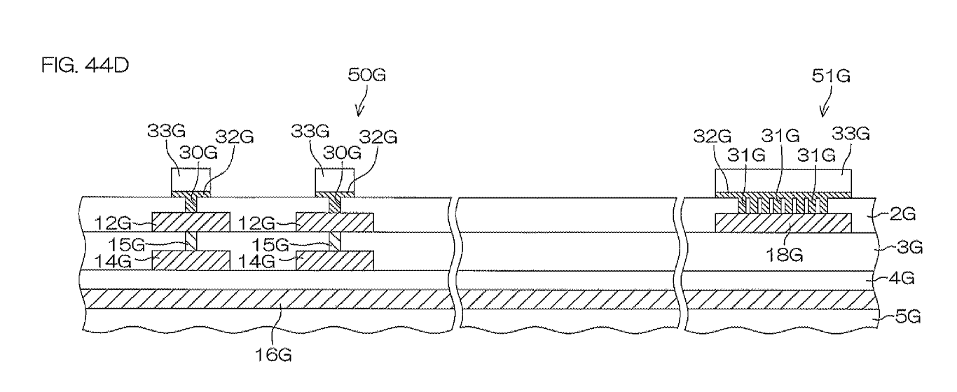

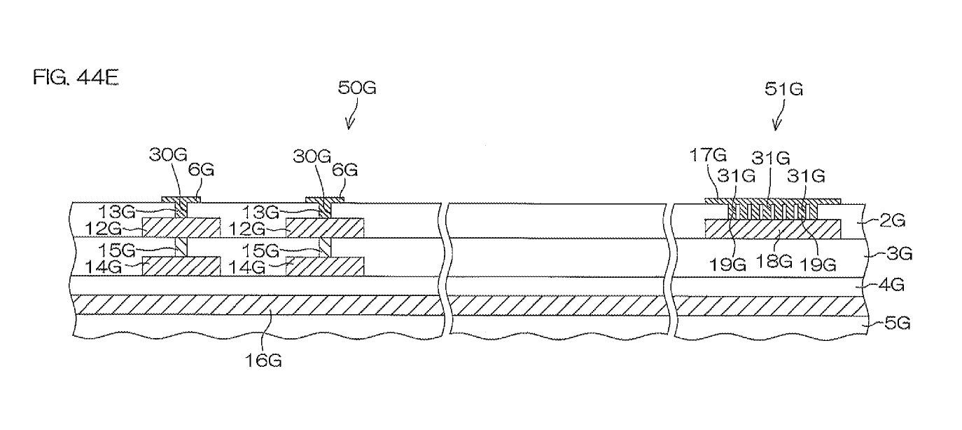

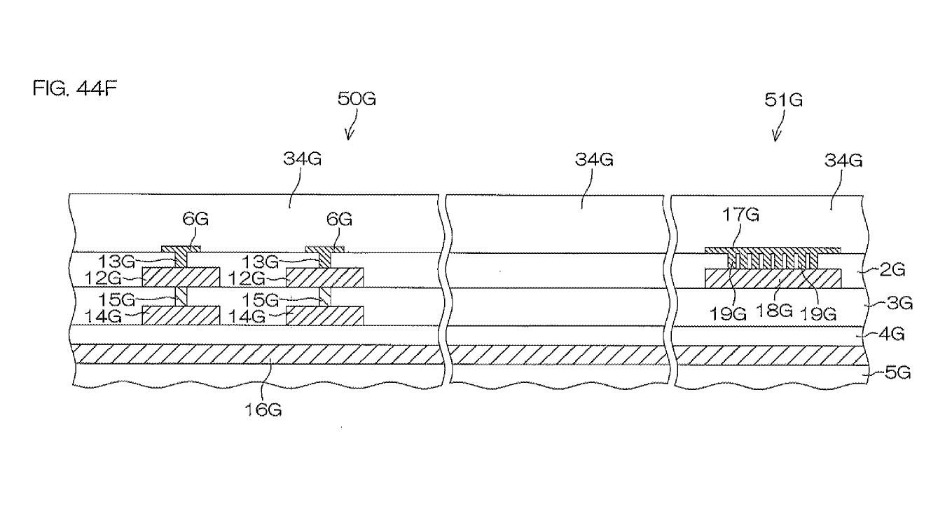

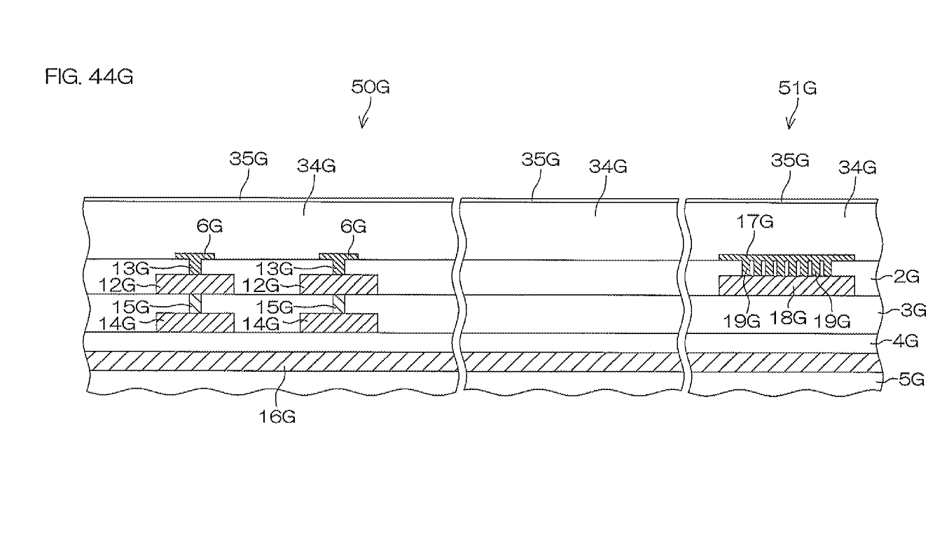

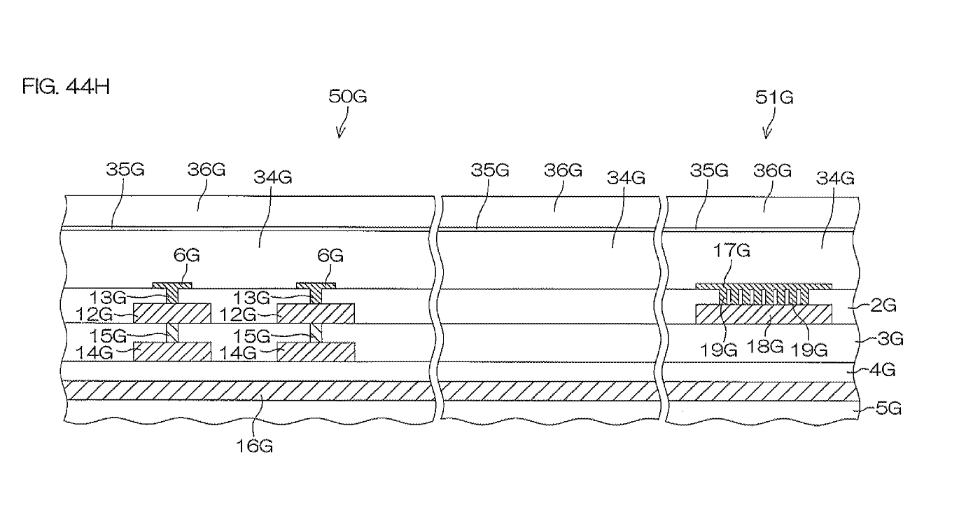

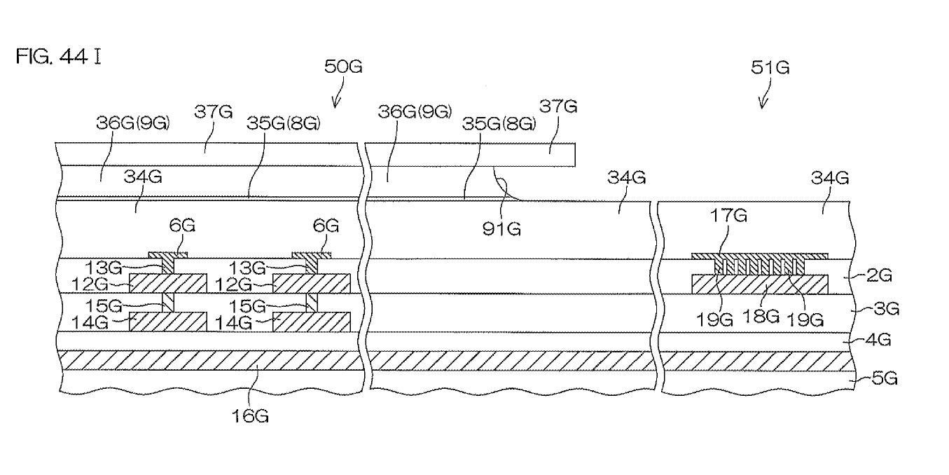

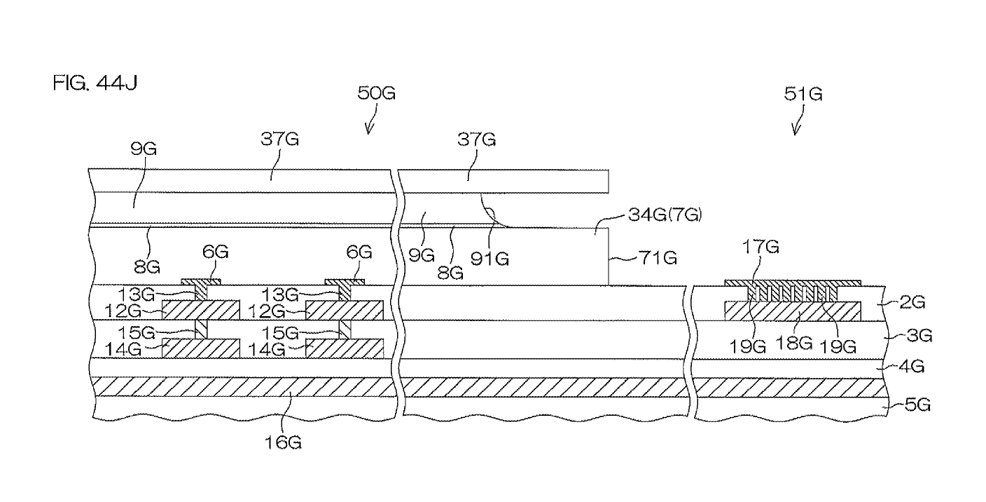

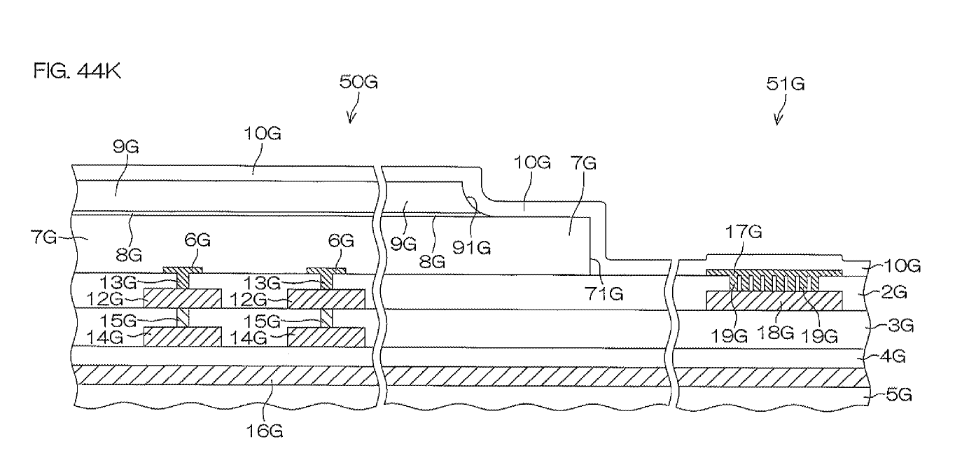

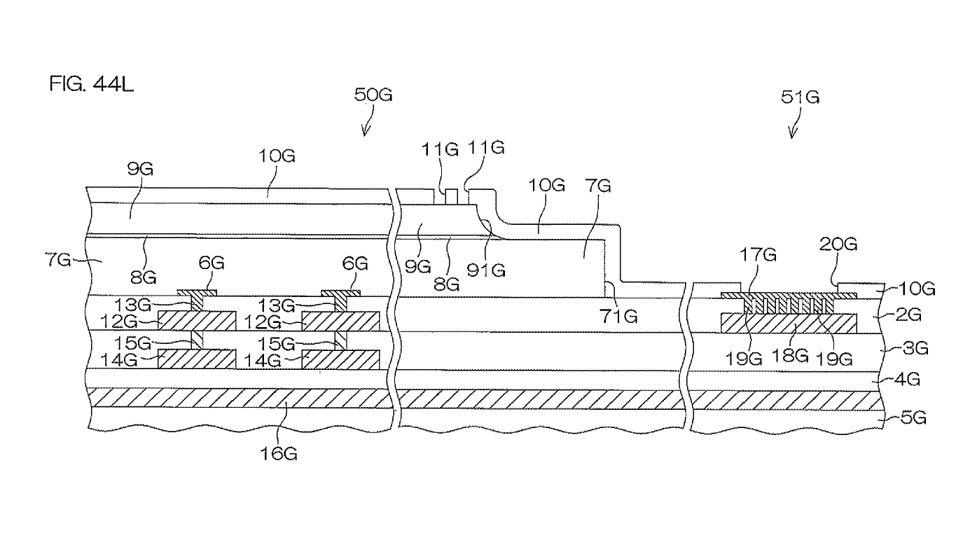

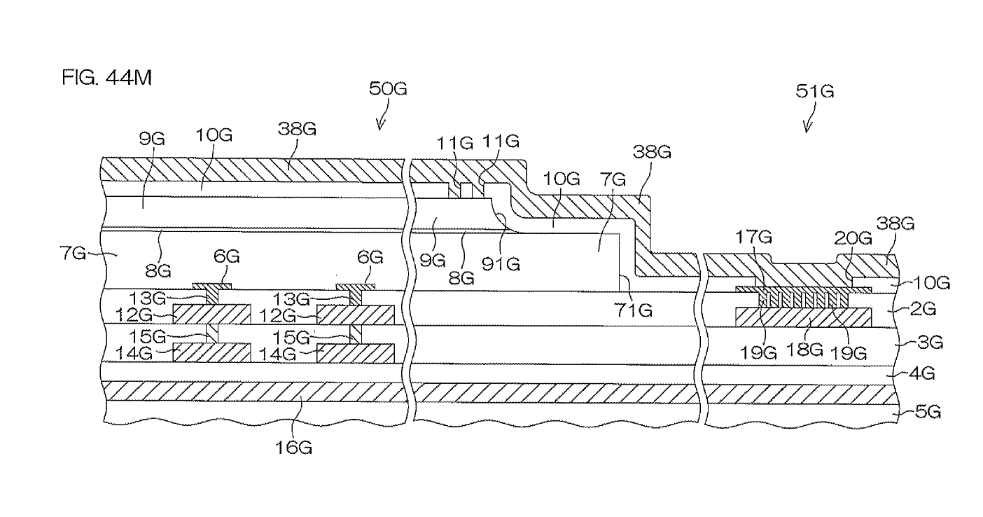

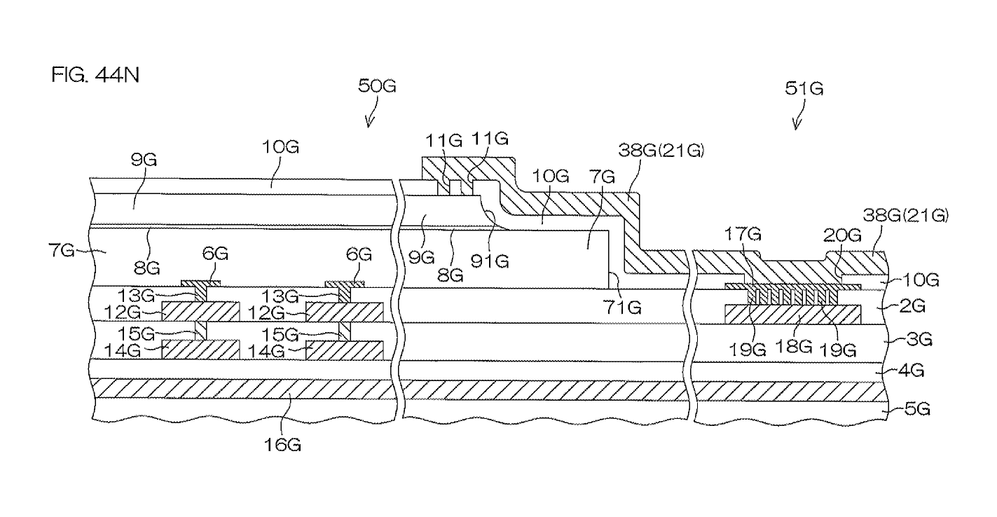

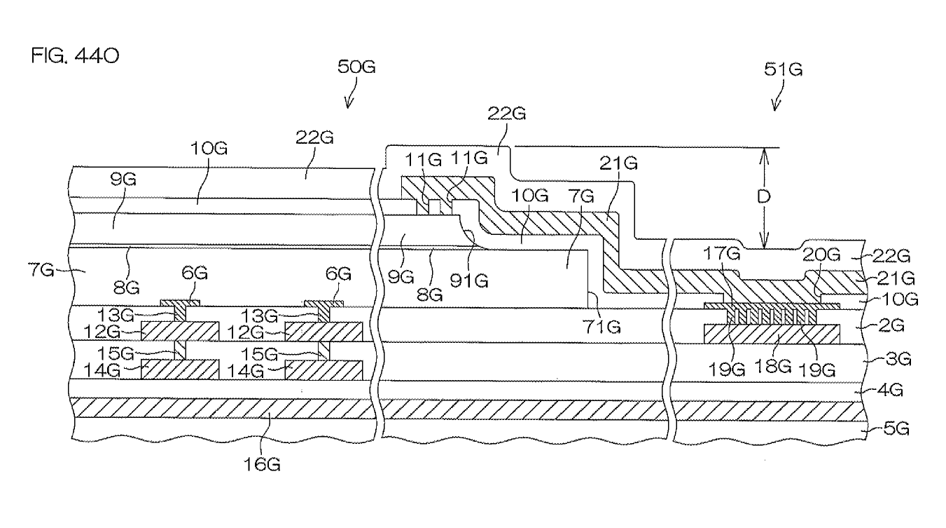

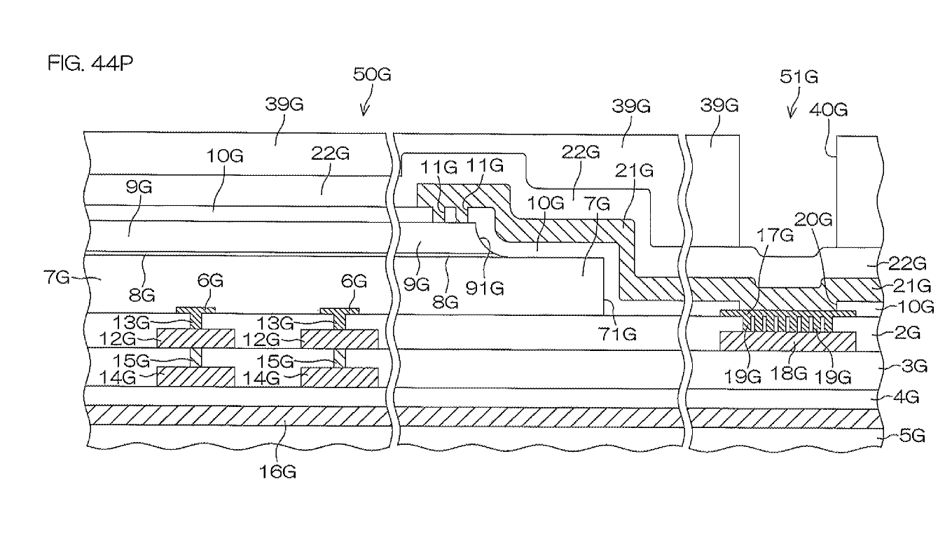

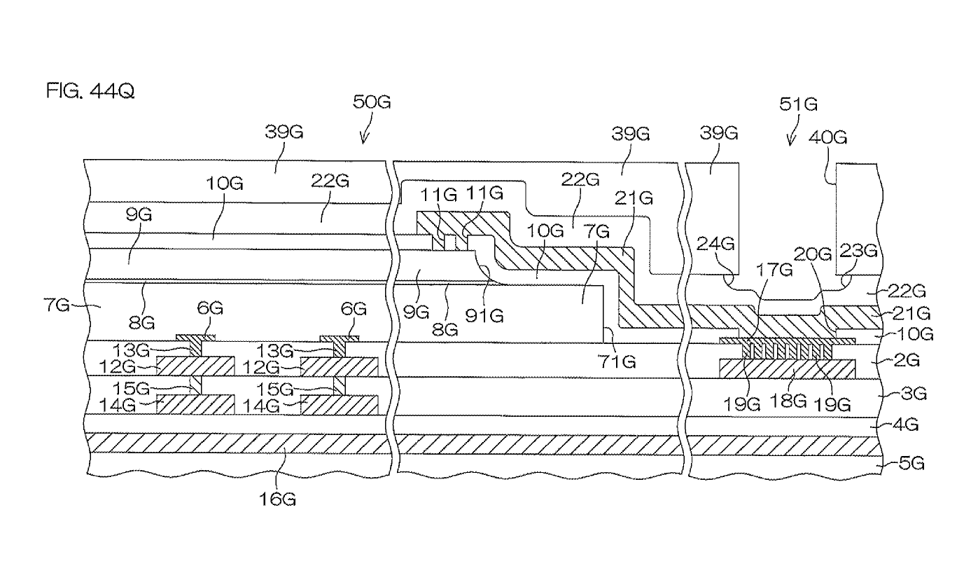

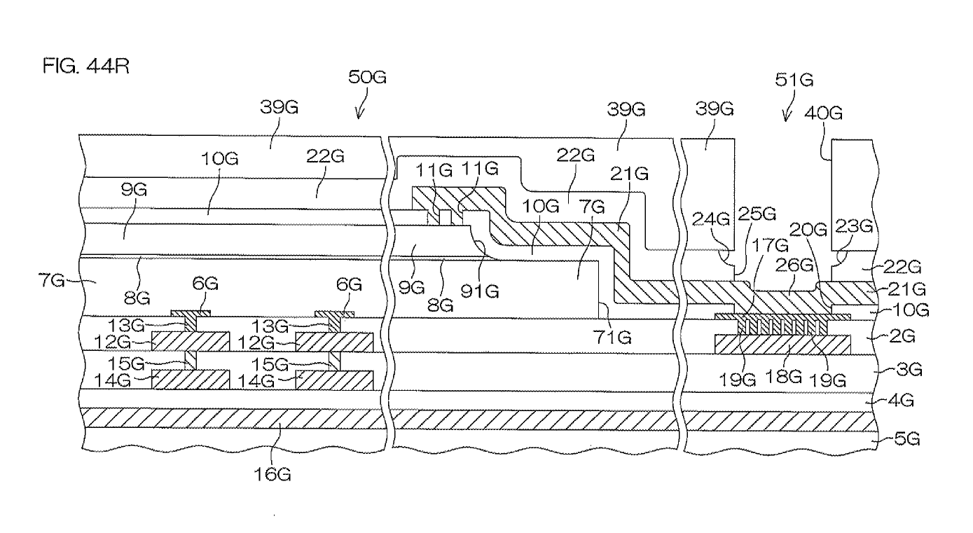

### Preferred Embodiment According to a Seventh Aspect of the Invention FIG. 43 and FIG. 44

FIG. 43 is a schematic sectional view of an image sensor according to a preferred embodiment of a seventh aspect of the present invention. In FIG. 43, only portions made of metal materials are hatched and portions besides these are not hatched.

The image sensor 1G, which is an example of a photoelectric converter, includes a semiconductor substrate (not shown). A semiconductor device, such as a MISFET (metal insulator semiconductor field effect transistor), etc., is formed on the semiconductor substrate.

Interlayer insulating films 2G to 5G are laminated on the semiconductor substrate. The interlayer insulating films 2G to 5G are made, for example, of silicon oxide (SiO₂).

Also, as shown in FIG. 43, a sensor forming region 50G and a pad forming region MG are set on the semiconductor substrate. The pad forming region MG is formed to an annular form that surrounds the sensor forming region 50G.

In the sensor forming region 50G, a plurality of lower electrodes 6G are arrayed in a matrix on the uppermost interlayer insulating film 2G. The lower electrodes 6G are made of tungsten (W). Each lower electrode 6G is formed to a square shape in a plan view. The lower electrode 6G has a thickness of no less than 0.2 μm and no more than 0.5 μm.

A photoabsorption layer 7G of rectangular shape in a plan view is formed on the interlayer insulating film 2G so as to cover all of the lower electrodes 6G together. The photoabsorption layer 7G is made of CIGS and exhibits a p-type conductivity. The photoabsorption layer 7G has a thickness of no less than 1.0 μm and no more than 1.4 μm. In the photoabsorption layer 7G, each region of fixed area and rectangular shape in a plan view that is centered at each lower electrode 6G is used for reading of a single pixel.

An upper surface of the photoabsorption layer 7G, with the exception of a peripheral edge portion thereof, is covered by a high-resistance buffer layer 8G. The high-resistance buffer layer 8G is made of cadmium sulfide (CdS). The high-resistance buffer layer 8G has a thickness, for example, of 0.05 μm.

On the high-resistance buffer layer 8G, a transparent conductive film 9G is formed so as to cover an entire upper surface of the high-resistance buffer layer 8G. The transparent conductive film 9G is made of zinc oxide (ZnO), which has a light transmitting property, and has conductivity imparted by addition of an n-type impurity (for example, P (phosphorus) or As (arsenic)). The transparent conductive film 9G has a thickness, for example, of 0.6 μm.

A side surface 91G of the transparent conductive film 9G is formed to a cross-sectional shape that is downwardly (inwardly) concavely curved and inclined so that as its lower end is approached, a side surface 71G of the photoabsorption layer 7G is approached. A lower end of the side surface 91G is continuous with a peripheral edge of the high-resistance buffer layer 8G. An upper end of the side surface 91G is positioned slightly inward with respect to the side surface 71G of the photoabsorption layer 7G.

An interlayer insulating film 10G is formed on a portion of the interlayer insulating film 2G exposed from the photoabsorption layer 7G, on a peripheral edge portion of the photoabsorption layer 7G, and on the transparent conductive film 9G so as to spread across these portions. The interlayer insulating film 10G is made of silicon nitride (SiN). The interlayer insulating film 10G has a thickness, for example, of 0.4 μm. Above a peripheral edge portion of the transparent conductive film 9G, a plurality of via holes 11G are penetratingly formed in the interlayer insulating film 10G. The via holes 11G form, for example, two columns and are mutually spaced and disposed along the peripheral edge of the transparent conductive film 9G.

In the sensor forming region 50G, wirings 12G are formed at positions opposing the respective lower electrodes 6G between the uppermost interlayer insulating film 2G and the interlayer insulating film 3G below it. Each lower electrode 6G and the opposing wiring 12G are electrically connected by a via 13G that penetrates through the interlayer insulating film 2G. The via 13G is made of tungsten and is formed integral to the lower electrode 6G.

Between the interlayer insulating film 3G and the interlayer insulating film 4G below it, capacitor upper electrodes 14G are formed at positions opposing the respective wirings 12G. Each wiring 12G and the opposing capacitor upper electrode 14G are electrically connected by a via 15G that penetrates through the interlayer insulating film 3G. The via 15G is made of tungsten.

Between the interlayer insulating film 4G and the interlayer insulating film 5G below it, a capacitor lower electrode 16G is formed to oppose all of the capacitor upper electrodes 14G together. A capacitive element (MIM capacitor) having an MIM (metal-insulator-metal) structure, in which the interlayer insulating film 4G is sandwiched as a capacitive film between the capacitor upper electrode 14G and the capacitor lower electrode 16G, is thereby formed according to each pixel. The lower electrode 6G and the capacitor upper electrode 14G of the MIM capacitor are electrically connected according to each pixel.

In the pad forming region 51G, a relay electrode 17G is formed on the uppermost interlayer insulating film 2G. The relay electrode 17G is made of tungsten.

Also, between the interlayer insulating film 2G and the interlayer insulating film 3G below it, a wiring 18G is formed at a position opposing the relay electrode 17G. The relay electrode 17G and the opposing wiring 18G are electrically connected by a plurality of vias 19G penetrating through the interlayer insulating film 2G. The vias 19G are made of tungsten and are formed integral to the relay electrode 17G.

A connection opening 20G of substantially square shape in a plan view is formed in the interlayer insulating film 10G at a position opposing the relay electrode 17G. The connection opening 20G penetrates through the interlayer insulating film 10G in the thickness direction. A top surface of the relay electrode 17G is thereby exposed inside the connection opening 20G.

An upper electrode 21G is disposed on the interlayer insulating film 10G. One end portion of the upper electrode 21G is disposed on a peripheral edge portion of the transparent conductive film 9G, enters inside the via holes 11G formed in the interlayer insulating film 10G, and is connected to the transparent conductive film 9G inside the via holes 11G. Also, another end portion of the upper electrode 21G enters inside the connection opening 20G and is connected to the relay electrode 17G inside the connection opening 20G. The upper electrode 21G has a thickness, for example, of no less than 0.7 μm and no more than 1.0 μm.

Also, a top surface protective film 22G is formed on a topmost surface of the image sensor 1G. The top surface protective film 22G is made, for example, of silicon nitride. The top surface protective film 22G has a thickness, for example, of 1.2 μm. In the top surface protective film 22G, a pad opening 23G, by which the portion of the upper electrode 21G entering inside the connection opening 20G is exposed as a bonding pad 26G, is formed at a position opposing the connection opening 20G.

The pad opening 23G is formed so that its cross-sectional shape takes on a wineglass-like form as a whole. Specifically, an upper portion of the pad opening 23G forms a tapered portion 24G that is arcuately inclined and swollen outward so that an interval between side surfaces thereof decreases towards a lower side. Also, a lower portion of the pad opening 23G forms a penetrating portion 25G that is continuous with a lower end portion of the tapered portion 24G and penetrates through the top surface protective film 22G in its film thickness direction.

FIG. 44A to FIG. 44N are schematic sectional views that successively illustrate a manufacturing process of the image sensor shown in FIG. 44. In FIG. 44A to FIG. 44N, only portions made of metal materials are hatched and portions besides these are not hatched.

In the manufacturing process of the image sensor 1G, first, as shown in FIG. 44A, the interlayer insulating film 5G, the capacitor lower electrode 16G, the interlayer insulating film 4G, the capacitor upper electrodes 14G, the interlayer insulating film 3G, the vias 15G, the wirings 12G and 18G, and the interlayer insulating film 2G are formed in that order on the semiconductor substrate (not shown). The via holes 30G penetrating through the interlayer insulating film 2G are then formed above the respective wirings 12G and the via holes 31G penetrating through the interlayer insulating film are formed above the wiring 18G by photolithography and etching.

Thereafter, as shown in FIG. 44B, tungsten, which is the material of the lower electrodes 6G, the vias 13G and 19G, and the relay electrode 17G, is deposited by the CVD method inside the via holes 30G and 31G and on the interlayer insulating film 2G to form a tungsten deposition layer 32G.

Thereafter, as shown in FIG. 44C, a resist pattern 33G that selectively covers only portions that become the lower electrodes 6G and the relay electrode 17G is formed by photolithography on the tungsten deposition layer 32G.

Then, as shown in FIG. 44D, portions of the tungsten deposition layer 32G exposed from the resist pattern 33G are removed by dry etching using the resist pattern 33G as a mask. The mixed gas of sulfur hexafluoride (SF₆) and argon (Ar) is used for the dry etching.

After the dry etching, the resist pattern 33G is removed as shown in FIG. 44E. The lower electrodes 6G, the vias 13G embedded in the via holes 30G, the relay electrode 17G, and the vias 19G embedded in the via holes 31G are thereby obtained.

Thereafter, as shown in FIG. 44F, a CIGS film 34G is formed by the MBE method on the interlayer insulating film 2G, the lower electrodes 6G, and the relay electrode 17G.

Thereafter, as shown in FIG. 44G, a cadmium sulfide film 35G is formed by the CBD method on the CIGS film 34G.

Further in succession, a zinc oxide film 36G is formed by the sputtering method on the cadmium sulfide film 35G as shown in FIG. 44H.

Then, as shown in FIG. 44I, a resist pattern 37G is formed by photolithography on the zinc oxide film 36G. The resist pattern 37G opposes a portion of the CIGS film 34G that is to become the photoabsorption layer 7G. Then, using the resist pattern 37G as a mask, the zinc oxide film 36G and the cadmium sulfide film 35G are removed selectively by wet etching by hydrofluoric acid (HF). The wet etching is continued for a predetermined time even after the portion of the zinc oxide film 36G that does not oppose the resist pattern 37G has been removed. The zinc oxide film 36G is thereby removed from below a peripheral edge portion of the resist pattern 37G as well. Consequently, the zinc oxide film 36G and the cadmium sulfide film 35G become the transparent conductive film 9G and the high-resistance buffer layer 8G, respectively, and the curved side surface 91G of the transparent conductive film 9G is obtained.

Then, while leaving the resist pattern 37G, dry etching using the resist pattern 37G as a mask is performed to selectively remove the CIGS film 34G as shown in FIG. 44J. The CIGS film 34G is left only at the portion opposing the resist pattern 37G. The CIGS film 34G thereby becomes the photoabsorption layer 7G and the relay electrode 17G is exposed on the interlayer insulating film 2G. Thereafter, the resist pattern 37G is removed.

Thereafter, as shown in FIG. 44K, the interlayer insulating film 10G is formed coveringly by the plasma CVD method on the portion of the interlayer insulating film 2G exposed from the photoabsorption layer 7G, on the peripheral edge portion of the photoabsorption layer 7G, and on the transparent conductive film 9G.

Thereafter, a resist pattern having openings that selectively expose portions at which the via holes 11G and the connection opening 20G are to be formed is formed by photolithography on the interlayer insulating film 10G. By then performing dry etching using the resist pattern as a mask, the via holes 11G that penetrate through the interlayer insulating film 10G are formed as shown in FIG. 44L. Also, the connection opening 20G that penetrates through the interlayer insulating film 10G is formed.

Thereafter, as shown in FIG. 44M, an aluminum film 38G made of aluminum is formed by the sputtering method on the interlayer insulating film 10G. The aluminum film 38G is also formed inside the via holes 11G and the connection opening 20G. The via holes 11G and the connection opening 20G are completely filled with the aluminum film 38G.

Thereafter, a resist pattern that covers a portion that is to become the upper electrode 21G is formed by photolithography on the aluminum film 38G. The aluminum film 38G is then removed selectively by dry etching using the resist pattern as a mask, and the aluminum film 38G is thereby processed to the upper electrode 21G as shown in FIG. 44N.

Thereafter, as shown in FIG. 44O, the top surface protective film 22G is formed on the upper electrode 21G and the interlayer insulating film 10G by the plasma CVD method under a temperature of no more than 200°. Whereas the photoabsorption layer 7G, the high-resistance buffer layer 8G, and the transparent conductive film 9G are formed on the sensor forming region 50G, these are not formed in the pad forming region 51G, and thus on the top surface of the top surface protective film 22G, a step D substantially equal to the thickness (of, for example, no less than 1 μm) of the photoabsorption layer 7G, the high-resistance buffer layer 8G, and the transparent conductive film 9G is formed between the sensor forming region 50G and the pad forming region 51G.

Then, as shown in FIG. 44P, a resist pattern 39G having a resist opening 40G that exposes a portion at which the pad opening 23G shown in FIG. 43 is to be formed is formed on the top surface protective film 22G. The resist pattern 39G is formed by spin-coating a resist onto the top surface protective film 22G and selectively removing the resist being after curing of the resist. A top surface of the resist pattern 39G is thus a flat surface. The step D is formed between the sensor forming region 50G and the pad forming region 51G on the top surface of the top surface protective film 22G and thus a thickness of the resist pattern 39G in the sensor forming region 50G is less than a thickness of the resist pattern 39G in the pad forming region 51G by just an amount corresponding to the step D.

By isotropic etching using the resist pattern 39G as a mask, the portion of the top surface protective film 22G exposed from the resist opening 40G is etched isotropically as shown in FIG. 44Q. The top surface protective film 22G is thereby removed so that a portion below a portion of the resist pattern 39G facing the resist opening 40G has an arcuate cross section. The arcuate portion forms the tapered portion 24G with which the interval between side surfaces decreases toward the lower side.

Such a tapered portion 24G can be formed, for example, using an etching apparatus (model No.: TCE-2802) made by Tokyo Ohka Kogyo Co., Ltd. under conditions of:

### Pressure: 0.3 to 1.5 Torr

### Output: 100 to 500 W

He (helium) gas flow rate: 10 to 100 ccm
SF₆ (sulfur hexafluoride) gas flow rate: 10 to 100 ccm

The tapered portion 24G can also be formed using a chemical dry etching apparatus (model No.: CDE-7-4) made by Shibaura Eletec Corp. under conditions of:

Pressure: 376 mTorr

### Output: 600 W

CF₄ gas flow rate: 300 ccm
O₂ gas flow rate: 100 ccm
N₂ gas flow rate: 50 ccm

Then, while leaving the resist pattern 39G, anisotropic etching using the resist pattern 39G as a mask is performed to selectively remove a portion of the top surface protective film 22G opposing the resist opening 40G and its lamination direction to form the penetrating portion 25G as shown in FIG. 44R. The pad opening 23G made of the tapered portion 24G and the penetrating portion 25G is thereby formed. A film thickness of a portion of the top surface protective film 22G at which the penetrating portion 25G is to be formed (portion opposing the resist opening 40G and its lamination direction) is less than a thickness of the resist pattern 39G in the sensor forming region 50G and thus even if the thickness of the resist pattern 39G in the sensor forming region 50G is small, the top surface protective film 22G does not become exposed from the resist pattern 39G in the sensor forming region 50G.

After the forming of the pad opening 23G, the resist pattern 39G is removed and the image sensor 1G shown in FIG. 43 is thereby obtained.

A problem that arises in a case where only one of either anisotropic etching or isotropic etching is applied as the method for forming the pad opening in the top surface protective film 22G shall now be described.

Whereas the photoabsorption layer 7G and the transparent conductive film 9G are formed in the sensor forming region 50G, the photoabsorption layer 7G and the transparent conductive film 9G are not formed in the pad forming region 51G. A step substantially equal to the thickness (of, for example, no less than 1.0 μm) of the photoabsorption layer 7G and the transparent conductive film 9G is thus formed between the sensor forming region 50G and the pad forming region 51G on the top surface of the top surface protective film 22G.

The resist pattern for anisotropic etching of the top surface protective film 22G is formed by spin coating the resist onto the top surface protective film 22G and selectively removing the resist after curing of the resist. The top surface of the resist pattern is thus a flat surface. A thickness of the resist pattern in the sensor forming region 50G is less than a thickness of the resist pattern in the pad forming region 51G by just an amount corresponding to the step because the step is formed between the sensor forming region 50G and the pad forming region 51G on the top surface of the top surface protective film 22G.

The pad opening is formed in the pad forming region 51G and thus the resist pattern has the opening for exposing the top surface protective film 22G at the portion of relatively large thickness on the pad forming region 51G. Thus, in a case where anisotropic etching is employed as the method for etching the top surface protective film 22G, particles made incident on the top surface of the resist pattern have a greater energy than particles made incident on the top surface of the top surface protective film 22G through the opening in the resist pattern. Consequently, by the time the portion of the top surface protective film 22G that is exposed from the resist pattern is removed (by the time the pad opening is formed), the resist pattern will have undergone significant film loss and in the sensor forming region 50G, the top surface protective film 22G may be exposed and subject to damage.

Also, zinc oxide, which is the material of the transparent conductive film 9G, degrades when exposed to a temperature in the excess of 200° C. Processing under a temperature exceeding 200° C. thus cannot be performed after the transparent conductive film 9G has been formed. The top surface protective film 22G is thus formed by the plasma CVD (chemical vapor deposition) method under a temperature of no more than 200° C. Consequently, a top surface protective film 22G of stable quality is not formed.

To avoid damaging of the top surface protective film 22G in the sensor forming region 50G, employment of wet etching or other isotropic etching as a method for etching the top surface protective film 22G for forming the pad opening may be considered. However, the film quality of the top surface protective film 22G is not stable and thus with wet etching, it is difficult to control the etching amount of the top surface protective film 22G precisely.

On the other hand, with the present preferred embodiment, after the resist pattern 39G has been formed on the top surface protective film 22G, the portion of the top surface protective film 22G that is exposed from the resist opening 40G is etched by isotropic etching. The tapered portion 24G that is dug in from the top surface of the top surface protective film 22G is thereby formed in the top surface protective film 22G. Thereafter, the penetrating portion 25G penetrating through the top surface protective film 22G from a bottom surface of the tapered portion 24G is formed by anisotropic etching, and the pad opening 23G that selectively exposes the upper electrode 21G is formed in the top surface protective film 22G. The amount of etching by isotropic etching thus suffices to be small and the duration of performing the isotropic etching suffices to be short, and film loss of the resist pattern 39G can thus be lessened. Consequently, exposing of the top surface protective film 22G due to film loss of the resist pattern 39G above the photoabsorption layer 7G, the high-resistance buffer layer 8G, and the transparent conductive film 9G can be prevented and damaging of the top surface protective film 22G by etching can be prevented. The pad opening 23G that selectively exposes the upper electrode 21G can thus be formed in the top surface protective film 22G without damaging the top surface protective film 22G by etching.

Also, in the isotropic etching for forming the tapered portion 24G, it suffices that the portion of the top surface protective film 22G at which the penetrating portion 25G is formed be thinned and that lessening of the etching amount by anisotropic etching be made possible, and there is no need to perform isotropic etching until the upper electrode 21G is exposed and thus precise control of the etching amount by isotropic etching is unnecessary. The tapered portion 24G can thus be formed readily and consequently the pad opening 23G can be formed readily.

Also, the top surface protective film 22G is formed at a low temperature of no more than 200° C. The transparent conductive film 9G made of zinc oxide (ZnO) is thus not exposed to a temperature exceeding 200° C. and degradation of the transparent conductive film 9G by heat can be prevented.

Also, with the image sensor 1G, the plurality of mutually-spaced lower electrodes 6G disposed on the interlayer insulating film 2G are covered all together by the photoabsorption layer 7G made of CIGS. That is, the photoabsorption layer 7G is not cut and divided according to each pixel, and thus as in the preferred embodiment according to the first aspect of the present invention, variation of sensitivity among pixels is not influenced by damage due to dry etching.

Also, as in the preferred embodiment according to the first aspect of the present invention, the pixel aperture ratio (pn junction area/pixel area) can be made 100% because the photoabsorption layer 7G is not cut and divided according to each pixel. A large number of carriers can thereby be generated even with weak light and dramatic improvement of sensitivity can be achieved.

Further, a shrinkage cavity does not form during forming of the transparent conductive film 9G because grooves for cutting and dividing the photoabsorption layer 7G are not formed. Degradation with time of the transparent conductive film 9G can thus be prevented and reliability can be improved.

Also, a step of forming an isolation film is unnecessary and the manufacturing process is thus simpler than that of the conventional photoelectric converter and time and cost required for manufacture can be reduced.

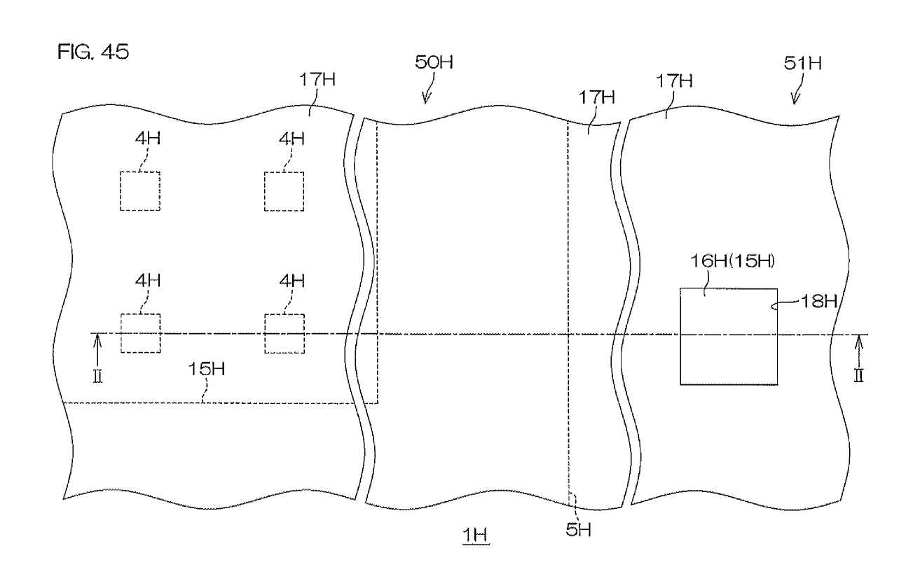

### Preferred Embodiment According to an Eighth Aspect of the Invention FIG. 45 to FIG. 48

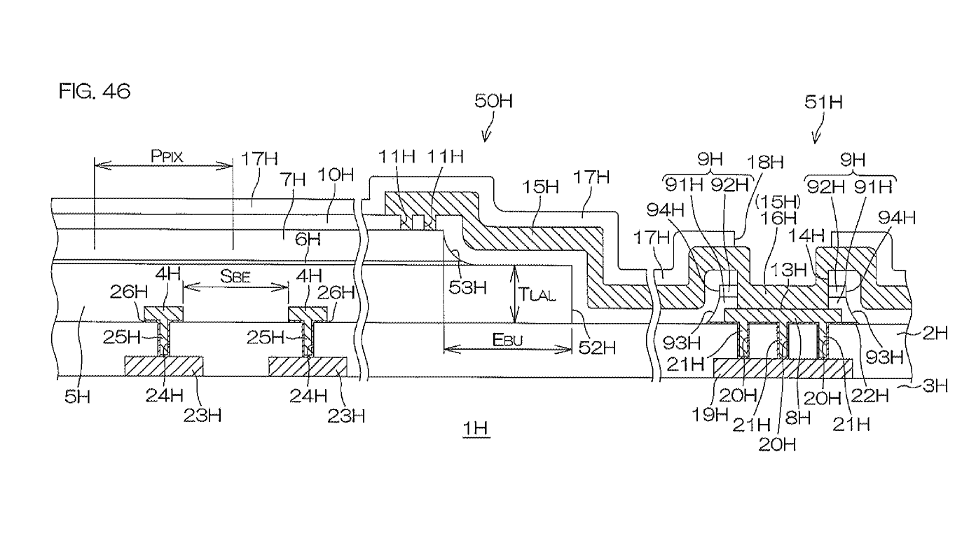

FIG. 45 is a schematic plan view of an image sensor according to a preferred embodiment of an eighth aspect of the present invention. FIG. 46 is a schematic sectional view of the image sensor taken along sectioning line II-II in FIG. 45. In FIG. 46, only portions made of metal materials are hatched and portions besides these are not hatched.

The image sensor 1H, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

Interlayer insulating films 2H and 3H are laminated on the semiconductor substrate. The interlayer insulating films 2H and 3H are made, for example, of silicon oxide (SiO₂).

Also, as shown in FIG. 45, a sensor forming region 50H and an annular pad forming region 51H surrounding it are set on the semiconductor substrate.

In the sensor forming region 50H, a plurality of lower electrodes 4H are arrayed in a matrix on the uppermost interlayer insulating film 2H. The lower electrodes 4H are made of tungsten (W). Each lower electrode 4H is formed to a square shape in a plan view. For example, in the case of 7.5 μm pitch, the length of one side of the lower electrode 4H in a plan view is no less than 2.0 μm and no more than 3.3 μm. The lower electrode 4H has a thickness of no less than 0.2 μm and no more than 0.4 μm. Also, as shown in FIG. 46, mutually adjacent lower electrodes 4H are spaced apart at equal intervals S_{BE} (≧T_{LAL}×3) each set to no less than three times the thickness T_{LAL} of a photoabsorption layer 5H to be described below.

The photoabsorption layer 5H of rectangular shape in a plan view is formed on the interlayer insulating film 2H so as to cover all of the lower electrodes 4H together. Specifically, the photoabsorption layer 5H is formed integrally on a rectangular region on the interlayer insulating film 2H in which the lower electrodes 4H are formed and on a rectangular annular region of fixed width at a periphery of the rectangular region. The photoabsorption layer 5H is made of CIGS and exhibits a p-type conductivity. The thickness T_{LAL} of the photoabsorption layer 5H is no less than 1.0 μm and no more than 1.4 μm. In the photoabsorption layer 5H, each region of fixed area and rectangular shape in a plan view that is centered at each lower electrode 4H is used for reading of a single pixel. The pixel pitch P_{PIX} that is the width of this region is no less than 5 μm and no more than 10 μm.

An upper surface of the photoabsorption layer 5H, with the exception of a peripheral edge portion thereof, is covered by a high-resistance buffer layer 6H. The high-resistance buffer layer 6H is made of cadmium sulfide (CdS). The high-resistance buffer layer 6H has a thickness, for example, of 0.05 μm.

On the high-resistance buffer layer 6H, a transparent conductive film 7H is formed so as to cover an entire upper surface of the high-resistance buffer layer 6H. The transparent conductive film 7H is made of zinc oxide (ZnO), which has a light transmitting property, and has conductivity imparted by addition of an n-type impurity (for example, Al₂O₃ (alumina)). The transparent conductive film 7H has a thickness, for example, of 0.6 μm.

A side surface 53H of the transparent conductive film 7H is formed to a cross-sectional shape that is downwardly (inwardly) concavely curved and inclined so that as its lower end is approached, a side surface 53H of the photoabsorption layer 5H is approached. A lower end of the side surface 53H is continuous with a peripheral edge of the high-resistance buffer layer 6H. An upper end of the side surface 53H is positioned inward with respect to the side surface 52H of the photoabsorption layer 5H by just a horizontal distance E_{BU}. The horizontal distance E_{BU} is no less than 5 μm and no more than 10 μm.

In the pad forming region 51H, a relay electrode 8H is formed on the uppermost interlayer insulating film 2H. The relay electrode 8H is made of the same material (tungsten) as the lower electrode 4H. The relay electrode 8H is formed to a square shape in a plan view. A length of one side of the relay electrode 8H in a plan view is no less than 60 μm and no more than 120 μm. The relay electrode 8H has a thickness of no less than 0.2 μm and no more than 0.4 μm.

Also, in the pad forming region 51H, a protective film 9H is formed on the uppermost interlayer insulating film 2H so as to cover a peripheral edge portion of the relay electrode 8H. The protective film 9H includes a first protective film 91H at a lower side and a second protective film 92H at an upper side.

The first protective film 91H is made of silicon oxide (SiO₂) and coats the peripheral edge portion of the relay electrode 8H. Each side surface 93H of the first protective film 91H is formed to a cross-sectional shape that is curved so as to be downwardly (inwardly) concave as its lower end is approached. The first protective film 91H has a thickness of approximately 2000 Å.

The second protective film 92H is formed of silicon nitride (SiN) and is formed on the first protective film 91H. Each side surface 94H of the second protective film 92H is formed to a planar shape perpendicular to the top surface of the interlayer insulating film 2H and a lower end thereof is continuous with an upper end of the side surface 93H of the first protective film 91H. The second protective film 92H has a thickness of approximately 2000 Å (the same as the thickness of the first protective film 91H).

An interlayer insulating film 10H is formed on a portion of the interlayer insulating film 2H exposed from the photoabsorption layer 5H, on a peripheral edge portion of the photoabsorption layer 5H, on the transparent conductive film 7H, and on the protective film 9H so as to spread across these portions. The interlayer insulating film 10H is made of silicon nitride (SiN). The interlayer insulating film 10H has a thickness, for example, of 0.4 μm. Above a peripheral edge portion of the transparent conductive film 7H, a plurality of via holes 11H are penetratingly formed in the interlayer insulating film 10H. The via holes 11H form, for example, two columns and are mutually spaced and disposed along the peripheral edge of the transparent conductive film 7H.

Also, in the pad forming region 51H, a pad opening 14H, exposing a portion of the relay electrode 8H as a pad 13H, is formed so as to continuously penetrate through the interlayer insulating film 10H and the protective film 9H. The pad opening 14H has a depth of no less than 5000 Å and no more than 6000 Å.

On the interlayer insulating film 10H, an upper electrode 15H is formed so as to cover entire peripheries of peripheral edge portions of the photoabsorption layer 5H and the transparent conductive film 7H. The upper electrode 15H is made of aluminum (Al). An extending portion 16H, extending toward the pad forming region 51H, is formed integral to the upper electrode 15H. An end portion of the extending portion 16H enters inside the pad opening 14H and is connected to the pad 13H (relay electrode 8H) inside the pad opening 14H.

Also, a top surface protective film 17H is formed on a topmost surface of the image sensor 1H. The top surface protective film 17H is made, for example, of silicon nitride. In the top surface protective film 17H, an opening 18H for exposing the portion of the extending portion 16H of the upper electrode 15H that enters into the pad opening 14H is formed at a position opposing the pad opening 14H.

Also, in the pad forming region 51H and between the interlayer insulating film 2H and the interlayer insulating film 3H below it, a first wiring 19H is formed at a position opposing the relay electrode 8H. A plurality of first via holes 20H are formed penetratingly through the interlayer insulating film 2H between the relay electrode 8H and the opposing first wiring 19H in the direction in which these oppose each other (thickness direction of the interlayer insulating film 2H). Each first via hole 20H has an inner diameter of, for example, 0.4 μm.

In each first via hole 20H, a first via 21H, made of the same material as the relay electrode 8H, is formed integral to the relay electrode 8H and without any gaps.

Also, a barrier film 22H is interposed between the relay electrode 8H plus the first vias 21H and the interlayer insulating film 2H. The barrier film 22H is made of titanium nitride (TiN). The relay electrode 8H is electrically connected to the opposing first wiring 19H via the first vias 21H and the barrier film 22H.

Also, in the sensor forming region 50H and between the uppermost interlayer insulating film 2H and the interlayer insulating film 3H below it, second wirings 23H are formed at positions opposing the respective lower electrodes 4H. A second via hole 24H is formed penetratingly through the interlayer insulating film 2H between each lower electrode 4H and the opposing second wiring 23H in the direction in which these oppose each other (thickness direction of the interlayer insulating film 2H). In each second via hole 24H, a second via 25H, made of the same material as the lower electrode 4H, is formed integral to the lower electrode 4H and without any gaps. Each lower electrode 4H is thereby electrically connected to the opposing second wiring 23H via the second via 25H. Each second via hole 24H has an inner diameter of, for example, 0.4 μm.

Also, a barrier film 26H is interposed between each lower electrode 4H plus the second via 25H and the interlayer insulating film 2H. The barrier films 26H are made of titanium nitride (TiN). Each lower electrode 4H is electrically connected to the opposing second wiring 23H via the second vias 25H and the barrier film 26H.

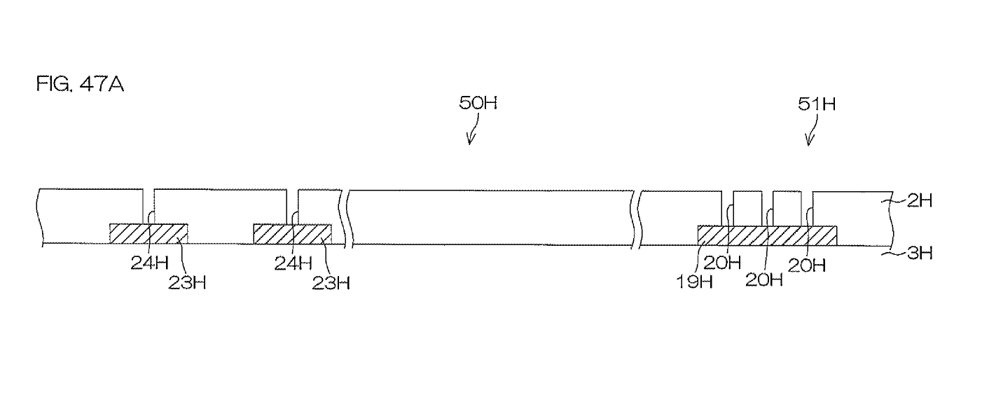

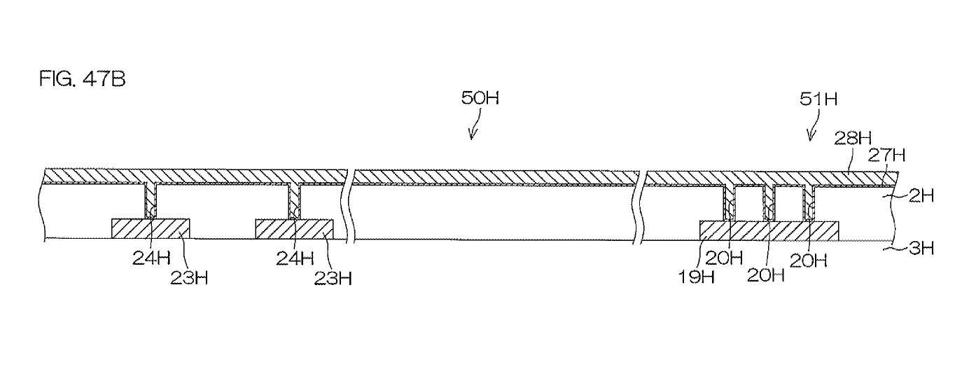

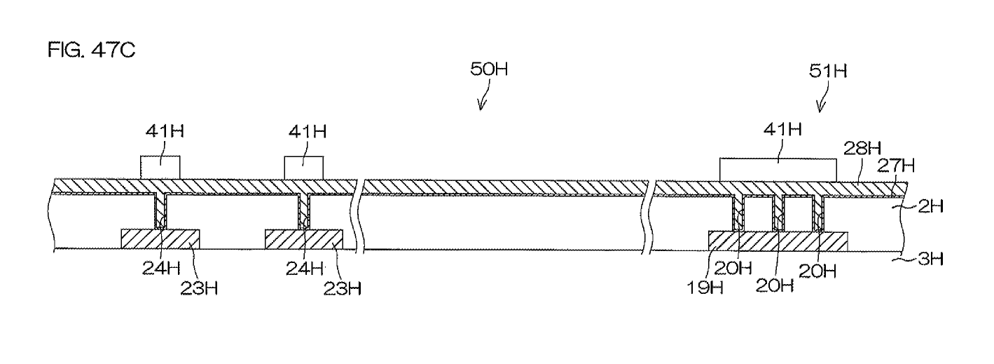

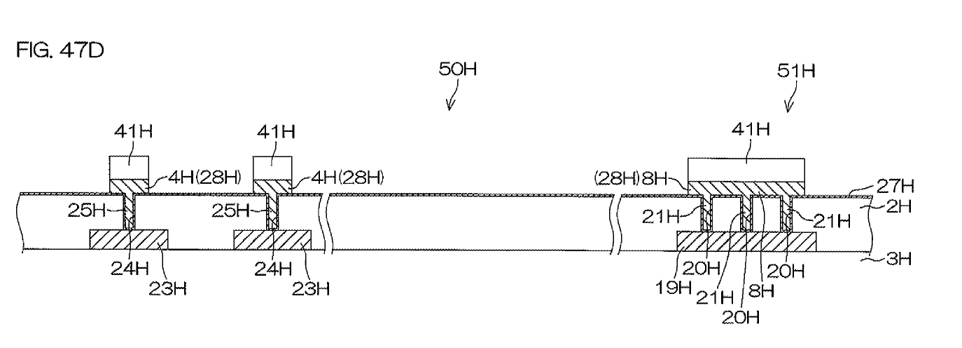

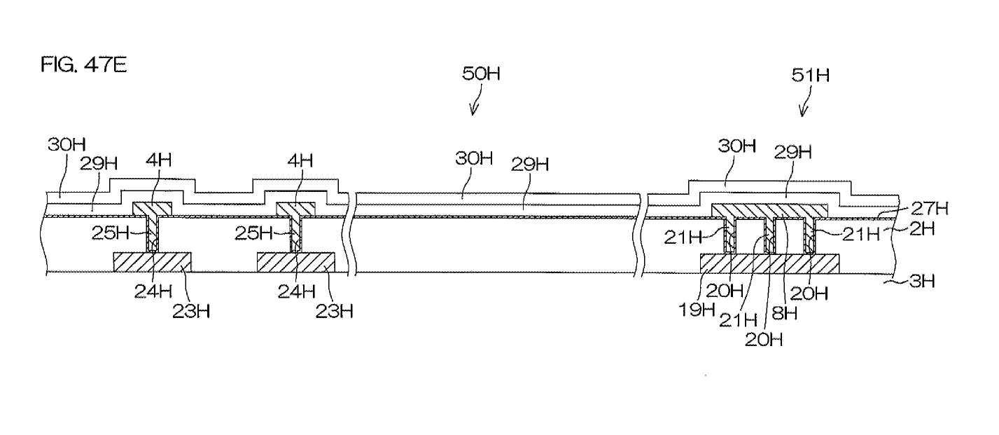

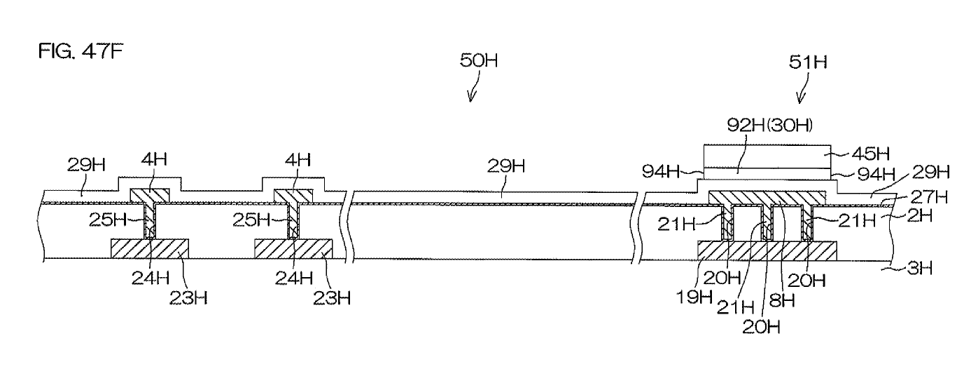

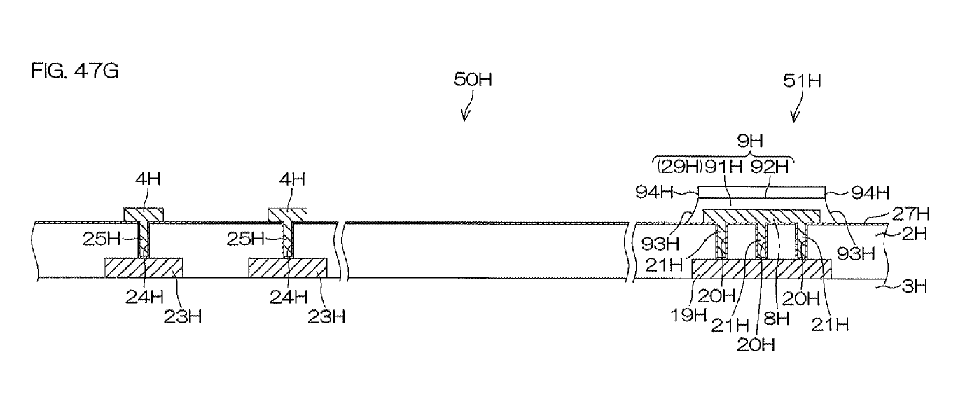

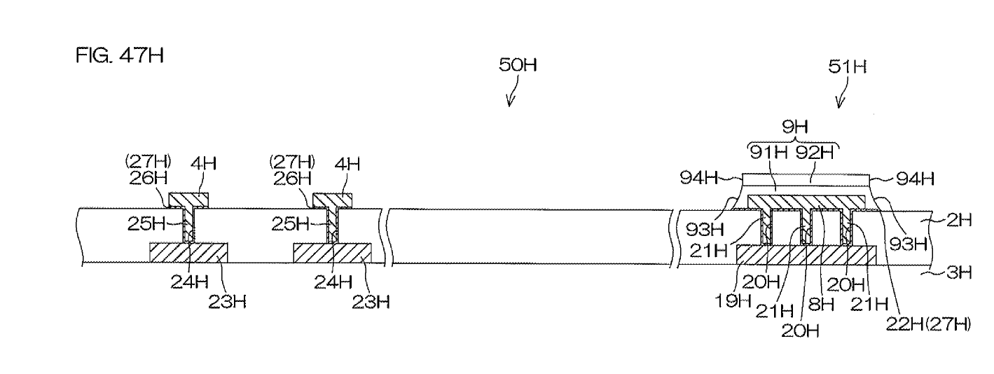

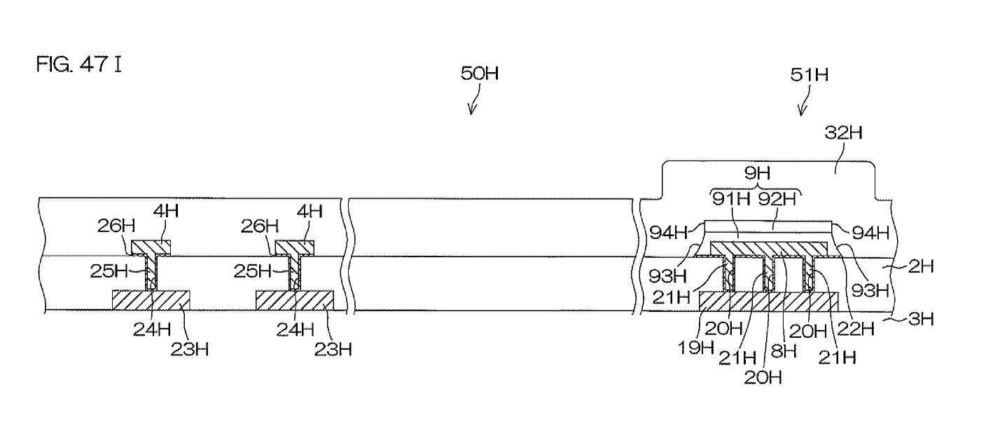

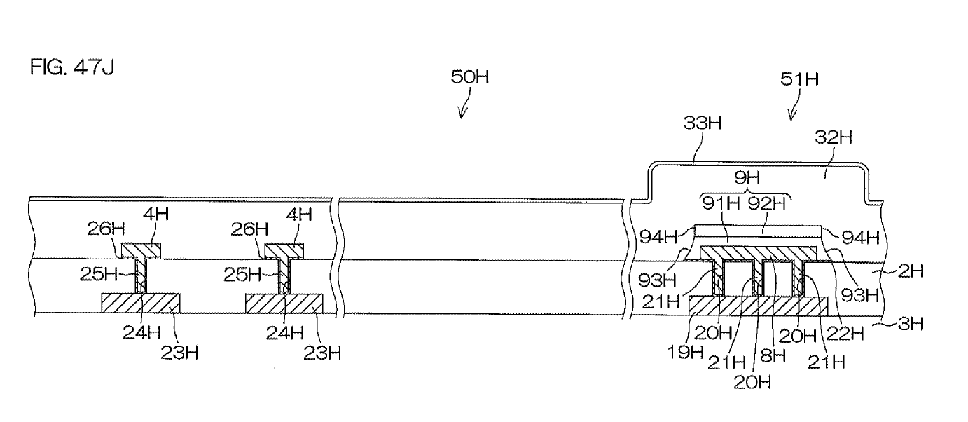

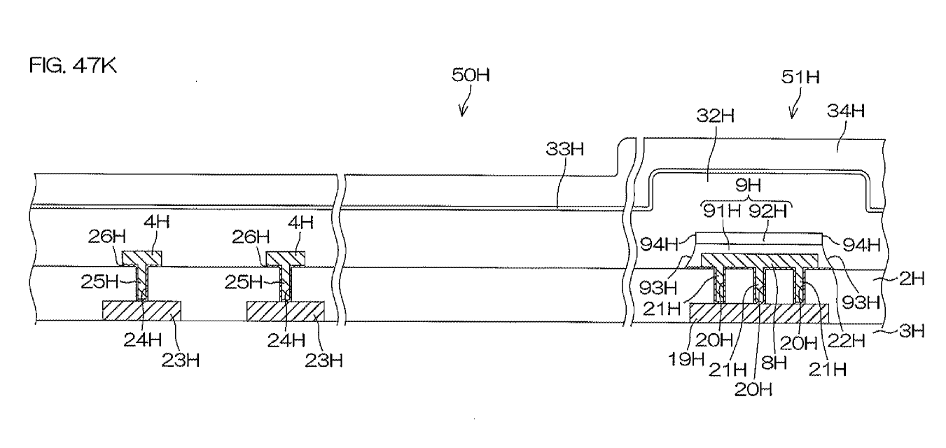

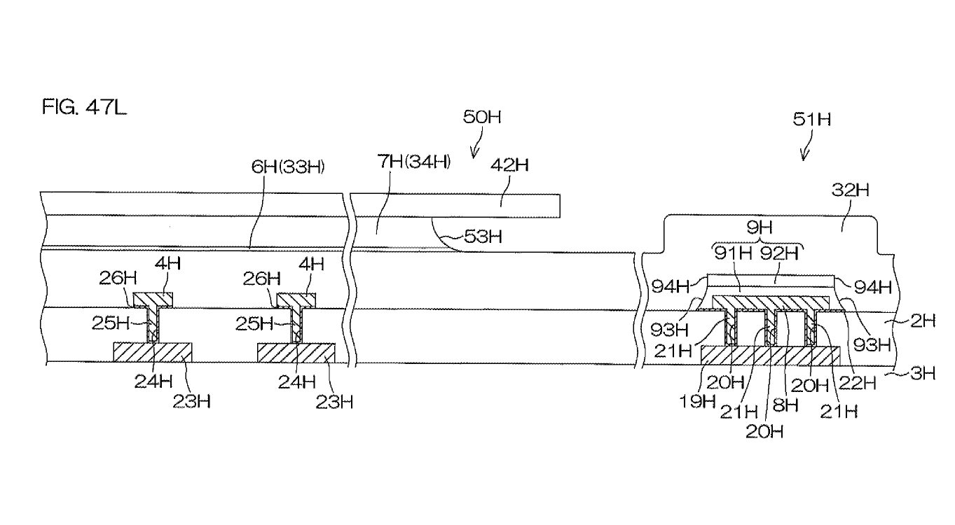

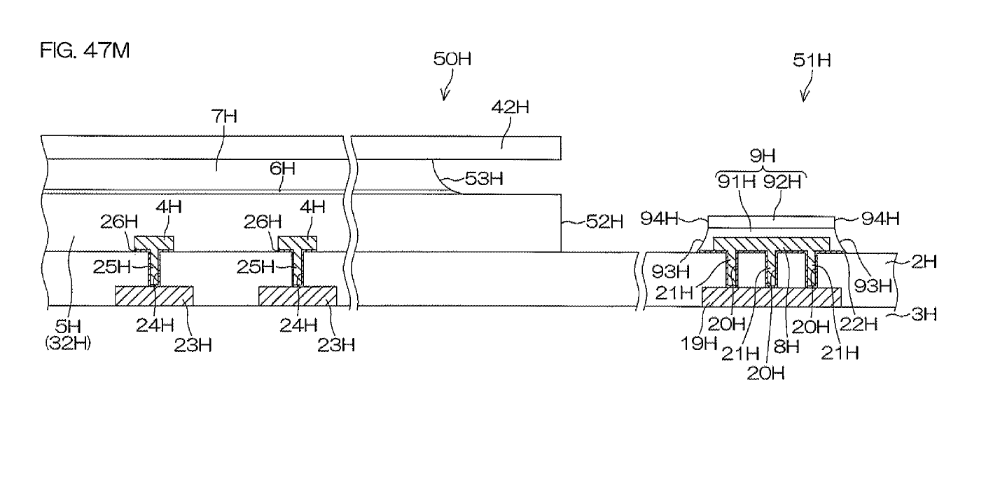

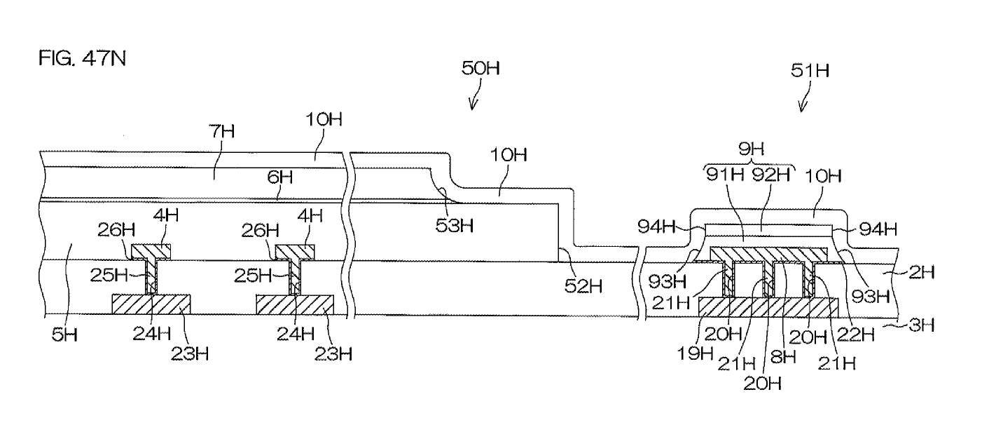

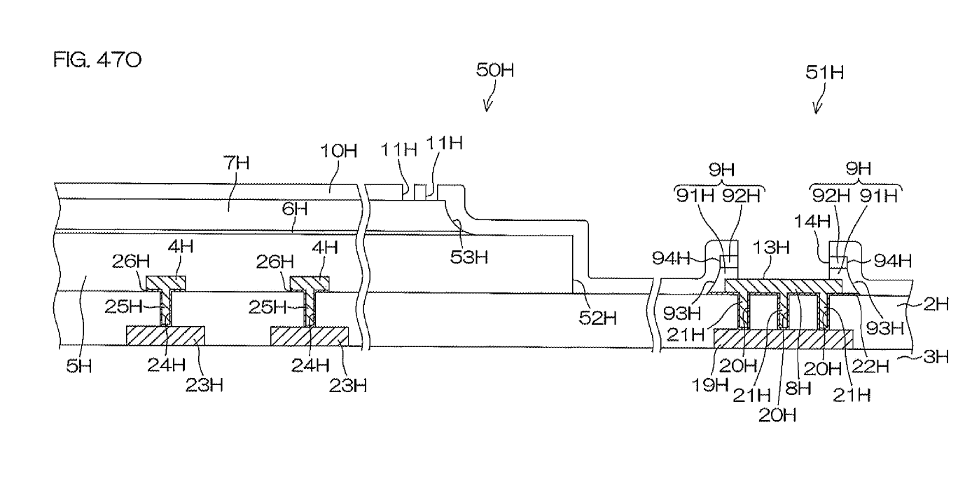

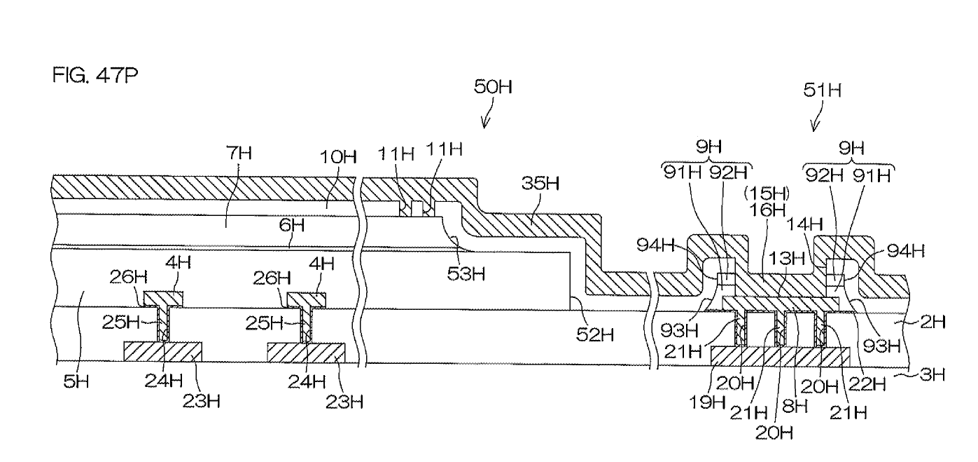

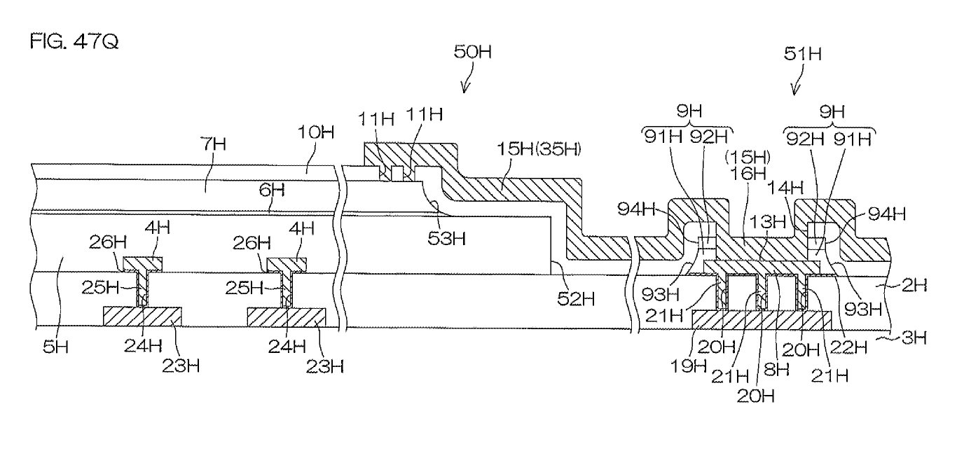

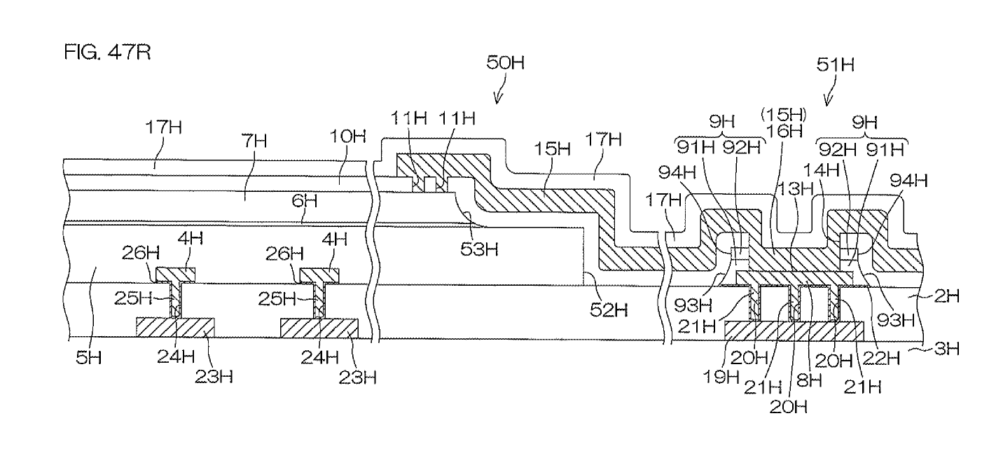

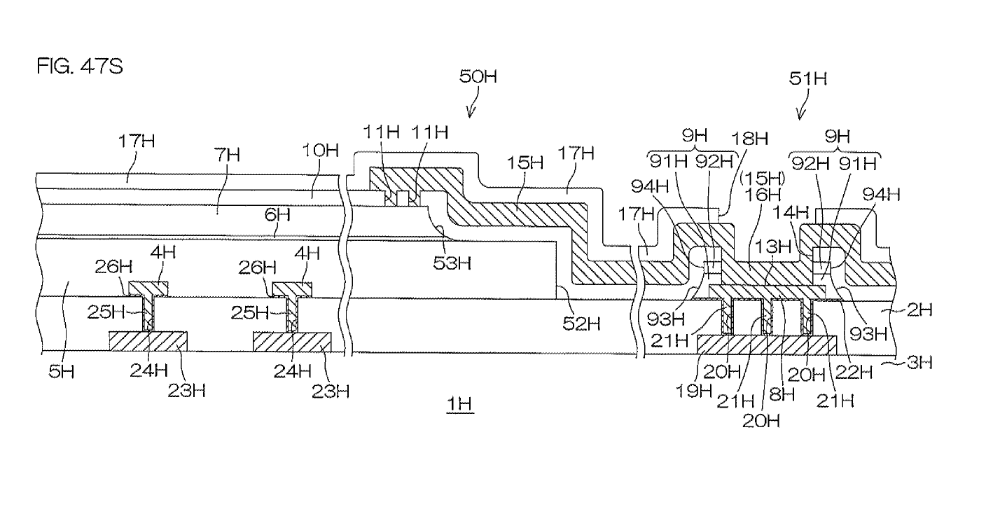

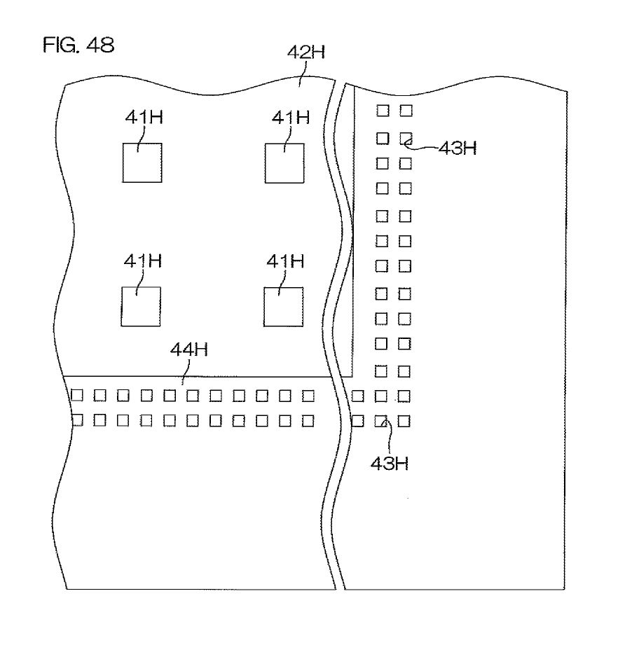

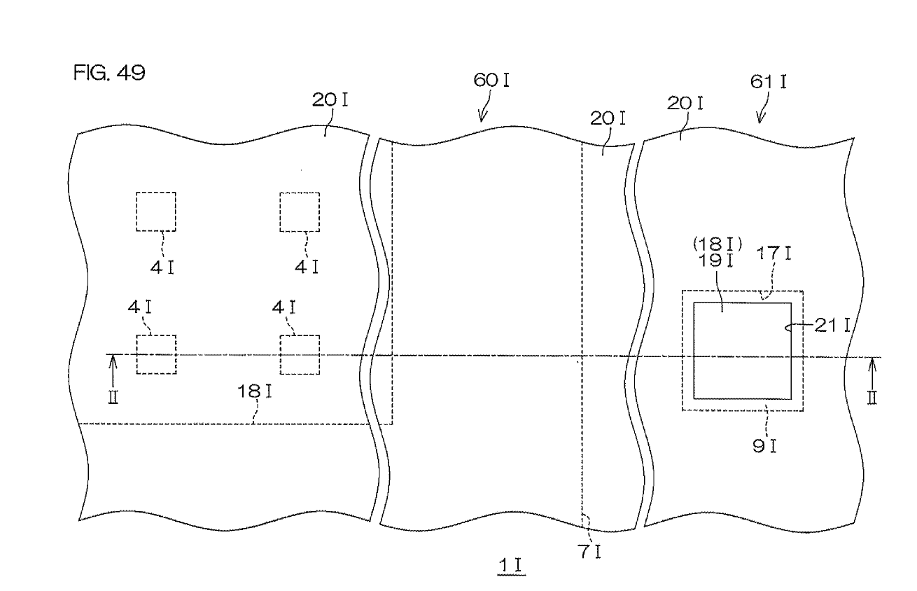

FIG. 47A to FIG. 47S are schematic sectional views that successively illustrate a manufacturing process of the image sensor shown in FIG. 46. FIG. 48 is a diagram for describing resist patterns used in the manufacturing process. In FIG. 47A to FIG. 47S, only portions made of metal materials are hatched and portions besides these are not hatched.

In the manufacturing process of the image sensor 1H, first, as shown in FIG. 47A, the interlayer insulating film 3H, the first wiring 19H plus the second wirings 23H, and the interlayer insulating film 2H are formed in that order on the semiconductor substrate (not shown). The first via holes 20H penetrating through the interlayer insulating film 2H are formed above the first wiring 19H and, at the same time, the second via holes 24H penetrating through the interlayer insulating film 2H are formed above the second wirings 23H, respectively, by photolithography and etching.

Thereafter, as shown in FIG. 47B, a barrier film 27H is formed on the interlayer insulating film 2H by the sputtering method. The barrier film 27H is made of a material (for example, titanium nitride) having etch selectivity with respect to a TEOS film 29H (to be described below). The barrier film 27H is also formed inside the first via holes 20H and the second via holes 24H. Thereafter, tungsten, which is the material of the lower electrodes 4H, the relay electrode 8H, the first vias 21H, and the second vias 25H, is deposited by the CVD method inside the first via holes 20H and the second via holes 24H and on the interlayer insulating film 2H to form a tungsten deposition layer 28H. A thickness of the tungsten deposition layer 28H on the interlayer insulating film 2H is 0.2 to 0.4 μm (2000 to 4000 Å).

Thereafter, as shown in FIG. 47C, a resist pattern 41H (see FIG. 48; in FIG. 48, a portion covering the relay electrode 8H is omitted) that selectively covers only portions that become the lower electrodes 4H and a portion that becomes the relay electrode 8H is formed by photolithography on the tungsten deposition layer 28H.

Then, as shown in FIG. 47D, portions of the tungsten deposition layer 28H exposed from the resist pattern 41H are removed by dry etching using the resist pattern 41H as a mask. The mixed gas of sulfur hexafluoride (SF₆) and argon (Ar) is used for the dry etching. The second vias 25H embedded in the second via holes 24H, the lower electrodes 4H, the first vias 21H embedded in the first via holes 20H, and the relay electrode 8H are thereby obtained at the same time.

After the dry etching, the resist pattern 41H is removed as shown in FIG. 47E. Thereafter, by the CVD (chemical vapor deposition) method using TEOS, the TEOS film 29H is formed on the interlayer insulating film 2H so as to cover the lower electrodes 4H and the relay electrode 8H all together. An SiN film 30H is then laminated on the TEOS film 29H by the plasma CVD method.

Then, as shown in FIG. 47F, a resist pattern 45H is formed to selectively cover only a portion that becomes the second protective film 92H. By then performing dry etching using the resist pattern 45H as a mask, the portion of the SiN film 30H that is exposed from the resist pattern 45H is anisotropically etched and removed. For the dry etching, a gas, with which a selectivity ratio of the SiN film 30H and the TEOS film 29H (SiN film 30H/TEOS film 29H) is, for example, no less than 1.5 and is preferably 2 to 5, is used, and specifically, a gas, such as CF₄+O₂ (mixed gas of tetrafluoromethane and oxygen), SF₆ (sulfur hexafluoride), etc., is used. The SiN film 30H thereby becomes the second protective film 92H, and the side surfaces 94H of planar shape of the second protective film 92H are obtained.

After the dry etching, the resist pattern 45H is removed as shown in FIG. 47G. Thereafter, by wet etching using the second protective film 92H as an etching mask (hard mask), a portion of the TEOS film 29H that is exposed from the second protective film 92H is isotropically etched and removed. Hydrofluoric acid (HF) is used for the wet etching. Here, the barrier film 27H is formed on the interlayer insulating film 2H, and the barrier film 27H acts as an etching stopper film and contact of the etching liquid (hydrofluoric acid) with the interlayer insulating film 2H is prevented. The TEOS film 29H thereby becomes the first protective film 91H that exposes the lower electrodes 4H and covers the relay electrode 8H and the curved side surfaces 93H of the first protective film 91H are obtained.

Thereafter, as shown in FIG. 47H, portions of the barrier film 27H exposed from the lower electrodes 4H and the protective film 9H are removed by dry etching (etch back). The chlorine (Cl₂) based gas is used for the dry etching. The barrier film 27H thereby becomes the barrier films 26H that prevent contact of the lower electrodes 4H plus the second vias 25H with the interlayer insulating film 2H and the barrier film 22H that prevents contact of the relay electrode 8H plus the first vias 21H with the interlayer insulating film 2H.

Thereafter, as shown in FIG. 47I, a CIGS film 32H is formed by the MBE method on the interlayer insulating film 2H and the lower electrodes 4H.

Thereafter, as shown in FIG. 47J, a cadmium sulfide film 33H is formed by the CBD method on the CIGS film 32H.

Further in succession, a zinc oxide film 34H is formed by the sputtering method on the cadmium sulfide film 33H as shown in FIG. 47K.

Then, as shown in FIG. 47L, a resist pattern 42H (see FIG. 48) is formed by photolithography on the zinc oxide film 34H. The resist pattern 42H opposes a portion of the CIGS film 32H that is to become the photoabsorption layer 5H. Then, using the resist pattern 42H as a mask, the zinc oxide film 34H and the cadmium sulfide film 33H are removed selectively by wet etching by hydrofluoric acid (HF). The wet etching is continued for a predetermined time even after the portion of the zinc oxide film 34H that does not oppose the resist pattern 42H has been removed. The zinc oxide film 34H is thereby removed from below a peripheral edge portion of the resist pattern 42H as well. Consequently, the zinc oxide film 34H and the cadmium sulfide film 33H become the transparent conductive film 7H and the high-resistance buffer layer 6H, respectively, and the curved side surface 53H of the transparent conductive film 7H is obtained.

Then, while leaving the resist pattern 42H, dry etching using the resist pattern 42H as a mask is performed to selectively remove the CIGS film 32H as shown in FIG. 47M. The CIGS film 32H is left only at the portion opposing the resist pattern 42H. The CIGS film 32H thereby becomes the photoabsorption layer 5H. Thereafter, the resist pattern 42H is removed.

Thereafter, as shown in FIG. 47N, the interlayer insulating film 10H is formed coveringly by the plasma CVD method on the portion of the interlayer insulating film 2H exposed from the photoabsorption layer 5H, on the peripheral edge portion of the photoabsorption layer 5H, on the transparent conductive film 7H, and on the protective film 9H.

Thereafter, a resist pattern having openings 43H (see FIG. 48) that selectively expose portions at which the via holes 11H and the pad opening 14H are to be formed is formed by photolithography on the interlayer insulating film 10H. By then performing dry etching using the resist pattern as a mask, the via holes 11H that penetrate through the interlayer insulating film 10H are formed as shown in FIG. 47O. Also, the pad opening 14H that penetrates continuously through the interlayer insulating film 10H and the protective film 9H is formed.

Thereafter, as shown in FIG. 47P, an aluminum film 35H made of aluminum is formed by the sputtering method on the interlayer insulating film 10H. The aluminum film 35H is also formed inside the via holes 11H and the pad opening 14H. The via holes 11H are completely filled with the aluminum film 35H.

Thereafter, a resist pattern 44H (see FIG. 48) that covers a portion that is to become the upper electrode 15H is formed by photolithography on the aluminum film 35H. The aluminum film 35H is then removed selectively by dry etching using the resist pattern as a mask, and the aluminum film 35H is thereby processed to the upper electrode 15H as shown in FIG. 47Q. Thereafter, as shown in FIG. 47R, the top surface protective film 17H is formed by the plasma CVD method, and when the opening 18H is formed by photolithography and etching as shown in FIG. 47S, the image sensor 1H shown in FIG. 46 is obtained.

As described above, with the image sensor 1H, the plurality of mutually-spaced lower electrodes 4H disposed on the interlayer insulating film 2H are covered all together by the photoabsorption layer 5H made of CIGS. That is, the photoabsorption layer 5H is not cut and divided according to each pixel, and thus as in the preferred embodiment according to the first aspect of the present invention, the variation of sensitivity among pixels is not influenced by damage due to dry etching.

Also, as in the preferred embodiment according to the first aspect of the present invention, the pixel aperture ratio (pn junction area/pixel area) can be made 100% because the photoabsorption layer 5H is not cut and divided according to each pixel. A large number of carriers can thereby be generated even with weak light and dramatic improvement of sensitivity can be achieved.

Further, a shrinkage cavity does not form during forming of the transparent conductive film 7H because grooves for cutting and dividing the photoabsorption layer 5H are not formed. Degradation with time of the transparent conductive film 7H can thus be prevented and reliability can be improved.

Also, a step of forming an isolation film is unnecessary and the manufacturing process is thus simpler than that of the conventional photoelectric converter and time and cost required for manufacture can be reduced.

Also, with the manufacturing method described above, the TEOS film 29H and the SiN film 30H are formed to cover the relay electrode 8H (FIG. 47E) before the dry etching of the CIGS film 32H (FIG. 47M). Then, after the processing of the TEOS film 29H and the SiN film 30H to the protective film 9H, the CIGS film 32H is dry etched to form the photoabsorption layer 5H in the state where the relay electrode 8H is covered by the protective film 9H. The relay electrode 8H is thus not exposed to the etching gas during the dry etching of the CIGS film 32H. Consequently, the relay electrode 8H, which is maintained in a satisfactory surface state, can be left on the interlayer insulating film 2H. Wire bonding strength can thus be improved.

Also, the protective film 9H includes the first protective film 91H and the second protective film 92H having etch selectivity with respect to the first protective film 91H, and in forming the first protective film 91H at the lower side, the TEOS film 29H is wet-etched using the second protective film 92H as the hard mask (FIG. 47G). The second protective film 92H (SiN), which is better in adhesion with respect to the TEOS film 29H than a resist mask, is used as the hard mask during the wet etching and thus the adhesion of the TEOS film 29H and the second protective film 92H can be improved. Thus, even during the wet etching of the TEOS film 29H, which is extremely large in area compared to the portion that is protected by the mask as described above, peeling of the mask due to the etching liquid can be suppressed. Consequently, the TEOS film 29H protected by the second protective film 92H can be processed to an ideal shape to form the first protective film 91H.

Also, when the removal of the TEOS film 29H is executed by dry etching, the top surfaces of the lower electrodes 4H may be damaged by the etching gas during the etching. However, by executing the removal by wet etching as described above, damaging of the lower electrodes 4H can be reduced. The top surface states of the lower electrode 4H can thus be maintained satisfactorily. Consequently, lowering of the reliability of the image sensor 1H can be suppressed.

Also, the protective film 9H that covers the relay electrode 8H is slightly etched by the etching gas used in the dry etching of the CIGS film 32H and made thinner than when it was formed. The difference between the thickness of the interlayer insulating film 10H that covers the transparent conductive film 7H and the total thickness of the protective film 9H and the interlayer insulating film 10H that cover the relay electrode 8H is thus comparatively small. The etching time necessary for forming the pad opening 14H is thus made substantially the same as the etching time necessary for forming the via holes 11H, with which there is no need to etch the protective film 9H. Consequently, damage of the transparent conductive film 7H due to etching during the forming of the via holes 11H and the pad opening 14H can be reduced. Lowering of reliability of the image sensor 1H can thus be suppressed.

Further, by the protective film 9H being made thinner than when it was formed, the total thickness of the protective film 9H and the interlayer insulating film 10H is decreased and thus the depth of the pad opening 14H can be decreased. The upper electrode 15H can thus be deposited with good coating property even at a step portion between the interior and the exterior of the pad opening 14H.

Also, the lower electrodes 4H, the relay electrode 8H, the first vias 21H, and the second vias 25H are all made of the same material and thus the lower electrodes 4H, the relay electrode 8H, the first vias 21H, and the second vias 25H can be formed in the same step. Thus, the step of polishing the deposition layer of the material of the vias by the CMP method and the step of forming the film made of the material of the lower electrodes by the sputtering method, which are deemed to be required in the manufacture of the conventional image sensor, can be omitted. The time and cost required for manufacture can be reduced thereby as well. Also, secure connection of the lower electrodes 4H and the second vias 25H and secure connection of the relay electrode 8H and the first vias 21H can be achieved, and the reliability of electrical connection of the lower electrodes 4H and the second vias 25H and the reliability of electrical connection of the relay electrode 8H and the first vias 21H can be improved.

Further, the barrier film 27H formed in the step of FIG. 47B has etch selectivity with respect to the TEOS film 29H, and the barrier film 27H can thus be used as the etching stopper film when wet etching of the TEOS film 29H is performed in the step of FIG. 47F. A step of forming an etching stopper film can thus be eliminated. Consequently, the time and cost required for manufacture can be reduced.

Also, in the manufacturing process of the image sensor 1H, the resist pattern 42H used in the wet etching for processing the zinc oxide film 34H to the transparent conductive film 7H is also used in the dry etching for processing the CIGS film 32H to the photoabsorption layer 5H and a mask (resist pattern) used exclusively for the dry etching is not formed. The manufacturing process of the image sensor 1H can thus be simplified.

Also, as shown in FIG. 47I to FIG. 47K, the CIGS film 32H, the cadmium sulfide film 33H, and the zinc oxide film 34H are formed consecutively. The time from the forming of the CIGS film 32H to the completion of forming of the zinc oxide film 34H can thus be made short, and the CIGS film 32H, the cadmium sulfide film 33H, and the zinc oxide film 34H can be respectively improved in film quality.

Further, the pad opening 14H and the via holes 11H are formed in the same step (step shown in FIG. 47O) and thus in comparison to a case where these are formed in separate steps, the number of masks required for forming these can be reduced and the manufacturing process of the image sensor 1H can be simplified.

Although the preferred embodiment of the eighth aspect of the present invention has been described above, the present preferred embodiment may also be changed as follows.

For example, a plurality (for example, three) of mutually-spaced relay electrodes 8H may be provided and the relay electrodes 8H may be electrically connected all together to the first wiring 19H. The upper electrode 15H can thereby be inserted between mutually adjacent relay electrodes 8H. The upper electrode 15H can thereby be put in contact not only with upper surfaces of the relay electrodes 8B but also side surfaces of the relay electrodes 8H. An area of contact of the relay electrodes 8H and the upper electrode 15H is thereby increased, and adhesion of the upper electrode 15H with the relay electrodes 8H can be improved.

### Preferred Embodiments According to a Ninth Aspect of the Invention FIG. 49 to FIG. 54

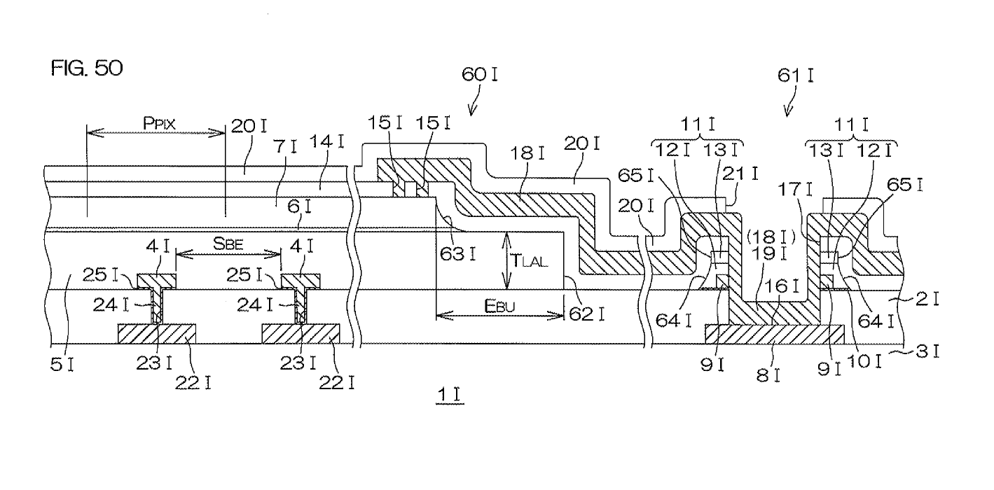

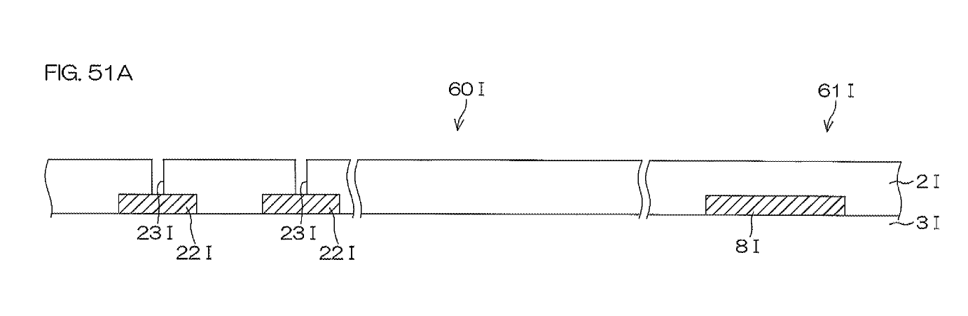

FIG. 49 is a schematic plan view of an image sensor according to a first preferred embodiment of a ninth aspect of the present invention. FIG. 50 is a schematic sectional view of the image sensor taken along sectioning line II-II in FIG. 49. In FIG. 50, only portions made of metal materials are hatched and portions besides these are not hatched.

The image sensor 1I, which is an example of a photoelectric converter, includes a semiconductor substrate (not shown) as a substrate thereof. A semiconductor device, such as a MISFET (metal insulator semiconductor field effect transistor), etc., is formed on the semiconductor substrate.

An interlayer insulating film 2I as an insulating layer and an interlayer insulating film 3I as a first interlayer insulating film are laminated on the semiconductor substrate. The interlayer insulating films 2I and 3I are made, for example, of silicon oxide (SiO₂).

Also, as shown in FIG. 49, a sensor forming region 60I and an annular pad forming region 61H surrounding it are set on the semiconductor substrate.

In the sensor forming region 60I, a plurality of lower electrodes 4I are arrayed in a matrix on the uppermost interlayer insulating film 2I. The lower electrodes 4I are made of tungsten (W). Each lower electrode 4I is formed to a square shape in a plan view. For example, in the case of 7.5 μm pitch, the length of one side of the lower electrode 4I in a plan view is no less than 2.0 μm and no more than 3.3 μm. The lower electrode 4I has a thickness of no less than 0.2 μm and no more than 0.4 μm. Also, as shown in FIG. 50, mutually adjacent lower electrodes 4I are spaced apart at equal intervals S_{BE} (≧T_{LAL}×3) each set to no less than three times the thickness T_{LAL} of a photoabsorption layer 5I to be described below.

The photoabsorption layer 5I of rectangular shape in a plan view is formed on the interlayer insulating film 2I so as to cover all of the lower electrodes 4I together. Specifically, the photoabsorption layer 5I is formed integrally on a rectangular region on the interlayer insulating film 2I in which the lower electrodes 4I are formed and on a rectangular annular region of fixed width at a periphery of the rectangular region. The photoabsorption layer 5I is made of CIGS and exhibits a p-type conductivity. The thickness T_{LAL} of the photoabsorption layer 5I is no less than 1.0 μm and no more than 1.4 μm. In the photoabsorption layer 5I, each region of fixed area and rectangular shape in a plan view that is centered at each lower electrode 4I is used for reading of a single pixel. The pixel pitch P_{PIX} that is the width of this region is no less than 5 μm and no more than 10 μm.

An upper surface of the photoabsorption layer 5I, with the exception of a peripheral edge portion thereof, is covered by a high-resistance buffer layer 6I. The high-resistance buffer layer 6I is made of cadmium sulfide (CdS). The high-resistance buffer layer 6I has a thickness, for example, of 0.05 μm.

On the high-resistance buffer layer 6I, a transparent conductive film 7I is formed so as to cover an entire upper surface of the high-resistance buffer layer 6I. The transparent conductive film 7I is made of zinc oxide (ZnO), which has a light transmitting property, and has conductivity imparted by addition of an n-type impurity (for example, Al₂O₃ (alumina)). The transparent conductive film 7I has a thickness, for example, of 0.6 μm.

A side surface 63I of the transparent conductive film 7I is formed to a cross-sectional shape that is downwardly (inwardly) concavely curved and inclined so that as its lower end is approached, a side surface 62I of the photoabsorption layer 5I is approached. A lower end of the side surface 63I is continuous with a peripheral edge of the high-resistance buffer layer 6I. An upper end of the side surface 63I is positioned inward with respect to the side surface 62I of the photoabsorption layer 5I by just a horizontal distance E_{BU}. The horizontal distance E_{BU} is no less than 5 μm and no more than 10 μm.

In the pad forming region 61I, a first wiring 8I is formed between the uppermost interlayer insulating film 2I and the interlayer insulating film 3I below it. The first wiring 8I is made of aluminum (Al).

On the uppermost interlayer insulating film 2I, a test electrode 9I used in an open/short test of the lower electrodes 4I is formed at a position opposing the first wiring 8I. The test electrode 9I is made electrically continuous with the lower electrodes 4I via a predetermined test pattern (TEG: test element group) and is made of the same material (tungsten) as the lower electrodes 4I. The test electrode 9I has a thickness of no less than 0.2 μm and no more than 0.4 μm. Also, a barrier film 10I is interposed between the test electrode 9I and the interlayer insulating film 2I. The barrier film 10I is made of titanium nitride (TiN).

Also, in the pad forming region 61I, a protective film 11I is formed on the test electrode 9I. The protective film 11I includes a first protective film 12I at a lower side and a second protective film 13I at an upper side.

The first protective film 12I is made of silicon oxide (SiO₂) and coats the entire surface of the test electrode 9I. Each side surface 641 of the first protective film 12I is formed to a cross-sectional shape that is curved so as to be downwardly (inwardly) concave as its lower end is approached. The first protective film 12I has a thickness of approximately 2000 Å.

The second protective film 13I is formed of silicon nitride (SiN) and is formed on the first protective film 12I. Each side surface 65I of the second protective film 13I is formed to a planar shape perpendicular to the top surface of the interlayer insulating film 2I and a lower end thereof is continuous with an upper end of the side surface 641 of the first protective film 12I. The second protective film 13I has a thickness of approximately 2000 Å (the same as the thickness of the first protective film 12I).

An interlayer insulating film 14I is formed as a second interlayer insulating film on a portion of the interlayer insulating film 2I exposed from the photoabsorption layer 5I, on a peripheral edge portion of the photoabsorption layer 5I, on the transparent conductive film 7I, and on the protective film 11I so as to spread across these portions. The interlayer insulating film 14I is made of silicon nitride (SiN). The interlayer insulating film 14I has a thickness, for example, of 0.4 μm. Above a peripheral edge portion of the transparent conductive film 7I, a plurality of via holes 15I are penetratingly formed in the interlayer insulating film 14I. The via holes 15I form, for example, two columns and are mutually spaced and disposed along the peripheral edge of the transparent conductive film 7I.

Also, in the pad forming region 61I, a pad opening 17I of substantially square shape in a plan view that exposes a portion of the first wiring 8I as a pad 16I, is formed at a position opposing the first wiring 8I. The pad opening 17I penetrates continuously through the interlayer insulating film 14I, the second protective film 13I, the first protective film 12I, the test electrode 9I, and the interlayer insulating film 2I in the thickness direction. The interlayer insulating film 2I, the test electrode 9I, the first protective film 12I, and the second protective film 13I are thereby exposed at side surfaces of the pad opening 17I. The test electrode 9I with the pad opening 17I formed therein has a rectangular annular shape surrounding the pad opening 17I in a plan view. The pad opening 17I has a depth of no less than 10000 Å and no more than 20000 Å.

On the interlayer insulating film 14I, an upper electrode 18I is formed so as to cover entire peripheries of peripheral edge portions of the photoabsorption layer 5I and the transparent conductive film 7I. The upper electrode 18I is made of aluminum (Al). An extending portion 19I, extending toward the pad forming region 61I, is formed integral to the upper electrode 18I. An end portion of the extending portion 19I enters inside the pad opening 17I and is connected to the pad 16I inside the pad opening 17I.

Also, a top surface protective film 20I is formed on a topmost surface of the image sensor 1I. The top surface protective film 20I is made, for example, of silicon nitride. In the top surface protective film 20I, an opening 21I for exposing the portion of the extending portion 19I of the upper electrode 18I that enters into the pad opening 17I is formed at a position opposing the pad opening 17I.

Also, in the sensor forming region 60I and between the uppermost interlayer insulating film 2I and the interlayer insulating film 3I below it, second wirings 22I are formed at positions opposing the respective lower electrodes 4I. A via hole 23I is formed penetratingly through the interlayer insulating film 2I between each lower electrode 4I and the opposing second wiring 22I in the direction in which these oppose each other (thickness direction of the interlayer insulating film 2I). In each via hole 23I, a via 24I, made of the same material as the lower electrode 4I, is formed integral to the lower electrode 4I and without any gaps. Each lower electrode 4I is thereby electrically connected to the opposing second wiring 22I via the via 24I. Each via hole 23I has an inner diameter of, for example, 0.4 μm.

Also, a barrier film 25I is interposed between each lower electrode 4I plus the via 24I and the interlayer insulating film 2I. The barrier films 25I are made of titanium nitride (TiN). Each lower electrode 4I is electrically connected to the opposing second wiring 22I via the vias 24I and the barrier film 25I.

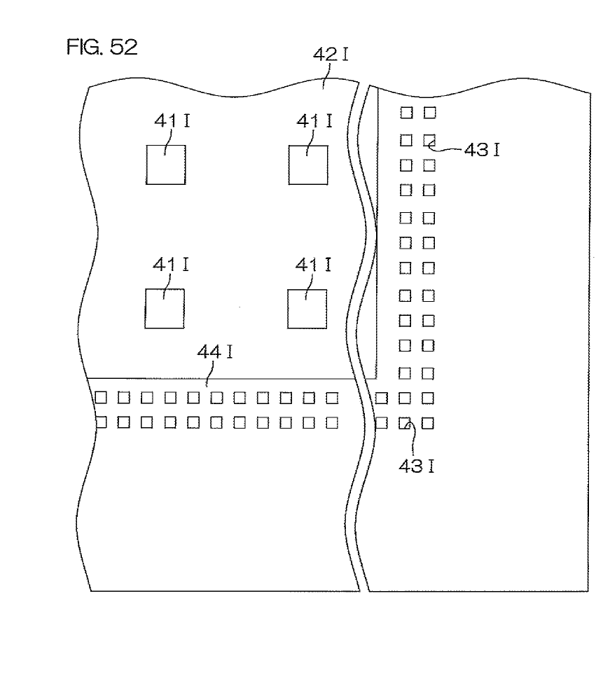

FIG. 51A to FIG. 51S are schematic sectional views that successively illustrate a manufacturing process of the image sensor shown in FIG. 50. FIG. 52 is a diagram for describing resist patterns used in the manufacturing process. In FIG. 51A to FIG. 51S, only portions made of metal materials are hatched and portions besides these are not hatched.

In the manufacturing process of the image sensor 1I, first, as shown in FIG. 51A, the interlayer insulating film 3I, the first wiring 8I plus the second wirings 22I, and the interlayer insulating film 2I are formed in that order on the semiconductor substrate (not shown). The via holes 23I penetrating through the interlayer insulating film 2I are then formed above the second wirings 22I, respectively, by photolithography and etching.

Thereafter, as shown in FIG. 51B, a barrier film 26I is formed on the interlayer insulating film 2I by the sputtering method. The barrier film 26I is made of a material (for example, titanium nitride) having etch selectivity with respect to a TEOS film 28I (to be described below). The barrier film 26I is also formed inside the via holes 23I. Thereafter, tungsten, which is the material of the lower electrodes 4I, the test electrode 9I, and the vias 24I, is deposited by the CVD method inside the via holes 23I and on the interlayer insulating film 2I to form a tungsten deposition layer 27I. A thickness of the tungsten deposition layer 27I on the interlayer insulating film 2I is 0.2 to 0.4 μm (2000 to 4000 Å).

Thereafter, as shown in FIG. 51C, a resist pattern 41I (see FIG. 52; in FIG. 52, a portion covering the test electrode 9I is omitted) that selectively covers only portions that become the lower electrodes 4I and a portion that becomes the test electrode 9I is formed by photolithography on the tungsten deposition layer 27I.

Then, as shown in FIG. 51D, portions of the tungsten deposition layer 27I exposed from the resist pattern 41I are removed by dry etching using the resist pattern 41I as a mask. The mixed gas of sulfur hexafluoride (SF₆) and argon (Ar) is used for the dry etching. The vias 24I embedded in the via holes 23I, the lower electrodes 4I, and the test electrode 9I are thereby obtained at the same time.

After the dry etching, the resist pattern 41I is removed as shown in FIG. 51E. Thereafter, by the CVD (chemical vapor deposition) method using TEOS, the TEOS film 28I is formed on the interlayer insulating film 2I so as to cover the lower electrodes 4I and the test electrode 9I all together. An SiN film 29I is then laminated on the TEOS film 28I by the plasma CVD method.

Thereafter, as shown in FIG. 51F, a resist pattern 45I is formed to selectively cover only a portion that becomes the second protective film 13I. By then performing dry etching using the resist pattern 45I as a mask, the portion of the SiN film 29I that is exposed from the resist pattern 45I is anisotropically etched and removed. For the dry etching, a gas, with which a selectivity ratio of the SiN film 29I and the TEOS film 28I (SiN film 29I/TEOS film 28I) is, for example, no less than 2, is used, and specifically a gas, such as CF₄+O₂ (mixed gas of tetrafluoromethane and oxygen), etc., is used. The SiN film 29I thereby becomes the second protective film 13I, and the side surfaces 65I of planar shape of the second protective film 13I are obtained.

After the dry etching, the resist pattern 45I is removed as shown in FIG. 51G. Thereafter, by wet etching using the second protective film 13I as an etching mask (hard mask), a portion of the TEOS film 28I that is exposed from the second protective film 13I is isotropically etched and removed. Hydrofluoric acid (HF) is used for the wet etching. Here, the barrier film 26I is formed on the interlayer insulating film 2I, and the barrier film 26I acts as an etching stopper film and contact of the etching liquid (hydrofluoric acid) with the interlayer insulating film 2I is prevented. The TEOS film 28I thereby becomes the first protective film 12I that exposes the lower electrodes 4I and covers the test electrode 9I and the curved side surfaces 641 of the first protective film 12I are obtained.

Thereafter, as shown in FIG. 51H, portions of the barrier film 26I exposed from the lower electrodes 4I and the protective film 11I are removed by dry etching (etch back). The chlorine (Cl₂) based gas is used for the dry etching. The barrier film 26I thereby becomes the barrier films 25I that prevent contact of the lower electrodes 4I plus the vias 24I with the interlayer insulating film 2I and the barrier film 10I that prevents contact of the test electrode 9I with the interlayer insulating film 2I.

Thereafter, as shown in FIG. 51I, a CIGS film 32I is formed as a photoabsorption material layer by the MBE method on the interlayer insulating film 2I and the lower electrodes 4I.

Thereafter, as shown in FIG. 51J, a cadmium sulfide film 33I is formed by the CBD method on the CIGS film 32I.

Further in succession, a zinc oxide film 34I is formed as a transparent conductive material film by the sputtering method on the cadmium sulfide film 33I as shown in FIG. 51K.

Then, as shown in FIG. 51L, a resist pattern 42I (see FIG. 52) is formed by photolithography on the zinc oxide film 34I. The resist pattern 42I opposes a portion of the CIGS film 32I that is to become the photoabsorption layer M. Then, using the resist pattern 42I as a mask, the zinc oxide film 34I and the cadmium sulfide film 33I are removed selectively by wet etching by hydrofluoric acid (HF). The wet etching is continued for a predetermined time even after the portion of the zinc oxide film 34I that does not oppose the resist pattern 42I has been removed. The zinc oxide film 34I is thereby removed from below a peripheral edge portion of the resist pattern 42I as well. Consequently, the zinc oxide film 34I and the cadmium sulfide film 33I become the transparent conductive film 7I and the high-resistance buffer layer 6I, respectively, and the curved side surface 63I of the transparent conductive film 7I is obtained.

Then, while leaving the resist pattern 42I, dry etching using the resist pattern 42I as a mask is performed to selectively remove the CIGS film 32I as shown in FIG. 51M. The CIGS film 32I is left only at the portion opposing the resist pattern 42I. The CIGS film 32I thereby becomes the photoabsorption layer M. Thereafter, the resist pattern 42I is removed.

Thereafter, as shown in FIG. 51N, the interlayer insulating film 14I is formed coveringly by the plasma CVD method on the portion of the interlayer insulating film 2I exposed from the photoabsorption layer 5I, on the peripheral edge portion of the photoabsorption layer 5I, on the transparent conductive film 7I, and on the protective film 11I.

A resist pattern having openings 43I (see FIG. 52) that selectively expose portions at which the via holes 15I and the pad opening 17I are to be formed is formed by photolithography on the interlayer insulating film 14I. By then performing dry etching using the resist pattern as a mask, the via holes 15I that penetrate through the interlayer insulating film 14I are formed as shown in FIG. 51O. Also, the pad opening 17I that penetrates continuously through the interlayer insulating film 14I, the second protective film 13I, the first protective film 12I, the test electrode 9I, and the interlayer insulating film 2I is formed.

Thereafter, as shown in FIG. 51P, an aluminum film 35I made of aluminum is formed by the sputtering method on the interlayer insulating film 14I. The aluminum film 35I is also formed inside the via holes 15I and the pad opening 17I. The via holes 151 are completely filled with the aluminum film 35I.

A resist pattern 44I (see FIG. 52) that covers a portion that is to become the upper electrode 18I is formed by photolithography on the aluminum film 35I. The aluminum film 35I is then removed selectively by dry etching using the resist pattern 44I as a mask, and the aluminum film 35I is thereby processed to the upper electrode 18I as shown in FIG. 51Q. Thereafter, as shown in FIG. 51R, the top surface protective film 20I is formed by the plasma CVD method, and when the opening 21I is formed by photolithography and etching as shown in FIG. 51S, the image sensor 1I shown in FIG. 50 is obtained.

As described above, with the present manufacturing method, the test electrode 9I for the open/short test of the lower electrodes 4I is exposed inside the pad opening 17I in the middle of manufacture of the image sensor 1I (step of FIG. 51O). Thus, by voltage application to the exposed test electrode 9I, a voltage can be applied to the lower electrodes 4I via the TEG or other test pattern between the test electrode 9I and the lower electrodes 4I. Consequently, insulation states of the lower electrodes 4I can be measured in the middle of manufacture of the image sensor 1I.

That is, a voltage does not have to be applied to the upper electrode 18I to measure the insulation states of the lower electrodes 4I and thus the insulation states of the lower electrodes 4I can be measured before completion (in the middle of manufacture) of the image sensor 1I for elimination of defective products at an early stage.

Also, the electrical connection of the upper electrode 18I and the pad 16I is formed not via the test electrode 9I but is formed by the upper electrode 18I directly contacting the pad 16I exposed at the pad opening 17I (FIG. 50). During the dry etching of the CIGS film 32I (step of FIG. 51M), the first wiring 8I used as the pad 16I is covered by the interlayer insulating film 2I, the test electrode 9I, and the protective film 11I (the first protective film 2I and the second protective film 13I) and is thus not exposed to the etching gas. A state of an upper surface of the first wiring 8I that is exposed as the pad 16I inside the pad opening 17I is thus maintained in a satisfactory state even after the dry etching. The upper electrode 18I can thus be connected to the pad 16I with good adhesion inside the pad opening 17I. Consequently, satisfactory reliability of electrical connection of the upper electrode 18I and the pad 16I can be maintained.

Also, the protective film 11I that coats the test electrode 9I is formed in steps (steps of FIG. 51E to FIG. 51G) executed before the step (step of FIG. 51M) of forming the photoabsorption layer 5I by dry etching. Thus, in the step of FIG. 51M, the CIGS film 32I is dry etched in the state where the test electrode 9I is covered by the protective film 11I. The test electrode 9I is thus not exposed to the etching gas during the dry etching of the CIGS film 32I. Consequently, damaging of the test electrode 9I by the etching gas can be reduced and loss of the test electrode 9I can be prevented. The test electrode 9I can thus be formed reliably.

Also, the protective film 11I includes the first protective film 12I and the second protective film 13I having etch selectivity with respect to the first protective film 12I, and in forming the first protective film 12I at the lower side, the TEOS film 28I is wet-etched using the second protective film 13I as the hard mask (step of FIG. 51G). The second protective film 13I (SiN), which is better in adhesion to the TEOS film 28I than a resist mask, is used as the hard mask during the wet etching and thus the adhesion of the TEOS film 28I and the mask can be improved. Thus, even during the wet etching of the TEOS film 28I, which is extremely large in area compared to the portion that is protected by the mask as described above, peeling of the mask due to the etching liquid can be suppressed. Consequently, the TEOS film 28I protected by the second protective film 13I can be processed to an ideal shape to form the first protective film 12I.

Also, if removal of the TEOS film 28I by dry etching is executed, the top surfaces of the lower electrodes 4I may be damaged by the etching gas during the etching. However, by executing wet etching as described above, damaging of the lower electrodes 4I can be reduced. The top surface states of the lower electrode 4I can thus be maintained satisfactorily. Consequently, lowering of the reliability of the image sensor 1I can be suppressed.

Also, the lower electrodes 4I, the test electrode 9I, and the vias 24I are all made of the same material and thus the lower electrodes 4I, the test electrode 9I, and the vias 24I can be formed in the same step. Thus, the step of polishing the deposition layer of the material of the vias by the CMP method and the step of forming the film made of the material of the lower electrodes by the sputtering method, which are deemed to be required in the manufacture of the conventional image sensor, can be omitted. The time and cost required for manufacture can be reduced thereby as well. Also, secure connection of the lower electrodes 4I and the vias 24I can be achieved, and the reliability of electrical connection of the lower electrodes 4I and the vias 24I can be improved.

Also, with the image sensor 1I, the plurality of mutually-spaced lower electrodes 4I disposed on the interlayer insulating film 2I are covered all together by the photoabsorption layer 5I made of CIGS. That is, the photoabsorption layer 5I is not cut and divided according to each pixel, and thus as in the preferred embodiment according to the first aspect of the present invention, there is no variation of sensitivity among pixels.

Also, as in the preferred embodiment according to the first aspect of the present invention, the pixel aperture ratio (pn junction area/pixel area) can be made 100% because the photoabsorption layer 5I is not cut and divided according to each pixel. A large number of carriers can thereby be generated even with weak light and dramatic improvement of sensitivity can be achieved.

Further, a shrinkage cavity does not form during forming of the transparent conductive film 7I because grooves for cutting and dividing the photoabsorption layer 5I are not formed. Degradation with time of the transparent conductive film 7I can thus be prevented and reliability can be improved.

Also, a step of forming an isolation film is unnecessary and the manufacturing process is thus simpler than that of the conventional photoelectric converter and time and cost required for manufacture can be reduced.

Also, in the manufacturing process of the image sensor 1I, the resist pattern 42I used in the wet etching for processing the zinc oxide film 34I to the transparent conductive film 7I is also used in the dry etching for processing the CIGS film 32I to the photoabsorption layer 5I and a mask (resist pattern) used exclusively for the dry etching is not formed. The manufacturing process of the image sensor 1I can thus be simplified.

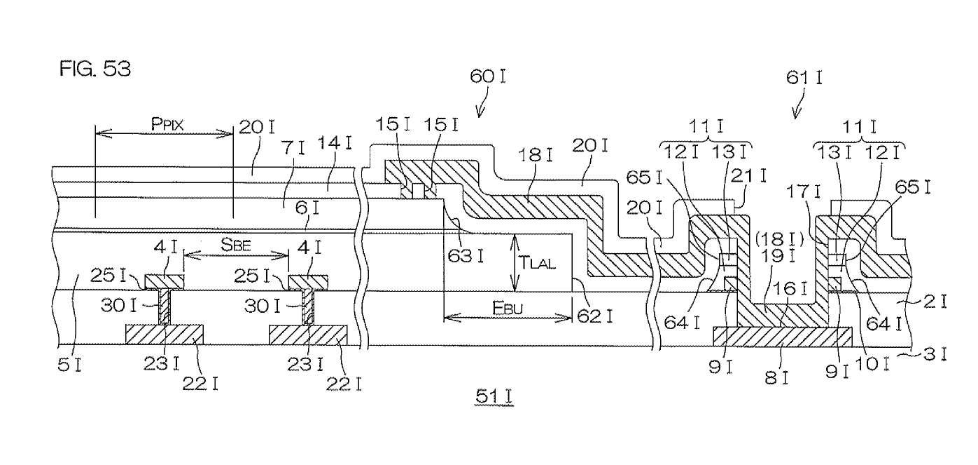

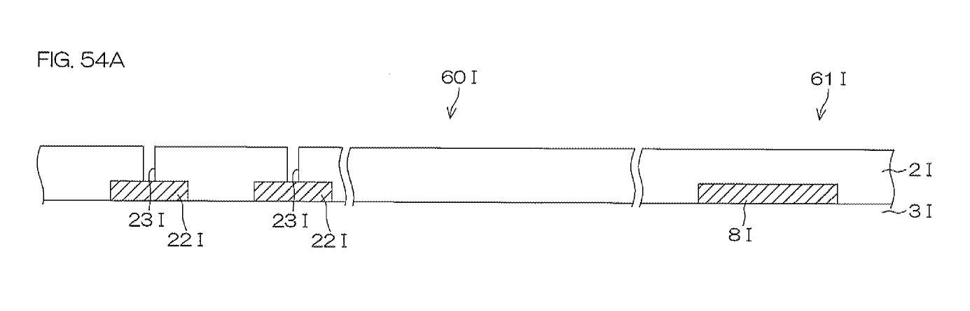

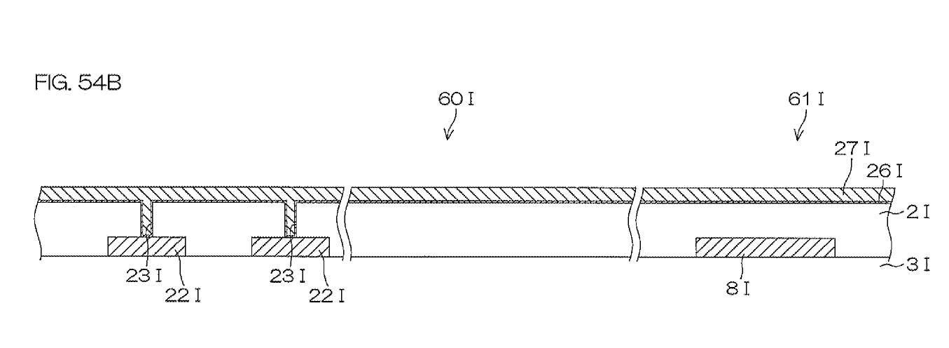

FIG. 53 is a schematic sectional view of an image sensor according to a second preferred embodiment of the ninth aspect of the present invention. In FIG. 53, portions corresponding to respective portions shown in FIG. 49 and FIG. 50 are provided with the same reference symbols. Also, in the following description, detailed description of portions provided with the same reference symbols shall be omitted.

Whereas in the first preferred embodiment, the lower electrodes 4I, the test electrode 9I, and the vias 24I are made of the same material (tungsten), in the image sensor 51I according to the second preferred embodiment, the lower electrodes 4I and the test electrode 9I are made of the same material (molybdenum) and vias 30I connecting the respective lower electrodes 4I and the second wirings 22I are made of a material (tungsten) that differs from that of the lower electrodes 4I and the test electrode 9I.

Besides the above, the arrangement is the same as that of the first preferred embodiment.

FIG. 54A to FIG. 54T are schematic sectional views that successively illustrate a manufacturing process of the image sensor shown in FIG. 53.

As shown in FIGS. 54A and 54B, in the manufacturing process of the image sensor 51I, tungsten, which is the material of the vias 30I, is deposited inside the via holes 23I and on the interlayer insulating film 2I to form the tungsten deposition layer 27I by the same steps as those of FIG. 51A and FIG. 51B being executed in the same order.

Thereafter, the tungsten deposition layer 27I is polished by the CMP (chemical mechanical polishing) method. The polishing of the tungsten deposition layer 27I is continued until a top surface of the barrier film 26I is exposed. The vias 30I that are embedded in the via holes 23I are thereby obtained as shown in FIG. 51C.

After the forming of the vias 30I, molybdenum, which is the material of the lower electrodes 4I and the test electrode 9I, is deposited by the sputtering method on the interlayer insulating film 2I to form a molybdenum deposition layer 31I as shown in FIG. 54D. The resist pattern 41I (see FIG. 52; in FIG. 52, a portion covering the test electrode 9I is omitted) that selectively covers only the portions that become lower electrodes 4I and the portion that becomes the test electrode 9I is then formed by photolithography on the molybdenum deposition layer 31I.

Thereafter, by the same steps as those of FIG. 51D to FIG. 51S being executed in the same order as shown in FIG. 54E to 54T, the lower electrodes 4I plus the test electrode 9I, the protective film 11I (the first protective film 12I plus the second protective film 13I), the photoabsorption layer 5I, the high-resistance buffer layer 6I, the transparent conductive film 7I, the interlayer insulating film 14I, the pad opening 17I, the upper electrode 18I, etc., are formed in that order. Thereafter, the top surface protective film 20I is formed, and when the opening 21I is formed by photolithography and etching, the image sensor 51I shown in FIG. 53 is obtained.

With the image sensor 51I, the lower electrodes 4I and the test electrode 9I are formed of molybdenum and thus in comparison to the case where tungsten is used, material costs of these components can be reduced.

On the other hand, molybdenum is not high in adhesion to aluminum, which is the material of the upper electrode 18I, and in a case where the test electrode 9I made of molybdenum is put in contact with the upper electrode 18I to form electrical connection of the upper electrode 18I and the pad 16I, the connection reliability may decrease. However, with the image sensor 51I, the upper electrode 18I that is made of aluminum is directly contacted with the pad 16I that is made of aluminum and exposed at the pad opening 17I and thus the reliability of electrical connection of the upper electrode 18I and the pad 16I is not lowered.

Other actions and effects of the image sensor 51I according to the second preferred embodiment are the same as the actions and effects of the image sensor 1I (first preferred embodiment) and thus description thereof shall be omitted.

### Preferred Embodiments According to a Tenth Aspect of the Invention FIG. 55 to FIG. 59

FIG. 55 is a schematic plan view of an image sensor according to a first preferred embodiment of a tenth aspect of the present invention. FIG. 56 is a schematic sectional view of the image sensor taken along sectioning line II-II in FIG. 55. In FIG. 56, only portions made of metal materials are hatched and portions besides these are not hatched.

The image sensor 1J, which is an example of a photoelectric converter, includes a semiconductor substrate 2J. The semiconductor substrate 2J is made, for example, of silicon (Si) or silicon carbide (SiC). A semiconductor device, such as a MISFET (metal insulator semiconductor field effect transistor), etc., is formed on the semiconductor substrate 2J.

Interlayer insulating films 3J to 6J are laminated on the semiconductor substrate 2J. The interlayer insulating films 3J to 6J are made, for example, of silicon oxide (SiO₂).

Also, as shown in FIG. 55, a sensor forming region 60J and an annular pad forming region 61J surrounding it are set on the semiconductor substrate 2J.

In the sensor forming region 60J, a plurality of lower electrodes 7J are arrayed in a matrix on the uppermost interlayer insulating film 3J. The lower electrodes 7J are made of tungsten (W). Each lower electrode 7J is formed to a square shape in a plan view. Mutually adjacent lower electrodes 7J are spaced at equal intervals.

A photoabsorption layer 8J of rectangular shape in a plan view is formed on the interlayer insulating film 3J so as to cover all of the lower electrodes 7J together. The photoabsorption layer 8J is made of CIGS (Cu(In,Ga)Se₂) and exhibits a p-type conductivity. In the photoabsorption layer 8J, each region of fixed area and rectangular shape in a plan view that is centered at each lower electrode 7J is used for reading of a single pixel.

An upper surface and side surfaces of the photoabsorption layer 8J are covered by a high-resistance buffer layer 9J. The high-resistance buffer layer 9J is made of cadmium sulfide (CdS).

On the high-resistance buffer layer 9J, a transparent conductive film 10J is formed so as to cover the high-resistance buffer layer 9J. The transparent conductive film 10J wraps around from an upper surface to side surfaces of the high-resistance buffer layer 9J to coat the entire upper surface and side surfaces of the high-resistance buffer layer 9J and a peripheral edge portion thereof contacts a top surface of the interlayer insulating film 3J. The transparent conductive film 10J is made of zinc oxide (ZnO), which has a light transmitting property, and has a laminated structure of i-type ZnO of high resistance without any impurity added and ZnO with conductivity imparted by addition of an n-type impurity (a laminated structure of iZnO/nZnO from the photoabsorption layer 8J side).

Between the uppermost interlayer insulating film 3J and the interlayer insulating film 3J below it, wirings 11J are formed at positions opposing the respective lower electrodes 7J. A via hole 12J is formed penetratingly in the interlayer insulating film 3J between each lower electrode 7J and the opposing wiring 11J and in a direction in which these oppose each other (thickness direction of the interlayer insulating film 3J). In the via hole 12J, a via 13J made of the same material as the lower electrode 7J is formed integral to the lower electrode 7J and without any gaps. Each lower electrode 7J is thereby electrically connected to the opposing wiring 11J by the via 13J.

Between the interlayer insulating film 4J and the interlayer insulating film 5J below it, capacitor upper electrodes 14J are formed at positions opposing the respective wirings 11J. Each wiring 11J and the opposing capacitor upper electrode 14J are electrically connected by a via 15J that penetrates through the interlayer insulating film 4J. The vias 15J are made of tungsten.

Between the interlayer insulating film 5J and the interlayer insulating film 6J below it, a capacitor lower electrode 16J is formed to oppose all of the capacitor upper electrodes 14J together. A capacitive element (MIM capacitor) having an MIM (metal-insulator-metal) structure, in which the interlayer insulating film 5J is sandwiched as a capacitive film between the capacitor upper electrode 14J and the capacitor lower electrode 16J, is thereby formed according to each pixel. The lower electrode 7J and the capacitor upper electrode 14J of the MIM capacitor are electrically connected according to each pixel.

In the pad forming region 61J, a plurality of pad wirings 17J are formed in a mutually spaced manner between the uppermost interlayer insulating film 3J and the interlayer insulating film 4J below it. As shown in FIG. 55, the plurality of pad wirings 17J include a single upper electrode pad wiring 70J and the remaining pad wirings 17J are semiconductor device pad wirings 71J that are electrically connected to the semiconductor device formed on the semiconductor substrate 2J. The wirings 11J and 14J and the pad wirings 17J are made of the same material and are made, for example, of a metal material that includes aluminum (Al).

Openings 18J, each exposing a portion of a pad wiring 17J, are formed in the interlayer insulating film 3J. An upper electrode 19J is disposed on the uppermost interlayer insulating film 3J. One end of the upper electrode 19J is disposed on a peripheral edge portion of the transparent conductive film 10J and extends toward the upper electrode pad wiring 70J, and another end enters inside the opening 18J and is connected to the upper electrode pad wiring 70J.

Also, openings (not shown), each exposing a portion of a semiconductor device pad wiring 71J, are formed in the interlayer insulating film 3J. A pad electrode 20J is formed on a portion of each semiconductor device pad wiring 71J that is exposed via the opening as shown in FIG. 55. A peripheral edge portion of each pad electrode 20J rides on the uppermost interlayer insulating film 3J. The upper electrode 19J and the pad electrodes 20J are made of a metal material that includes aluminum.

A top surface protective film 21J is formed on a topmost surface of the image sensor 1J. The top surface protective film 21J is made, for example, of silicon nitride (SiN). Pad openings 24J and 25J, for exposing the upper electrode 19J and the pad electrodes 20J as bonding pads 22J and 23J, are formed in the top surface protective film 21J. Wires (not shown) for electrical connection with leads, etc., are bonded to the bonding pads 22J and 23J.

FIG. 57A to FIG. 57L are schematic sectional views that successively illustrate a manufacturing process of the image sensor shown in FIG. 56. In FIG. 57A to FIG. 57L, only portions made of metal materials are hatched and portions besides these are not hatched.

In the manufacturing process of the image sensor 1J, first, as shown in FIG. 57A, the interlayer insulating film 6J, the capacitor lower electrode 16J, the interlayer insulating film 5J, the capacitor upper electrodes 14J, the interlayer insulating film 4J, and the vias 15J are formed in that order on the semiconductor substrate 2J. The wirings 11J and the pad wirings 17J are then formed on the interlayer insulating film 4J. Thereafter, the interlayer insulating film 3J is formed and the via holes 12J penetrating through the interlayer insulating film 3J are formed above the respective wirings 11J by photolithography and etching.

Thereafter, as shown in FIG. 57B, tungsten, which is the material of the lower electrodes 7J and the vias 13J, is deposited by the CVD (chemical vapor deposition) method inside the via holes 12J and on the interlayer insulating film 3J to form a tungsten deposition layer 31J.

Thereafter, as shown in FIG. 57C, a resist pattern 41J that selectively covers only portions that become the lower electrodes 7J is formed by photolithography on the tungsten deposition layer 31J.

Then, as shown in FIG. 57D, portions of the tungsten deposition layer 31J exposed from the resist pattern 41J are removed by dry etching using the resist pattern 41J as a mask. The mixed gas of sulfur hexafluoride (SF₆) and argon (Ar) is used for the dry etching.

After the dry etching, the resist pattern 41J is removed as shown in FIG. 57E. The lower electrodes 7J and the vias 13J embedded in the via holes 12J are thereby obtained.

Thereafter, as shown in FIG. 57F, a CIGS film 32J is formed by the MBE (molecular beam epitaxy) method on the interlayer insulating film 3J and the lower electrodes 7J.

Thereafter, a resist pattern (not shown) that selectively covers only a portion that is to become the photoabsorption layer 8J is formed by photolithography on the CIGS film 32J. By then performing dry etching using the resist pattern as a mask, the photoabsorption layer 8J that covers all of the lower electrodes 7J together is obtained as shown in FIG. 57G. Thereafter, the resist pattern is removed.

Thereafter, as shown in FIG. 57H, the high-resistance buffer layer 9J is formed by the CBD (chemical bath deposition) method on the upper surface and side surfaces of the photoabsorption layer 8J.

Thereafter, a zinc oxide film 33J is formed by the sputtering method on the upper surface and side surfaces of the high-resistance buffer layer 9J and on the interlayer insulating film 3J at the periphery as shown in FIG. 57I.

Thereafter, a resist pattern (not shown) that selectively covers a portion that is to become the transparent conductive film 10J is formed by photolithography on the zinc oxide film 33J. The zinc oxide film 33J is then processed to the transparent conductive film 10J by dry etching using the resist pattern as a mask as shown in FIG. 57J. The resist pattern is thereafter removed.

Thereafter, a resist pattern (not shown) that selectively exposes portions at which the openings 18J are to be formed is formed by photolithography on the interlayer insulating film 3J. The openings 18J penetrating through the interlayer insulating film 3J are then formed by dry etching using the resist pattern as a mask as shown in FIG. 57K.

Thereafter, a metal film (not shown) made of a metal material that includes aluminum is formed by the sputtering method on the interlayer insulating film 3J and the transparent conductive film 10J. The metal film is also formed inside the openings 18J. Thereafter, a resist pattern (not shown) that covers portions that are to become the upper electrode 19J and the pad electrodes 20J is formed by photolithography on the metal film. The metal film is then removed selectively by dry etching using the resist pattern as a mask, and the metal film is thereby processed to the upper electrode 19J and the pad electrodes 20J as shown in FIG. 57L.

Thereafter, the top surface protective film 21J is formed by the plasma CVD method, and when the pad openings 24J and 25J are formed by photolithography and etching, the image sensor 1J shown in FIG. 56 is obtained.

As described above, with the image sensor 1J, the plurality of lower electrodes 7J are disposed on the uppermost interlayer insulating film 3J. The lower electrodes 7J are covered all together by the photoabsorption layer 8J. The transparent conductive film 10J is formed on the photoabsorption layer 8J. The transparent conductive film 10J is connected to the upper electrode 19J. Also, the upper electrode pad wiring 70J is formed between the uppermost interlayer insulating film 3J and the interlayer insulating film 4J below it. In the pad forming region 61J, outside the region in which the photoabsorption layer 8J is formed, the opening 18J that exposes a portion of the upper electrode pad wiring 70J is formed penetratingly in the thickness direction in the interlayer insulating film 3J. The upper electrode 19J enters inside the opening 18J and is connected to the upper electrode pad wiring 70J inside the opening 18J. That is, a pad electrode for relaying the upper electrode 19J and the upper electrode pad wiring 70J is not provided on the interlayer insulating film 3J but the upper electrode 19J is directly connected to the upper electrode pad wiring 70J inside the opening 18J that penetrates through the interlayer insulating film 3J.

If the CIGS film 32J made of the material of the photoabsorption layer 8J is formed on the interlayer insulating film 3J and patterned to the photoabsorption layer 8J by dry etching and the openings 18J are thereafter formed in the interlayer insulating film 3J, the upper electrode pad wiring 70J will be covered by the interlayer insulating film 3J during the dry etching of the CIGS film 32J. The top surface of the upper electrode pad wiring 70J can thereby be prevented from being exposed to the etching gas and damaging of the top surface of the upper electrode pad wiring 70J can be prevented during the dry etching of the CIGS film 32J. Consequently, the top surface of the upper electrode pad wiring 70J is maintained in a satisfactory state and satisfactory electrical connection of the upper electrode 19J and the upper electrode pad wiring 70J can be achieved.

Also, the transparent conductive film 10J is formed to cover the plurality of lower electrodes 7J all together. That is, the transparent conductive film 10J is not cut and divided according to each pixel but is provided in common to the plurality of pixels. Thus, in comparison to an arrangement in which the transparent conductive film 10J is provided according to each pixel, the number of the transparent conductive film 10J can be lessened and a structure for supplying electricity to the transparent conductive film 10J can be simplified.

Also, the photoabsorption layer 8J is formed to cover the plurality of lower electrodes 7J all together. That is, the photoabsorption layer 8J is provided in common to the plurality of the pixels. Variation of sensitivity among the pixels is thus small. Also, grooves for cutting and dividing the photoabsorption layer 8J are not formed and an isolation film for isolating the photoabsorption layer 8J according to each pixel is not provided because the photoabsorption layer 8J is not cut and divided according to each pixel. The pixel aperture ratio (pn junction area/pixel area) is thus 100%. A large number of carriers can thereby be generated even with weak light and dramatic improvement of sensitivity can be achieved. Further, a shrinkage cavity does not form during forming of the transparent conductive film 10J because grooves for cutting and dividing the photoabsorption layer 8J are not formed. Degradation with time of the transparent conductive film 10J can thus be prevented and reliability can be improved. Also, a step of forming an isolation film is unnecessary and the manufacturing process is thus simpler than that of the conventional image sensor and time and cost required for manufacture can be reduced.

Also, with the present preferred embodiment according to the tenth aspect, the photoabsorption layer does not have to be formed to cover all of the lower electrodes together and may instead be formed in plurality to cover the respective lower electrodes individually. This mode shall now be described below by way of a second preferred embodiment.

FIG. 58 is a schematic sectional view of an image sensor according to the second preferred embodiment of the tenth aspect of the present invention. In FIG. 58, only portions made of metal materials are hatched and portions besides these are not hatched.

The image sensor 101J shown in FIG. 58 includes a semiconductor substrate 102J. The semiconductor substrate 102J is made, for example, of silicon (Si) or silicon carbide (SiC). A semiconductor device, such as a MISFET (not shown), is formed on the semiconductor substrate 102J.

Interlayer insulating films 103J to 106J are laminated on the semiconductor substrate 102J. The interlayer insulating films 103J to 106J are made, for example, of silicon oxide (SiO₂).

Also, in the same manner as in the first preferred embodiment, a sensor forming region 160J and an annular pad forming region 161J surrounding it are set on the semiconductor substrate 102J.

In the sensor forming region 160J, a plurality of lower electrodes 107J are arrayed in a matrix on the uppermost interlayer insulating film 103J. The lower electrodes 107J are made of molybdenum (Mo). Each lower electrode 107J is formed to a square shape in a plan view. Mutually adjacent lower electrodes 107J are spaced at equal intervals.

Photoabsorption layers 108J, each of flat quadrangular prism shape, are formed on the interlayer insulating film 103J so as to cover the respective lower electrodes 107J individually. In other words, individually separated photoabsorption layers 108J of rectangular shape in a plan view and side view are arrayed in a matrix on the interlayer insulating film 103J and a single lower electrode 107J is disposed at a center of a bottom portion of each photoabsorption layer 108J. Each photoabsorption layer 108J is made of CIGS (Cu(In,Ga)Se₂) and exhibits a p-type conductivity. A single lower electrode 107J and the photoabsorption layer 108J covering it is used for reading of a single pixel.

The respective photoabsorption layers 108J are isolated from each other by an isolation film 109J. The isolation film 109J coats side surfaces of the respective photoabsorption layers 108J and portions of the interlayer insulating film 103J that face intervals between the respective photoabsorption layers 108J. The isolation film 109J is made of silicon oxide.

A portion of an upper surface of each photoabsorption layer 108J other than a peripheral edge portion thereof is exposed from the isolation film 109J and a high-resistance buffer layer 110J is formed at the exposed portion. The high-resistance buffer layers 110J are made of cadmium sulfide (CdS).

On the isolation film 109J and the high-resistance buffer layers 110J, a transparent conductive film 111J is formed so as to cover these all together. At sides of the photoabsorption layers 108J aligned along an outermost periphery, a peripheral edge portion of the transparent conductive film 111J borders a top surface of the interlayer insulating film 103J. The transparent conductive film 111J is made of zinc oxide (ZnO), which has a light transmitting property, and has a laminated structure of i-type ZnO of high resistance without any impurity added and ZnO with conductivity imparted by addition of an n-type impurity (a laminated structure of iZnO/nZnO from the photoabsorption layer 108J side).

Between the uppermost interlayer insulating film 103J and the interlayer insulating film 104J below it, wirings 112J are formed at positions opposing the respective lower electrodes 107J. A via hole 113J is formed penetratingly in the interlayer insulating film 103J between each lower electrode 107J and the opposing wiring 112J and in a direction in which these oppose each other (thickness direction of the interlayer insulating film 103J). In the via hole 113J, a via 114J made of the same material as the lower electrode 107J is formed integral to the lower electrode 107J and without any gaps. Each lower electrode 107J is thereby electrically connected to the opposing wiring 112J via the via 114J.

Between the interlayer insulating film 104J and the interlayer insulating film 105J below it, capacitor upper electrodes 115J are formed at positions opposing the respective wirings 112J. Each wiring 112J and the opposing capacitor upper electrode 115J are electrically connected by a via 116J that penetrates through the interlayer insulating film 104J. The vias 114J and 116J are made of tungsten (W).

Between the interlayer insulating film 105J and the interlayer insulating film 106J below it, a capacitor lower electrode 117J is formed to oppose all of the capacitor upper electrodes 115J together. A capacitive element (MIM capacitor) having an MIM structure, in which the interlayer insulating film 105J is sandwiched as a capacitive film between the capacitor upper electrode 115J and the capacitor lower electrode 117J, is thereby formed according to each pixel. The lower electrode 107J and the capacitor upper electrode 115J of the MIM capacitor are electrically connected according to each pixel.

In the pad forming region 161J, a plurality of pad wirings 118J are formed in a mutually spaced manner between the uppermost interlayer insulating film 103J and the interlayer insulating film 104J below it. In the same manner as in the first preferred embodiment, the plurality of pad wirings 118J include a single upper electrode pad wiring 118J and the remaining pad wirings 118J are semiconductor device pad wirings that are electrically connected to the semiconductor device formed on the semiconductor substrate 102J. The wirings 112J and 115J and the pad wirings 118J are made of the same material and are made, for example, of a metal material that includes aluminum.

Openings 119J, each exposing a portion of a pad wiring 118J, are formed in the interlayer insulating film 103J. An upper electrode 120J is disposed on the uppermost interlayer insulating film 103J. One end of the upper electrode 120J is disposed on a peripheral edge portion of the transparent conductive film 111J and extends toward the upper electrode pad wiring 118J, and another end enters inside the opening 119J and is connected to the upper electrode pad wiring 118J.

Also, although not illustrated, openings, each exposing a portion of a semiconductor device pad wiring 118J, are formed in the interlayer insulating film 3J. A pad electrode is formed on a portion of each semiconductor device pad wiring 118J that is exposed via the opening. A peripheral edge portion of each pad electrode rides on the uppermost interlayer insulating film 103J. The upper electrode 120J and the pad electrodes are made of a metal material that includes aluminum.

A top surface protective film 121J is formed on a topmost surface of the image sensor 101J. The top surface protective film 121J is made, for example, of silicon nitride (SiN). Pad openings 123J, for exposing the upper electrode 120J and the pad electrodes as bonding pads 122J, are formed in the top surface protective film 121J at positions opposing the respective pad wirings 118J. Wires (not shown) for electrical connection with leads, etc., are bonded to the bonding pads 122J.

FIG. 59A to FIG. 59L are schematic sectional views that successively illustrate a manufacturing process of the image sensor shown in FIG. 58. In FIG. 59A to FIG. 59L, only portions made of metal materials are hatched and portions besides these are not hatched.

In the manufacturing process of the image sensor 101J, first, as shown in FIG. 59A, the interlayer insulating film 106J, the capacitor lower electrode 117J, the interlayer insulating film 105J, the capacitor upper electrodes 115J, the interlayer insulating film 104J, and the vias 116J are formed in that order on the semiconductor substrate 102J. The wirings 112J and the pad wirings 118J are then formed on the interlayer insulating film 104J. Thereafter, the interlayer insulating film 103J is formed and the via holes 113J penetrating through the interlayer insulating film 103J are formed above the respective wirings 112J by photolithography and etching.

Thereafter, as shown in FIG. 59B, tungsten, which is the material of the vias 114J, is deposited by the CVD method inside the via holes 113J and on the interlayer insulating film 103J to form a tungsten deposition layer 51J.

Thereafter, the tungsten deposition layer 51J is polished by the CMP method. The polishing of the tungsten deposition layer 51J is continued until an upper surface of the interlayer insulating film 103J is exposed. Vias 114J embedded inside the via holes 113J are thereby obtained as shown in FIG. 59C.

After the forming of the vias 114J, a molybdenum film 52J is formed by the sputtering method on the interlayer insulating film 103J as shown in FIG. 59D.

Thereafter, a resist pattern (not shown) that selectively covers only portions that become the lower electrodes 107J is formed by photolithography on the molybdenum film 52J. By then performing dry etching using the resist pattern as a mask, the portions of the molybdenum film 52J exposed from the resist pattern are removed, and the lower electrodes 107J are formed as shown in FIG. 59E. After the forming of the lower electrodes 107J, the resist pattern is removed.

Thereafter, as shown in FIG. 59F, a CIGS film 53J is formed by the MBE method on the interlayer insulating film 103J. The lower electrodes 107J are covered by the CIGS film 53J.

Thereafter, a resist pattern (not shown) that selectively covers only portions that become the photoabsorption layers 108J is formed by photolithography on the CIGS film 53J. By then performing dry etching using the resist pattern as a mask, the portions of the CIGS film 53J exposed from the resist pattern are removed and the CIGS film 53J is cut and divided into the photoabsorption layers 108J as shown in FIG. 59G. Thereafter, the resist pattern is removed.

Thereafter, as shown in FIG. 59H, a TEOS (tetraethoxysilane) film 54J is formed on the interlayer insulating film 103J by the CVD method using TEOS.

Thereafter, a resist pattern (not shown), having openings at portions opposing the respective photoabsorption layers 108J, is formed by photolithography on the TEOS film 54J. By then performing wet etching using the resist pattern as a mask, the TEOS film 54J is removed partially, and the TEOS film 54J becomes the isolation film 109J that exposes the portions of the upper surfaces of the respective photoabsorption layers 108J besides the peripheral edge portions as shown in FIG. 59I. After the forming of the isolation film 109J, the resist pattern is removed.

Thereafter, as shown in FIG. 59J, the high-resistance buffer layers 110J are formed by the CBD method on the respective photoabsorption layers 108J exposed from the isolation film 109J.

Thereafter, a zinc oxide film made of zinc oxide is formed by the sputtering method on the interlayer insulating film 103J. The isolation film 109J and the high-resistance buffer layers 110J are covered all together by the zinc oxide film. A resist pattern (not shown) that selectively covers a portion that is to become the transparent conductive film 111J is then formed by photolithography on the zinc oxide film. The portion of the zinc oxide film exposed from the resist pattern is then removed by dry etching using the resist pattern as a mask and the zinc oxide film is processed to the transparent conductive film 111J as shown in FIG. 59K. After the forming of the transparent conductive film 111J, the resist pattern is removed.

Thereafter, a resist pattern (not shown) that selectively exposes portions at which the openings 119J are to be formed is formed by photolithography on the interlayer insulating film 103J. The openings 119J penetrating through the interlayer insulating film 3J are then formed by dry etching using the resist pattern as a mask as shown in FIG. 59L. Thereafter, a metal film (not shown) made of a metal material that includes aluminum is formed by the sputtering method on the interlayer insulating film 103J and the transparent conductive film 111J. The metal film is also formed inside the openings 119J. Thereafter, a resist pattern (not shown) that covers portions that are to become the upper electrode 120J and the pad electrodes is formed by photolithography on the metal film. The metal film is then removed selectively by dry etching using the resist pattern as a mask, and the metal film is thereby processed to the upper electrode 120J and the pad electrodes.

Thereafter, the top surface protective film 121J is formed by the plasma CVD method, and when the pad openings 123J are formed by photolithography and etching, the image sensor 101J shown in FIG. 58 is obtained.

As described above, with the image sensor 101J, the plurality of lower electrodes 107J are disposed on the uppermost interlayer insulating film 103J. The lower electrodes 107J are covered individually by the photoabsorption layers 108J. The transparent conductive film 111J is formed on the photoabsorption layers 108J. The transparent conductive film 111J is connected to the upper electrode 120J. Also, the upper electrode pad wiring 118J is formed between the uppermost interlayer insulating film 103J and the interlayer insulating film 104J below it. In the pad forming region 161J outside the region in which the photoabsorption layers 108J are formed, the opening 119J that exposes a portion of the upper electrode pad wiring 118J is formed penetratingly in the thickness direction in the interlayer insulating film 103J. The upper electrode 120J enters inside the opening 119J and is connected to the upper electrode pad wiring 118J inside the opening 119J. That is, a pad electrode for relaying the upper electrode 120J and the upper electrode pad wiring 118J is not provided on the interlayer insulating film 103J but the upper electrode 120J is directly connected to the upper electrode pad wiring 118J inside the opening 119J that penetrates through the interlayer insulating film 103J.

If the CIGS film 53J made of the material of the photoabsorption layer 108J is formed on the interlayer insulating film 103J and patterned to the photoabsorption layers 108J by dry etching and the openings 119J are thereafter formed in the interlayer insulating film 103J, the upper electrode pad wiring 118J will be covered by the interlayer insulating film 103J during the dry etching of the CIGS film 53J. The top surface of the upper electrode pad wiring 118J can thereby be prevented from being exposed to the etching gas and damaging of the top surface of the upper electrode pad wiring 118J can be prevented during the dry etching of the CIGS film 53J. Consequently, the top surface of the upper electrode pad wiring 118J is maintained in a satisfactory state and satisfactory electrical connection of the upper electrode 120J and the upper electrode pad wiring 118J can be achieved.

The lower electrodes 107J and the vias 114J may be formed integrally from the same material, for example, tungsten.

Although the preferred embodiments of the present invention have been described above, the preferred embodiments may also be changed as follows.

For example, although CIGS was given as an example of a chalcopyrite compound semiconductor, besides CIGS, CuAlS₂, CuAlSe₂, CuAlTe₂, CuGaS₂, CuGaSe₂, CuGaTe₂, CuInS₂, CuInTe₂, AgAlS₂, AgAlSe₂, AgAlTe₂, AgGaS₂, AgGaSe₂, AgGaTe₂, AgInS₂, AgInSe₂, AgInTe₂, etc., can be cited as examples of I-III-VI₂ type semiconductors, and ZnSiP₂, ZnSiAs₂, ZnSiSb₂, ZnGeP₂, ZnGeAs₂, ZnGeSb₂, ZnSnP₂, ZnSnAs₂, ZnSnSb₂, CdSiP₂, CdSiAs₂, CdSiSb₂, CdGeP₂, CdGeAs₂, CdGeSb₂, CdSnP₂, CdSnAs₂, CdSnSb₂, etc., can be cited as examples of II-IV-V₂ type semiconductors.

Also, the present invention is not restricted to image sensors and can also be applied to self-generating ICs with built-in solar cells that make use of photoelectrically converted electrical signals as a DC power source and other types of photoelectric converters. In a case of application to a self-generating IC with a built-in solar cell, the lower electrode does not have to be provided in plurality and, for example, just one lower electrode may be provided on an interlayer insulating film.

Also, the preferred embodiments described above are merely specific examples used for clarifying the technical details of the present invention, the present invention should not be interpreted as being restricted to these specific examples, and the spirit and scope of the present invention are limited only by the attached claims.

Examples of other characteristics apparent from the disclosure by the present application include the following.

### Characteristics Apparent from the Preferred Embodiment According to the Second Aspect of the Invention

Preferably, the photoelectric converter according to the present invention further includes a first wiring formed below the insulating layer, a relay electrode formed of the same material as the lower electrodes and on the insulating layer outside a region in which the photoabsorption layer is formed and electrically connected to the first wiring, an interlayer insulating film formed on and across the insulating layer, the photoabsorption layer, the transparent conductive film, and the relay electrode, and an upper electrode formed on the interlayer insulating film and electrically connected to the transparent conductive film and the relay electrode.

Charges taken out from the transparent conductive film by the upper electrode are transmitted to a MISFET (metal insulator semiconductor field effect transistor) or other semiconductor device by the first wiring below the insulating layer. Although the upper electrode is thus required to be electrically connected to the first wiring, the following problems X1 to X3 occur in a case where the upper electrode is directly connected to the first wiring.

X1. In order to manufacture the photoelectric converter in as few steps as possible, it is preferable to form a via hole for making the upper electrode contact the transparent conductive film and a pad opening for making the upper electrode contact the first wiring in the same step. However, whereas a via hole can be formed by etching just the interlayer insulating film, both the interlayer insulating film and the insulating layer must be etched to form the pad opening. Thus, even after the via hole has been formed by etching of the interlayer insulating film, etching must be continued to form the pad opening and thus a portion of the transparent conductive film that is exposed via the via hole may be damaged by the etching, thereby the reliability of the photoelectric converter may be impaired.

X2. Meanwhile, if the via hole and the pad opening are formed in separate steps, the number of steps for manufacturing the photoelectric converter increases and the number of masks necessary for forming the via hole and the pad opening increases. Consequently, the time and cost required for manufacture increase.

X3. Also, the depth of the pad opening is the sum of thicknesses of the interlayer insulating film and the insulating layer and it is thus difficult to deposit the upper electrode with good coating property at a step portion formed between the interior and the exterior of the pad opening.

With the present photoelectric converter, the upper electrode is not directly connected to the first wiring but is connected to the relay electrode formed of the same material as the lower electrodes and on the insulating layer outside the region in which the photoabsorption layer is formed. The upper electrode is thus electrically connected to the first wiring via the relay electrode. The problems X1 to X3 can thus be avoided.

A pad opening that exposes a portion of the relay electrode as a pad and a via hole that exposes a peripheral edge portion of an upper surface of the transparent conductive film may be penetratingly formed in a thickness direction in the interlayer insulating film, and the upper electrode may enter inside the pad opening and the via hole and be connected to each of the relay electrode and the transparent conductive film.

Such a photoelectric converter may be manufactured by a manufacturing method including the following steps B1 to B11.

B1. A step of forming a first wiring on an interlayer insulating film in a pad forming region.

B2. A step of forming an insulating layer on the interlayer insulating film so as to cover the first wiring.

B3. A step of forming, from the same material, a relay electrode, electrically connected to the first wiring, at a position on the insulating layer that opposes the first wiring and lower electrodes at positions on the insulating layer separated from the relay electrode.

B4. A step of forming a protective film on the insulating layer so as to cover the relay electrode.

B5. A step of forming a photoabsorption material layer, made of a chalcopyrite compound semiconductor, on the insulating film so as to cover the plurality of lower electrodes and the protective film all together.

B6. A step of forming a transparent conductive material film on the photoabsorption material layer.

B7. A step of forming a mask on the transparent conductive material film so as to cover a predetermined portion of a sensor forming region that differs from the pad forming region.

B8. A step of selectively removing the transparent conductive material film by wet etching using the mask to process the transparent conductive material film to a transparent conductive film.

B9. A step of selectively removing the photoabsorption material layer by dry etching using the mask to process the photoabsorption material layer to a photoabsorption layer.

B10. A step of removing the mask after the forming of the photoabsorption layer and forming an interlayer insulating film on and across the insulating layer, the photoabsorption layer, the transparent conductive film, and the protective film.

B11. A step of forming an upper electrode, electrically connected to the transparent conductive film and the relay electrode, on the interlayer insulating film.

Also, in a case where the upper electrode is connected to the transparent conductive film inside a via hole and connected to the relay electrode inside a pad opening, the method for manufacturing the photoelectric converter preferably further includes the following step B12.

B12. A step of selectively and continuously removing the interlayer insulating film and the insulating layer outside a region in which the photoabsorption layer is formed to form a pad opening exposing a portion of the relay electrode as a pad and selectively removing the interlayer insulating film to penetratingly form a via hole above a peripheral edge portion of an upper surface of the transparent conductive film.

With the above manufacturing method, for example, the following problem X4 occurs if the step of forming the protective film (step B4) is not executed.

X4. The relay electrode is exposed to an etching gas during dry etching of the photoabsorption material layer and the relay electrode may thus be etched and lost during the dry etching. Even if the relay electrode remains on the insulating layer without becoming lost, a top surface thereof is roughened by the dry etching and adhesion with the upper electrode decreases. Consequently, a wire bonding fault may occur.

On the other hand, in the present method for manufacturing the photoelectric converter, the protective film is formed so as to cover the relay electrode in the step B4 before the dry etching of the photoabsorption material layer. The photoabsorption layer is formed by the dry etching of the photoabsorption material layer in the state where the relay electrode is covered by the protective film. The relay electrode is thus not exposed to the etching gas during the dry etching of the photoabsorption material layer. Consequently, the relay electrode with a satisfactory top surface state being maintained can be made to remain on the insulating layer. Wire bonding strength can thus be improved.

Also, by the etching gas used in the dry etching of the photoabsorption material layer, the protective film that covers the relay electrode is made thinner than when it was formed, and thus a difference between the thickness of the interlayer insulating film that covers the transparent conductive film and the total thickness of the protective film and the interlayer insulating film that cover the relay electrode is comparatively small. The etching time necessary for forming the pad opening is thus made substantially the same as the etching time necessary for forming the via hole, with which there is no need to etch the protective film. Consequently, damage of the transparent conductive film due to etching can be reduced in the case of forming the pad opening for contact of the upper electrode and the relay electrode and the via hole for contact of the upper electrode and the transparent conductive film in the same step (step B12). Lowering of reliability of the photoelectric converter can thus be suppressed.

Also, in the case where the pad opening and the via hole are formed in the same step (step B12), the number of steps for manufacturing the photoelectric converter can be decreased and the number of masks necessary for forming the via hole and the pad opening can be reduced in comparison to a case where these are formed in separate steps. Consequently, increases of the time and cost required for manufacture can be suppressed.

Further, by the protective film being made thinner than when it was formed, the total thickness of the protective film and the interlayer insulating film is decreased and the depth of the pad opening can be decreased. The upper electrode can thus be deposited with good coating property even at the step portion between the interior and the exterior of the pad opening.

Also, the mask used in the wet etching for processing the transparent conductive material film to the transparent conductive film is also used in the dry etching for processing the photoabsorption material layer to the photoabsorption layer and a mask used exclusively for the dry etching is not formed. The manufacturing process of the photoelectric converter can thus be simplified.

Also preferably, a plurality of relay electrodes are disposed in mutually spaced manner and the respective relay electrodes are electrically connected to the first wiring. The upper electrode can thereby be inserted between mutually adjacent relay electrodes. The upper electrode can thereby be put in contact not only with upper surfaces of the relay electrodes but also with side surfaces of the relay electrodes. An area of contact of the relay electrodes and the upper electrode is thereby increased, and adhesion of the upper electrode with the relay electrodes can be improved.

Also, in the same layer as the first wiring, a plurality of second wirings may be disposed opposite the respective lower electrodes and a first via electrically connecting the relay electrode and the first wiring and second vias electrically connecting the lower electrodes and the second wirings may be formed penetratingly in the insulating layer. Preferably in this case, the lower electrodes, the relay electrode, the first via, and the second vias are made of the same material. The material may be tungsten. If the lower electrodes, the relay electrode, the first via, and the second vias are made of the same material, the lower electrodes, the relay electrode, the first via, and the second vias can be made in the same step. A step of polishing the deposition layer of the material of the vias by a CMP method and a step of forming a film made of the material of the lower electrodes by a sputtering method, which are deemed to be required in the manufacture of the conventional photoelectric converter, can thus be omitted. Consequently, the time and cost required for manufacture can be reduced.

The photoelectric converter of the present structure may be manufactured by a method for manufacture, which includes the following step B13 in addition to the steps B1 to B11 and with which the step of forming the insulating layer is the following step B14 and the step of forming the lower electrodes and the relay electrode include the following steps B15 to B18.

B13. A step of forming second wirings on the interlayer insulating film in the sensor forming region.

B14. (The step of forming the insulating layer is) a step of forming the insulating layer so as to cover both the first and second wirings.

(The step of forming the lower electrodes and the relay electrode includes)

B15. a step of forming a first via hole penetrating through the insulating layer in a thickness direction and reaching the first wiring and second via holes penetrating through the insulating layer in the thickness direction and reaching the second wirings,

B16. a step of forming a barrier film, made of a material with etch selectivity with respect to the protective film, inside the first and second via holes and on the insulating layer,

B17. a step of embedding tungsten in the first and second via holes and depositing tungsten on the insulating layer to form an electrode material layer, and

B18. a step of patterning the electrode material layer to form the lower electrodes and the relay electrode.

In the step of forming the electrode material layer, the first via hole and the second via holes are completely filled with the material (tungsten) of the lower electrodes.

Then, in the step of forming the lower electrodes and the relay electrode, second vias connected to the respective lower electrodes and a first via connected to the relay electrode are formed together with the lower electrodes and the relay electrode. Reliable connection of the lower electrodes with the second vias and reliable connection of the relay electrode with the first via can thereby be achieved, and reliability of electrical connection of the lower electrodes and the second vias and reliability of electrical connection of the relay electrode and the first via can be improved.

Also preferably, the step of forming the protective film includes the following steps B19 and B20.

B19. A step of forming a protective material layer on the insulating layer so as to cover the plurality of lower electrodes and the relay electrode all together.

B20. A step of selectively removing the protective material film by wet etching using a mask formed on the relay electrode to form a protective material film.

If the removal of the protective material film is executed by dry etching, the top surfaces of the lower electrodes may be damaged by the etching gas during the etching. However, by executing the removal by wet etching as described above, the damaging of the lower electrodes can be reduced. The top surfaces of the lower electrodes can thus be maintained in satisfactory states. Consequently, lowering of reliability of the photoelectric converter can be suppressed.

Further, the barrier film formed in the step B16 is made of a material with etch selectivity with respect to the protective film, and it is thus preferable for the barrier film to serve in common as an etching stopper film when the wet etching of the protective material film is performed. A step of forming an etching stopper film can thus be eliminated. Consequently, the time and cost required for manufacture can be reduced.

### Characteristics Apparent from the Preferred Embodiment According to the Third Aspect of the Invention

Preferably, the photoelectric converter according to the present invention further includes a wiring formed on the insulating layer and in the same layer as the lower electrodes and a protective film formed on the insulating layer so as to cover the wiring.

Such a photoelectric converter may be manufactured by a manufacturing method including the following steps C1 to C8.

C1. A step of forming an insulating layer.

C2. A step of forming, from the same material and on the insulating layer, a plurality of lower electrodes that are mutually spaced and disposed in a sensor forming region and a wiring disposed in a peripheral region outside the sensor forming region.

C3. A step of forming a protective film on the insulating layer so as to cover the wiring.

C4. A step of forming a photoabsorption material layer, made of a chalcopyrite compound semiconductor, on the insulating layer so as to cover the plurality of lower electrodes and the protective film all together.

C5. A step of forming a transparent conductive material film on the photoabsorption material layer.

C6. A step of forming a mask on the transparent conductive material film so as to cover a predetermined portion of the sensor forming region.

C7. A step of selectively removing the transparent conductive material film by wet etching using the mask to process the transparent conductive material film to a transparent conductive film.

C8. A step of selectively removing the photoabsorption material layer by dry etching using the mask to process the photoabsorption material layer to a photoabsorption layer.

With the above manufacturing method, for example, the following problem X5 occurs if the step (step C3) of forming the protective film is not executed.

X5. The wiring is exposed to the etching gas during dry etching of the photoabsorption material layer and the wiring may thus be etched and lost during the dry etching. Even if the wiring remains on the insulating layer without becoming lost, a top surface thereof is roughened by the dry etching and reliability as wiring may decrease.

Meanwhile, in the present method for manufacturing the photoelectric converter, the protective film is formed so as to cover the wiring in the step C3 before the dry etching of the photoabsorption material layer. The photoabsorption layer is formed by the dry etching of the photoabsorption material layer in the state where the wiring is covered by the protective film. The wiring is thus not exposed to the etching gas during the dry etching of the photoabsorption material layer. Consequently, the wiring with a satisfactory top surface state being maintained can be made to remain on the insulating layer. The wiring can thus be put to any use.

For example, in a case where the photoelectric converter includes an MIM capacitor having capacitor upper electrodes electrically connected to the respective lower electrodes and a capacitor lower electrode opposing the plurality of capacity upper electrodes across the insulating layer, the wiring covered by the protective film may be electrically connected to the capacitor lower electrode. Consequently, by connecting the wiring to a substrate potential, the potential of the capacitor lower electrode can be maintained at the substrate potential.

Also preferably, in the case of the arrangement that includes the MIM capacitor, the capacitor lower electrode is formed so as to oppose the capacitor upper electrodes all together. The step of forming the capacitor lower electrode can thereby be simplified in comparison to a case where a plurality of capacitor lower electrodes are formed in respective correspondence to the capacitor upper electrodes.

Further preferably, the wiring is made of the same material as the lower electrodes. The wiring and the lower electrodes can thereby be formed in the same step. The number of steps for manufacturing the photoelectric converter can thus be decreased and the number of masks necessary for forming the wiring and the lower electrodes can be reduced in comparison to a case where these are formed in separate steps. Consequently, increases of the time and cost required for manufacture can be suppressed.

### Characteristics Apparent from the Preferred Embodiment According to the Fourth Aspect of the Invention

Preferably, with the photoelectric converter according to the present invention, a side surface of the transparent electrode film is positioned further inward than a side surface of the photoabsorption layer in a plan view.

The side surface of the photoabsorption layer is damaged by dry etching during the processing to the photoabsorption layer. If a pn junction is formed on the side surface of the photoabsorption layer, a dark current due to the damage may arise. With the present photoelectric converter, the side surface of the transparent conductive film is positioned further inward than the side surface of the photoabsorption layer in a plan view. The transparent conductive film is thus not in contact with the side surface of the photoabsorption layer and a pn junction due to the photoabsorption layer and the transparent conductive film is not formed on the side surface of the photoabsorption layer. Generation of a dark current due to damage of the side surface of the photoabsorption layer can thus be prevented.

Also, in a case where the upper electrode that is electrically connected to the transparent conductive film is provided, an interlayer insulating film is preferably formed on and across the insulating layer, the photoabsorption layer, and the transparent conductive film. The photoabsorption layer and the upper electrode can thus be isolated from each other and short-circuiting of the photoabsorption layer and the transparent conductive film via the upper electrode can be prevented because the interlayer insulating film is interposed between the photoabsorption layer and the upper electrode.

The side surface of the photoabsorption layer is not covered by the transparent conductive film and thus preferably, the interlayer insulating film borders the side surface of the photoabsorption layer in order to reliably prevent contact of the upper electrode with the side surface of the photoabsorption layer.

Preferably, the side surface of the transparent conductive film is inclined so that as its lower end is approached, the side surface approaches the side surface of the photoabsorption layer. Improvement of coverage of the side surface of the transparent conductive film by the interlayer insulating film can thus be achieved.

A high-resistance buffer layer may be formed at an interface of the photoabsorption layer and the transparent conductive film.

In a case where the high-resistance buffer layer is included, the photoelectric converter may be manufactured by a manufacturing method including the following steps D1 to D9.

D1. A step of forming an insulating layer.

D2. A step of laminating an electrode material layer, made of a material of lower electrodes, on the insulating layer.

D3. A step of selectively removing the electrode material layer to form a plurality of lower electrodes that are mutually spaced and disposed on the insulating layer.

D4. A step of forming a photoabsorption material layer, made of a chalcopyrite compound semiconductor, on the insulating layer so as to cover the plurality of lower electrodes all together.

D5. A step of forming, in succession to the forming of the photoabsorption material layer, a high-resistance buffer layer on the photoabsorption material layer.

D6. A step of forming, in succession to the forming of the high-resistance buffer layer, a transparent conductive material film on the high-resistance buffer layer.

D7. A step of forming a mask on the transparent conductive material film.

D8. A step of selectively removing the transparent conductive material film by wet etching using the mask to process the transparent conductive material film to a transparent conductive film.

D9. A step of selectively removing the photoabsorption material layer by dry etching using the mask to process the photoabsorption material layer to a photoabsorption layer.

The mask used in the wet etching for processing the transparent conductive material film to the transparent conductive film is also used in the dry etching for processing the photoabsorption material layer to the photoabsorption layer and a mask used exclusively for the dry etching is not formed. The manufacturing process of the photoelectric converter can thus be simplified.

In a case where the photoabsorption layer is made of CIGS, the high-resistance buffer layer is made of cadmium sulfide (CdS), and the transparent conductive film is made of zinc oxide (ZnO), it is especially preferable for the forming of the photoabsorption layer, the high-resistance buffer layer, and the transparent conductive film to be performed consecutively as in the steps D4 to D6. The time from the forming of the photoabsorption layer to the completion of forming of the transparent conductive film can thus be made short, and the photoabsorption layer, the high-resistance buffer layer, and the transparent conductive film can be improved in film quality.

On a peripheral edge portion of an upper surface of the transparent conductive film, a via hole may be formed to penetrate the interlayer insulating film in a thickness direction and the upper electrode may enter inside the via hole and be connected to the transparent conductive film inside the via hole.

In a region outside a region in which the photoabsorption layer is formed, a pad may be formed by exposing a portion of a wiring, formed below the insulating layer, from a pad opening penetrating continuously through the insulating layer and the interlayer insulating film in the thickness direction, and the upper electrode may enter inside the pad opening and be connected to the pad inside the pad opening.

In the case of the arrangement in which the upper electrode is connected to the transparent conductive film inside the via hole and connected to the pad inside the pad opening, the method for manufacturing the photoelectric converter preferably further includes the following steps D10 to D12.

D10. A step of forming a wiring before forming the insulating layer.

D11. A step of removing the mask after the photoabsorption layer has been formed and forming an interlayer insulating film on and across the insulating layer, the photoabsorption layer, and the transparent conductive film.

D12. A step of performing, in a region outside a region in which the photoabsorption layer is formed, continuous selective removal of the interlayer insulating film and the insulating layer to form a pad opening exposing a portion of the wiring as a pad and selective removal of the interlayer insulating film to penetratingly form a via hole above a peripheral edge portion of an upper surface of the transparent conductive film.

The pad opening and the via holes are formed in the same step (step D12) and thus in comparison to a case where these are formed in separate steps, the number of masks required for forming these can be reduced and the manufacturing process of the photoelectric converter can be simplified.

### Characteristics Apparent from the Preferred Embodiment According to the Fifth Aspect of the Invention

Also preferably, the photoelectric converter according to the present invention further includes a protective film made of Al₂O₃ that is formed so as to cover the transparent conductive film and the photoabsorption layer and a top surface protective film formed so as to cover the transparent conductive film and the photoabsorption layer.

The protective film made of aluminum oxide (Al₂O₃) is formed by an RF sputtering method under ordinary temperature. Thus, even after the forming of the transparent conductive film, thermal damage is not applied to the transparent conductive film. Degradation of the transparent conductive film due to thermal damage can thus be suppressed.

Also, a film structure of Al₂O₃ can be made dense even by a film forming method executed under ordinary temperature. The protective film (Al₂O₃ film) of dense structure exhibits excellent water impermeability and thus regardless of the film quality of the top surface protective film, entry of water into portions below (transparent conductive film side of) the protective film can be suppressed satisfactorily. Consequently, degradation of the photoabsorption layer and the transparent conductive film due to entry of water, etc., can be suppressed.

The protective film may be disposed at the transparent conductive film side relative to the top surface protective film or may coat a top surface of the top surface protective film.

Also, in case where an interlayer insulating film is formed on and across the insulating layer and the transparent conductive film and an upper electrode, electrically connected to the transparent conductive film, is formed on the interlayer insulating film, the protective film may be interposed between the top surface protective film and the interlayer insulating film plus the upper electrode. Also, the protective film may be interposed between the interlayer insulating film and the insulating layer plus the transparent conductive film. Further, the protective film may be interposed between the top surface protective film and the interlayer insulating film and between the upper electrode and the interlayer insulating film.

The chalocopyrite compound semiconductor that is the material of the photoabsorption layer may be CIGS (Cu(In,Ga)Se₂).

The material of the transparent conductive film may be zinc oxide (ZnO). In this case, the material of the top surface protective film may be silicon nitride (SiN).

SiN has a good insulating property and thus a lower side of the top surface protective film at which the transparent conductive film and the photoabsorption layer are disposed is isolated satisfactorily across the top surface protective film from an upper side of the top surface protective film. Electrical influences on the transparent conductive film and the photoabsorption layer can thus be suppressed. Consequently, the photoelectric converter can be made to operate with stability.

On the other hand, in the case where the transparent conductive film is ZnO, processing under a temperature exceeding 200° C. cannot be performed after the forming of the transparent conductive film, and thus the top surface protective film (SiN film) must be formed by a plasma CVD (chemical vapor deposition) method at no more than 200° C. The film structure of the top surface protective film may thus be rough and the top surface protective film may not exhibit adequate water impermeability.

However, with the present photoelectric converter, the protective film made of Al₂O₃ is formed to cover the transparent conductive film and the photoabsorption layer and entry of water below (to the transparent conductive film side of) the protective film can be suppressed satisfactorily. That is, with the present photoelectric converter, good insulating property and water impermeability can be realized by the transparent conductive film and the photoabsorption layer being covered by both the protective film made of Al₂O₃ and the top surface protective film made of SiN.

### Characteristics Apparent from the Preferred Embodiments According to the Sixth Aspect of the Invention

Also preferably, the photoelectric converter according to the present invention further includes lower wirings disposed opposite the lower electrodes across the insulating layer and electrically connected to the lower electrodes, an electrode pad formed in the same layer as the lower wirings and outside the region in which the photoabsorption layer is formed, a via disposed to penetrate through the insulating layer in the thickness direction and having a lower end connected to the electrode pad, an interlayer insulating film formed on and across the insulating layer and the transparent conductive film and having a pad opening exposing an upper surface of the via, and an upper wiring formed on the interlayer insulating film, entering inside the pad opening, and electrically connected to the via.

With the present photoelectric converter, the upper wiring is electrically connected to the via inside the pad opening. The lower end of the via is connected to the electrode pad. The upper wiring can thereby be connected electrically to the electrode pad via the via.

The present photoelectric converter may be manufactured, for example, by a manufacturing method including the following steps F1 to F12.

F1. A step of forming lower wirings on a first interlayer insulating film in a sensor forming region and forming an electrode pad on the first interlayer insulating film in a pad forming region outside the sensor forming region.

F2. A step of forming an insulating layer on the first interlayer insulating film so as to cover the lower wirings and the electrode pad.

F3. A step of forming, in a portion of the insulating layer above the electrode pad, a via penetrating through the insulating layer in a thickness direction and having its lower end connected to the electrode pad.

F4. A step of forming, from the same material, lower electrodes, electrically connected to the lower wirings, at positions on the insulating layer opposing the lower wirings and a sacrificial layer covering the via at a position on the insulating layer opposing the electrode pad.

F5. A step of forming a photoabsorption material layer, made of a chalcopyrite compound semiconductor, on the insulating layer so as to cover the lower electrodes and the sacrificial layer all together.

F6. A step of forming a transparent conductive material film on the photoabsorption material layer.

F7. A step of forming a mask on the transparent conductive material film so as to cover a predetermined portion of the sensor forming region.

F8. A step of selectively removing the transparent conductive material film by wet etching using the mask to process the transparent conductive material film to a transparent conductive film.

F9. A step of selectively removing the photoabsorption material layer by dry etching using the mask to process the photoabsorption material layer to a photoabsorption layer.

F10. A step of removing the mask after the forming of the photoabsorption layer and forming a second interlayer insulating film on and across the insulating layer, the transparent conductive film, and the sacrificial layer.

F11. A step of removing the sacrificial layer and the second interlayer insulating film from above the via to form a pad opening exposing an upper surface of the via.

F12. A step of forming an upper wiring, entering inside the pad opening and electrically connected to the via, on the second interlayer insulating film.

Also, the photoelectric converter may be manufactured by a manufacturing method including the following steps F13 to F25.

F13. A step of forming lower wirings on a first interlayer insulating film in a sensor forming region and forming an electrode pad on the first interlayer insulating film in a pad forming region outside the sensor forming region.

F14. A step of forming an insulating layer on the first interlayer insulating film so as to cover the lower wirings and the electrode pad.

F15. A step of forming, in a portion of the insulating layer above the electrode pad, a via penetrating through the insulating layer in a thickness direction and having its lower end connected to the electrode pad.

F16. A step of forming, from the same material, lower electrodes, electrically connected to the lower wirings, at positions on the insulating layer opposing the lower wirings and a sacrificial layer covering the via at a position on the insulating layer opposing the electrode pad.

F17. A step of forming a photoabsorption material layer, made of a chalcopyrite compound semiconductor, on the insulating layer so as to cover the lower electrodes and the sacrificial layer all together.

F18. A step of forming a transparent conductive material film on the photoabsorption material layer.

F19. A step of forming a mask on the transparent conductive material film so as to cover a predetermined portion of the sensor forming region.

F20. A step of selectively removing the transparent conductive material film by wet etching using the mask to process the transparent conductive material film to a transparent conductive film.

F21. A step of selectively removing the photoabsorption material layer by dry etching using the mask to process the photoabsorption material layer to a photoabsorption layer.

F22. A step of removing the mask and removing the sacrificial layer after the forming of the photoabsorption layer to expose an upper surface of the via on the insulating layer.

F23. A step of forming a second interlayer insulating film on and across the insulating layer, the transparent conductive film, and the via after the removal of the sacrificial layer.

F24. A step of removing the second interlayer insulating film above the via to form a pad opening exposing an upper surface of the via.

F25. A step of forming an upper wiring, entering inside the pad opening and electrically connected to the via, on the second interlayer insulating film.

With the present manufacturing method, in the middle of manufacturing the photoelectric converter, the lower electrodes, electrically connected to the lower wirings, and the sacrificial layer, electrically connected via the via to the electrode pad in the same layer as the lower wirings, are formed at the same time on the insulating layer. By voltage application to the sacrificial layer, a voltage can be applied to the electrode pad via the via even in the middle of manufacture of the photoelectric converter. An isolation state of the lower electrodes can thereby be measured.

The sacrificial layer that can be used for measurement is formed on the insulating layer and is thus exposed to the etching gas during the dry etching of the photoabsorption material layer and may thereby receive damage on its top surface. It is thus difficult to connect wiring, etc., to the sacrificial layer with satisfactory adhesion. Thus, if the upper wiring and the electrode pad are electrically connected by connecting the upper wiring to the sacrificial layer, adhesion of the sacrificial layer and the upper wiring is not strong and it is thus difficult to maintain reliability of electrical connection of the upper wiring and the electrode pad satisfactorily.

On the other hand, with the present manufacturing method, the sacrificial layer is removed during the forming of the pad opening or before the forming of the pad opening and the upper surface of the via, the lower end of which is connected to the electrode pad, is exposed inside the pad opening. The via is covered by the sacrificial layer during the dry etching of the photoabsorption material layer and is thus not exposed to the etching gas. Thus, unlike the top surface of the sacrificial layer after the dry etching, the upper surface of the via exposed inside the pad opening is maintained in a satisfactory state. The upper wiring can thus be connected with good adhesion to the via inside the pad opening. Consequently, the reliability of electrical connection of the upper wiring and the electrode pad can be maintained satisfactorily.

In the case where the via hole is formed penetratingly in the thickness direction of the interlayer insulating film above the transparent conductive film, the upper wiring may enter inside the via hole and be connected to the transparent conductive film. Preferably, a conductive barrier film is interposed between the upper wiring and the upper surface of the via.

The material of the via may be tungsten. Tungsten oxidizes readily and thus if a contact area of tungsten and the upper wiring is large, the upper wiring may separate from the tungsten due to vibration generated during wire bonding onto the upper wiring.

However, with the present photoelectric converter, the upper wiring is connected not to an electrode or other conductive member of comparatively large area but to the via of comparatively small area. The contact area of the tungsten and the upper wiring is thus small. Separation of the upper wiring can thus be suppressed even if vibration is generated during wire bonding. Further, even in a case where the material of the via is tungsten, good adhesion of the via with respect to the upper wiring can be maintained, and the reliability of electrical connection of the upper wiring and the electrode pad can be maintained satisfactorily.

### Characteristics Apparent from the Preferred Embodiment According to the Seventh Aspect of the Invention

Also preferably, with the photoelectric converter according to the present invention, the transparent conductive film is made of ZnO, the photoelectric converter further includes an upper electrode having one end connected to the transparent conductive film and another end disposed in a region on the insulating layer at a side of the photoabsorption layer and a top surface protective film covering the transparent conductive film and the upper electrode all together, an opening for exposing the upper electrode is formed in the top surface protective film in the region at the side of the photoabsorption layer, and the opening is made of a penetrating portion penetrating through the top surface protective film in its thickness direction and a tapered portion being in communication with the penetrating portion and having side surfaces that spread apart further as a top surface side of the top surface protective film is approached.

The photoelectric converter having the opening made of the penetrating portion and the tapered portion may be manufactured by a manufacturing method including the following steps G1 to G8.

G1. A step of forming lower electrodes on an insulating layer.

G2. A step of forming a photoabsorption layer, made of a chalcopyrite compound semiconductor, on the insulating layer so as to cover the lower electrodes.

G3. A step of forming a transparent conductive film made of ZnO on the photoabsorption layer.

G4. A step of forming an upper electrode having one end portion connected to the transparent conductive film and another end portion disposed in a region on the insulating layer at a side of the photoabsorption layer.

G5. A step of forming a top surface protective film covering the transparent conductive film and the upper electrode all together.

G6. A step of forming, on the top surface protective film, a resist film having a resist opening partially exposing a portion of the top surface protective film formed in the region at the side of the photoabsorption layer.

G7. A step of forming, by isotropic etching of the portion of the top surface protective film exposed from the resist opening, a tapered portion dug in from the top surface of the top surface protective film.

G8. A step of forming, by anisotropic etching, a penetrating portion penetrating through the top surface protective film from a bottom surface of the tapered portion.

After the resist film has been formed on the top surface protective film, the portion of the top surface protective film that is exposed from the resist opening is etched by isotropic etching. The tapered portion that is dug in from the top surface of the top surface protective film is thereby formed in the top surface protective film. Thereafter, the penetrating portion penetrating through the top surface protective film from the bottom surface of the tapered portion is formed by anisotropic etching, and the opening that selectively exposes the upper electrode is formed in the top surface protective film.

That is, above the upper electrode, after the top surface protective film has been thinned to a certain thickness by isotropic etching, the penetrating portion (opening) is formed by anisotropic etching at the portion of the top surface protective film that has been thinned. The amount of etching by isotropic etching thus suffices to be small and the duration of performing the isotropic etching suffices to be short, and film loss of the resist film can thus be lessened. Consequently, exposure of the top surface protective film due to film loss of the resist film above the photoabsorption layer and the transparent conductive film can be prevented and damaging of the top surface protective film by etching can be prevented. The opening that selectively exposes the upper electrode can thus be formed in the top surface protective film without damaging the top surface protective film by etching.

Also, in the isotropic etching for forming the tapered portion, it suffices that the portion of the top surface protective film at which the penetrating portion is formed be thinned and that lessening of the etching amount by anisotropic etching be made possible and there is no need to perform isotropic etching until the upper electrode is exposed and thus precise control of the etching amount by isotropic etching is unnecessary. The tapered portion can thus be formed readily and consequently, the opening can be formed readily.

The chalocopyrite compound semiconductor that is the material of the photoabsorption layer may be Cu(In,Ga)Se₂.

Also, the top surface protective film is preferably formed under a low temperature of no more than 200° C. In this case, the transparent conductive film made of zinc oxide (ZnO) is not exposed to a temperature exceeding 200° C. and degradation of the transparent conductive film by heat can be prevented.

As an example of a top surface protective film formed under a low temperature of no more than 200° C., a top surface protective film made of silicon nitride (SiN) can be cited.

### Characteristics Apparent from the Preferred Embodiment According to the Eighth Aspect of the Invention

Also preferably, the photoelectric converter according to the present invention further includes a first wiring formed below the insulating layer, a relay electrode formed of the same material as the lower electrodes and on the insulating layer outside the region in which the photoabsorption layer is formed and electrically connected to the first wiring, a first protective film formed so as to cover the relay electrode, a second protective film formed on the first protective film and having etch selectivity with respect to the first protective film, an interlayer insulating film formed on and across the insulating layer, the photoabsorption layer, the transparent conductive film, the relay electrode, and the second protective film, and an upper electrode formed on the interlayer insulating film, electrically connected to the transparent conductive film via a via hole penetrating through the interlayer insulating film, and electrically connected to the relay electrode via a pad opening penetrating through the interlayer insulating film, the second protective film, and the first protective film.

Charges taken out from the transparent conductive film by the upper electrode are transmitted, for example, to a MISFET (metal insulator semiconductor field effect transistor) or other semiconductor device by the first wiring below the insulating layer. Although the upper electrode is thus required to be electrically connected to the first wiring, the same problems as the abovementioned problems X1 to X3 occur in the case where the upper electrode is directly connected to the first wiring.

With the present photoelectric converter, the upper electrode is not directly connected to the first wiring but is connected to the relay electrode that is formed of the same material as the lower electrodes and on the insulating layer outside the region in which the photoabsorption layer is formed. The upper electrode is thus electrically connected to the first wiring via the relay electrode. The problems X1 to X3 can thus be avoided.

Such a photoelectric converter may be manufactured by a manufacturing method including the following steps H1 to H14.

H1. A step of forming a first wiring on a first interlayer insulating film in a pad forming region.

H2. A step of forming an insulating layer on the first interlayer insulating film so as to cover the first wiring.

H3. A step of forming, from the same material, a relay electrode, electrically connected to the first wiring, at a position on the insulating layer that opposes the first wiring and lower electrodes at positions on the insulating layer separated from the relay electrode.

H4. A step of forming a first material film on the insulating layer so as to cover the lower electrodes and the relay electrode all together.

H5. A step of laminating a second material film, with etch selectivity with respect to the first material film, on the first material film.

H6. A step of selectively removing the second material film by dry etching using a resist mask formed on the relay electrode to process the second material film to a second protective film.

H7. A step of selectively removing the first material film by wet etching using the second protective film as a hard mask to process the first material film to a first protective film.

H8. A step of forming a photoabsorption material layer, made of a chalcopyrite compound semiconductor, on the insulating film so as to cover the plurality of lower electrodes and the second protective film all together.

H9. A step of forming a transparent conductive material film on the photoabsorption material layer.

H10. A step of forming a mask on the transparent conductive material film so as to cover a predetermined portion of a sensor forming region that differs from the pad forming region.

H11. A step of selectively removing the transparent conductive material film by wet etching using the mask to process the transparent conductive material film to a transparent conductive film.

H12. A step of selectively removing the photoabsorption material layer by dry etching using the mask to process the photoabsorption material layer to a photoabsorption layer.

H13. A step of removing the mask after the forming of the photoabsorption layer and forming a second interlayer insulating film on and across the insulating layer, the photoabsorption layer, the transparent conductive film, and the second protective film.

H14. A step of forming, on the second interlayer insulating film, an upper electrode electrically connected to the transparent conductive film via a via hole penetrating through the second interlayer insulating film and electrically connected to the relay electrode via a pad opening penetrating through the second interlayer insulating film, the second protective film, and the first protective film.

With the above manufacturing method, for example, the same problem as the abovementioned problem X4 occurs if the step of forming the first protective film (step H7) is not executed.

However, in the present method for manufacturing the photoelectric converter, the first protective film is formed so as to cover the relay electrode in the step H7 before the dry etching of the photoabsorption material layer. The photoabsorption layer is formed by the dry etching of the photoabsorption material layer in the state where the relay electrode is covered by the first protective film. The relay electrode is thus not exposed to the etching gas during the dry etching of the photoabsorption material layer. Consequently, the relay electrode with a satisfactory top surface state being maintained can be made to remain on the insulating layer. Wire bonding strength can thus be improved.

In a case where a protective film that covers the relay electrode is formed by a method in which a material film is laminated on the insulating film so as to cover the relay electrode and wet etching of the material film is performed upon forming a resist mask, covering just a portion that is to become the protective film, on the material film, the area of the resist mask is extremely small in comparison to the area of the material film that is etched and the resist mask may thus peel due to the etching liquid during the wet etching.

On the other hand, with the present method for manufacturing the photoelectric converter, in wet-etching the first material film to process it into the first protective film (step H7), the hard mask (second protective film), which is better in adhesion to the first material film than a resist mask, is used instead of a resist mask and thus the adhesion of the first material film and the mask can be improved. Peeling of the mask due to the etching liquid during the wet etching can be suppressed. Consequently, the first material film can be processed to an ideal shape.

Also, due to the etching gas used in the dry etching of the photoabsorption material layer, a total thickness of the first protective film and the second protective film (these shall be referred to collectively as the “protective film”) that cover the relay electrode is made thinner than when the films were formed, and thus the difference between the thickness of the interlayer insulating film that covers the transparent conductive film and the total thickness of the protective film and the interlayer insulating film that cover the relay electrode is comparatively small. An etching time necessary for forming the pad opening is thus made substantially the same as the etching time necessary for forming the via hole, with which there is no need to etch the protective film. Consequently, in the case of forming the pad opening for contact of the upper electrode and the relay electrode and the via hole for contact of the upper electrode and transparent conductive film in the same step, damage of the transparent conductive film due to etching can be reduced. Lowering of reliability of the photoelectric converter can thus be suppressed.

Also, in the case where the pad opening and the via hole are formed in the same step, the number of steps for manufacturing the photoelectric converter can be decreased and the number of masks necessary for forming the via hole and the pad opening can be reduced in comparison to a case where these are formed in separate steps. Consequently, increases of the time and cost required for manufacture can be suppressed.

Further, by the protective film being made thinner than when it was formed, the total thickness of the protective film and the interlayer insulating film is decreased and the depth of the pad opening can be decreased. The upper electrode can thus be deposited with good coating property even at the step portion between the interior and the exterior of the pad opening.

Also, the mask used in the wet etching for processing the transparent conductive material film to the transparent conductive film is also used in the dry etching for processing the photoabsorption material layer to the photoabsorption layer and a mask used exclusively for the dry etching is not formed. The manufacturing process of the photoelectric converter can thus be simplified.

Also, the combination of the first protective film and the second protective film may be a combination where the first protective film is a silicon oxide film and the second protective film is a silicon nitride film.

Also, a plurality of second wirings may be disposed in the same layer as the first wiring and opposite the respective lower electrodes, and a first via electrically connecting the relay electrode and the first wiring and second vias electrically connecting the lower electrodes and the second wirings may be formed penetratingly in the insulating layer. In this case, the lower electrodes, the relay electrode, the first via, and the second vias are preferably made of the same material. The material may be tungsten. If the lower electrodes, the relay electrode, the first via, and the second vias are made of the same material, the lower electrodes, the relay electrode, the first via, and the second via can be formed in the same step. Thus, the step of polishing the deposition layer of the material of the vias by the CMP method and the step of forming the film made of the material of the lower electrodes by the sputtering method, which are deemed to be required in the manufacture of the conventional photoelectric converter, can be omitted. Consequently, the time and cost required for manufacture can be reduced.

The photoelectric converter of the present structure may be manufactured by a method for manufacture, which includes the following step H15 in addition to the steps H1 to H14 and with which the step of forming the insulating layer is the following step H16 and the step of forming the lower electrodes and the relay electrode include the following steps H17 to H20.

H15. A step of forming second wirings on the interlayer insulating film in the sensor forming region.

H16. (The step of forming the insulating layer is) a step of forming the insulating layer so as to cover both the first and second wirings.

(The step of forming the lower electrodes and the relay electrode includes:)

H17. A step of forming a first via hole penetrating through the insulating layer in a thickness direction and reaching the first wiring and second via holes penetrating through the insulating layer in the thickness direction and reaching the second wirings;

H18. A step of forming a barrier film, made of a material with etch selectivity with respect to the protective film, inside the first and second via holes and on the insulating layer;

H19. A step of embedding tungsten in the first and second via holes and depositing tungsten on the insulating layer to form an electrode material layer; and

H20. A step of patterning the electrode material layer to form the lower electrodes and the relay electrode.

In the step of forming the electrode material layer, the first via hole and the second via holes are completely filled with the material (tungsten) of the lower electrodes.

Then, in the step of forming the lower electrodes and the relay electrode, the second vias connected to the respective lower electrodes and the first via connected to the relay electrode are formed together with the lower electrodes and the relay electrode. Reliable connection of the lower electrodes with the second vias and reliable connection of the relay electrode with the first via can thereby be achieved, and reliability of electrical connection of the lower electrodes and the second vias and reliability of electrical connection of the relay electrode and the first via can be improved.

### Characteristics Apparent from the Preferred Embodiments According to the Ninth Aspect of the Invention

Also preferably, the photoelectric converter according to the present invention further includes a first wiring formed below the insulating layer, an interlayer insulating film formed on and across the insulating layer, the photoabsorption layer, and the transparent conductive film, a pad formed by exposing a portion of the first wiring from a pad opening penetrating through the interlayer insulating film and the insulating layer in a thickness direction outside a region in which the photoabsorption layer is formed, a test electrode used for open/short test of the lower electrodes and formed on the insulating layer so as to be exposed at a side surface of the pad opening, and an upper electrode formed on the interlayer insulating film and electrically connected to the transparent conductive film and the pad.

The present photoelectric converter may be manufactured, for example, by a manufacturing method including the following steps I1 to I12.

I1. A step of forming a first wiring on a first interlayer insulating film in a pad forming region.

I2. A step of forming an insulating layer on the first interlayer insulating film so as to cover the first wiring.

I3. A step of forming, from the same material and on the insulating layer, a test electrode at a position opposing the first wiring and lower electrodes at positions separated from the test electrode.

I4. A step of forming a protective film on the insulating layer so as to cover the test electrodes.

I5. A step of forming a photoabsorption material layer, made of a chalcopyrite compound semiconductor, on the insulating film so as to cover the plurality of lower electrodes and the protective film all together.

I6. A step of forming a transparent conductive material film on the photoabsorption material layer.

I7. A step of forming a mask on the transparent conductive material film so as to cover a predetermined portion of a sensor forming region that differs from the pad forming region.

I8. A step of selectively removing the transparent conductive material film by wet etching using the mask to process the transparent conductive material film to a transparent conductive film.

I9. A step of selectively removing the photoabsorption material layer by dry etching using the mask to process the photoabsorption material layer to a photoabsorption layer.

I10. A step of removing the mask after the forming of the photoabsorption layer and forming a second interlayer insulating film on and across the insulating layer, the photoabsorption layer, the transparent conductive film, and the protective film.

I11. A step of forming a pad opening penetrating through the second interlayer insulating film, the protective film, the test electrode, and the insulating layer to expose a portion of the first wiring as a pad and expose the test electrode at a side surface of the pad opening.

I12. A step of forming an upper electrode, electrically connected to the transparent conductive film and the pad, on the second interlayer insulating film.

With the present manufacturing method, the test electrode for the open/short test of the lower electrodes is exposed inside the pad opening in the middle of manufacture of the photoelectric converter. Thus, if a test pattern is formed between the lower electrode and the test electrode, a voltage can be applied to the exposed test electrode to thereby measure insulation states of the lower electrodes even in the middle of manufacture of the photoelectric converter.

Also, the electrical connection of the upper electrode and the pad is formed not via the test electrode but is formed by the upper electrode directly contacting the pad exposed to the pad opening. The first wiring that is used as the pad is covered at least by the insulating layer, the test electrode, and the protective film during the dry etching of the photoabsorption material layer and is thus not exposed to the etching gas. An upper surface of the first wiring that is exposed as the pad inside the pad opening is thus maintained in a satisfactory state. The upper electrode can thus be connected to the pad with good adhesion inside the pad opening. Consequently, satisfactory reliability of electrical connection of the upper electrode and the pad can be maintained.

Also, the protective film that coats the test electrode is formed, for example, in the step I4 executed before the step I9 of forming the photoabsorption layer by dry etching. Thus, in the step I9, the photoabsorption material layer is dry etched in the state where the test electrode is covered by the protective film. The test electrode is thus not exposed to the etching gas during the dry etching of the photoabsorption material layer. Consequently, damaging of the test electrode by the etching gas can be reduced and loss of the test electrode can be prevented. The test electrode can thus be formed reliably.

Also, the protective film may include a first protective film at a lower side that covers the test electrode and a second protective film formed on the first protective film and having etch selectivity with respect to the first protective film.

The photoelectric converter that includes the first protective film and the second protective film may be manufactured by a manufacturing method in which the step I4 in the steps I1 to I12 includes the following steps I4-1 to I4-4.

I4-1. A step of laminating a first material film on the insulating layer so as to cover the lower electrodes and the test electrode all together.

I4-2. A step of laminating a second material film, having etch selectivity with respect to the first material film, on the first material film.

I4-3. A step of selectively removing the second material film by dry etching using a resist mask formed on the test electrode to process the second material film to a second protective film.

I4-4. A step of selectively removing the first material film by wet etching using the second protective film as a hard mask to process the first material film to a first protective film.

In the present method, in performing the wet etching of the first material film, the hard mask is used as the mask and thus the adhesion of the first material film and the mask can be improved. Peeling of the mask due to the etching liquid can thus be suppressed during the wet etching. Consequently, the first material film can be processed to an ideal shape.

Also, the test electrode may be interposed between the insulating layer and the interlayer insulating film (second interlayer insulating film) and be in the same layer as the lower electrodes. In this case, the test electrode is preferably made of the same material as the lower electrodes. If the lower electrodes and the test electrode are made of the same material, the lower electrodes and the test electrode can be formed in the same step.

Further, a plurality of second wirings may be disposed in the same layer as the first wiring and opposite the respective lower electrodes and vias electrically connecting the lower electrodes and the second wirings may be formed to penetrate through the insulating layer. In this case, the lower electrodes, the test electrode, and the vias are preferably made of the same material. The material may be tungsten.

If the lower electrodes, the test electrode, and the vias are made of the same material, the lower electrodes, the test electrode, and the vias can be formed in the same step. Thus, the step of polishing the deposition layer of the material of the vias by the CMP method and the step of forming the film made of the material of the lower electrodes by the sputtering method, which are deemed to be required in the manufacture of the conventional photoelectric converter, can be omitted. Consequently, the time and cost required for manufacture can be reduced.

### Characteristics Apparent from the Preferred Embodiments According to the Tenth Aspect of the Invention

Also preferably, the photoelectric converter according to the present invention further includes an upper electrode pad wiring formed below the insulating layer, an opening penetrating through the insulating layer in the thickness direction outside a region in which the photoabsorption layer is formed and exposing a portion of the upper electrode pad wiring, and an upper electrode connected to the transparent conductive film, entering inside the opening, and connected to the upper electrode pad wiring inside the opening.

With the present photoelectric converter, the upper electrode pad wiring is formed below the insulating layer. Outside the region in which the photoabsorption layer is formed, the opening that exposes a portion of the upper electrode pad wiring is formed penetratingly in the thickness direction in the insulating layer. The upper electrode enters inside the opening and is connected to the upper electrode pad wiring inside the opening. That is, a pad electrode for relaying the upper electrode and the upper electrode pad wiring is not provided on the insulating layer but the upper electrode is directly connected to the upper electrode pad wiring inside the opening that penetrates through the insulating layer.

If the photoabsorption material layer made of the material of the photoabsorption layer is formed on the insulating layer and patterned to the photoabsorption layer by dry etching and the opening is thereafter formed in the insulating layer, the upper electrode pad wiring will be covered by the insulating layer during the dry etching of the photoabsorption material layer. The top surface of the upper electrode pad wiring can thereby be prevented from being exposed to the etching gas and damaging of the top surface of the upper electrode pad wiring can be prevented during the dry etching of the photoabsorption material layer. Consequently, the top surface of the upper electrode pad wiring is maintained in a satisfactory state and satisfactory electrical connection of the upper electrode and the upper electrode pad wiring can be achieved.

In a case where the photoelectric converter includes a semiconductor substrate and a semiconductor device is formed on the semiconductor substrate, a semiconductor device pad wiring that is not connected to the upper wiring but is electrically connected to the semiconductor device may be formed in the same layer as the upper electrode pad wiring.

Also, the upper electrode pad wiring may be formed between the insulating layer and an interlayer insulating film formed below the insulating layer and may border the insulating layer and the interlayer insulating film.

The above characteristics that are apparent from the disclosures of the respective preferred embodiments according to the first to tenth aspects of the combination may be combined mutually among different preferred embodiments. Also, components expressed in the respective preferred embodiments may be combined within the scope of the present invention.

### DESCRIPTION OF THE SYMBOLS

1A . . . Image sensor, 2A . . . Interlayer insulating film, 6A . . . Lower electrode, 7A . . . Photoabsorption layer, 9A . . . Transparent conductive film, 10A . . . Wiring, 11A . . . Via hole, 12A . . . Via, 31A . . . Tungsten deposition layer, 1B . . . Image sensor, 2B . . . Interlayer insulating film, 4B . . . Lower electrode, 5B . . . Photoabsorption layer, 7B . . . Transparent conductive film, 8B . . . Relay electrode, 9B . . . Protective film, 10B . . . Interlayer insulating film, 11B . . . Via hole, 14B . . . Pad opening, 15B . . . Upper electrode, 19B . . . First wiring, 21B . . . First via, 23B . . . Second wiring, 25B . . . Second via, 27B . . . Barrier film, 28B . . . Tungsten deposition layer, 29B . . . TEOS film, 32B . . . CIGS film, 34B . . . Zinc oxide film, 41B . . . Resist pattern, 42B . . . Resist pattern, 45B . . . Resist pattern, 60B . . . Sensor forming region, 61B . . . Pad forming region, 1C . . . Image sensor, 2C . . . Semiconductor substrate, 8C . . . Substrate contact region, 9C . . . Interlayer insulating film, 13C . . . Lower electrode, 14C . . . Photoabsorption layer, 16C . . . Transparent conductive film, 17C . . . First wiring, 24C . . . Capacitor upper electrode, 28C . . . Capacitor lower electrode, 42C . . . Resist pattern, 49C . . . CIGS film, 51C . . . Zinc oxide film, 60C . . . Sensor forming region, 61C . . . Peripheral wiring region, 1D . . . Image sensor, 2D . . . Interlayer insulating film, 6D . . . Lower electrode, 7D . . . Photoabsorption layer, 8D . . . High-resistance buffer layer, 9D . . . Transparent conductive film, 10D . . . Interlayer insulating film, 11D . . . Via hole, 12D . . . Wiring, 13D . . . Pad, 14D . . . Pad opening, 15D . . . Upper electrode, 16D . . . Extending portion, 32D . . . CIGS film, 33D . . . Cadmium sulfide film, 34D . . . Zinc oxide film, 42D . . . Resist pattern, 71D . . . Side surface, 91D . . . Side surface, 1E . . . Image sensor, 2E . . . Interlayer insulating film, 6E . . . Lower electrode, 7E . . . Photoabsorption layer, 17E . . . Top surface protective film, 25E . . . Water-impermeable thin film, 51E . . . Image sensor, 52E . . . Water-impermeable thin film, 61E . . . Image sensor, 62E . . . Water-impermeable thin film, 71E . . . Image sensor, 72E . . . Water-impermeable thin film, 1F . . . Image sensor, 2F . . . Interlayer insulating film, 3F . . . Interlayer insulating film, 6F . . . Lower electrode, 7F . . . Photoabsorption layer, 9F . . . Transparent conductive film, 11F . . . Via hole, 12F . . . Electrode pad, 14F . . . Pad opening, 15F . . . Upper wiring, 19F . . . Lower wiring, 26F . . . Via, 27F . . . Upper surface (of via), 29F . . . Conductive barrier film, 30F . . . Lower end (of via), 32F . . . CIGS film, 34F . . . Zinc oxide film, 36F . . . Sacrificial layer, 42F . . . Resist pattern, 45F . . . Sensor forming region, 46F . . . Pad forming region, 51F . . . Image sensor, 62F . . . Via, 63F . . . Upper surface (of via), 64F . . . Lower end (of via), 72F . . . Via, 73F . . . Upper surface (of via), 74F . . . Lower end (of via), 82F . . . Via, 83F . . . Upper surface (of via), 84F . . . Lower end (of via), 92F . . . Via, 93F . . . Upper surface (of via), 94F . . . Lower end (of via), 1G . . . Image sensor, 7G . . . Photoabsorption layer, 9G . . . Transparent conductive film, 22G . . . Top surface protective film, 23G . . . Pad opening, 24G . . . Tapered portion, 25G . . . Penetrating portion, 39G . . . Resist pattern, 40G . . . Resist opening, D . . . Step, 1H . . . Image sensor, 2H . . . Interlayer insulating film, 4H . . . Lower electrode, 5H . . . Photoabsorption layer, 7H . . . Transparent conductive film, 8H . . . Relay electrode, 9H . . . Protective film, 10H . . . Interlayer insulating film, 11H . . . Via hole, 14H . . . Pad opening, 15H . . . Upper electrode, 19H . . . First wiring, 20H . . . First via hole, 21H . . . First via, 23H . . . Second wiring, 24H . . . Second via hole, 25H . . . Second via, 28H . . . Tungsten deposition layer, 29H . . . TEOS film, 30H . . . SiN film, 32H . . . CIGS film, 34H . . . Zinc oxide film, 1I . . . Image sensor, 21 . . . Interlayer insulating film, 31 . . . Interlayer insulating film, 41 . . . Lower electrode, 5I . . . Photoabsorption layer, 71 . . . Transparent conductive film, 81 . . . First wiring, 91 . . . Test electrode, 11I . . . Protective film, 121 . . . First protective film, 131 . . . Second protective film, 14I . . . Interlayer insulating film, 161 . . . Pad, 171 . . . Pad opening, 181 . . . Upper electrode, 221 . . . Second wiring, 241 . . . Via, 301 . . . Via, 321 . . . CIGS film, 341 . . . Zinc oxide film, 1J . . . Image sensor, 2J . . . Semiconductor substrate, 3J . . . Interlayer insulating film, 4J . . . Interlayer insulating film, 7J . . . Lower electrode, 8J . . . Photoabsorption layer, 10J . . . Transparent conductive film, 17J . . . Pad wiring, 18J . . . Opening, 19J . . . Upper electrode, 60J . . . Sensor forming region, 61J . . . Pad forming region, 70J . . . Upper electrode pad wiring, 71J . . . Semiconductor device pad wiring, 101J . . . Image sensor, 102J . . . Semiconductor substrate, 103J . . . Interlayer insulating film, 104J . . . Interlayer insulating film, 107J . . . Lower electrode, 108J . . . Photoabsorption layer, 111J . . . Transparent conductive film, 118J . . . Pad wiring, upper electrode pad wiring, semiconductor device pad wiring, 119J . . . Opening, 120J . . . Upper electrode, 160J . . . Sensor forming region, 161J . . . Pad forming region

What is claimed is:

1. A photoelectric converter comprising:
an insulating layer;
a plurality of lower electrodes mutually spaced and disposed on the insulating layer;
a photoabsorption layer made of a chalcopyrite compound semiconductor and formed to cover the plurality of lower electrodes all together; and
a transparent conductive film formed to cover the photoabsorption layer, wherein a side surface of the transparent conductive film is positioned further inward than a side surface of the photoabsorption layer in a plan view.

2. The photoelectric converter according to claim 1, further comprising:
an interlayer insulating film formed on and across the insulating layer, the photoabsorption layer, and the transparent conductive film; and
an upper electrode formed on the interlayer insulating film and electrically connected to the transparent conductive film.

3. The photoelectric converter according to claim 2, wherein the interlayer insulating film borders the side surface of the photoabsorption layer.

4. The photoelectric converter according to claim 2, wherein the side surface of the transparent conductive film is inclined so that as its lower end is approached, the side surface approaches the side surface of the photoabsorption layer.

5. The photoelectric converter according to claim 2, further comprising a high-resistance buffer layer formed at an interface of the photoabsorption layer and the transparent conductive film.

6. The photoelectric converter according to claim 2, wherein on a peripheral edge portion of an upper surface of the transparent conductive film,
a via hole is formed to penetrate through the interlayer insulating film in a thickness direction and
the upper electrode enters inside the via hole and is connected to the transparent conductive film.

7. The photoelectric converter according to claim 2, further comprising:
a wiring formed below the insulating layer; and
a pad formed by exposing a portion of the wiring from a pad opening penetrating continuously through the insulating layer and the interlayer insulating film in the thickness direction outside a region in which the photoabsorption layer is formed; and
wherein the upper electrode enters inside the pad opening and is connected to the pad.
